(19) United States
(12) Patent Application Publication
(10) Pub. No.: US 2025/0393471 A1
(43) Pub. Date: Dec. 25, 2025

(54) COMPOUND AND LIGHT-EMITTING DEVICE

(71) Applicant: SEMICONDUCTOR ENERGY LABORATORY CO., LTD., Atsugi-shi (JP)

(72) Inventors: Kazuki KAJIYAMA, Hadano (JP); Sachiko KAWAKAMI, Atsugi (JP); Tsunenori SUZUKI, Yokohama (JP); Naoaki HASHIMOTO, Sagamihara (JP); Yuki HAYASHI, Atsugi (JP); Satoshi SEO, Sagamihara (JP)

(21) Appl. No.: 19/247,738

(22) Filed: Jun. 24, 2025

(30) Foreign Application Priority Data
Jun. 19, 2024 (JP) 2024-116109
Jul. 5, 2024 (JP) 2024-108609

(51) Int. Cl. H10K 85/60; H10K 50/12; H10K 50/15; H10K 101/30

(52) U.S. Cl. CPC H10K 85/636; H10K 85/633; H10K 50/12; H10K 50/15; H10K 85/626; H10K 85/6574; H10K 2101/30

(57) ABSTRACT

To provide a light-emitting device having favorable characteristics. To provide a novel organic compound. The light-emitting device includes at least a light-emitting layer and a hole-transport layer between a pair of electrodes. The light-emitting layer includes a first compound as a host and a second compound as a guest. The HOMO level of the second compound is higher than the HOMO level of the first compound. The hole-transport layer includes a third compound including deuterium. The third compound is represented by General Formula (G1).

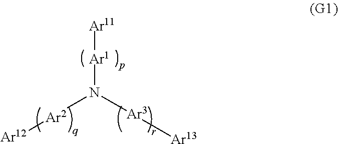

### BACKGROUND OF THE INVENTION

### 1. Field of the Invention

One embodiment of the present invention relates to an organic compound, an organic semiconductor element, a light-emitting device, a light-receiving device, a photodiode sensor, a display module, a lighting module, a display apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Thus, specific examples of the technical field of one embodiment of the present invention disclosed in this specification include a semiconductor device, a display apparatus, a liquid crystal display apparatus, a lighting device, a power storage device, a memory device, an image capturing device, a driving method thereof, and a manufacturing method thereof.

### 2. Description of the Related Art

Organic electroluminescence (EL) devices (organic EL elements), which utilize EL of an organic compound (organic EL) and are typified by light-emitting devices, light-receiving devices, and light-emitting and light-receiving devices, are being put to practical use.

In the basic structure of the light-emitting devices, for example, an organic compound layer including a light-emitting material (an EL layer) is located between a pair of electrodes. Carriers are injected by application of voltage to the device, and recombination energy of the carriers is used to obtain light emission from the light-emitting material.

In the basic structure of the light-receiving devices, an organic compound layer including a photoelectric conversion material (an active layer) is located between a pair of electrodes. This device absorbs light energy to generate carriers, whereby electrons from the photoelectric conversion material can be obtained.

For example, a functional panel in which a pixel provided in a display region includes a light-emitting element (light-emitting device) and a photoelectric conversion element (light-receiving device) is known (Patent Document 1).

Although the characteristics of organic EL devices have been improved considerably, advanced requirements for various characteristics including efficiency and durability are not yet satisfied.

For example, Patent Document 2 discloses a technique for substituting a deuterium atom for a hydrogen atom contained in a host material (a deuteration technique). Deuteration of a host material is effective in increasing the lifetime of a light-emitting device, but complicates the synthesis pathway and greatly increases the cost of raw materials. Another problem is that high temperature and high pressure are needed for the synthesis, for example. Another problem is that a purification step after the synthesis reaction is complicated, so that an organic compound obtained by the deuteration is difficult to purify and cannot have high purity.

### REFERENCES

[Patent Document 1] PCT International Publication No. WO2020/152556
[Patent Document 2] Japanese Translation of PCT International Application No. 2013-503860
[Patent Document 3] Japanese Published Patent Application No. 2017-139457

### SUMMARY OF THE INVENTION

An object of one embodiment of the present invention is to provide a novel light-emitting device. Another object of one embodiment of the present invention is to provide a light-emitting device having high emission efficiency and high reliability.

Another object of one embodiment of the present invention is to provide a method for synthesizing a novel organic compound. Another object of one embodiment of the present invention is to provide a method for deuterating an organic compound. Another object of one embodiment of the present invention is to provide a method for synthesizing a deuterated organic compound. Another object of one embodiment of the present invention is to provide an organic compound having an effect of increasing the lifetime of an organic EL device or a light-receiving device, by a method for synthesizing the organic compound part of which is selectively deuterated. Another object of one embodiment of the present invention is to make a molecular design with which the degree of complexity of a synthesis pathway can be lowered and increases in temperature and pressure in a synthesis condition and the like can be suppressed, and to synthesize an organic compound with such a molecular design.

Another object of one embodiment of the present invention is to provide a novel organic compound. Another object of one embodiment of the present invention is to provide an organic compound that is easy to synthesize. Another object of one embodiment of the present invention is to provide an organic compound that is stable in an excited state. Another object of one embodiment of the present invention is to provide an organic compound that can be used for an organic EL device or a light-receiving device. Another object of one embodiment of the present invention is to provide an organic compound that can be used for a carrier-transport layer of an organic EL device. Another object of one embodiment of the present invention is to provide an organic EL device with a long driving lifetime. Another object of one embodiment of the present invention is to provide an organic compound that can be used for a cap layer of a light-emitting device. Another object of one embodiment of the present invention is to provide a novel organic EL device. Another object of one embodiment of the present invention is to reduce the manufacturing cost of an organic EL device. Another object of one embodiment of the present invention is to provide a light-emitting apparatus, an electronic appliance, or a lighting device having low power consumption.

Note that the description of these objects does not preclude the existence of other objects. In one embodiment of the present invention, there is no need to achieve all the objects. Other objects will be apparent from and can be derived from the description of the specification, the drawings, the claims, and the like.

One embodiment of the present invention is a light-emitting device which includes at least a light-emitting layer and a hole-transport layer between a pair of electrodes and in which the light-emitting layer includes a first compound as a host and a second compound as a guest; a HOMO level of the second compound is higher than a HOMO level of the first compound; and the hole-transport layer includes a third compound including deuterium.

One embodiment of the present invention is a light-emitting device which includes at least a light-emitting layer and a hole-transport layer between a pair of electrodes and in which the light-emitting layer includes a first compound as a host and a second compound as a guest; a HOMO level of the second compound is higher than a HOMO level of the first compound; the hole-transport layer is in contact with the light-emitting layer; and the hole-transport layer includes a third compound including deuterium.

One embodiment of the present invention is a light-emitting device which includes at least a light-emitting layer and a hole-transport layer between a pair of electrodes and in which the light-emitting layer includes a first compound as a host and a second compound as a guest; a HOMO level of the second compound is higher than a HOMO level of the first compound; a difference between the HOMO level of the first compound and the HOMO level of the second compound is greater than 0.30 eV and less than 0.90 eV; the hole-transport layer is in contact with the light-emitting layer; and the hole-transport layer includes a third compound including deuterium.

One embodiment of the present invention is a light-emitting device which includes at least a light-emitting layer and a hole-transport layer between a pair of electrodes and in which the light-emitting layer includes a first compound as a host and a second compound as a guest; the first compound has an electron mobility higher than or equal to 1×10⁻⁷ cm²/Vs when a square root of electric field strength [V/cm] is 600; the hole-transport layer is in contact with the light-emitting layer; and the hole-transport layer includes a third compound including deuterium.

In the above light-emitting device of one embodiment of the present invention, a molecular structure of the third compound includes only one triarylamine skeleton.

In the above light-emitting device of one embodiment of the present invention, the third compound is different from the first compound and the second compound the light-emitting layer includes.

In the above light-emitting device of one embodiment of the present invention, the second compound is a fluorescent compound.

In the above light-emitting device of one embodiment of the present invention, the first compound consists only of carbon and hydrogen.

In the above light-emitting device of one embodiment of the present invention, a molecular structure of the first compound includes an anthracene skeleton.

In the above light-emitting device of one embodiment of the present invention, an electron-transport layer is further provided between the pair of electrodes, and the electron-transport layer has a stacked-layer structure including two or more layers.

In the above light-emitting device of one embodiment of the present invention, an electron-transport layer is further provided between the pair of electrodes, and the electron-transport layer includes no 8-quinolinol metal complex.

One embodiment of the present invention is a light-emitting device which includes at least a light-emitting layer, a hole-transport layer, a first electron-transport layer, and a second electron-transport layer between a pair of electrodes and in which the light-emitting layer includes a first compound as a host and a second compound as a guest; the first electron-transport layer is between the light-emitting layer and the second electron-transport layer; the first electron-transport layer includes a compound including a diazine or triazine skeleton; the second electron-transport layer includes a compound including a phenanthroline skeleton; the hole-transport layer is in contact with the light-emitting layer; and the hole-transport layer includes a third compound including deuterium.

One embodiment of the present invention is a light-emitting device which includes at least a light-emitting layer and a hole-transport layer between a pair of electrodes and in which the light-emitting layer includes a first compound as a host and a second compound as a guest; a molecular structure of the second compound includes a fused heteroaromatic ring including four or more rings; the hole-transport layer is in contact with the light-emitting layer; and the hole-transport layer includes a third compound including deuterium.

One embodiment of the present invention is an organic compound represented by General Formula (G1).

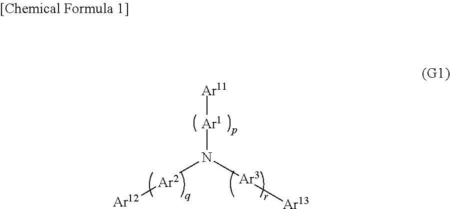

In General Formula (G1), Ar¹ to Ar³ each independently represent a substituted or unsubstituted arylene group having 6 to 30 ring-forming carbon atoms; Ar¹¹ represents a substituted or unsubstituted aryl group having 6 to 30 ring-forming carbon atoms or a substituted or unsubstituted heteroaryl group having 1 to 30 ring-forming carbon atoms; Ar¹² represents a group represented by any one of General Formulae (g1) to (g10) below; p, q, and r each independently represent an integer of 0 to 4; the organic compound represented by General Formula (G1) includes one or more deuteriums; when Ar¹² represents a group represented by General Formula (g1) below, Ar¹³ represents a group represented by any one of General Formulae (g1) to (g10) below; and when Ar¹² represents a group represented by any one of General Formulae (g2) to (g10) below, Ar¹³ represents a substituted or unsubstituted aryl group having 6 to 30 ring-forming carbon atoms or a substituted or unsubstituted heteroaryl group having 1 to 30 ring-forming carbon atoms.

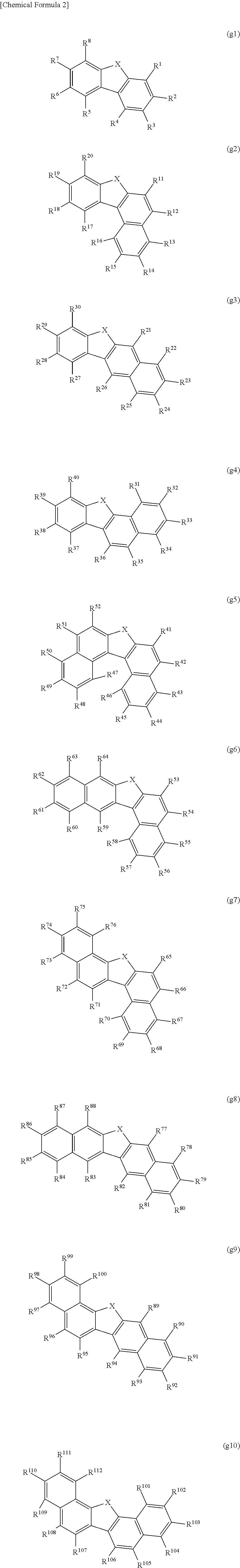

In General Formulae (g1) to (g10), X represents oxygen or sulfur; R¹ to R⁸ and R¹¹ to R¹² each independently represent hydrogen (including deuterium), a straight-chain or branched-chain alkyl group having 1 to 10 carbon atoms, a cycloalkyl group having 3 to 10 carbon atoms, a substituted or unsubstituted aryl group having 6 to 30 carbon atoms, or a substituted or unsubstituted heteroaryl group having 1 to 30 carbon atoms; and any one of R¹ to R⁸, any one of R¹¹ to R²⁰, any one of R²¹ to R³⁰, any one of R³¹ to R⁴⁰, any one of R⁴¹ to R⁵², any one of R⁵³ to R⁶⁴, any one of R⁶⁵ to R⁷⁶, any one of R⁷⁷ to R⁷⁸, any one of R⁸⁹ to R¹⁰², and any one of R¹⁰¹ to R¹¹² each represent a bond with any one of Ar² and Ar³.

One embodiment of the present invention is an organic compound represented by General Formula (G1).

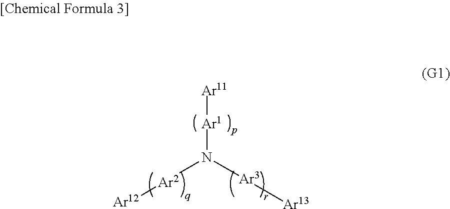

In General Formula (G1), Ar¹ to Ar³ each independently represent a substituted or unsubstituted arylene group having 6 to 30 ring-forming carbon atoms; Ar¹¹ represents a substituted or unsubstituted aryl group having 6 to 30 ring-forming carbon atoms or a substituted or unsubstituted heteroaryl group having 1 to 30 ring-forming carbon atoms; Ar¹² represents a group represented by any one of General Formulae (g1) to (g4) below; p, q, and r each independently represent an integer of 0 to 4; the organic compound represented by General Formula (G1) includes one or more deuteriums; when Ar¹² represents a group represented by General Formula (g1) below, Ar¹³ represents a group represented by any one of General Formulae (g1) to (g4) below; and when Ar¹² represents a group represented by any one of General Formulae (g2) to (g10) below, Ar¹³ represents a substituted or unsubstituted aryl group having 6 to 30 ring-forming carbon atoms or a substituted or unsubstituted heteroaryl group having 1 to 30 ring-forming carbon atoms.

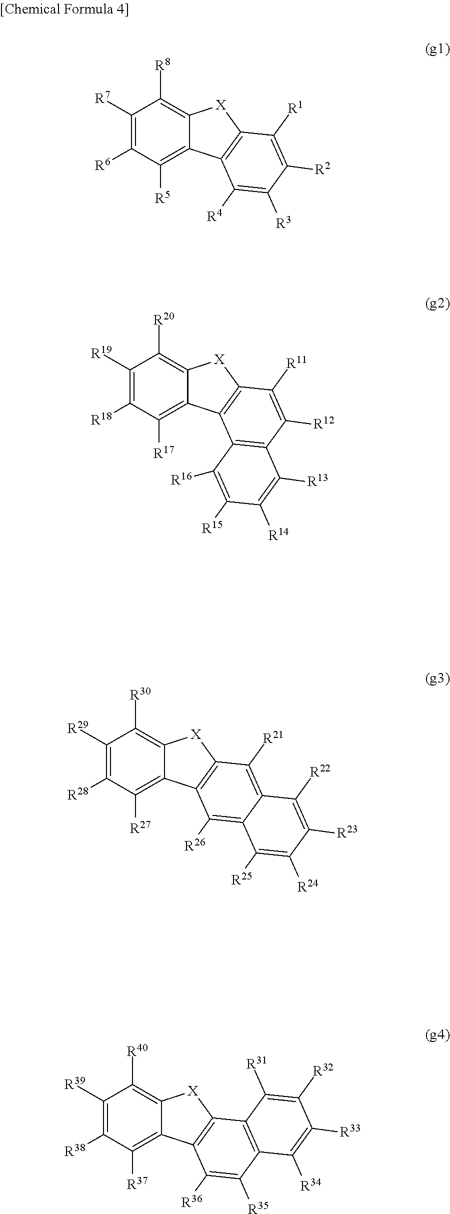

In General Formulae (g1) to (g4), X represents oxygen or sulfur; R¹ to R⁸ and R¹¹ to R⁴⁰ each independently represent hydrogen (including deuterium), a straight-chain or branched-chain alkyl group having 1 to 10 carbon atoms, a cycloalkyl group having 3 to 10 carbon atoms, a substituted or unsubstituted aryl group having 6 to 30 carbon atoms, or a substituted or unsubstituted heteroaryl group having 1 to 30 carbon atoms; and any one of R¹ to R⁸, any one of R¹¹ to R²⁰, any one of R²¹ to R³⁰, and any one of R³¹ to R⁴⁰ each represent a bond with any one of Ar² and Ar³.

One embodiment of the present invention is an organic compound represented by General Formula (G1).

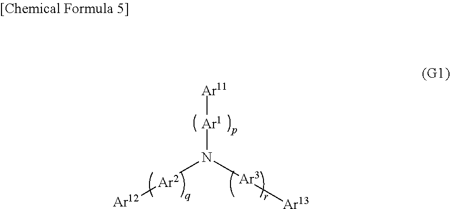

In General Formula (G1), Ar¹ to Ar³ each independently represent a substituted or unsubstituted arylene group having 6 to 30 ring-forming carbon atoms; Ar¹¹ represents a substituted or unsubstituted aryl group having 6 to 30 ring-forming carbon atoms or a substituted or unsubstituted heteroaryl group having 1 to 30 ring-forming carbon atoms; Ar¹² and Ar¹³ each independently represent a group represented by any one of General Formulae (g1) to (g4) below; p, q, and r each independently represent an integer of 0 to 4; and the organic compound represented by General Formula (G1) includes one or more deuteriums.

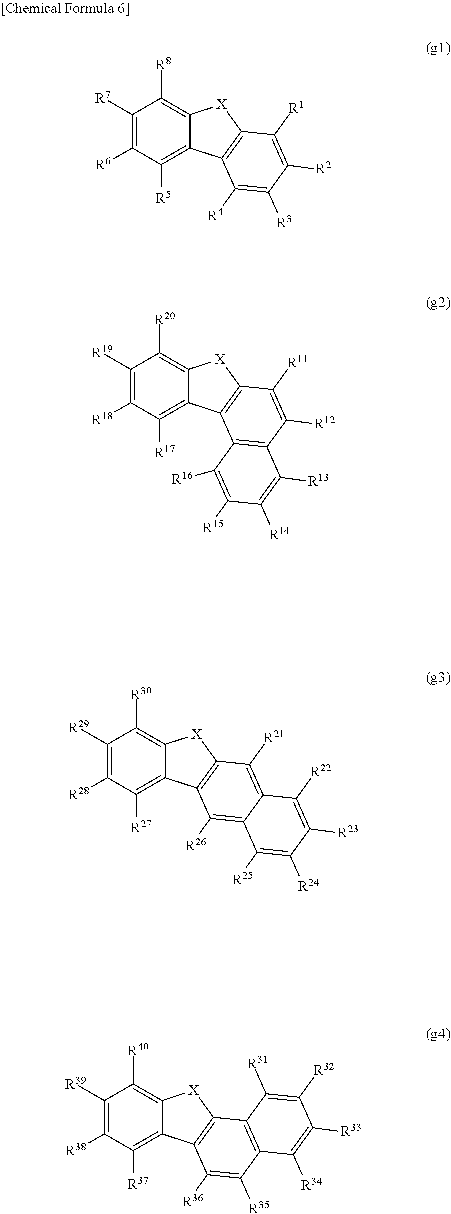

In General Formulae (g1) to (g4), X represents oxygen or sulfur; R¹ to R⁸ and R¹¹ to R⁴⁰ each independently represent hydrogen (including deuterium), a straight-chain or branched-chain alkyl group having 1 to 10 carbon atoms, a cycloalkyl group having 3 to 10 carbon atoms, a substituted or unsubstituted aryl group having 6 to 30 carbon atoms, or a substituted or unsubstituted heteroaryl group having 1 to 30 carbon atoms; and any one of R¹ to R⁸, any one of R¹¹ to R²⁰, any one of R²¹ to R³⁰, and any one of R³¹ to R⁴⁰ each represent a bond with any one of Ar² and Ar³.

One embodiment of the present invention is an organic compound represented by General Formula (G1).

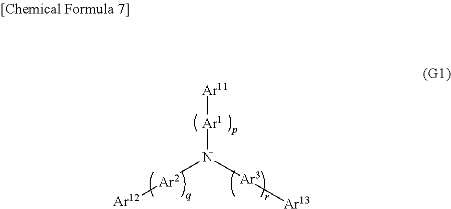

In General Formula (G1), Ar¹ to Ar³ each independently represent a substituted or unsubstituted arylene group having 6 to 30 ring-forming carbon atoms; Ar¹¹ and Ar¹² each independently represent a substituted or unsubstituted aryl group having 6 to 30 ring-forming carbon atoms or a substituted or unsubstituted heteroaryl group having 1 to 30 ring-forming carbon atoms; Ar¹³ represents a group represented by any one of General Formulae (g2) to (g4) below; p, q, and r each independently represent an integer of 0 to 4; and the organic compound represented by General Formula (G1) includes one or more deuteriums.

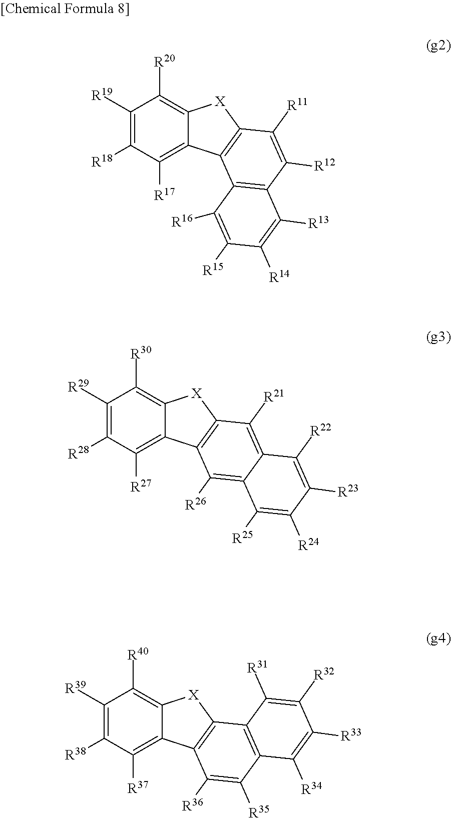

In General Formulae (g2) to (g4), X represents oxygen or sulfur; R¹¹ to R⁴⁰ each independently represent hydrogen (including deuterium), a straight-chain or branched-chain alkyl group having 1 to 10 carbon atoms, a cycloalkyl group having 3 to 10 carbon atoms, a substituted or unsubstituted aryl group having 6 to 30 carbon atoms, or a substituted or unsubstituted heteroaryl group having 1 to 30 carbon atoms; and any one of R¹¹ to R²⁰, any one of R²¹ to R³⁰, and any one of R³¹ to R⁴⁰ each represent a bond with Ar³.

One embodiment of the present invention is an organic compound represented by Structural Formula (100), (101), (152), or (153).

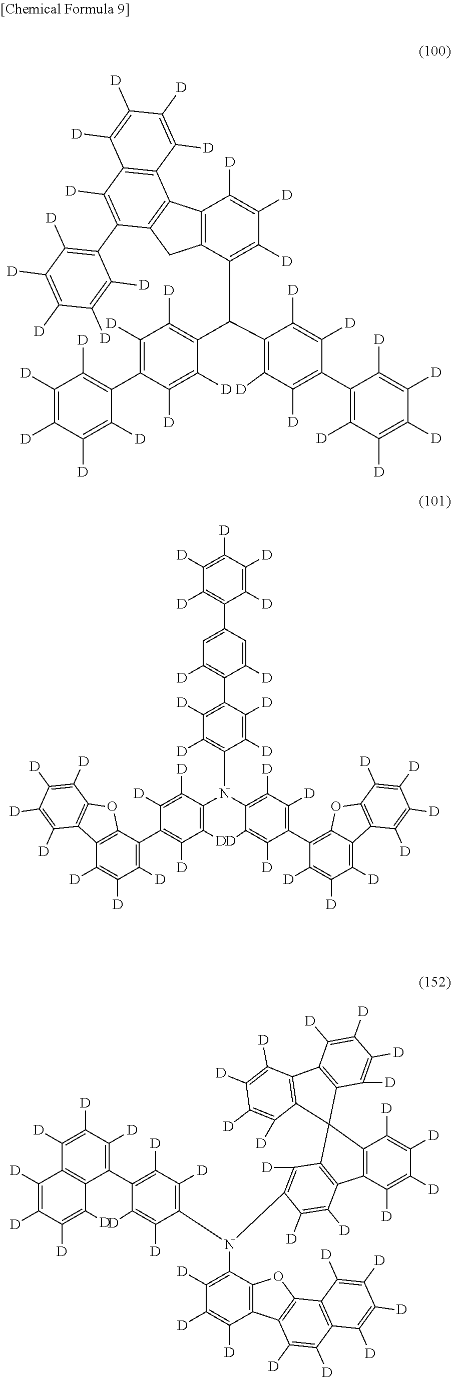

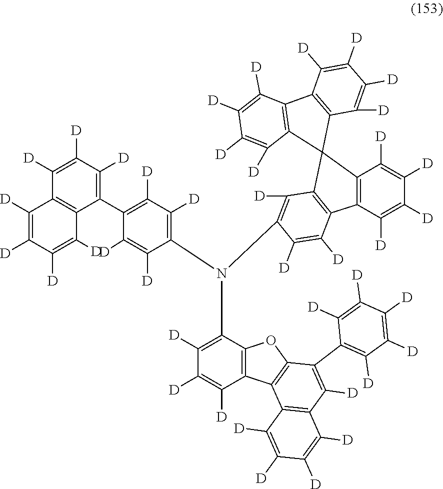 [SMILES: [2H]c1c([2H])c([2H])c(-c2c([2H])c3c([2H])c([2H])c([2H])c([2H])c3c3c2oc2c(N(c4c([2H])c([2H])c(-c5c([2H])c([2H])c([2H])c6c([2H])c([2H])c([2H])c([2H])c56)c([2H])c4[2H])c4c([2H])c([2H])c5c(c4[2H])C4(c6c([2H])c([2H])c([2H])c([2H])c6-c6c([2H])c([2H])c([2H])c([2H])c64)c4c([2H])c([2H])c([2H])c([2H])c4-5)c([2H])c([2H])c([2H])c23)c([2H])c1[2H]]

One embodiment of the present invention is a light-emitting device which includes a pair of electrodes and an organic compound layer and in which the organic compound layer includes an organic compound represented by General Formula (G1).

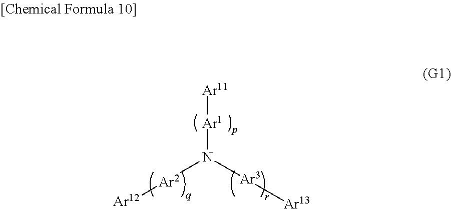

In General Formula (G1), Ar¹ to Ar³ each independently represent a substituted or unsubstituted arylene group having 6 to 30 ring-forming carbon atoms; Ar¹¹ represents a substituted or unsubstituted aryl group having 6 to 30 ring-forming carbon atoms or a substituted or unsubstituted heteroaryl group having 1 to 30 ring-forming carbon atoms; Ar¹² represents a group represented by any one of General Formulae (g1) to (g10) below; p, q, and r each independently represent an integer of 0 to 4; the organic compound represented by General Formula (G1) includes one or more deuteriums; when Ar¹² represents a group represented by General Formula (g1) below, Ar¹³ represents a group represented by any one of General Formulae (g1) to (g10) below; and when Ar¹² represents a group represented by any one of General Formulae (g2) to (g10) below, Ar¹³ represents a substituted or unsubstituted aryl group having 6 to 30 ring-forming carbon atoms or a substituted or unsubstituted heteroaryl group having 1 to 30 ring-forming carbon atoms.

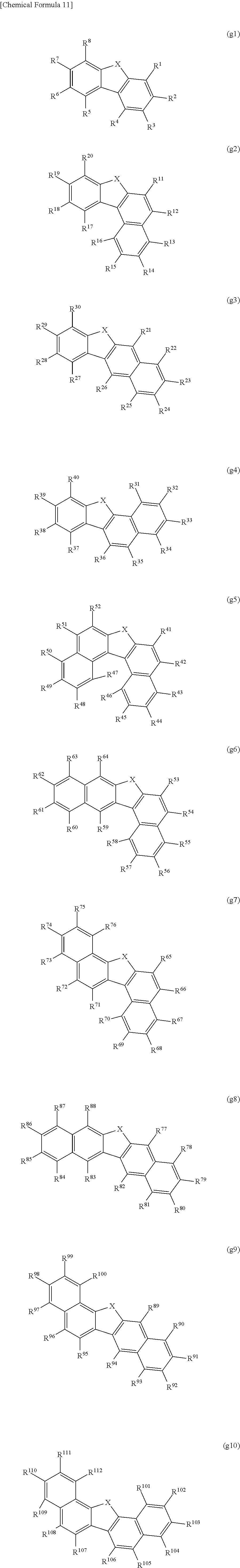

In General Formulae (g1) to (g10), X represents oxygen or sulfur; R¹ to R⁸ and R¹¹ to R¹¹² each independently represent hydrogen (including deuterium), a straight-chain or branched-chain alkyl group having 1 to 10 carbon atoms, a cycloalkyl group having 3 to 10 carbon atoms, a substituted or unsubstituted aryl group having 6 to 30 carbon atoms, or a substituted or unsubstituted heteroaryl group having 1 to 30 carbon atoms; and any one of R¹ to R⁸, any one of R¹¹ to R²⁰, any one of R²¹ to R³⁰, any one of R³¹ to R⁴⁰, any one of R⁴¹ to R⁵², any one of R⁵³ to R⁶⁴, any one of R⁶⁵ to R⁷⁶, any one of R⁷⁷ to R⁸⁸, any one of R⁸⁹ to R¹⁰⁰, and any one of R¹⁰¹ to R¹¹² each represent a bond with any one of Ar² and Ar³.

In the above light-emitting device of one embodiment of the present invention, the organic compound layer is between the pair of electrodes, the organic compound layer includes a light-emitting layer and a hole-transport layer, and the hole-transport layer includes the organic compound represented by General Formula (G1).

In the above light-emitting device of one embodiment of the present invention, the organic compound layer is between the pair of electrodes, the organic compound layer includes a light-emitting layer and a hole-transport layer, the hole-transport layer is in contact with the light-emitting layer, and the hole-transport layer includes the organic compound represented by General Formula (G1).

In the above light-emitting device of one embodiment of the present invention, the organic compound layer is between the pair of electrodes, the organic compound layer includes a light-emitting layer and a hole-transport layer, the light-emitting layer includes a fluorescent compound, and the hole-transport layer includes the organic compound represented by General Formula (G1).

One embodiment of the present invention is a light-receiving device which includes a pair of electrodes and an organic compound layer and in which the organic compound layer includes an organic compound represented by General Formula (G1).

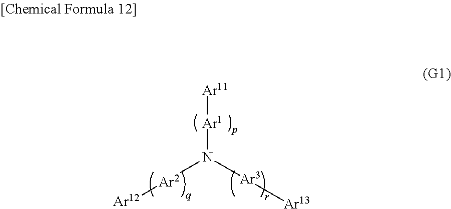

In General Formula (G1), Ar¹ to Ar³ each independently represent a substituted or unsubstituted arylene group having 6 to 30 ring-forming carbon atoms; Ar¹¹ represents a substituted or unsubstituted aryl group having 6 to 30 ring-forming carbon atoms or a substituted or unsubstituted heteroaryl group having 1 to 30 ring-forming carbon atoms; Ar¹² represents a group represented by any one of General Formulae (g1) to (g10) below; p, q, and r each independently represent an integer of 0 to 4; the organic compound represented by General Formula (G1) includes one or more deuteriums; when Ar¹² represents a group represented by General Formula (g1) below, Ar¹³ represents a group represented by any one of General Formulae (g1) to (g10) below; and when Ar¹² represents a group represented by any one of General Formulae (g2) to (g10) below, Ar¹³ represents a substituted or unsubstituted aryl group having 6 to 30 ring-forming carbon atoms or a substituted or unsubstituted heteroaryl group having 1 to 30 ring-forming carbon atoms.

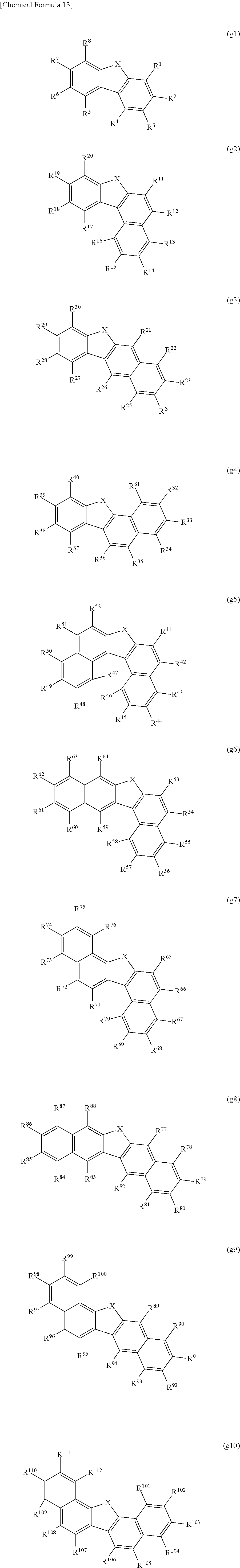

In General Formulae (g1) to (g10), X represents oxygen or sulfur; R¹ to R⁸ and R¹¹ to R¹¹² each independently represent hydrogen (including deuterium), a straight-chain or branched-chain alkyl group having 1 to 10 carbon atoms, a cycloalkyl group having 3 to 10 carbon atoms, a substituted or unsubstituted aryl group having 6 to 30 carbon atoms, or a substituted or unsubstituted heteroaryl group having 1 to 30 carbon atoms; and any one of R¹ to R⁸, any one of R¹¹ to R²⁰, any one of R²¹ to R³⁰, any one of R³¹ to R⁴⁰, any one of R⁴¹ to R⁵², any one of R⁵³ to R⁶⁴, any one of R⁶⁵ to R⁷⁶, any one of R⁷⁷ to R⁸⁸, any one of R⁸⁹ to R¹⁰⁰, and any one of R¹⁰¹ to R¹¹² each represent a bond with any one of Ar² and Ar³.

Another embodiment of the present invention is an electronic appliance including a sensor, an operation button, a speaker, or a microphone, and the above light-emitting device or the above light-receiving device.

Another embodiment of the present invention is a lighting device including a housing and the above light-emitting device or the above light-receiving device.

According to one embodiment of the present invention, a novel light-emitting device can be provided. According to another embodiment of the present invention, a light-emitting device having high emission efficiency and high reliability can be provided.

According to another embodiment of the present invention, a novel organic compound can be provided. According to another embodiment of the present invention, a method for deuterating an organic compound can be provided. According to another embodiment of the present invention, a method for synthesizing a deuterated organic compound. According to another embodiment of the present invention, an organic compound having an effect of increasing the lifetime of an organic EL device or a light-receiving device can be provided by a method for synthesizing the organic compound part of which is selectively deuterated. As a result, the degree of complexity of a synthesis pathway, the equivalent or kind of a reagent used, the temperature and pressure in the synthesis pathway, and the like can be reduced in substitution of deuteriums for some or all of hydrogens of an organic compound.

According to another embodiment of the present invention, an organic compound that is easy to synthesize can be provided. According to another embodiment of the present invention, a method for synthesizing a novel organic compound can be provided. According to another embodiment of the present invention, an organic compound that is stable in an excited state can be provided. According to another embodiment of the present invention, an organic compound that can be used for an organic EL device or a light-receiving device can be provided. According to another embodiment of the present invention, an organic compound that can be used for a carrier-transport layer of an organic EL device can be provided. According to another embodiment of the present invention, an organic compound that can be used for a cap layer of a light-emitting device can be provided. According to another embodiment of the present invention, a novel organic EL device can be provided. According to another embodiment of the present invention, an organic EL device with a long driving lifetime can be provided. According to another embodiment of the present invention, the manufacturing cost of an organic EL device can be reduced. According to another embodiment of the present invention, a light-emitting apparatus, an electronic appliance, or a lighting device having low power consumption can be provided.

Note that the description of these effects does not preclude the existence of other effects. One embodiment of the present invention does not necessarily have all these effects. Other effects will be apparent from and can be derived from the description of the specification, the drawings, the claims, and the like.

### BRIEF DESCRIPTION OF THE DRAWINGS

FIGS. 1A and 1B are schematic diagrams of a light-emitting device.

FIGS. 2A to 2E each illustrate a structure of a light-emitting device.

FIGS. 3A and 3B are a top view and a cross-sectional view, respectively, of a light-emitting apparatus.

FIGS. 4A to 4G are top views each illustrating a structure example of a pixel.

FIGS. 5A to 5I are top views each illustrating a structure example of a pixel.

FIGS. 6A and 6B are perspective views illustrating a structure example of a display module.

FIGS. 7A and 7B are cross-sectional views each illustrating a structure example of a display apparatus.

FIG. 8 is a perspective view illustrating a structure example of a display apparatus.

FIG. 9 is a cross-sectional view illustrating a structure example of a display apparatus.

FIG. 10 is a cross-sectional view illustrating a structure example of a display apparatus.

FIGS. 11A to 11C are a cross-sectional view and top views illustrating structure examples of a display apparatus.

FIG. 12 is a cross-sectional view illustrating a structure example of a display apparatus.

FIGS. 13A to 13C are a cross-sectional view and top views illustrating a structure example of a display apparatus.

FIGS. 14A to 14D illustrate examples of electronic appliances.

FIGS. 15A to 15F illustrate examples of electronic appliances.

FIGS. 16A to 16G illustrate examples of electronic appliances.

FIG. 17 shows absorption and emission spectra of a toluene solution of an organic compound.

FIG. 18 shows absorption and emission spectra of a thin film of an organic compound.

FIG. 19 shows absorption and emission spectra of a toluene solution of an organic compound.

FIG. 20 shows absorption and emission spectra of a thin film of an organic compound.

FIG. 21 illustrates a structure of a light-emitting device.

FIG. 22 shows luminance-current density characteristics of light-emitting devices.

FIG. 23 shows luminance-voltage characteristics of light-emitting devices.

FIG. 24 shows current efficiency-luminance characteristics of light-emitting devices.

FIG. 25 shows current density-voltage characteristics of light-emitting devices.

FIG. 26 shows electroluminescence spectra of light-emitting devices.

FIG. 27 shows a driving time-dependent change in luminance of light-emitting devices.

FIG. 28 shows luminance-current density characteristics of light-emitting devices.

FIG. 29 shows luminance-voltage characteristics of light-emitting devices.

FIG. 30 shows current efficiency-luminance characteristics of light-emitting devices.

FIG. 31 shows current density-voltage characteristics of light-emitting devices.

FIG. 32 shows electroluminescence spectra of light-emitting devices.

FIG. 33 shows a driving time-dependent change in luminance of light-emitting devices.

FIG. 34 shows absorption and emission spectra of a toluene solution of an organic compound.

FIG. 35 shows absorption and emission spectra of a thin film of an organic compound.

FIG. 36 shows absorption and emission spectra of a toluene solution of an organic compound.

FIG. 37 shows absorption and emission spectra of a thin film of an organic compound.

FIG. 38 shows luminance-current density characteristics of light-emitting devices.

FIG. 39 shows luminance-voltage characteristics of light-emitting devices.

FIG. 40 shows current efficiency-luminance characteristics of light-emitting devices.

FIG. 41 shows current density-voltage characteristics of light-emitting devices.

FIG. 42 shows electroluminescence spectra of light-emitting devices.

FIG. 43 shows a driving time-dependent change in luminance of light-emitting devices.

FIG. 44 shows luminance-current density characteristics of light-emitting devices.

FIG. 45 shows luminance-voltage characteristics of light-emitting devices.

FIG. 46 shows current efficiency-luminance characteristics of light-emitting devices.

FIG. 47 shows current density-voltage characteristics of light-emitting devices.

FIG. 48 shows electroluminescence spectra of light-emitting devices.

FIG. 49 shows a driving time-dependent change in luminance of light-emitting devices.

FIG. 50 shows luminance-current density characteristics of light-emitting devices.

FIG. 51 shows luminance-voltage characteristics of light-emitting devices.

FIG. 52 shows current efficiency-luminance characteristics of light-emitting devices.

FIG. 53 shows current density-voltage characteristics of light-emitting devices.

FIG. 54 shows electroluminescence spectra of light-emitting devices.

FIG. 55 shows a driving time-dependent change in luminance of light-emitting devices.

FIG. 56 shows luminance-current density characteristics of light-emitting devices.

FIG. 57 shows luminance-voltage characteristics of light-emitting devices.

FIG. 58 shows current efficiency-luminance characteristics of light-emitting devices.

FIG. 59 shows current density-voltage characteristics of light-emitting devices.

FIG. 60 shows electroluminescence spectra of light-emitting devices.

FIG. 61 shows a driving time-dependent change in luminance of light-emitting devices.

### DETAILED DESCRIPTION OF THE INVENTION

Embodiments of the present invention will be described in detail below with reference to the drawings. Note that the present invention is not limited to the following description, and the modes and details of the present invention can be modified in various ways without departing from the spirit and scope of the present invention. Therefore, the present invention should not be construed as being limited to the description in the following embodiments.

In this specification, the term “deuterated organic compound”, “deuterated compound”, “deuterium compound, or “deuterium-containing organic compound” refers to an organic compound in which, with a focus on hydrogen (including deuterium) present at a certain position(s), the proportion of the hydrogen (including the deuterium) being deuterium is higher than the natural abundance of deuterium. This proportion is preferably adequately higher than the natural abundance. Here, “adequately” means that 7.5% or more of the hydrogen (including the deuterium) has been replaced with deuterium, for example. Note that deuteration of an organic compound can be verified by NMR, mass spectrometry, or the like.

Note that the position, size, range, or the like of each component illustrated in drawings and the like is not accurately represented in some cases for easy understanding. Therefore, the disclosed invention is not necessarily limited to the position, size, range, or the like disclosed in the drawings and the like.

In describing structures of the invention with reference to the drawings in this specification and the like, the same components in different drawings are commonly denoted by the same reference numeral.

### Embodiment 1

In this embodiment, a light-emitting device in which a deuterium-containing organic compound of one embodiment of the present invention is used for a hole-transport layer is described.

### <Structure Example of Light-Emitting Device>

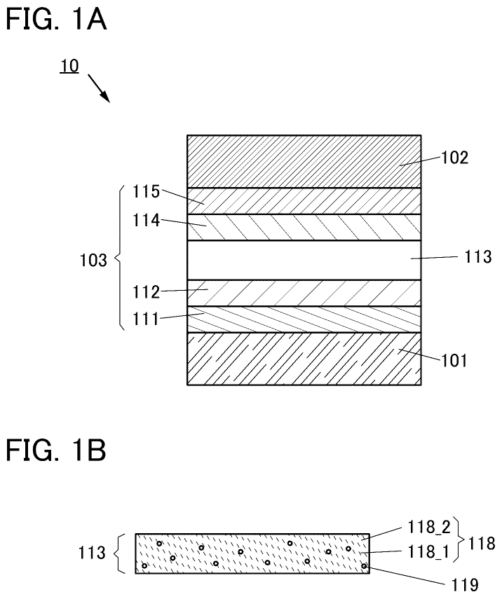

FIG. 1A is a schematic cross-sectional view of a light-emitting device 10 of one embodiment of the present invention. The light-emitting device 10 includes a pair of electrodes (a first electrode 101 and a second electrode 102) and an organic compound layer 103 between the pair of electrodes. The organic compound layer 103 includes at least a light-emitting layer 113. In Embodiment 1, the organic compound layer 103 includes a hole-transport layer 112.

The organic compound layer 103 illustrated in FIG. 1A includes functional layers such as a hole-injection layer 111, the hole-transport layer 112, an electron-transport layer 114, and an electron-injection layer 115, in addition to the light-emitting layer 113.

Although description is given in this embodiment assuming that the first electrode 101 and the second electrode 102 of the pair of electrodes serve as an anode and a cathode, respectively, the structure of the light-emitting device 10 is not limited thereto. That is, the first electrode 101 may be a cathode, the second electrode 102 may be an anode, and the stacking order of the layers between the electrodes may be reversed. In other words, the hole-injection layer 111, the hole-transport layer 112, the light-emitting layer 113, the electron-transport layer 114, and the electron-injection layer 115 may be stacked in this order from the anode side.

The structure of the organic compound layer 103 is not limited to the structure illustrated in FIG. 1A, and a structure including at least one layer selected from the hole-injection layer 111, the hole-transport layer 112, the electron-transport layer 114, and the electron-injection layer 115 may be employed. Alternatively, the organic compound layer 103 may include a functional layer which has a function of lowering a hole- or electron-injection barrier, improving a hole- or electron-transport property, inhibiting a hole- or electron-transport property, or reducing quenching by an electrode, for example. Note that the functional layer may be either a single layer or stacked layers.

FIG. 1B is a schematic cross-sectional view illustrating an example of the light-emitting layer 113 in FIG. 1A. The light-emitting layer 113 illustrated in FIG. 1B includes host materials 118 (an organic compound 118_1 and an organic compound 118_2) and a guest material 119 (a light-emitting substance). Note that the organic compounds 118_1 and 118_2 may be the same compound, in which case the host material 118 used in the light-emitting layer is one kind of material.

As the guest material 119, a light-emitting organic compound is used. As the light-emitting organic compound, either a fluorescent substance (hereinafter also referred to as a fluorescent compound) or a phosphorescent substance (hereinafter also referred to as a phosphorescent compound) is suitably used. Specifically, a light-emitting device exhibiting a blue emission color preferably includes a fluorescent substance as a light-emitting material to have high reliability, and a light-emitting device exhibiting a green emission color and a light-emitting device exhibiting a red emission color each preferably include a phosphorescent compound as a light-emitting material in terms of emission efficiency and power consumption.

In the case where the light-emitting layer 113 includes a phosphorescent compound as the guest material 119, the host materials 118 are present in the largest proportion by weight, and the guest material 119 is dispersed in the host materials 118. Here, the lowest triplet excited levels (T₁ levels) of the host materials 118 (the organic compounds 118_1 and 118_2) in the light-emitting layer 113 are preferably higher than the T₁ level of the guest material 119 in the light-emitting layer 113.

In the case where the light-emitting layer 113 includes a fluorescent compound as the guest material 119, the host materials 118 are present in the largest proportion by weight, and the guest material 119 is dispersed in the host materials 118. The lowest triplet excited levels (T₁ levels) of the host materials 118 (the organic compounds 118_1 and 118_2) in the light-emitting layer 113 are preferably lower than the T₁ level of the guest material 119 in the light-emitting layer 113, in which case the proportion of delayed fluorescent components due to triplet-triplet annihilation (TTA) is increased, and the effect of increasing emission efficiency can be achieved. Note that in the light-emitting device 10 including a fluorescent compound in the light-emitting layer 113, one kind of material may be used as the host material 118 in the light-emitting layer 113; in that case, the organic compounds 118_1 and 118_2 are the same material. Alternatively, in the light-emitting device 10 including a fluorescent compound in the light-emitting layer 113, two kinds of materials can be used as the host materials 118 in the light-emitting layer 113. Further alternatively, two light-emitting layers including the respective host materials to which the same fluorescent compound or different fluorescent compounds is/are dispersed may be stacked. In the case of stacking light-emitting layers, each light-emitting layer may include either one kind of host material or two kinds of host materials.

In the case where a phosphorescent compound is used as the guest material 119, the host materials 118 (the organic compounds 118_1 and 118_2) in the light-emitting layer 113 preferably form an exciplex. Note that an exciplex is an excited state formed by two or more kinds of substances. In photoexcitation, the exciplex is formed by interaction between one substance in an excited state and another substance in a ground state.

Here, the light-emitting device 10 sometimes enters a state of electron excess depending on the structure of the light-emitting layer 113 or the electron-transport layer 114 described above. In a state of electron excess, a carrier recombination region in the light-emitting layer 113 is localized on the hole-transport layer 112 side to be narrowed. Such a state is advantageous in terms of optical interference and can thus increase the emission efficiency. On the other hand, such a state increases the exciton density in the light-emitting layer 113 or makes electrons more likely to reach the hole-transport layer 112, which tends to promote deterioration of the light-emitting device 10.

The present inventors have found that in the light-emitting device 10 under a specific condition causing such an electron excess state, using a deuterated compound for the hole-transport layer 112 enables the light-emitting device 10 to be less likely to deteriorate and highly reliable while achieving high emission efficiency. Hereinafter, the details will be described.

First, holes are trapped by the guest material 119 when the highest occupied molecular orbital (HOMO) level of the guest material 119 is higher than the HOMO level of the host material 118 in the light-emitting layer 113. In such a light-emitting layer 113, injected holes are trapped on the anode side of the light-emitting layer 113 and do not easily move, whereas electrons flow from the cathode side, which easily brings about the above-described state of electron excess. Thus, in one embodiment of the present invention, a layer provided in the vicinity of the light-emitting layer 113, such as the hole-transport layer 112, includes a deuterated compound when the HOMO level of the guest material 119 is higher than the HOMO level of the host material 118. A deuterated compound has increased stability in an excited state or a state of holding carriers; thus, by applying a deuterated compound to the hole-transport layer 112 of the light-emitting device 10 in a state of electron excess, the light-emitting device 10 can have increased reliability.

In such a structure, when the difference between the HOMO level of the guest material 119 and the HOMO level of the host material 118 is greater than 0.30 eV, particularly when the difference is greater than or equal to 0.35 eV or greater than or equal to 0.40 eV, the light-emitting layer 113 has an extremely high hole-trapping property while promising to achieve high emission efficiency. As a result, electrons are more excessively supplied, and a compound included in a layer close to the light-emitting layer 113, such as the hole-transport layer 112, deteriorates more in some cases. Here, by including a deuterated compound in the hole-transport layer 112, the light-emitting device 10 can be highly reliable. Meanwhile, when the hole-trapping property is too high, more electrons reach the hole-transport layer 112 to lower the exciton generation rate in the light-emitting layer 113, which might reduce the emission efficiency. Thus, the difference between the HOMO level of the guest material 119 and the HOMO level of the host material 118 is preferably less than 0.90 eV, further preferably less than or equal to 0.70 eV, still further preferably less than or equal to 0.50 eV. With such a structure, the light-emitting device 10 can have high emission efficiency and high reliability.

Note that the lowest unoccupied molecular orbital (LUMO) level and the HOMO level of a material can be derived from the electrochemical characteristics (the reduction potential and the oxidation potential) of the material. The electrochemical characteristics can be measured by cyclic voltammetry (CV), differential pulse voltammetry (DPV), or the like; in the case of comparing values of different compounds, it is preferable to compare values estimated by the same measurement. The LUMO level or the HOMO level can also be derived by photoelectron spectroscopy, optical absorption spectroscopy, inverse photoelectron spectroscopy, or the like. Note that an apparent end of an absorption spectrum does not necessarily reflect a HOMO-LUMO gap; thus, the levels are preferably estimated using the above-described electrochemical characteristics.

Although the case where the light-emitting layer 113 has a hole-trapping property is described above, the light-emitting device 10 having other structures also easily enters a state of electron excess. For example, the light-emitting device 10 easily enters a state of electron excess in the case where the host material 118 in the light-emitting layer 113 has high electron mobility. Thus, in another embodiment of the present invention, the hole-transport layer 112 includes a deuterated compound in the case where the electron mobility of the host material 118 when the square root of electric field strength [V/cm] is 600 is higher than or equal to 1×10⁻⁷ cm²/Vs. Note that the electron mobility can be measured in a manner similar to a method described in Japanese Published Patent Application No. 2020-096171. As the structure of an electron-only element used for the measurement, an element structure in which electrons are readily injected into the compound subjected to the electron mobility measurement can be selected as appropriate.

In the case where a compound whose molecular structure includes a fused heteroaromatic ring with four or more rings is used as the guest material 119, the guest material 119 readily accepts and transports electrons, easily causing electron excess while promising to achieve high emission efficiency of the light-emitting device 10. That is, electrons easily reach the hole-transport layer 112 and might further degrade a compound included in a layer in contact with the light-emitting layer 113, such as the hole-transport layer 112. Thus, in another embodiment of the present invention, a layer in contact with the light-emitting layer 113, the hole-transport layer 112, or the like includes a deuterated compound when the light-emitting layer 113 has such a structure, whereby deterioration of the hole-transport layer 112 due to electrons is inhibited. This structure enables high emission efficiency while inhibiting deterioration over time due to driving of the light-emitting device 10.

The light-emitting device 10 sometimes enters a state of electron excess in the case where the electron-transport layer 114 has a stacked-layer structure of two or more layers, i.e., in the case where the electron-transport layer 114 includes at least a first electron-transport layer and a second electron-transport layer and the first electron-transport layer is provided between the light-emitting layer 113 and the second electron-transport layer. In this case, it is particularly preferable that the first electron-transport layer include a compound with a diazine or triazine skeleton and the second electron-transport layer include a compound with a phenanthroline skeleton to enable the light-emitting device 10 to have a low driving voltage. This structure enables the light-emitting device to have low power consumption; meanwhile, such a structure has an extremely high electron-transport property, easily causing the light-emitting device 10 to enter a state of electron excess. Thus, in another embodiment of the present invention, the hole-transport layer 112 includes a deuterated compound when the electron-transport layer 114 has such a structure in the light-emitting device 10, whereby both low power consumption and high reliability can be achieved.

In the case where the difference between the LUMO level of the host material 118 in the light-emitting layer 113 and the LUMO level of a material included in the electron-transport layer 114 in contact with the light-emitting layer 113 is small, the property of injecting electrons from the electron-transport layer 114 into the light-emitting layer 113 is high, readily causing electron excess. Specifically, in the case where the difference between the LUMO level of the host material 118 in the light-emitting layer 113 and the LUMO level of the material included in the electron-transport layer 114 in contact with the light-emitting layer 113 is less than or equal to 0.25 eV, the electron-injection property is extremely high; thus, using a deuterium compound for the hole-transport layer 112 in the light-emitting device 10 having such a structure can achieve high emission efficiency while inhibiting luminance degradation due to driving of the light-emitting device 10.

Here, in Embodiment 1, when the hole-transport layer 112 includes a stack of two or more layers with different structures, a layer that is in contact with the light-emitting layer 113 particularly preferably includes a deuterated compound. This is because, in the hole-transport layer 112 of the light-emitting device 10 in a state of electron excess as described above, the layer that is in contact with the light-emitting layer 113 is readily affected by degradation due to electrons.

Note that the hole-transport layer 112 preferably includes a material different from a material included in the light-emitting layer 113. In the case where the hole-transport layer 112 and the light-emitting layer 113 include the same material, electrons injected into the light-emitting layer 113 easily move to the adjacent hole-transport layer 112, sometimes inducing a decrease in emission efficiency or deterioration of the hole-transport layer 112. However, in the case where the hole-transport layer 112 and the light-emitting layer 113 include different materials, holes and electrons can be prevented from moving to the hole-transport layer 112, so that the emission efficiency can be increased. When the hole-transport layer 112 and the light-emitting layer 113 include different materials, the light-emitting device 10 can have favorable carrier balance and high efficiency.

The deuterated compound used for the hole-transport layer 112 is preferably an aromatic amine compound. In particular, a compound whose molecular structure has only one triarylamine skeleton is preferable. Such a compound tends to have a deeper HOMO level than a compound such as a diamine or a triamine, thereby facilitating injection of holes into the light-emitting layer 113; thus, such a compound is suitable for the light-emitting device 10 in a state of electron excess, in terms of reliability. Furthermore, a compound having a diamine or triamine structure tends to have a high evaporation temperature and is thus likely to be decomposed by heat during deposition by evaporation. Decomposition of a compound presumably lowers the purity of a film formed by depositing the compound by evaporation and reduces the reliability of the light-emitting device 10. Meanwhile, the evaporation temperature of a compound with only one triarylamine skeleton tends to be adequately lower than the decomposition temperature of the compound; thus, a film formed by depositing the compound by evaporation can have high purity, enabling the light-emitting device 10 to be highly reliable.

Non-limiting examples of the deuterated compound used for the hole-transport layer 112 include compounds represented by Structural Formulae (400) to (426) below and compounds described later in Embodiment 2 (an organic compound represented by General Formula (G1) and specific examples thereof).

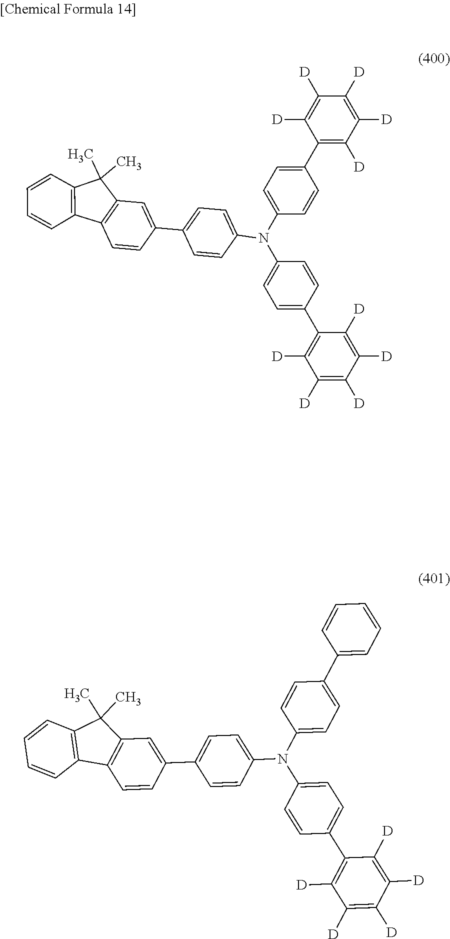

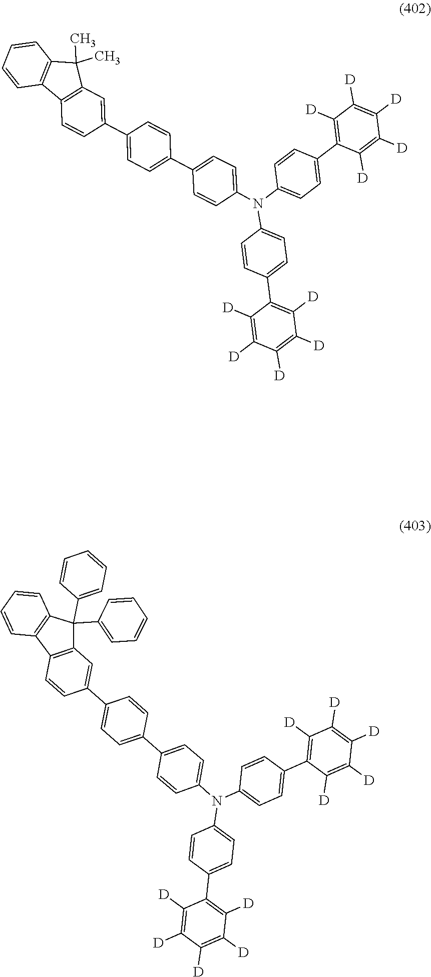

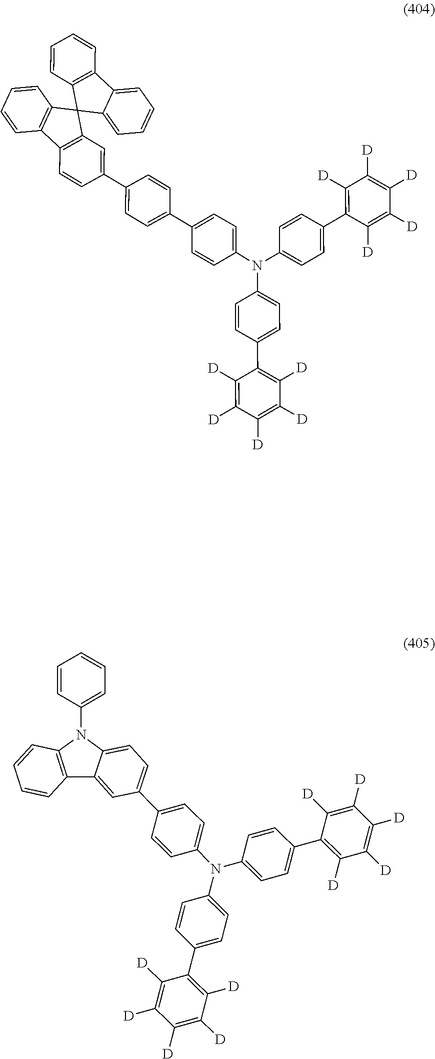

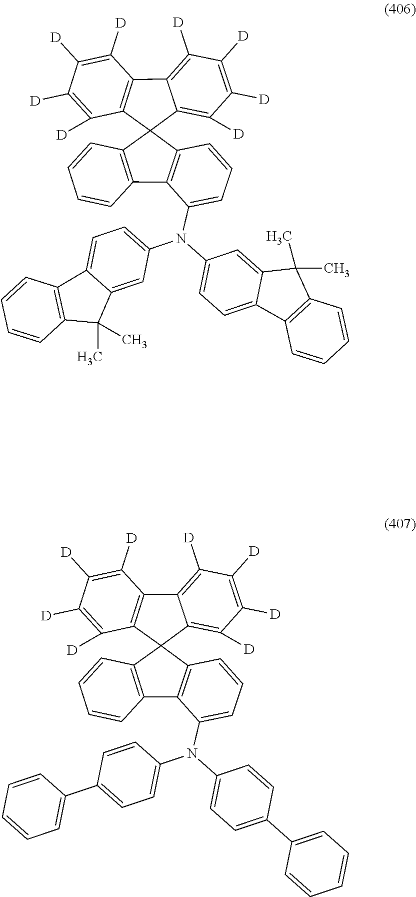

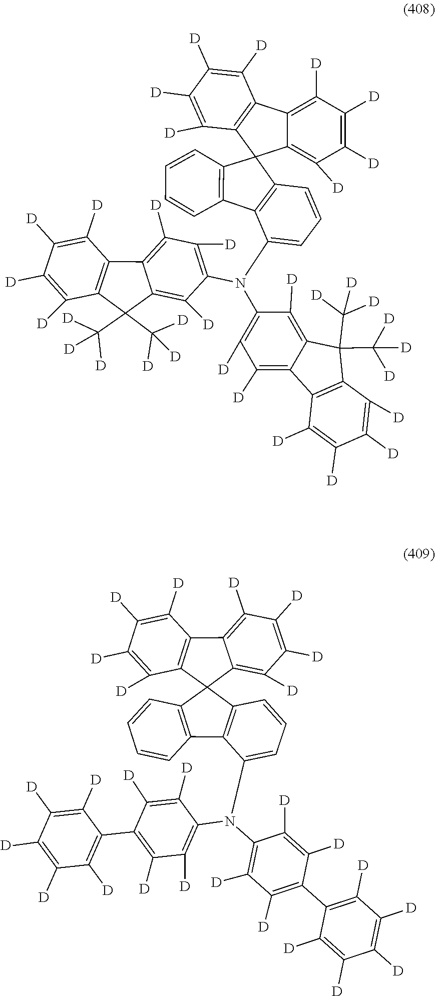

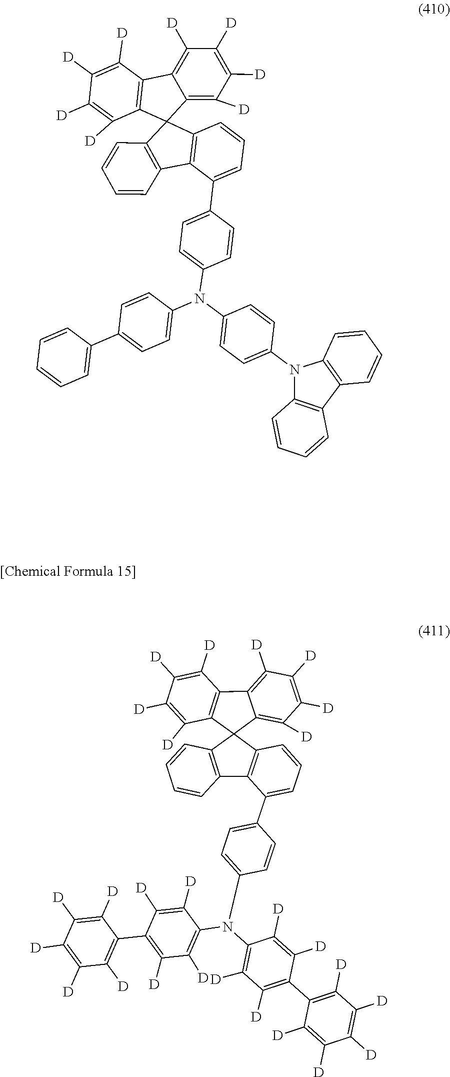

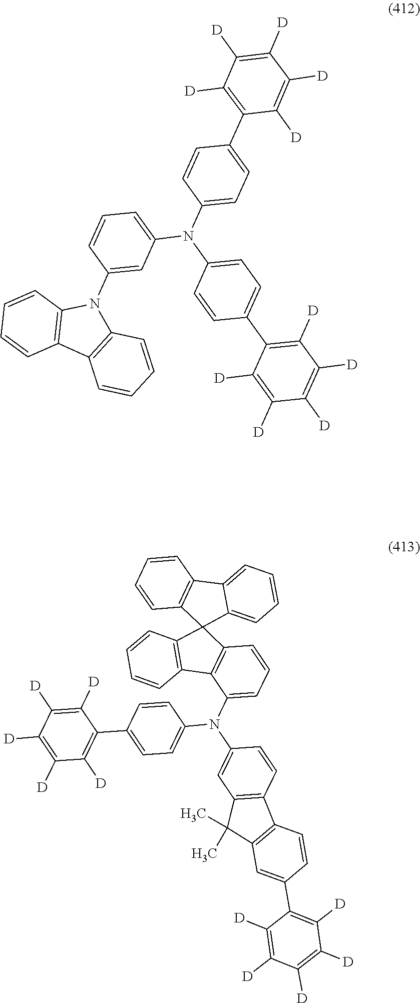

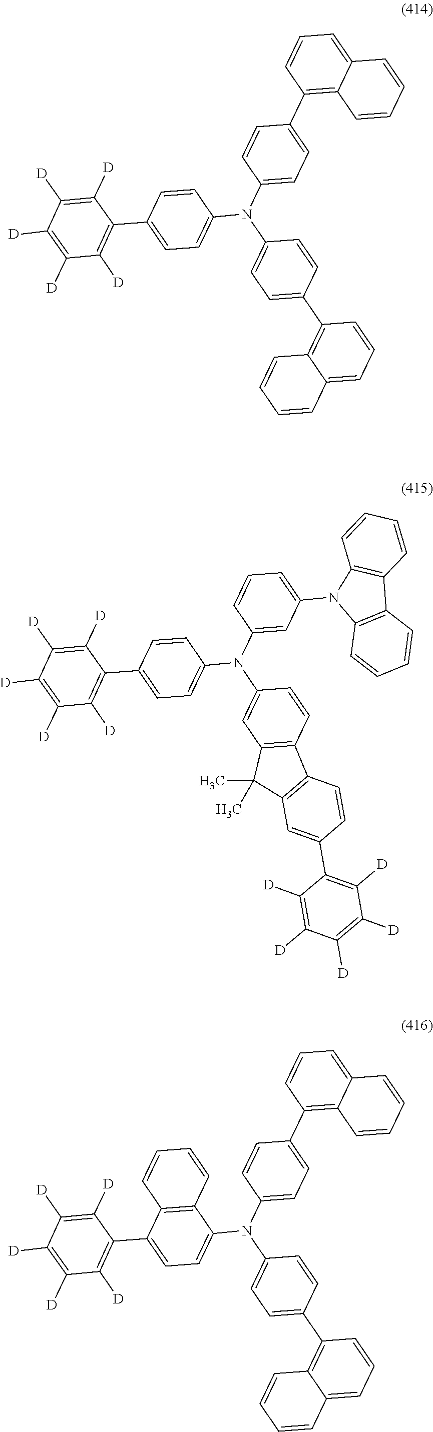

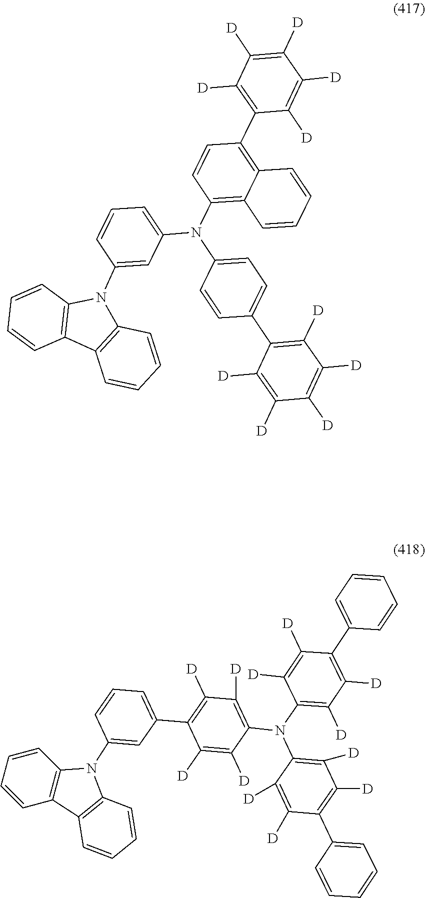

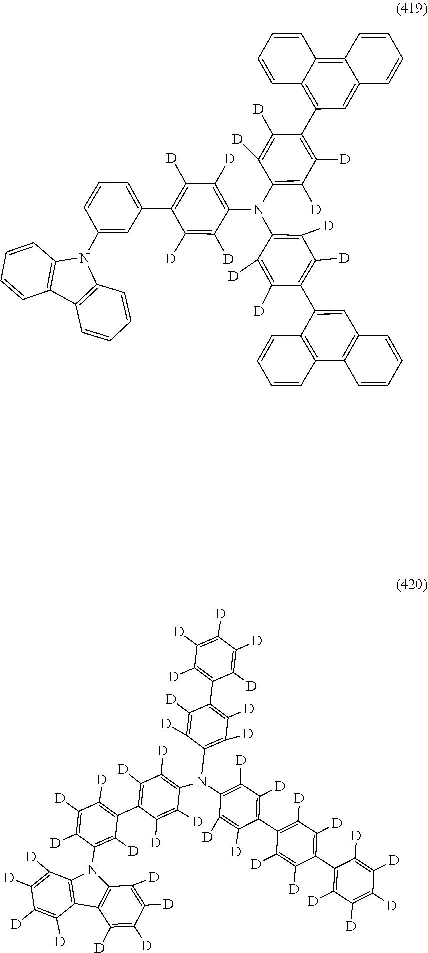

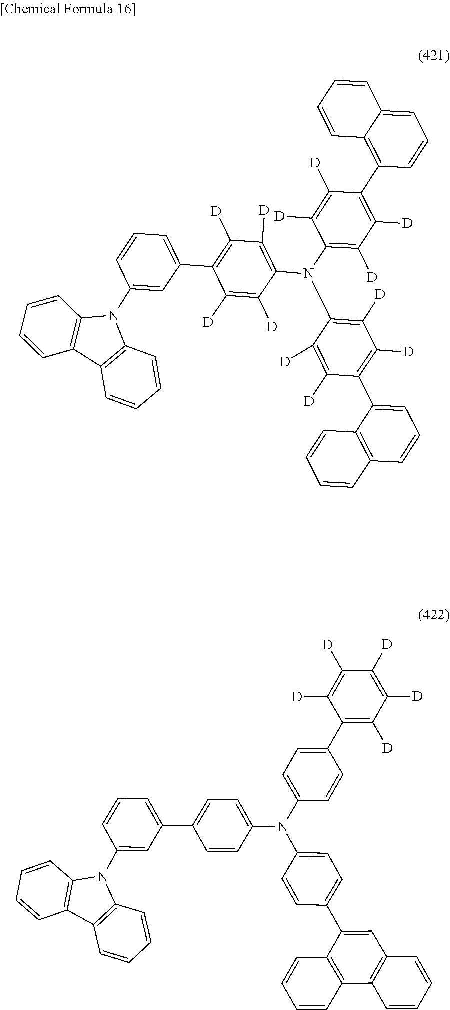

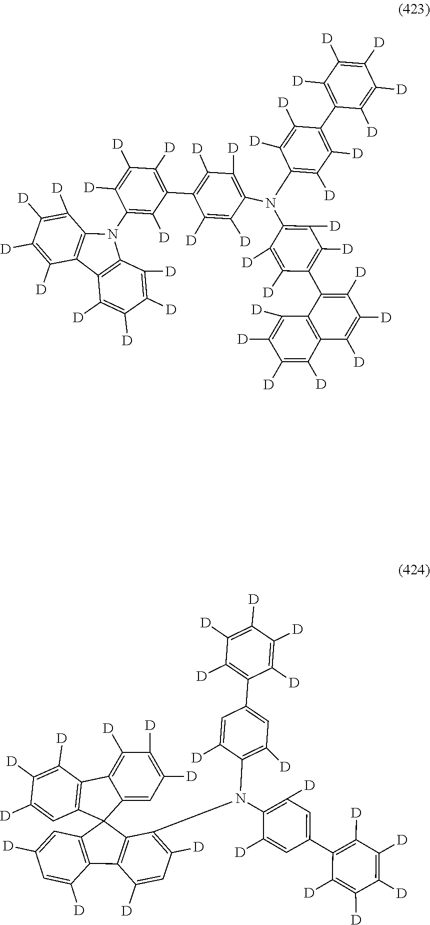

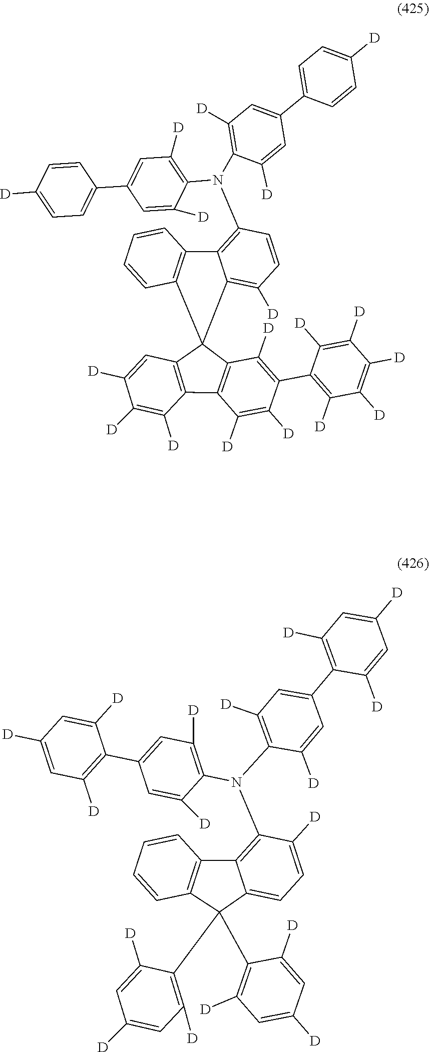

Here, in the light-emitting device 10 in a state of electron excess as described above, the recombination region in the light-emitting layer 113 is narrowed and the exciton density is increased. As a result, TTA described above is likely to occur and the emission efficiency is increased in the case of using a fluorescent compound. Thus, in the above structure, the guest material 119 is preferably a fluorescent compound. In the case where a fluorescent compound is used as the guest material 119, a compound consisting only of carbon and hydrogen is suitably used as the host material 118 to improve the reliability. When a compound whose molecular structure has an anthracene skeleton is used as the host material 118, TTA easily occurs and the emission efficiency can be increased. In addition, a compound with an anthracene skeleton has high electrochemical stability and can excite a blue-light-emitting guest material; thus, the compound is suitable as a host material of a blue-light-emitting device. While being suitable as a host material as described above, a compound with an anthracene skeleton has a high electron-transport property, and holes do not easily enter the compound, easily causing electron excess. Thus, using a deuterated compound for the hole-transport layer 112 can inhibit deterioration caused by the electron excess, while taking the advantage of using a compound with an anthracene skeleton as the host material 118. In view of the above, the light-emitting device 10 where the host material 118 is an anthracene compound, which consists only of carbon and hydrogen, is particularly favorable.

Note that also in the case where the electron-transport layer 114 has a stacked-layer structure, using a deuterated compound for the hole-transport layer 112 can enhance the effect of increasing the reliability.

In the case where separate coloring by a photolithography method is employed, the organic compound layer 103 is sometimes exposed to an etchant. Here, when the electron-transport layer 114 includes an 8-quinolinol metal complex, the 8-quinolinol metal complex might be etched, which is not desirable. Therefore, it is preferable that the organic compound layer 103 not include an 8-quinolinol metal complex. It is particularly preferable that the electron-transport layer 114 not include an 8-quinolinol metal complex.

Note that the description in the following embodiments and examples can be referred to for other light-emitting device structures. That is, this embodiment can be freely combined with any of the other embodiments and the examples.

### Embodiment 2

In this embodiment, organic compounds of embodiments of the present invention will be described.

### <Example of Organic Compound>

### <<Example 1 of Organic Compound>>

One embodiment of the present invention is an organic compound represented by General Formula (G1).

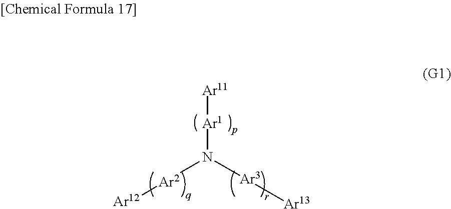

In General Formula (G1), Ar¹ to Ar³ each independently represent a substituted or unsubstituted arylene group having 6 to 30 ring-forming carbon atoms; Ar¹¹ represents a substituted or unsubstituted aryl group having 6 to 30 ring-forming carbon atoms or a substituted or unsubstituted heteroaryl group having 1 to 30 ring-forming carbon atoms; Ar¹² represents a group represented by any one of General Formulae (g1) to (g10) below; and p, q, and r each independently represent an integer of 0 to 4. The organic compound represented by General Formula (G1) includes one or more deuteriums. When Ar¹² represents a group represented by General Formula (g1) below, Ar¹³ represents a group represented by any one of General Formulae (g1) to (g10) below. When Ar¹² represents a group represented by any one of General Formulae (g2) to (g10) below, Ar¹³ represents a substituted or unsubstituted aryl group having 6 to 30 ring-forming carbon atoms or a substituted or unsubstituted heteroaryl group having 1 to 30 ring-forming carbon atoms.

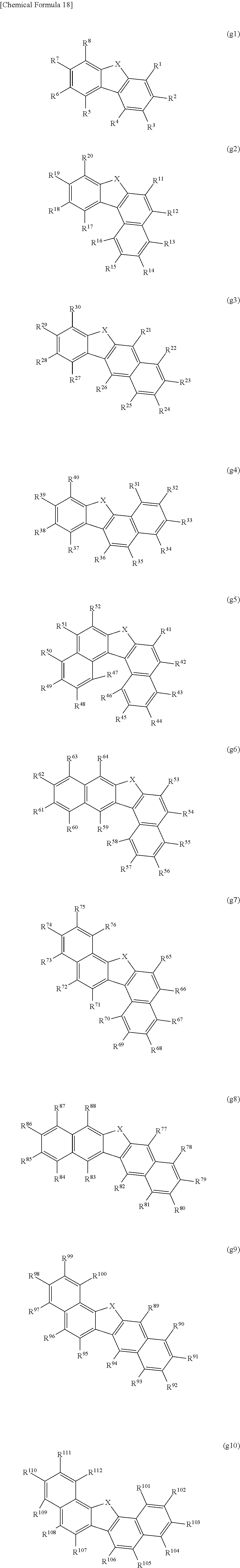

In General Formulae (g1) to (g10), X represents oxygen or sulfur, and R¹ to R⁸ and R¹¹ to R¹¹² each independently represent hydrogen (including deuterium), a straight-chain or branched-chain alkyl group having 1 to 10 carbon atoms, a cycloalkyl group having 3 to 10 carbon atoms, a substituted or unsubstituted aryl group having 6 to 30 carbon atoms, or a substituted or unsubstituted heteroaryl group having 1 to 30 carbon atoms. Note that any one of R¹ to R⁸, any one of R¹¹ to R²⁰, any one of R²¹ to R³⁰, any one of R³¹ to R⁴⁰, any one of R⁴¹ to R⁵², any one of R⁵³ to R⁶⁴, any one of R⁶⁵ to R⁷⁶, any one of R⁷⁷ to R⁸⁸, any one of R⁸⁹ to R¹⁰⁰, and any one of R¹⁰¹ to R¹¹² each represent a bond with any one of Ar² and Ar³.

In particular, when Ar¹² represents a group represented by any one of General Formulae (g1) to (g4), the organic compound has a high hole-transport property and high heat resistance and can be suitably used for a light-emitting device.

The group represented by any one of General Formulae (g1) to (g10) and substituted for Ar¹² or Ar¹³ preferably includes deuterium, in which case the organic compound represented by General Formula (G1) is less likely to deteriorate, and a light-emitting device including the organic compound can be highly reliable. In the case where the organic compound represented by General Formula (G1) is used in a light-emitting device, the organic compound enters a state of accepting a carrier such as a hole or an electron or an excited state with carriers recombined. The molecular structure of the organic compound in either state is more likely to be broken down than the molecular structure of the organic compound in a state without carriers or a ground state. Here, a carbon-deuterium bond is more stable than a carbon-hydrogen bond; thus, in the case where the group represented by any one of General Formulae (g1) to (g10) includes deuterium, bond dissociation is less likely to occur, leading to a more stable molecular structure. By including this organic compound, a light-emitting device can be highly reliable.

In the case where the arylene group substituted for Ar¹ includes deuterium, the molecular structure is stable owing to a carbon-deuterium bond, which is less likely to be cut than a carbon-hydrogen bond, and thus, the organic compound can be suitably used for a highly reliable light-emitting device. Specifically, when the organic compound accepts holes, the holes are highly likely to be localized at Ar¹, which is bonded to a nitrogen atom. It is thus presumable that the effect of the deuteration is enhanced in the case where the arylene group substituted for Ar¹ includes deuterium.

At least one set among a set of Ar¹ and Ar¹, a set of Ar² and Ar¹², and a set of Ar³ and Ar¹³ preferably includes a group in which a plurality of benzene rings are bonded to each other. In other words, at least one of the three groups bonded to the nitrogen (N) in General Formula (G1) preferably includes a group in which a plurality of benzene rings are bonded to each other. For example, a biphenyl group or a terphenyl group is preferable. Examples of a biphenyl group include a para-biphenyl group, a meta-biphenyl group, and an ortho-biphenyl group. When a para-biphenyl group is included, the glass transition temperature (Tg) can be increased. When a meta-biphenyl group or an ortho-biphenyl group is included, the solubility of a material is improved, facilitating the synthesis and purification. The same applies to a biphenyl group or a biphenylene group included in a terphenyl group. A terphenyl group is preferably included, in which case the Tg can be further increased.

Two of Ar¹¹, Ar¹², and Ar¹³ preferably have the same skeleton to reduce the raw material cost and the number of synthesis steps.

Furthermore, Ar¹² and Ar¹³ preferably have the same skeleton to reduce the raw material cost and the number of synthesis steps.

It is preferable that at least one of Ar¹¹, Ar¹², and Ar¹³ include deuterium. It is further preferable that two of Ar¹, Ar¹², and Ar¹³ include deuterium. It is still further preferable that all of Ar¹¹, Ar¹², and Ar¹³ include deuterium. When the compound includes more deuterium-containing groups, the compound can be more stable and can be inhibited from deteriorating, and moreover, a light-emitting device including the compound can be more reliable. At least one of Ar¹¹, Ar¹², and Ar¹³ preferably includes a plurality of deuteriums; specifically, it is preferable that six or more of hydrogens be deuteriums, it is further preferable that ten or more of hydrogens be deuteriums, and it is still further preferable that half or more of hydrogens be deuteriums. It is particularly preferable that all hydrogens be deuteriums. The expression “all hydrogens are deuteriums” means that all of R¹¹ to R²⁰ represent deuteriums in General Formula (g2) above, for example. In addition, when at least one of R¹¹ to R²⁰ represent a substituent, the expression means that all hydrogens in the substituent are deuteriums. The same applies to the other general formulae. A larger number of deuteriums lead to higher stability of the compound.

The stability of the compound can be further increased when the structure in which at least one of Ar¹¹, Ar¹², and Ar¹³ includes a larger number of deuteriums is combined with the above-described structure in which a larger number of groups among Ar¹¹, Ar¹² and Ar¹³ include deuteriums.

Only some hydrogens of the compound may be deuteriums. In the case where only some hydrogens are deuteriums, the manufacturing cost can be reduced because a raw material including deuterium is expensive. In the case where only some hydrogens of the compound are deuteriums, it is preferable that at least one of Ar¹, Ar², Ar³, Ar¹¹, Ar¹², and Ar¹³ include deuterium. For example, it is preferable that the group represented by any one of General Formulae (g1) to (g10) include deuterium.

At least one of Ar¹¹, Ar¹², and Ar¹³ preferably has a fused ring with three or more rings. When the fused ring is included, the heat resistance of the compound can be increased. Note that when the fused ring has a large number of rings, the compound is less soluble and is difficult to synthesize and purify, which is not preferable for high purification. Thus, the number of rings in the fused ring is greater than or equal to 3 and less than or equal to 5, preferably greater than or equal to 3 and less than or equal to 4.

### <<Example 2 of Organic Compound>>

One embodiment of the present invention is an organic compound represented by General Formula (G1).

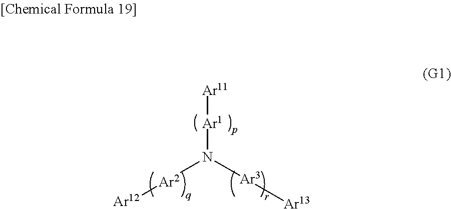

In General Formula (G1), Ar¹ to Ar³ each independently represent a substituted or unsubstituted arylene group having 6 to 30 ring-forming carbon atoms, Ar¹¹ represents a substituted or unsubstituted aryl group having 6 to 30 ring-forming carbon atoms or a substituted or unsubstituted heteroaryl group having 1 to 30 ring-forming carbon atoms, Ar¹² and Ar¹³ each independently represent a group represented by any one of General Formulae (g1) to (g4) below, and p, q, and r each independently represent an integer of 0 to 4. The organic compound represented by General Formula (G1) includes one or more deuteriums.

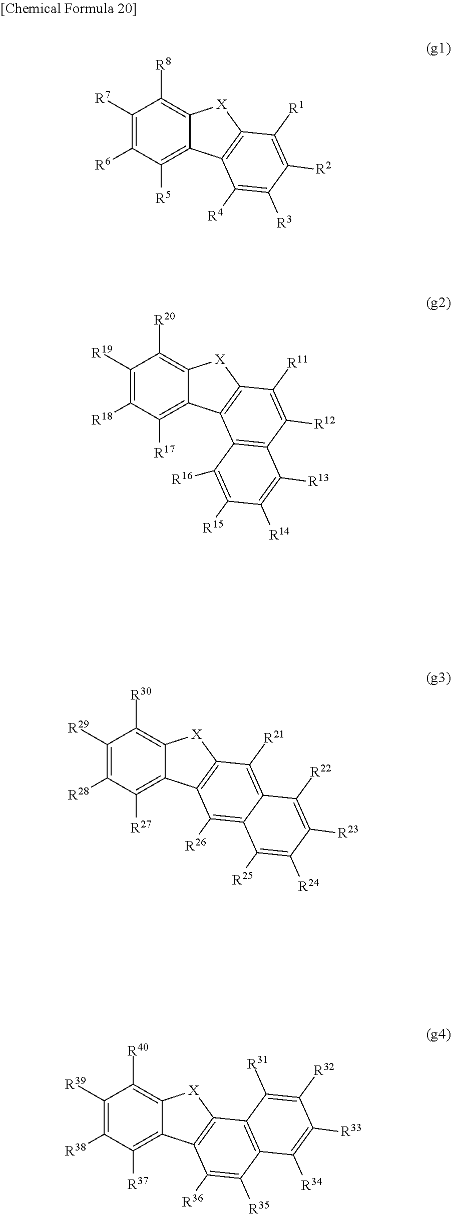

In General Formulae (g1) to (g4), X represents oxygen or sulfur, and R¹ to R⁸ and R¹¹ to R⁴⁰ each independently represent hydrogen (including deuterium), a straight-chain or branched-chain alkyl group having 1 to 10 carbon atoms, a cycloalkyl group having 3 to 10 carbon atoms, a substituted or unsubstituted aryl group having 6 to 30 carbon atoms, or a substituted or unsubstituted heteroaryl group having 1 to 30 carbon atoms. Note that any one of R¹ to R⁸, any one of R¹¹ to R²⁰, any one of R²¹ to R³⁰, and any one of R³¹ to R⁴⁰ each represent a bond with any one of Ar² and Ar³.

### <<Example 3 of Organic Compound>>

One embodiment of the present invention is an organic compound represented by General Formula (G1).

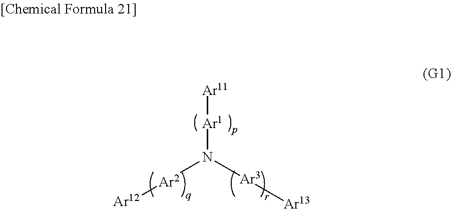

In General Formula (G1), Ar¹ to Ar³ each independently represent a substituted or unsubstituted arylene group having 6 to 30 ring-forming carbon atoms, Ar¹¹ and Ar¹² each independently represent a substituted or unsubstituted aryl group having 6 to 30 ring-forming carbon atoms or a substituted or unsubstituted heteroaryl group having 1 to 30 ring-forming carbon atoms, Ar¹³ represents a group represented by any one of General Formulae (g2) to (g4) below, and p, q, and r each independently represent an integer of 0 to 4. The organic compound represented by General Formula (G1) includes one or more deuteriums.

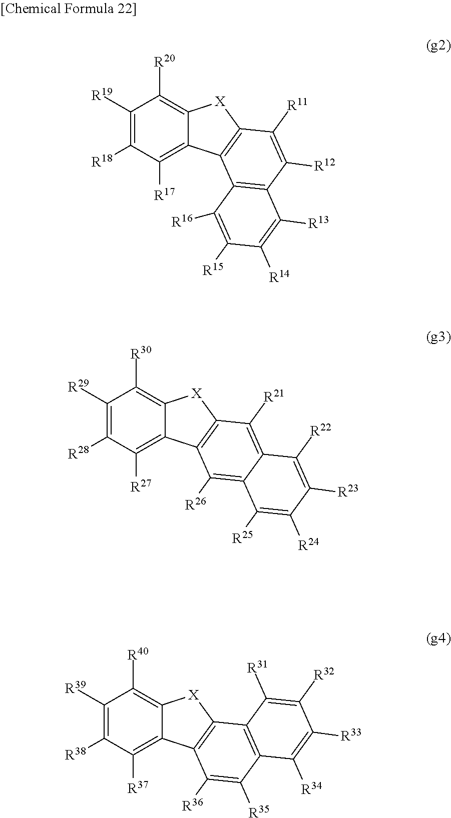

In General Formulae (g2) to (g4), X represents oxygen or sulfur, and R¹¹ to R⁴⁰ each independently represent hydrogen (including deuterium), a straight-chain or branched-chain alkyl group having 1 to 10 carbon atoms, a cycloalkyl group having 3 to 10 carbon atoms, a substituted or unsubstituted aryl group having 6 to 30 carbon atoms, or a substituted or unsubstituted heteroaryl group having 1 to 30 carbon atoms. Note that any one of R¹¹ to R²⁰, any one of R²¹ to R³⁰, and any one of R³¹ to R⁴⁰ each represent a bond with Ar³.

Examples of the substituted or unsubstituted arylene group having 6 to 30 ring-forming carbon atoms in General Formula (G1) above include a phenylene group, a biphenyl-diyl group, a naphthalene-diyl group, a fluorene-diyl group, an anthracene-diyl group, a phenanthrene-diyl group, a terphenyl-diyl group, a triphenylene-diyl group, a tetracene-diyl group, a benzanthracene-diyl group, and a spirobi[9H-fluorene]-diyl group. At least one of Ar¹ to Ar³ can be any of these arylene groups, and is particularly preferably a group in which phenylene groups are connected to each other. The nitrogen (N) in General Formula (G1) and the group represented by any one of General Formulae (g1) to (g10) are preferably bonded to each other through a phenylene group, in which case the synthesis can sometimes be facilitated. When at least one of Ar¹ to Ar³ includes a phenylene group, the Tg of the compound is increased. When at least one of Ar¹ to Ar³ includes a phenylene group, the sublimation temperature can be lower than when the at least one of Ar¹ to Ar³ includes a different group (e.g., a naphthalene-diyl group). When at least one of Ar¹ to Ar³ includes a phenylene group, the compound can have a high hole-transport property, and a light-emitting device including the compound can have a reduced driving voltage, which is preferable.

Examples of the substituted or unsubstituted aryl group having 6 to 30 ring-forming carbon atoms in General Formulae (G1) and (g1) to (g10) above include a phenyl group, a biphenyl group, a terphenyl group, a naphthyl group, an anthryl group, a fluorenyl group, a diphenylfluorenyl group, a spirobifluorenyl group, a pyrenyl group, a phenanthryl group, a triphenylenyl group, a perylenyl group, a tetracenyl group, and a chrysenyl group.

Examples of the substituted or unsubstituted heteroaryl group having 1 to 30 ring-forming carbon atoms and the substituted or unsubstituted heteroaryl group having 1 to 30 carbon atoms in General Formulae (G1) and (g1) to (g10) above include a pyridin-yl group, a pyrazin-yl group, a pyrimidin-yl group, a pyridazin-yl group, a triazin-yl group, a quinolin-yl group, a quinazolin-yl group, an isoquinolin-yl group, a pyrrol-yl group, a naphthyridin-yl group, a phenanthridin-yl group, a quinoxalin-yl group, an imidazol-yl group, a benzimidazol-yl group, an oxazol-yl group, an isoxazol-yl group, a thiazol-yl group, an isothiazol-yl group, a furan-yl group, a thiophen-yl group, a benzofuran-yl group, a benzothiophen-yl group, a dibenzofuran-yl group, a dibenzothiophen-yl group, a carbazol-yl group, an indol-yl group, a phenanthren-yl group, a benzonaphthofuran-yl group, a benzothiophen-yl group, a dinaphthofuran-yl group, and a dinaphthothiophen-yl group. It is particularly preferable to use a pyrrol-yl group, a furan-yl group, a thiophen-yl group, a benzofuran-yl group, a benzothiophen-yl group, a dibenzofuran-yl group, a dibenzothiophen-yl group, a carbazol-yl group, an indol-yl group, a benzonaphthofuran-yl group, a benzothiophen-yl group, a dinaphthofuran-yl group, or a dinaphthothiophen-yl group to increase the hole-transport property.

Examples of the straight-chain or branched-chain alkyl group having 1 to 10 carbon atoms in General Formulae (g1) to (g10) above include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, an n-hexyl group, a 3-methylpentyl group, a 2-methylpentyl group, a 2-ethylbutyl group, a 1,2-dimethylbutyl group, and a 2,3-dimethylbutyl group.

Examples of the cycloalkyl group having 3 to 10 carbon atoms in General Formulae (g1) to (g10) above include a cyclopropyl group, a cyclobutyl group, a cyclopentyl group, and a cyclohexyl group.

In General Formulae (G1) and (g1) to (g10), hydrogen may be replaced with deuterium as appropriate.

In the case where the arylene group, aryl group, or heteroaryl group has a substituent, as the substituent, an alkyl group having 1 to 6 carbon atoms, a cycloalkyl group having 3 to 6 carbon atoms, or an aryl group having 6 to 13 carbon atoms can also be selected. Specific examples of the substituent include a cyano group and a hydroxyl group. Specifically, examples of the alkyl group having 1 to 6 carbon atoms include a methyl group, an ethyl group, a propyl group, an isopropyl group, a butyl group, an isobutyl group, a tert-butyl group, a pentyl group, a neopentyl group, an isopentyl group, and an n-hexyl group. Examples of the cycloalkyl group having 3 to 6 carbon atoms include a cyclopropyl group, a cyclobutyl group, a cyclopentyl group, and a cyclohexyl group. Examples of the aryl group having 6 to 13 carbon atoms include a phenyl group, a naphthyl group, and a fluorenyl group.

### Specific Example

The following are specific examples of the organic compound of one embodiment of the present invention having the structure represented by General Formula (G1) above.

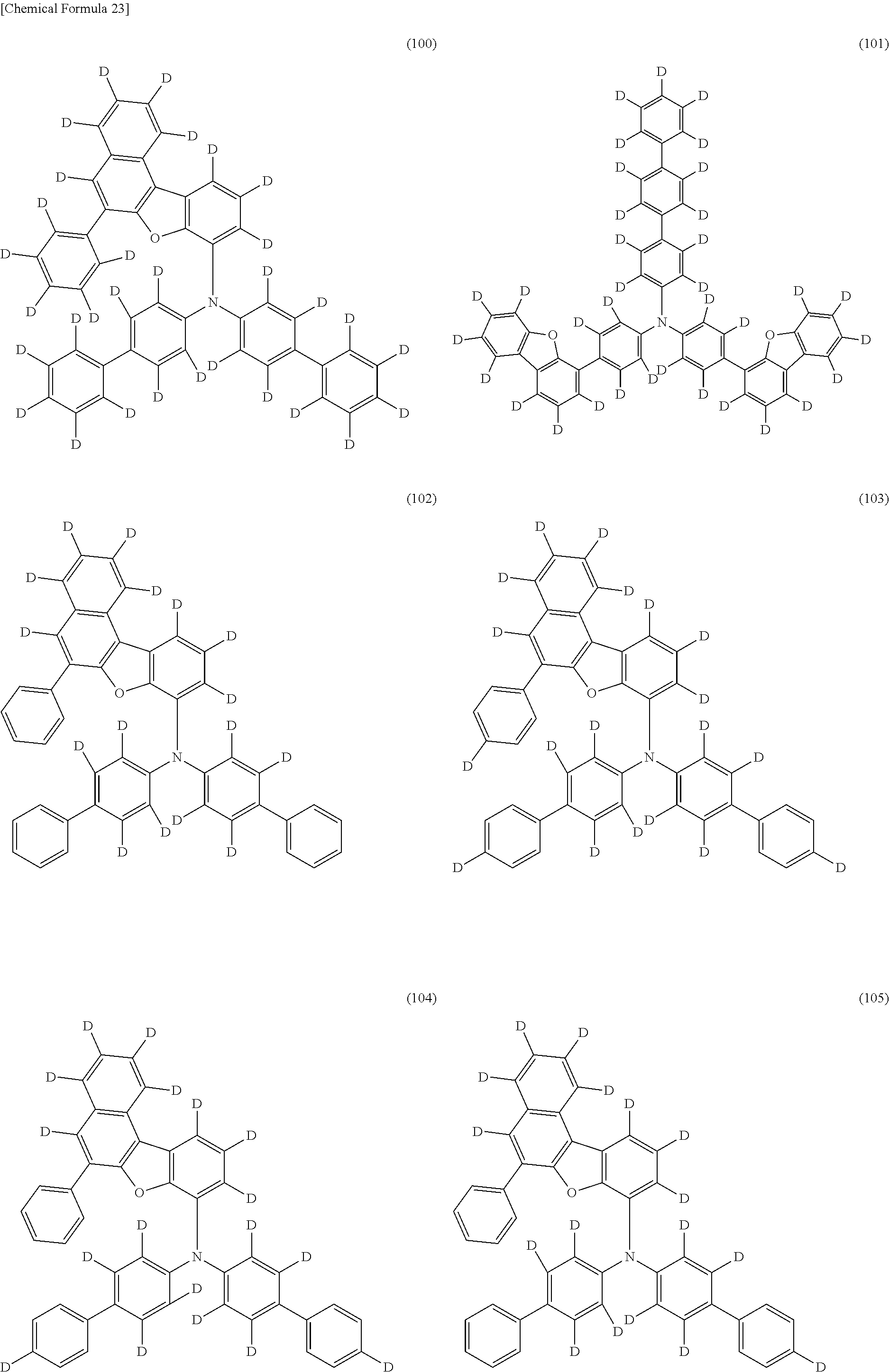

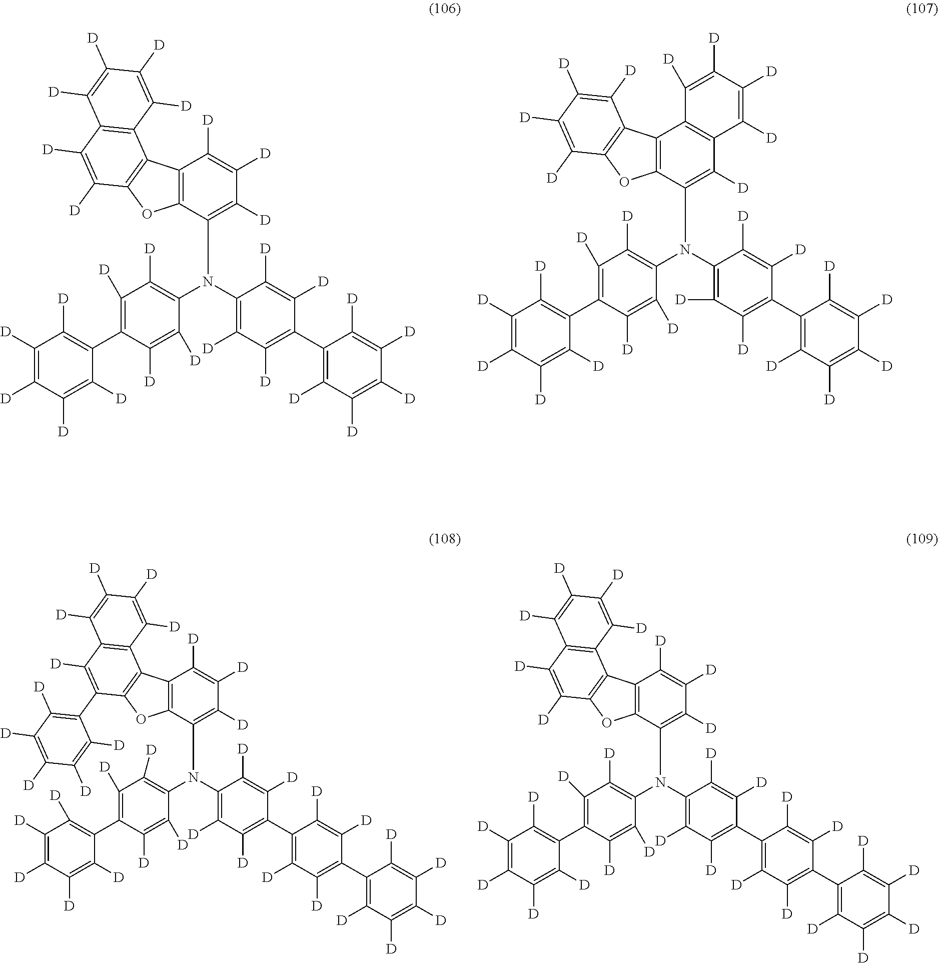

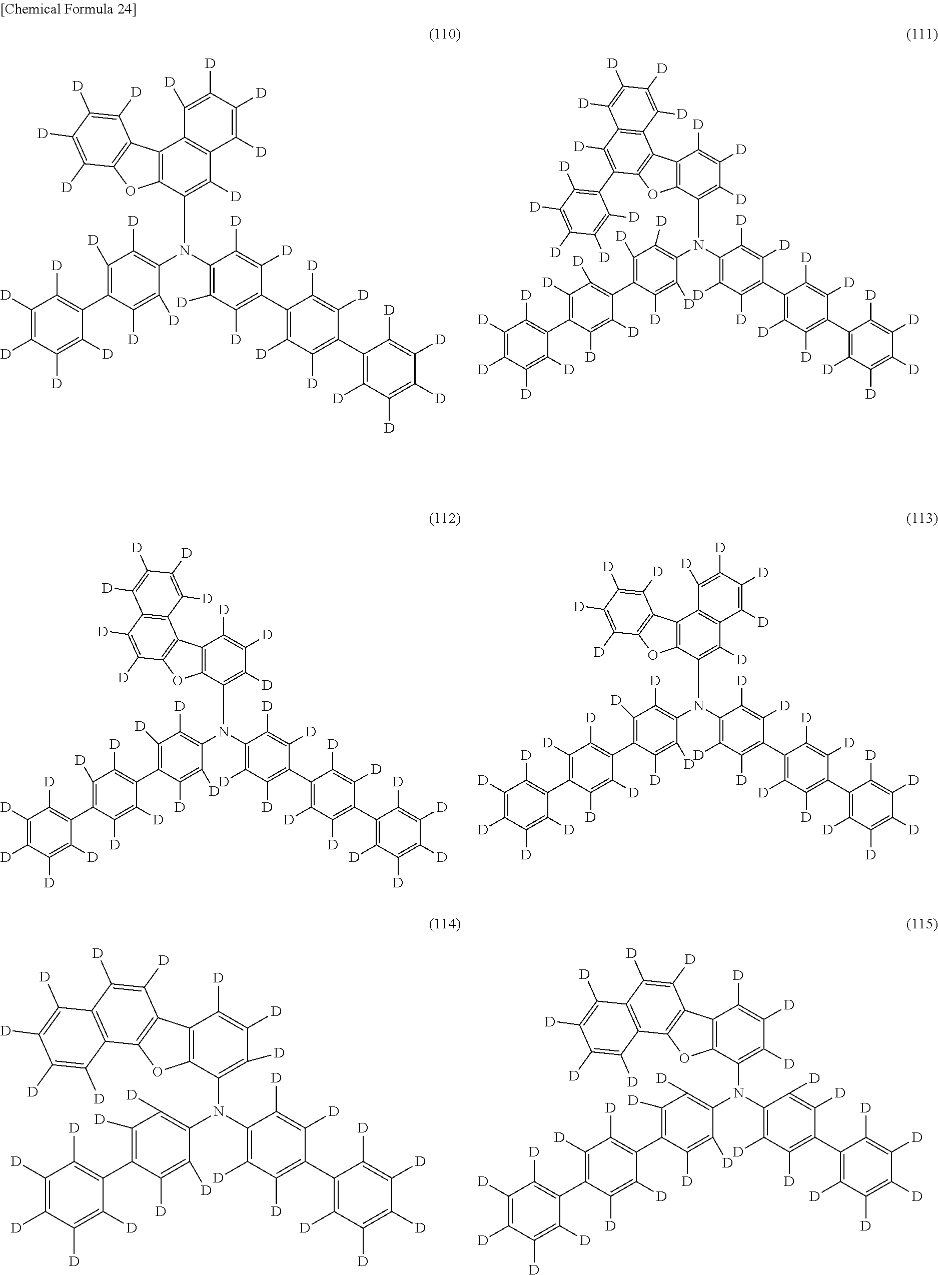

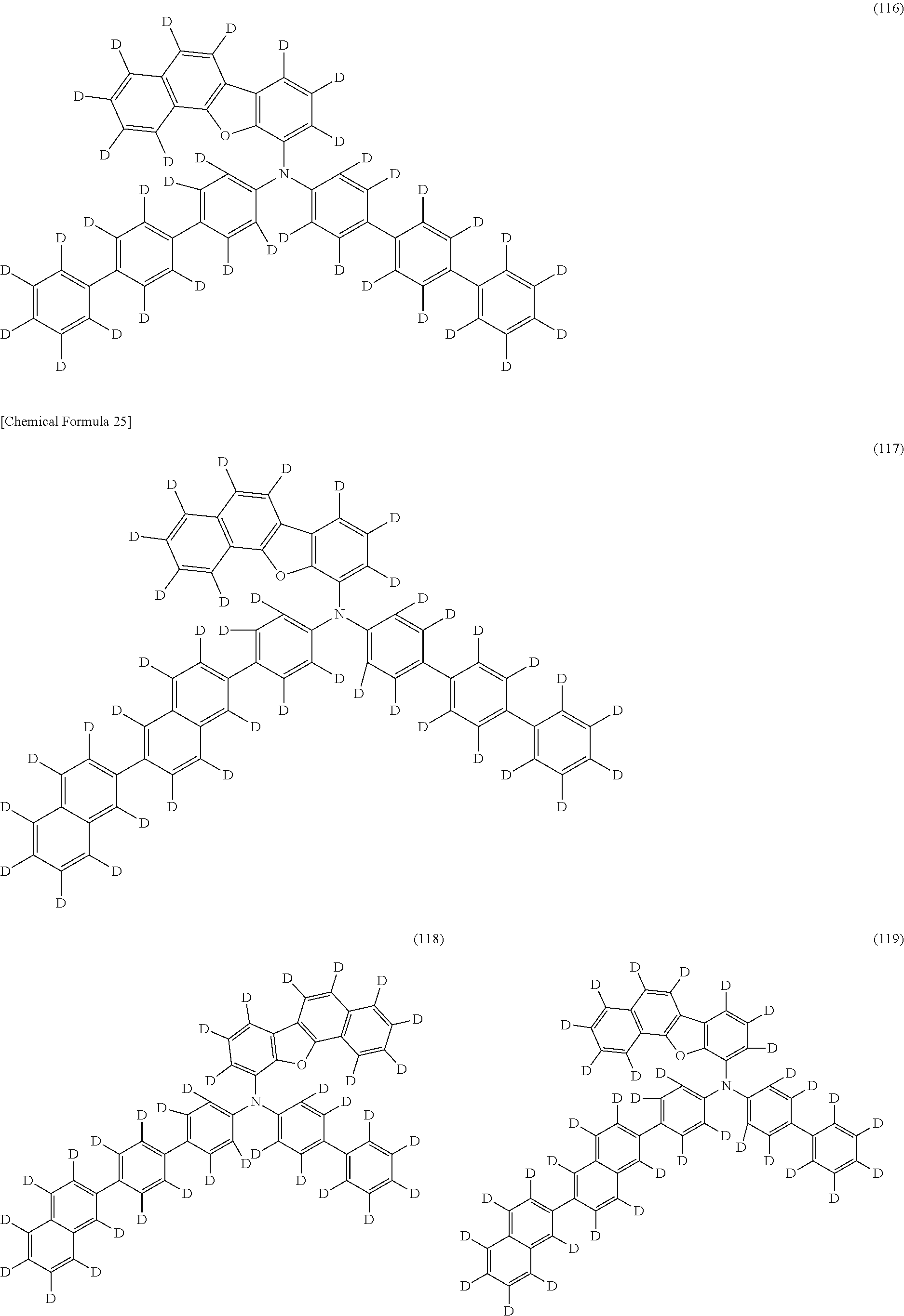

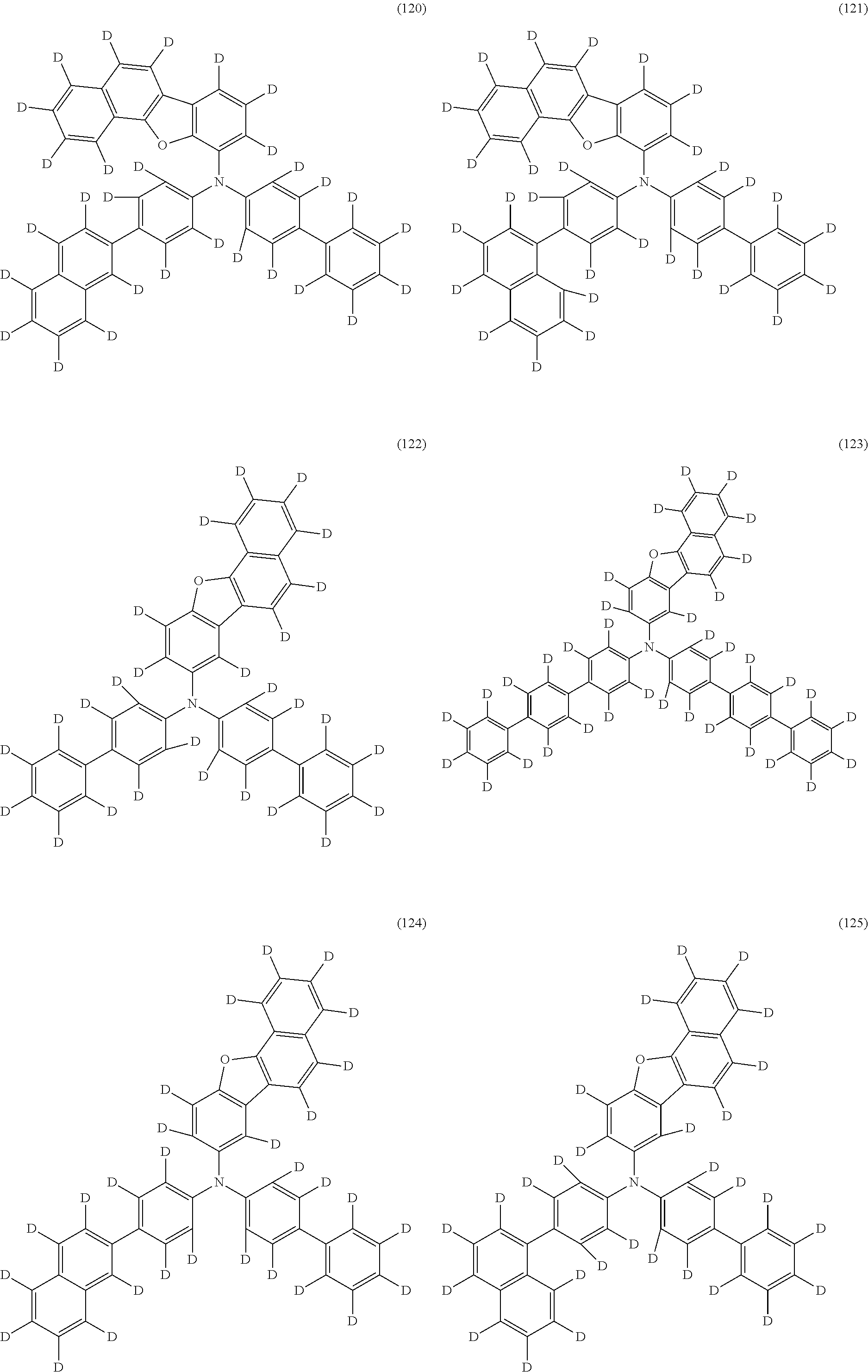

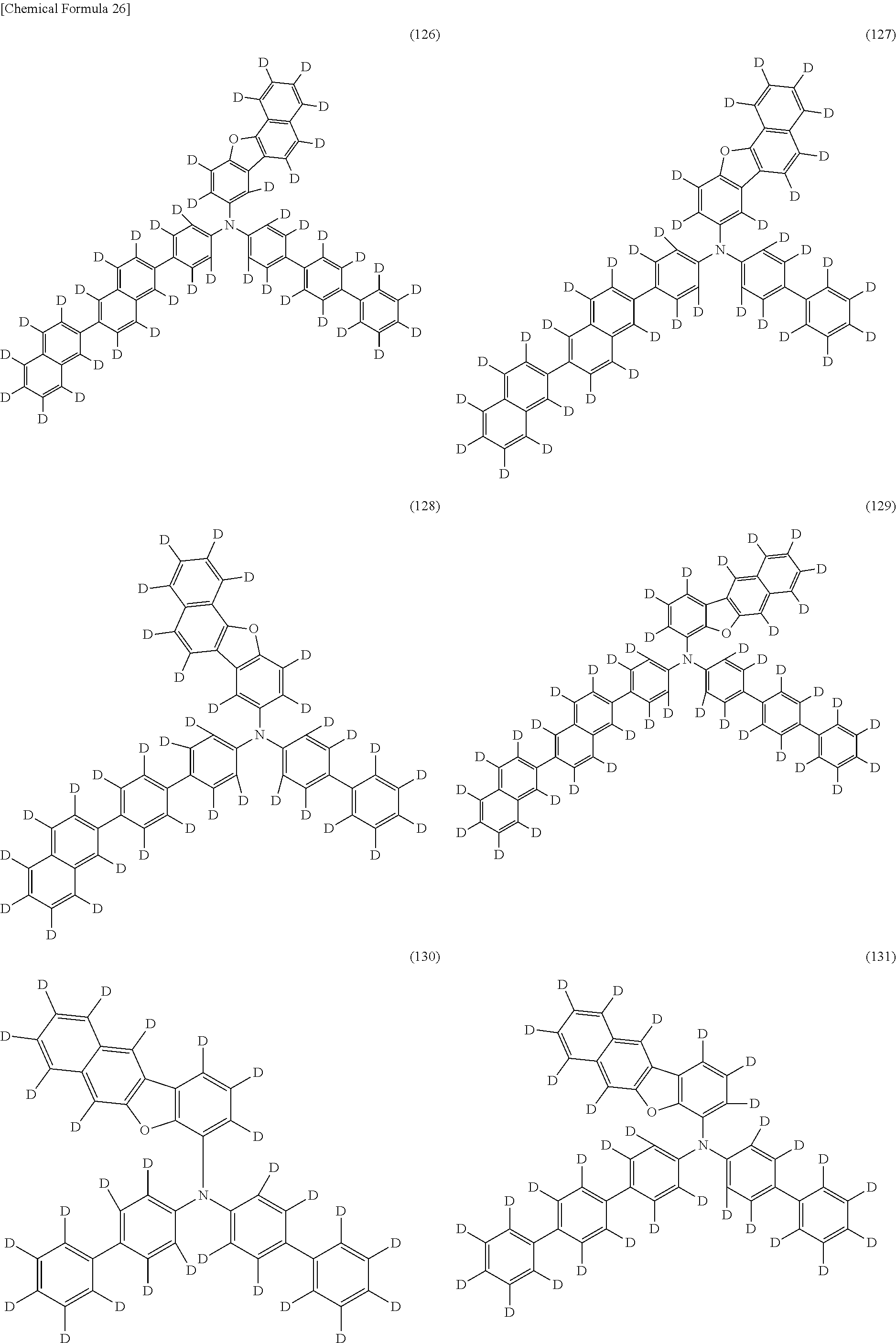

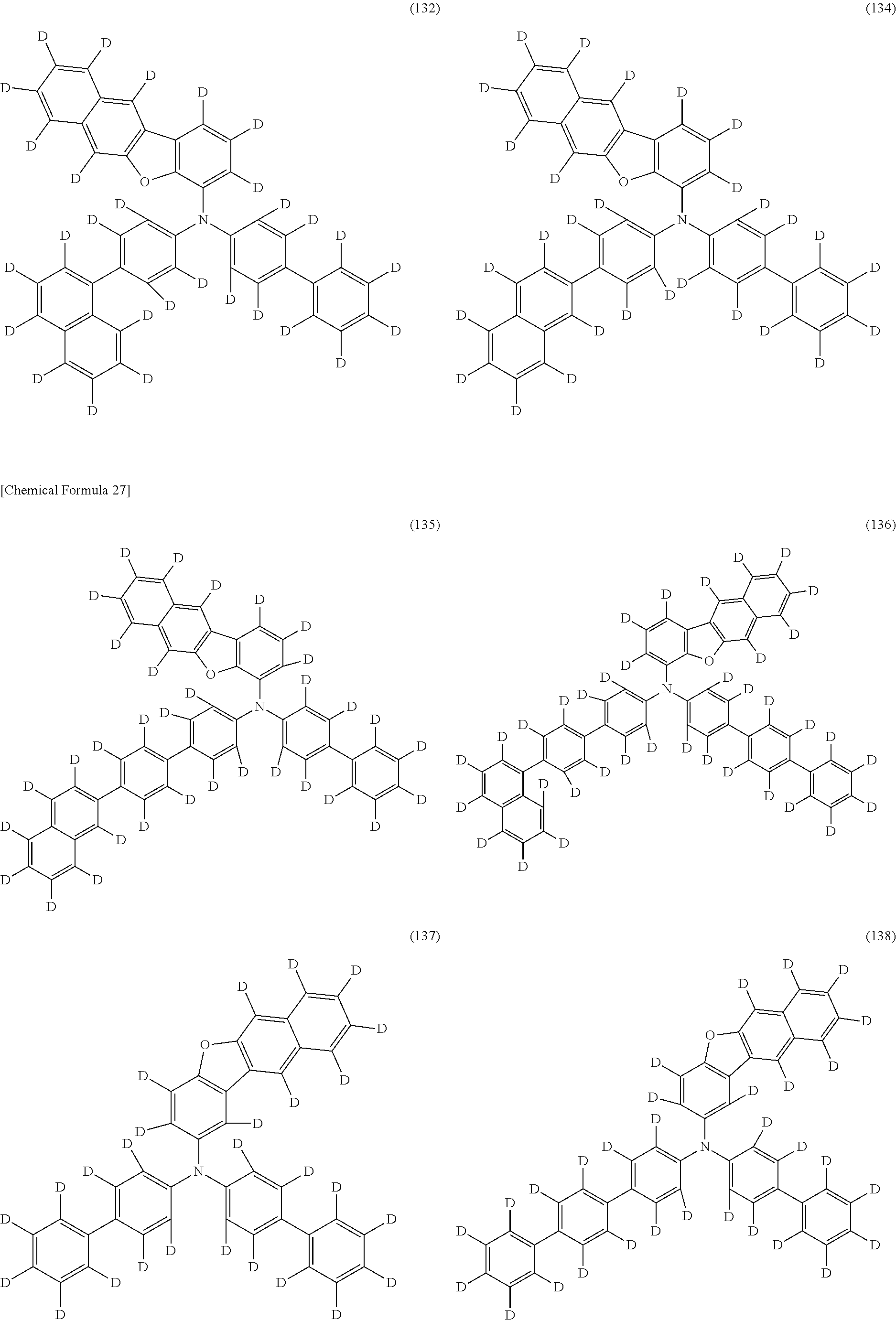

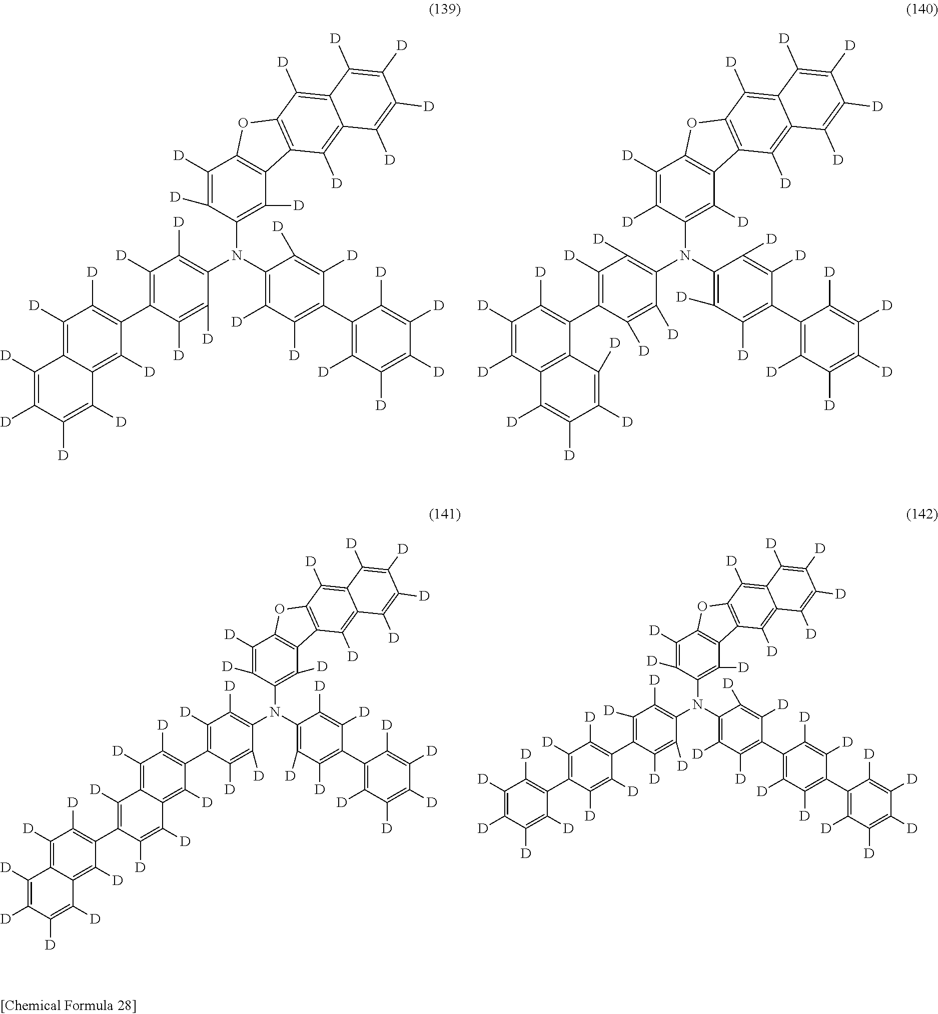

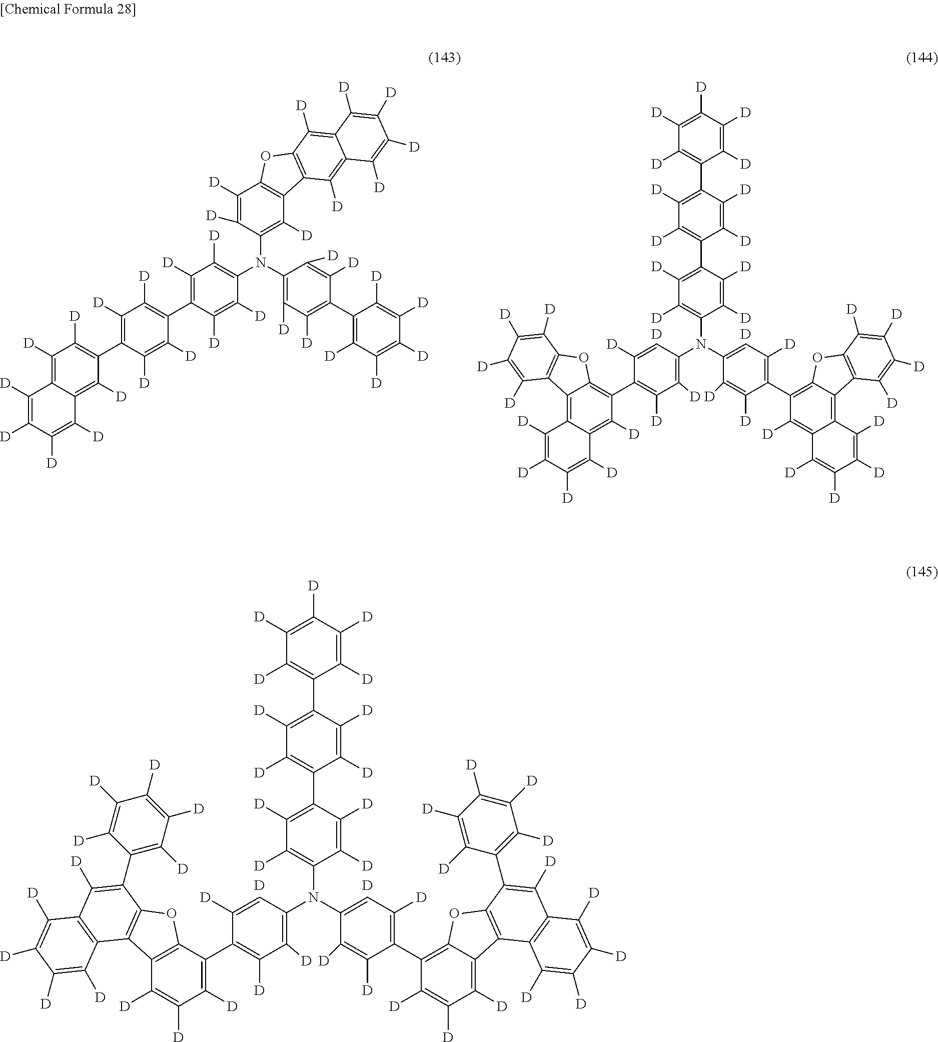

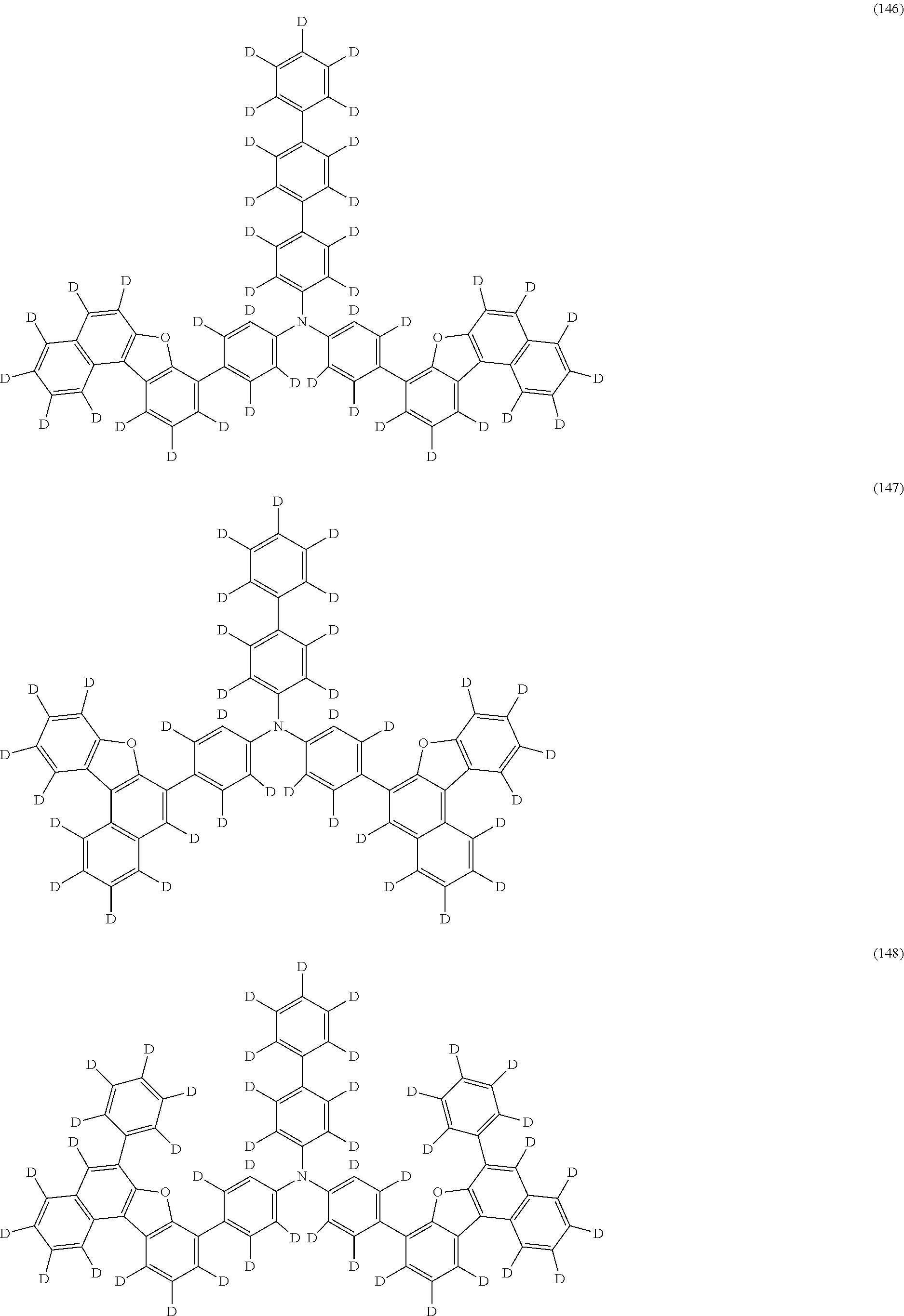

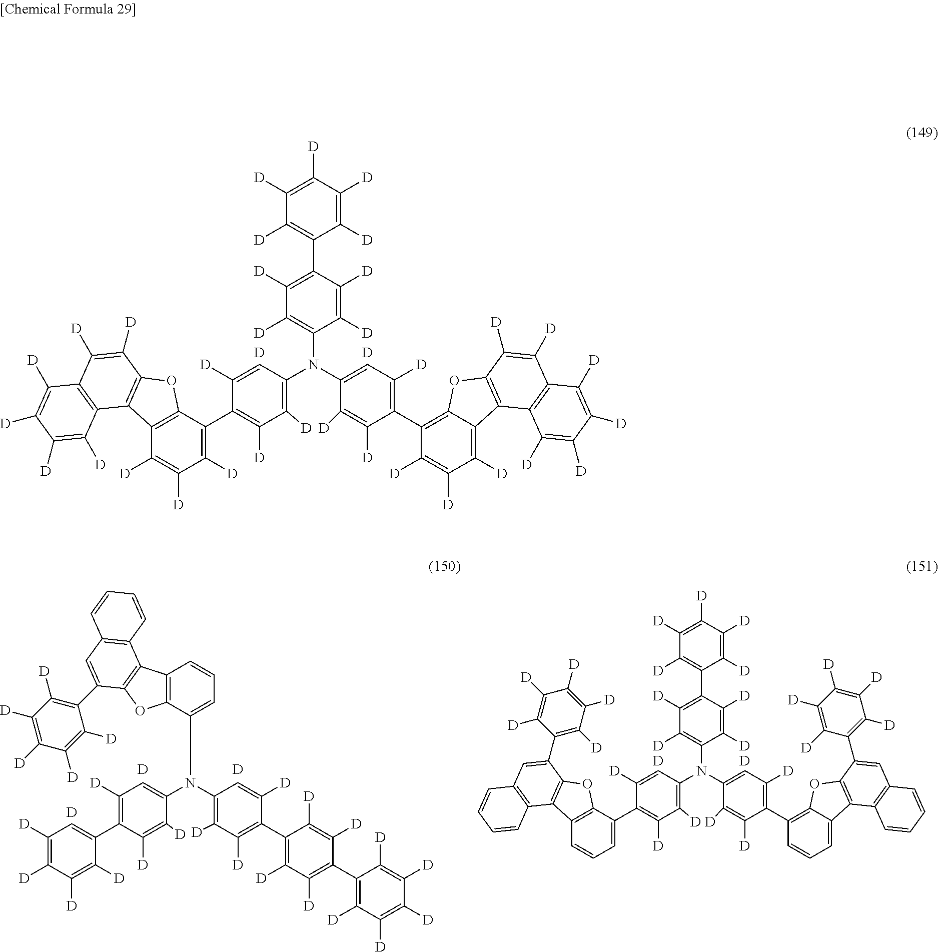

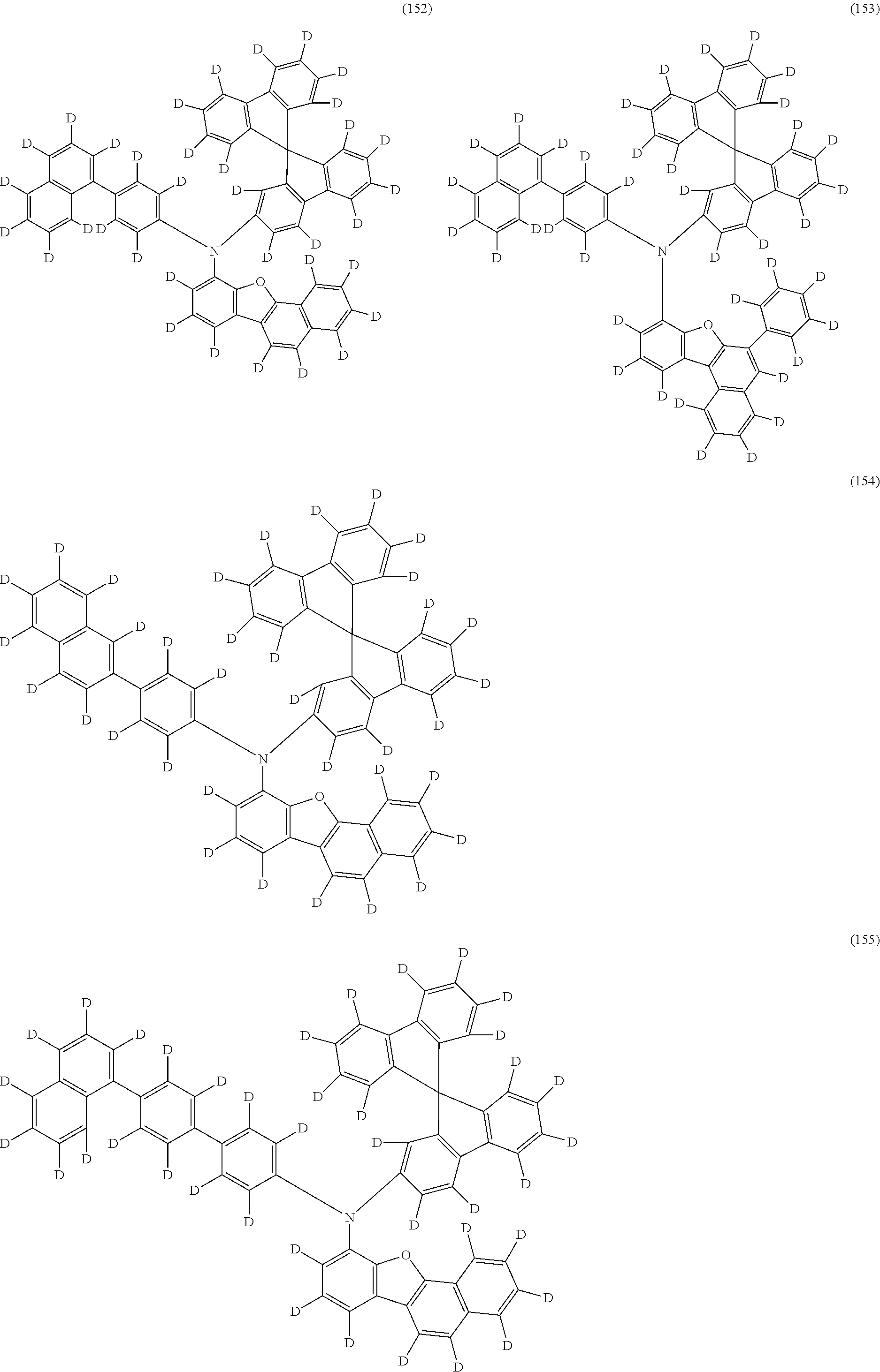

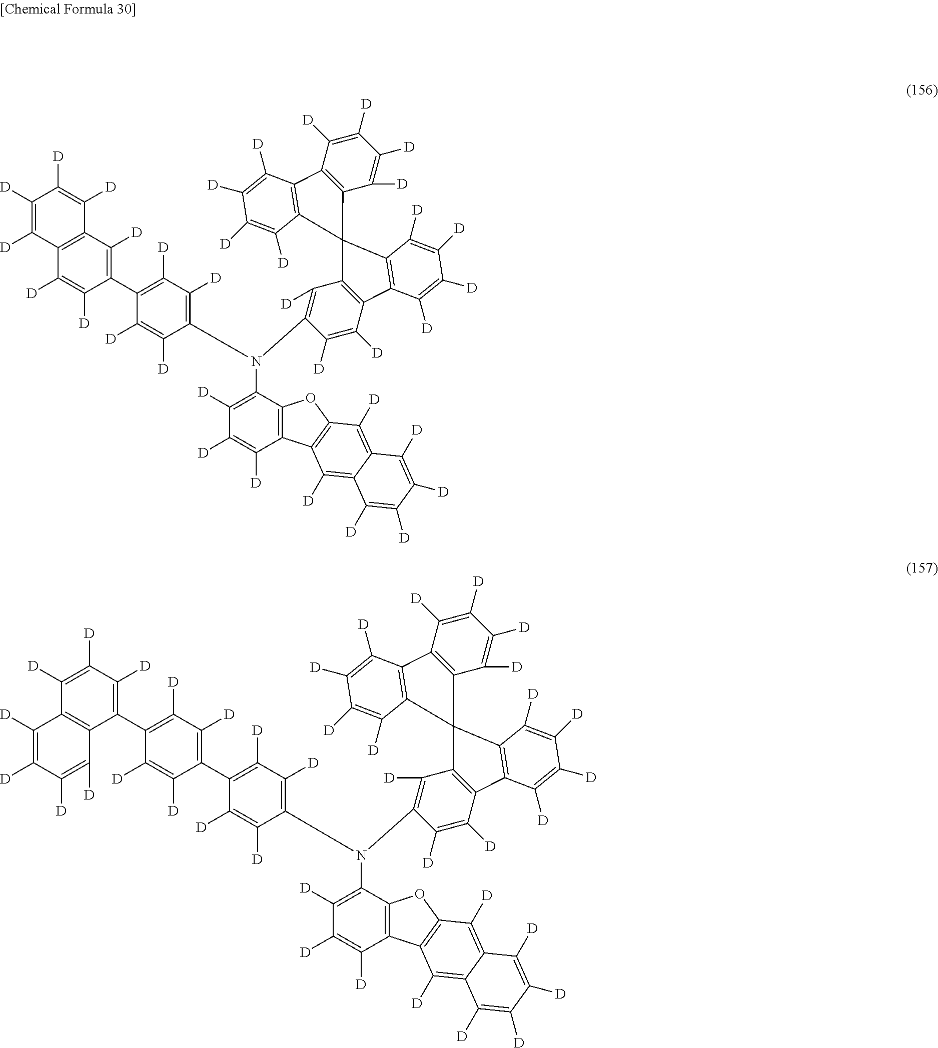

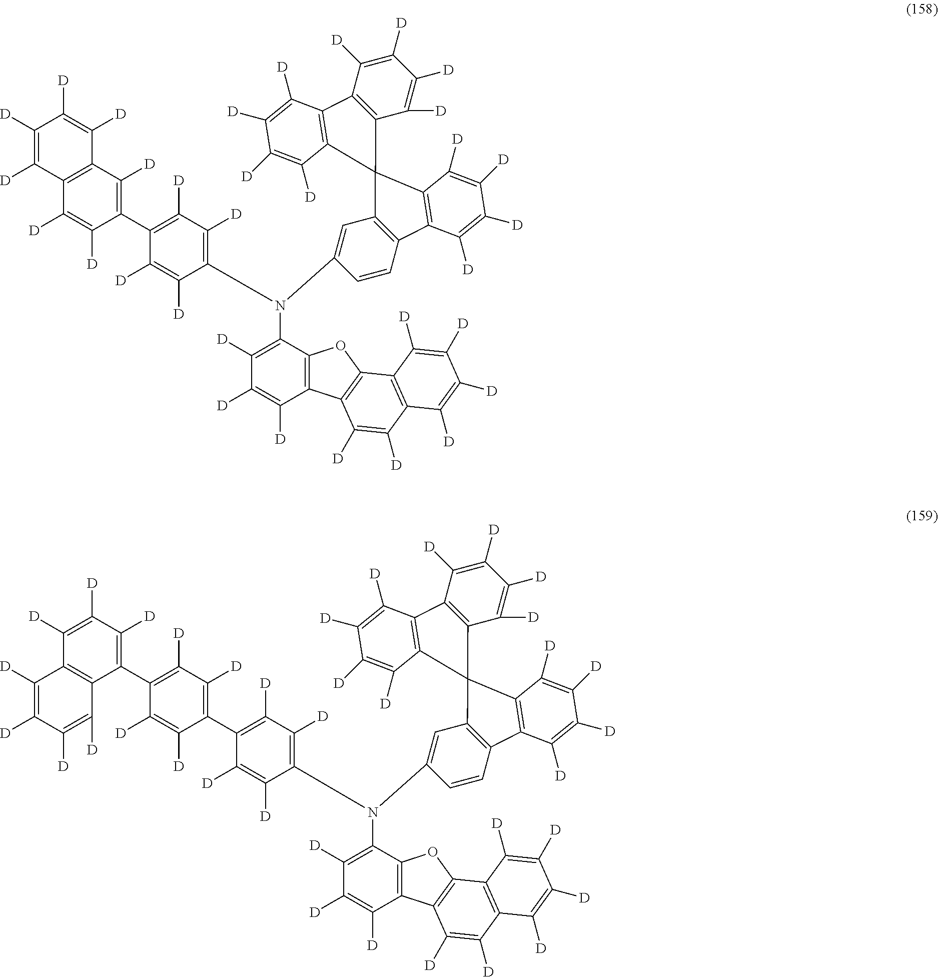

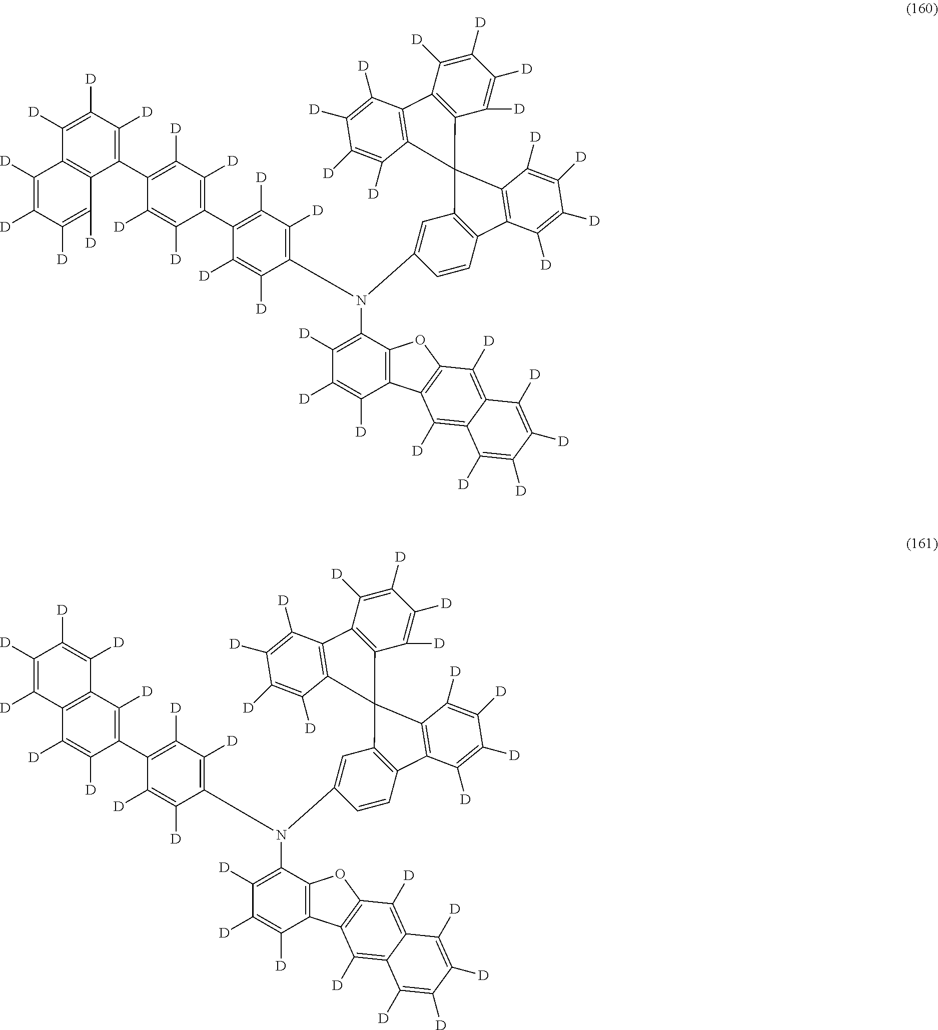

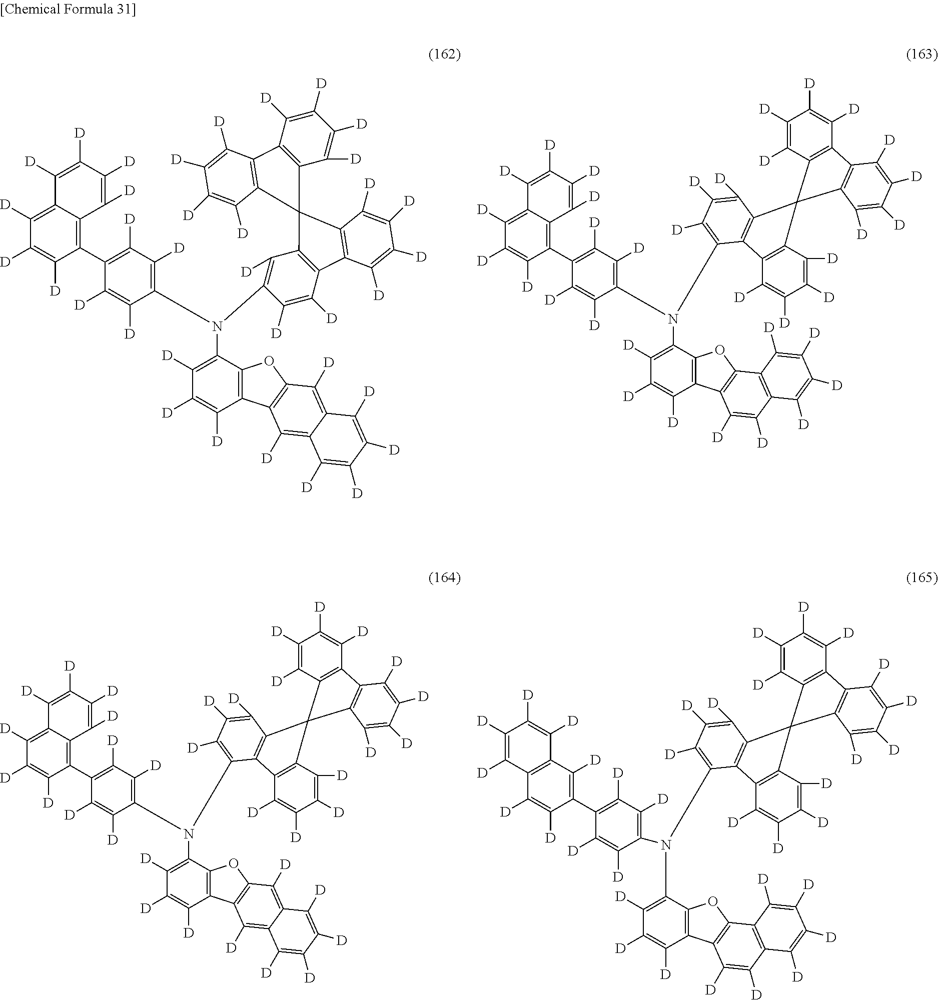

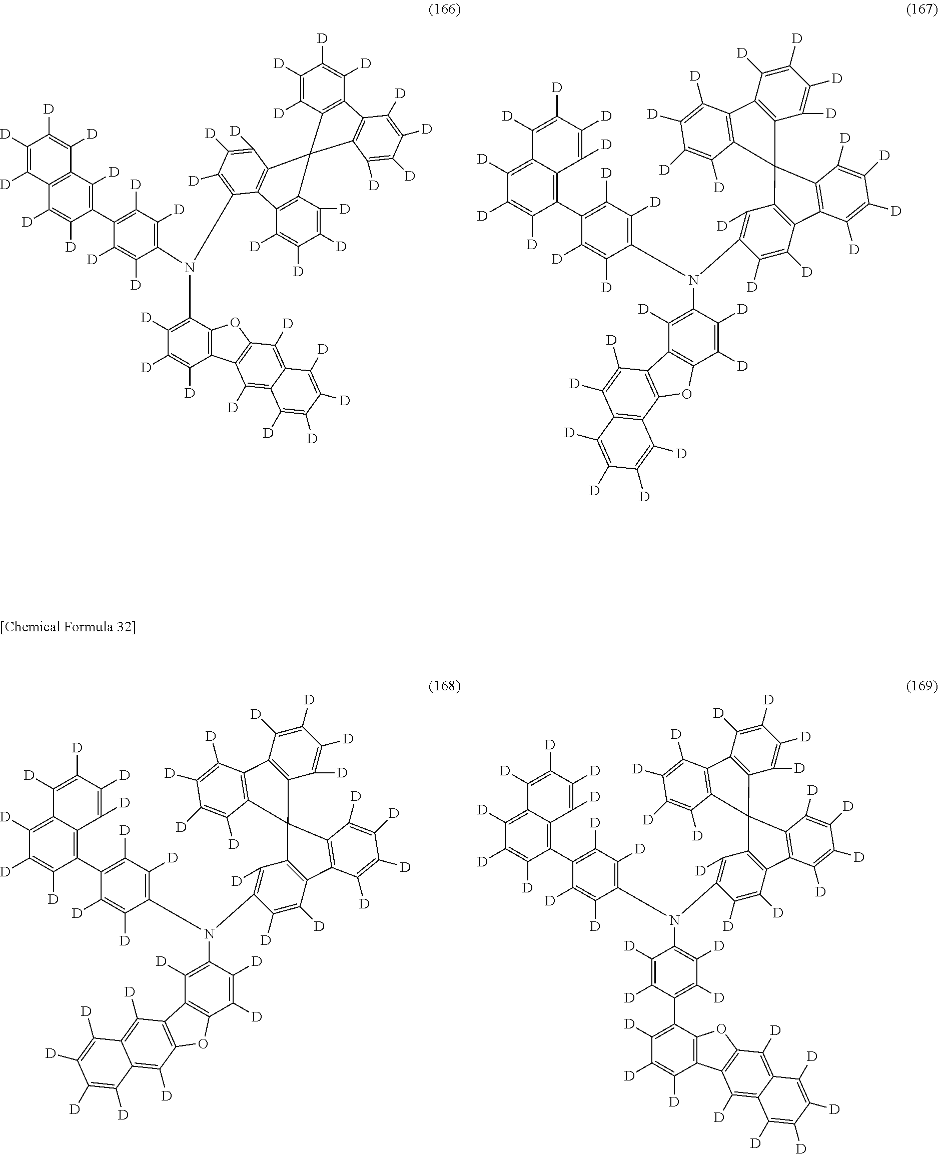

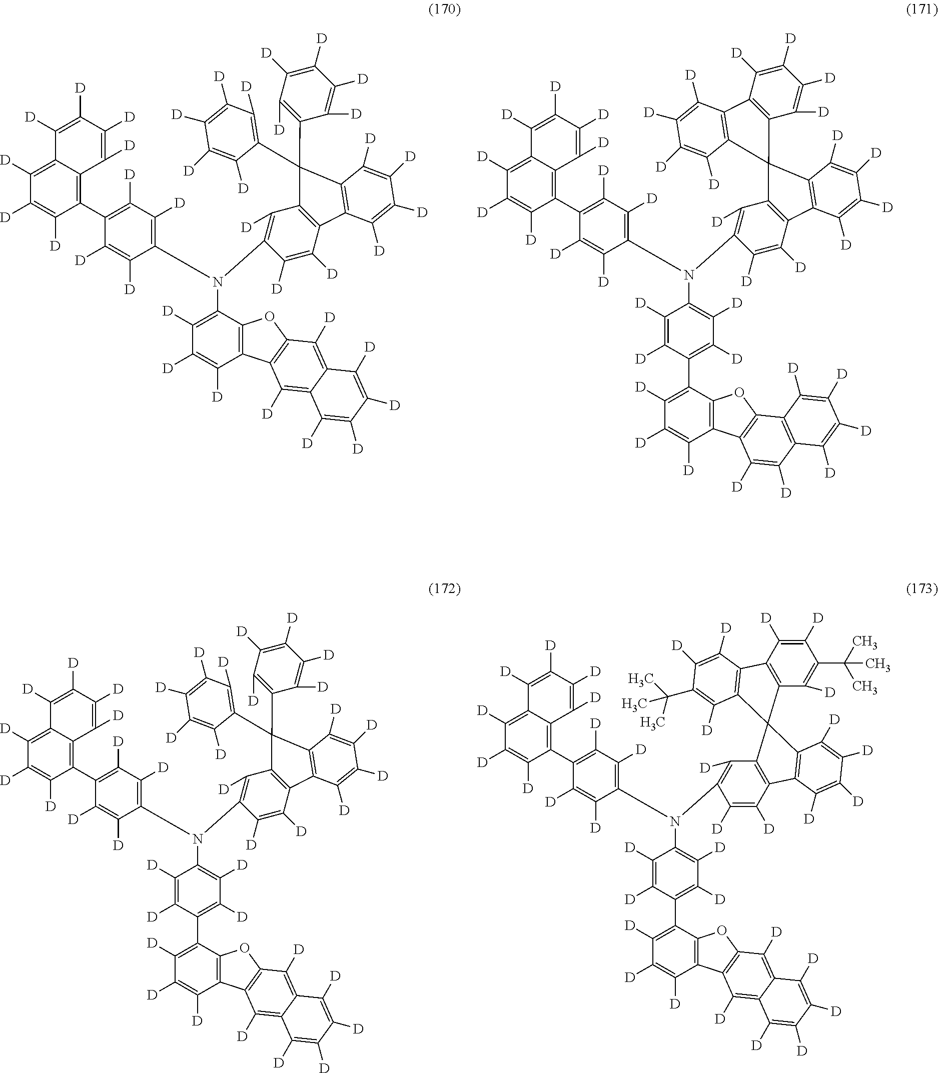

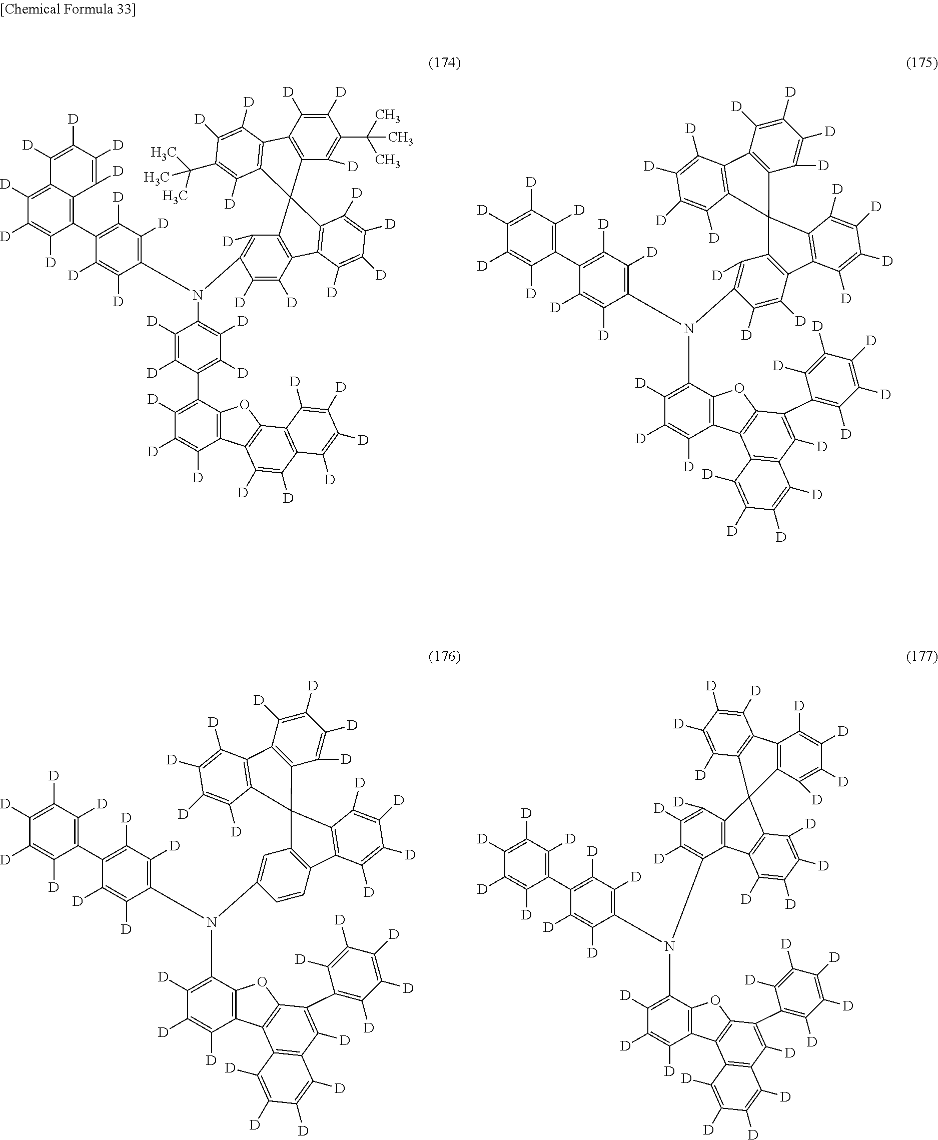

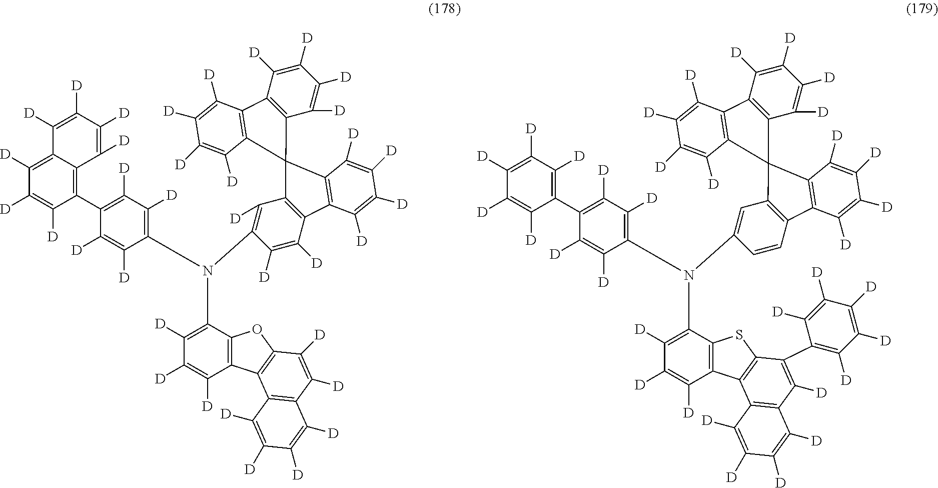

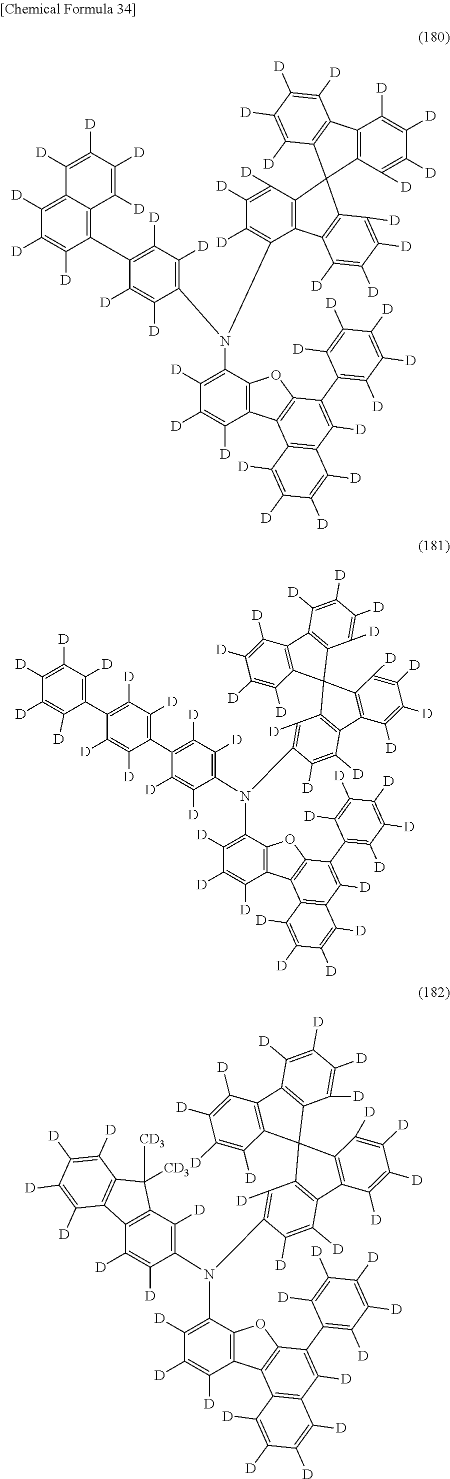

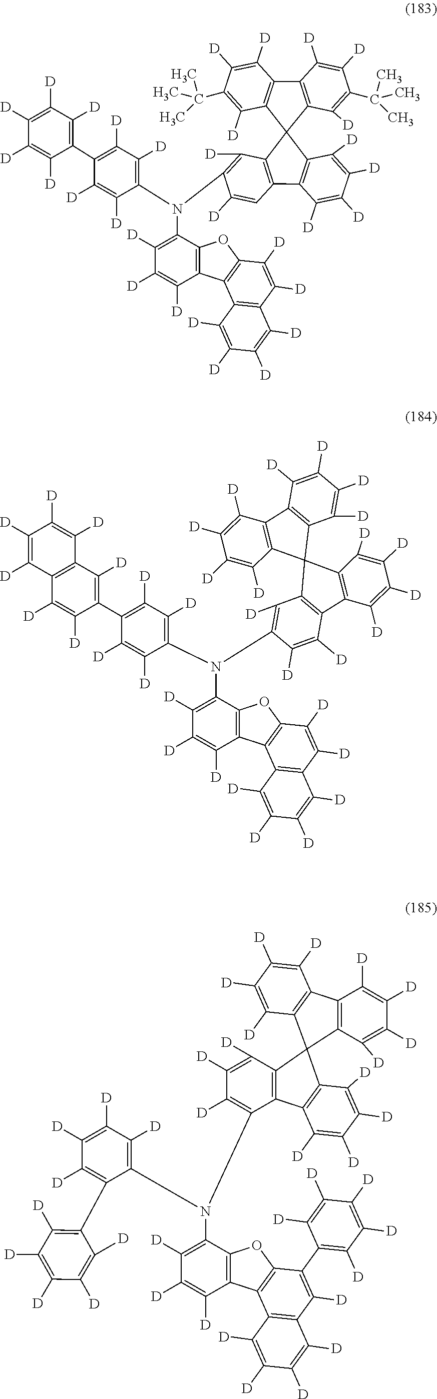

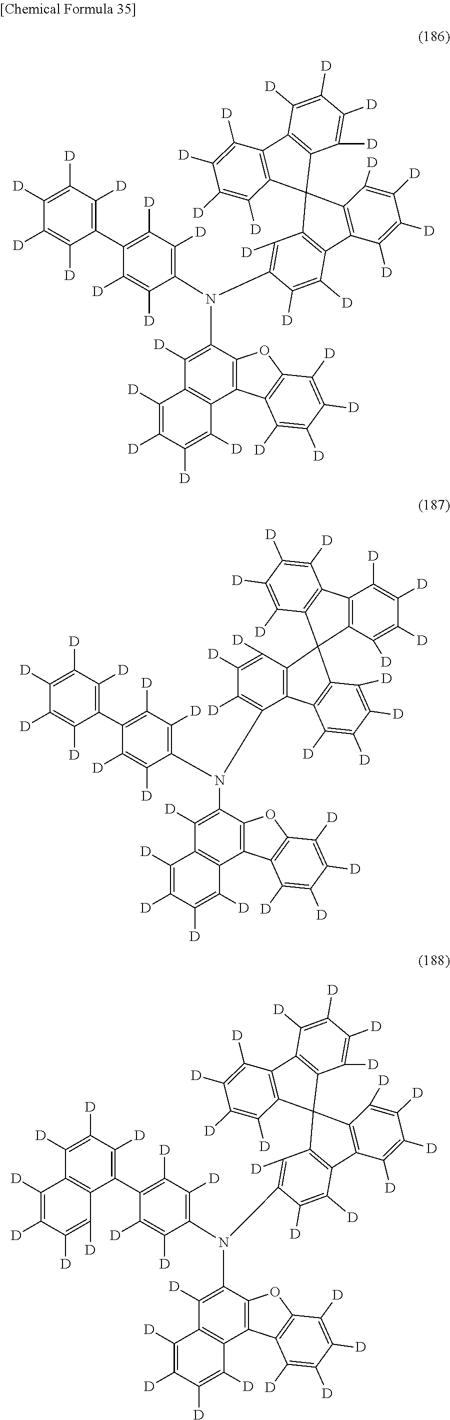

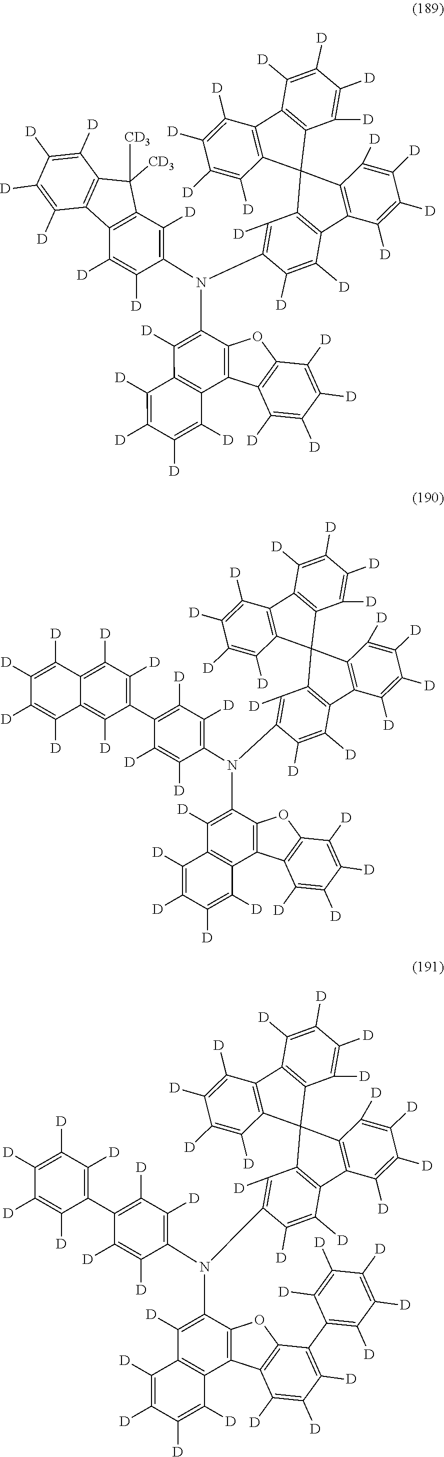

The organic compounds represented by Structural Formulae (100) to (191) above are examples of the organic compound represented by General Formula (G1) above. The organic compound of one embodiment of the present invention is not limited thereto.

The organic compound represented by General Formula (G1) above preferably has a molecular structure in which deuteriums are substituted for all hydrogens, with no hydrogen included, as shown in Structural Formulae (100), (101), (106) to (149), (152) to (157), (162) to (172), (175), (177), (178), (180) to (182), and (184) to (191) above. Note that the proportion of deuterium introduced by deuteration is preferably higher than or equal to 80%, and may be below 100%.

As specific examples of a molecular structure that includes both hydrogen and deuterium, Structural Formulae (102) to (105), (150), (151), (158) to (161), (173), (174), (176), (179), and (183) are shown.

Deuterated raw materials for simple structures such as a phenyl group, a biphenylyl group, and a phenylene group are easily available, which reduces the production cost. Thus, using a molecular structure in which only these groups include deuterium makes it possible to provide the organic compounds of embodiments of the present invention at low cost, and to provide a highly reliable light-emitting device including any of these organic compounds. For example, a light-emitting device can be highly reliable by including any of the organic compounds with a structure having three biphenyl groups including deuterium, or specifically, a structure in which each of the three skeletons bonded to the nitrogen has a biphenyl group including deuterium (nine deuteriums). In that case, the organic compounds of embodiments of the present invention each include 27 deuteriums; this structure can sufficiently enhance the effect of the deuteration. Thus, the total number of deuteriums in the organic compound is preferably greater than or equal to 27.

Furthermore, the organic compound preferably has a molecular structure in which three phenyl groups and three phenylene groups are distributed to the above three skeletons, in which case a light-emitting device including the organic compound can be highly reliable as in the case where the organic compound has the structure including three biphenyl groups. Moreover, since the molecular structure includes 27 or more deuteriums, the effect of the deuteration can be sufficiently enhanced as described above, which is preferable. It is particularly preferable that a group directly bonded to the nitrogen include deuterium. Examples of such a molecular structure with 27 or more deuteriums are shown by Structural Formulae (150) and (151) above. A structure that is obtained by adding one phenylene group to Structural Formula (150) or (151) and that resultantly includes 31 or more deuteriums, or a structure that is obtained by adding two phenylene groups to Structural Formula (150) or (151) and that resultantly includes 35 or more deuteriums may be employed, and also in such a case, a highly reliable light-emitting device can be provided at low cost as described above.

When a deuterated organic compound is used as a material for a light-emitting device, for example, the driving lifetime of the light-emitting device can be increased. Accordingly, with the deuterated organic compound, the light-emitting device can have a long driving lifetime, which enables a highly reliable electronic appliance and contributes to a reduction in the device cost for a consumer. Furthermore, a light-emitting material including deuterium generally tends to have improved emission efficiency, thereby achieving a light-emitting apparatus, an electronic appliance, or a lighting device with low power consumption.

<Method for synthesizing Organic Compound>

As examples of a method for synthesizing the organic compound of one embodiment of the present invention, methods for synthesizing the organic compound represented by General Formula (G1) below will be described below. Note that the methods for synthesizing the organic compound represented by General Formula (G1) can employ a variety of reactions and are not limited to the following synthesis methods.

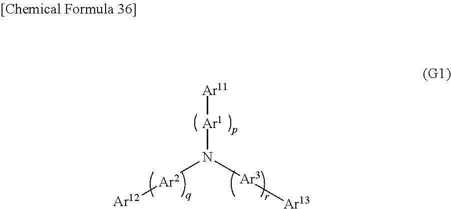

For Ar¹, Ar², Ar³, Ar¹¹, Ar¹², Ar¹³, p, q, and r in General Formula (G1) above, the corresponding description in <Example of Organic Compound> is to be referred to. Note that the corresponding description in <Example of Organic Compound> can be referred to also for Ar¹, Ar², Ar³, Ar¹¹, Ar¹², Ar¹³, p, q, and r in the following synthesis schemes. For Rⁿ (n is a natural number) or Q^{m} (m is a natural number) used in the synthesis schemes, the first description thereof can be referred to as appropriate.

A synthesis method of the organic compound represented by General Formula (G1) above is described. The organic compound represented by General Formula (G1) includes one or more deuteriums. A deuteration reaction will be described later.

First, in accordance with Synthesis Scheme (s-1), an aryl compound (Compound 1) and an arylamine compound (Compound 2) are coupled, so that a diarylamine compound (Compound 3) can be obtained.

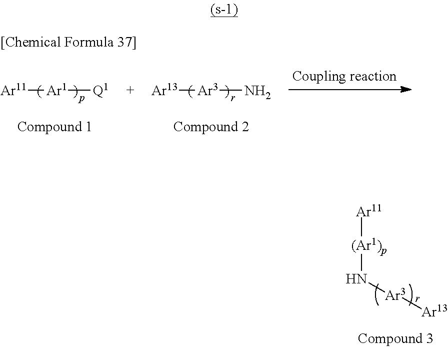

In Synthesis Scheme (s-1), Q¹ represents chlorine, bromine, iodine, or a trifluoromethanesulfonyl group.

In the case where a Buchwald-Hartwig reaction using a palladium catalyst is employed in Synthesis Scheme (s-1), a palladium compound such as bis(dibenzylideneacetone)palladium(0), palladium(II) acetate, [1,1-bis(diphenylphosphino)ferrocene]palladium(II) dichloride, tetrakis(triphenylphosphine)palladium(0), or allylpalladium(II) chloride (dimer) and a ligand such as tri(tert-butyl)phosphine, tri(n-hexyl)phosphine, tricyclohexylphosphine, di(1-adamantyl)-n-butylphosphine, 2-dicyclohexylphosphino-2′,6′-dimethoxybiphenyl, tri(ortho-tolyl)phosphine, or di(tert-butyl)(1-methyl-2,2-diphenylcyclopropyl)phosphine (abbreviation: cBRIDP) can be used.

In the reaction in Synthesis Scheme (s-1), an organic base such as t-butoxysodium, an inorganic base such as potassium carbonate, cesium carbonate, or sodium carbonate, or the like can be used. In this reaction, a phase transfer catalyst such as 18-crown-6-ether can also be used. As a solvent in this reaction, toluene, xylene, benzene, tetrahydrofuran, dioxane, or the like can be used. In the case of causing an amination reaction without using a palladium catalyst, it is also possible to use a nickel catalyst, a ruthenium catalyst, an iron catalyst, or the like. Reagents that can be used in this reaction are not limited to the above reagents.

The target substance can be obtained also by causing a coupling reaction using copper or a copper compound in Synthesis Scheme (s-1). As an example of a base to be used in this reaction, an inorganic base such as potassium carbonate can be given. As examples of a solvent that can be used in this reaction, 1,3-dimethyl-3,4,5,6-tetrahydro-2(1H)-pyrimidinone (DMPU), N-methylpyrrolidone, toluene, xylene, benzene, and the like can be given. In the coupling reaction using copper or a copper compound, the target substance can be obtained in a shorter time and in a higher yield when the reaction temperature is higher than or equal to 100° C.; therefore, it is preferable to use DMPU or xylene, which has a high boiling point. A reaction temperature higher than or equal to 150° C. is further preferable, and accordingly, DMPU is further preferably used. Reagents that can be used in this reaction are not limited to the above reagents.

The target substance can be obtained also by using nickel or a nickel compound instead of copper or a copper compound in Synthesis Scheme (s-1); in that case, reaction conditions such as a base, a solvent, and a reaction temperature are similar to those for the reaction using copper or a copper compound.

Then, in accordance with Synthesis Scheme (s-2), a reaction is caused between the diarylamine compound (Compound 3) and an aryl compound (Compound 4), so that the target organic compound represented by General Formula (G1) can be obtained.

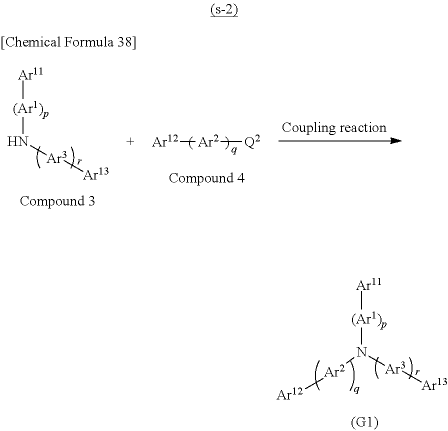

In Synthesis Scheme (s-2), Q² represents chlorine, bromine, iodine, or a trifluoromethanesulfonyl group.

In the case where a Buchwald-Hartwig reaction using a palladium catalyst or a coupling reaction using copper or a copper compound is employed in Synthesis Scheme (s-2), the reaction can be performed under the same conditions as the reaction in Synthesis Scheme (s-1).

The diarylamine compound (Compound 3) shown in Synthesis Schemes (s-1) and (s-2) above can also be synthesized in accordance with Synthesis Scheme (s-3) below. Specifically, the diarylamine compound (Compound 3) can also be synthesized by causing a reaction between an arylamine compound (Compound 5) and an aryl compound (Compound 6).

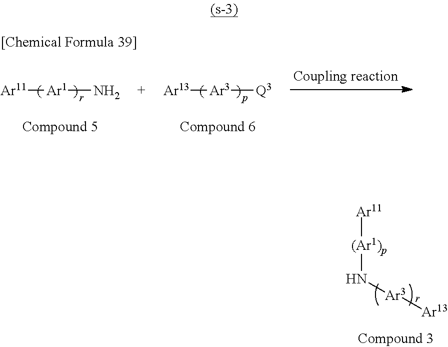

In Synthesis Scheme (s-3), Q³ represents chlorine, bromine, iodine, or a trifluoromethanesulfonyl group.

In the case where a Buchwald-Hartwig reaction using a palladium catalyst or a coupling reaction using copper or a copper compound is employed in Synthesis Scheme (s-3), the reaction can be performed under the same conditions as the reaction in Synthesis Scheme (s-1).

As with Synthesis Schemes (s-1) to (s-3), the target organic compound represented by General Formula (G1) can be obtained in accordance with Synthesis Schemes (s-4) and (s-5) or Synthesis Schemes (s-6) and (s-7).

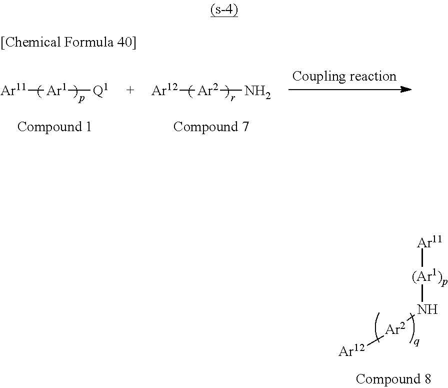

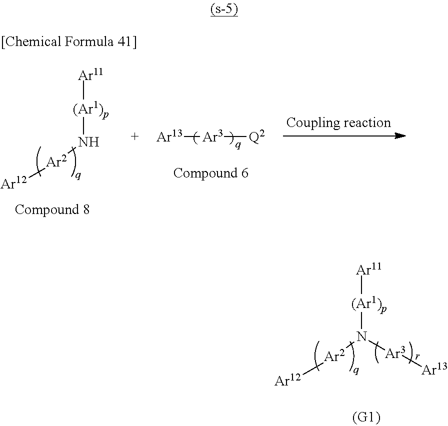

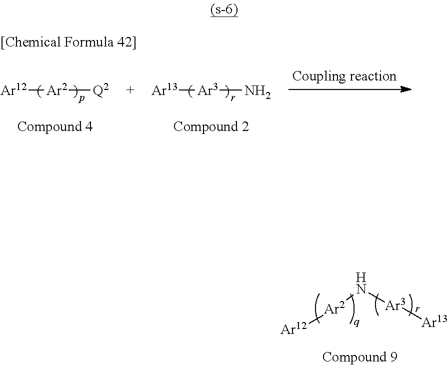

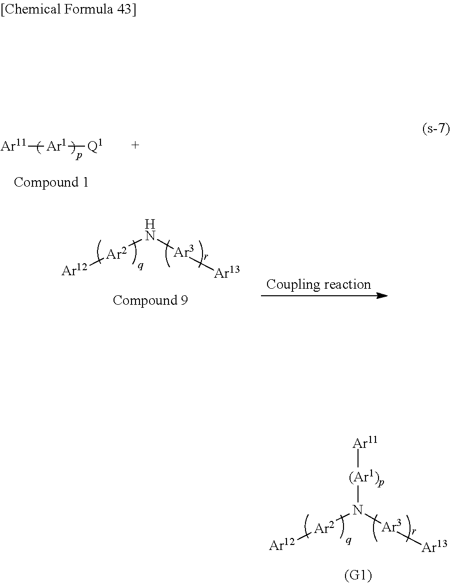

In the case where a Buchwald-Hartwig reaction using a palladium catalyst or a coupling reaction using copper or a copper compound is employed in Synthesis Schemes (s-4) and (s-5) or Synthesis Schemes (s-6) and (s-7), the reaction can be performed under the same conditions as the reaction in Synthesis Scheme (s-1).

The diarylamine compound (Compound 8) shown in Synthesis Schemes (s-4) and (s-5) above can also be synthesized in accordance with Synthesis Scheme (s-8) below. Specifically, the diarylamine compound (Compound 8) can also be synthesized by causing a reaction between the arylamine compound (Compound 5) and the aryl compound (Compound 4).

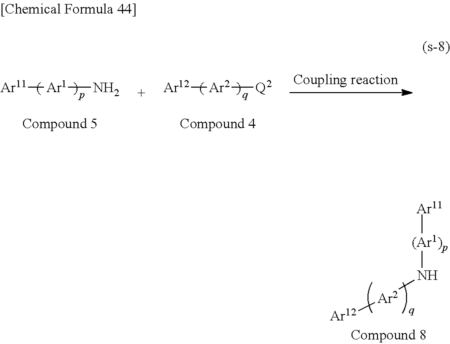

In the case where a Buchwald-Hartwig reaction using a palladium catalyst or a coupling reaction using copper or a copper compound is employed in Synthesis Scheme (s-8), the reaction can be performed under the same conditions as the reaction in Synthesis Scheme (s-1).

The diarylamine compound (Compound 9) shown in Synthesis Schemes (s-6) and (s-7) above can also be synthesized in accordance with Synthesis Scheme (s-9) below. Specifically, the diarylamine compound (Compound 9) can also be synthesized by causing a reaction between an arylamine compound (Compound 7) and the aryl compound (Compound 6).

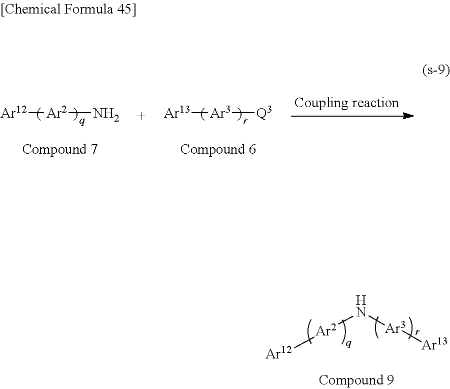

In the case where a Buchwald-Hartwig reaction using a palladium catalyst or a coupling reaction using copper or a copper compound is employed in Synthesis Scheme (s-9), the reaction can be performed under the same conditions as the reaction in Synthesis Scheme (s-1).

In the case where p and q are each an integer of 1 to 4, a reaction is caused between a triarylamine compound (Compound 10) and a halogenating reagent (Compound 11) in accordance with Synthesis Scheme (s-10), so that a triarylamine halide compound (Compound 12) can be obtained.

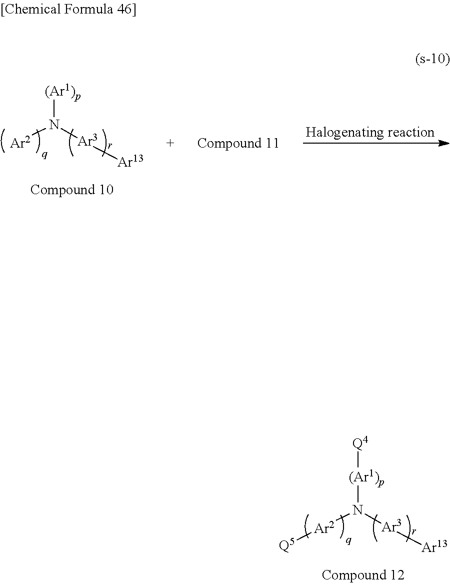

In Synthesis Scheme (s-10), Q⁴ and Q⁵ each independently represent chlorine, bromine, or iodine.

In Synthesis Scheme (s-10), as the halogenating reagent, N-chlorosuccinimide, N-bromosuccinimide, N-iodosuccinimide, 1,3-diiodo-5,5-dimethylimidazolidine-2,4-dione, bromine, iodine, or the like can be used, for example. Reagents that can be used in this reaction are not limited to the above reagents.

Then, a reaction is caused between the triarylamine halide compound (Compound 12) and a boron reagent (Compound 13) in accordance with Synthesis Scheme (s-11), so that an organoboron compound (Compound 14) can be obtained.

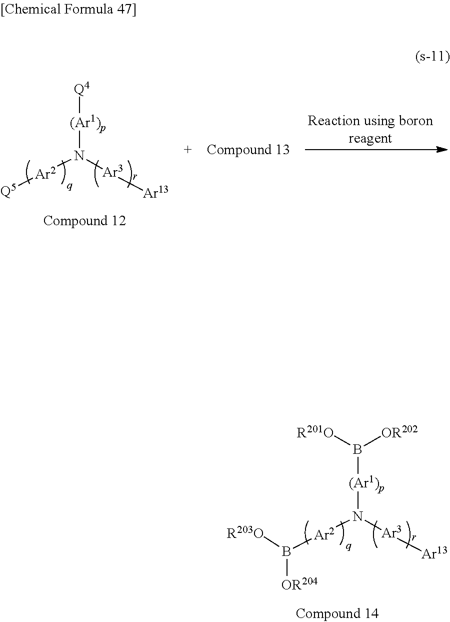

In Synthesis Scheme (s-11), R²⁰¹ to R²⁰⁴ each independently represent hydrogen (including deuterium) or an alkyl group having 1 to 6 carbon atoms. In the case where R²⁰¹ to R²⁰⁴ each represent hydrogen, Compound 14 is a boron compound. Furthermore, R²⁰¹ and R²⁰² may be bonded to each other to form a ring and R²⁰³ and R²⁰⁴ may be bonded to each other to form a ring, in which case the boron compound is pinacolborane, for example.

In the case where a Miyaura-Ishiyama borylation reaction is employed in Synthesis Scheme (s-11), bis(pinacolato)diboron or the like can be used as a boron reagent. Examples of a palladium-containing catalyst that can be used in this reaction include bis(dibenzylideneacetone)palladium(0) and [1,1-bis(diphenylphosphino)ferrocene]palladium(II) dichloride. In this reaction, an inorganic base such as potassium acetate, sodium acetate, or potassium hydroxide can be used. In this reaction, dioxane, tetrahydrofuran, dimethylformamide, acetonitrile, dimethyl sulfoxide, polyethylene glycol, toluene, or the like can be used as a solvent. Reagents that can be used in this reaction are not limited to the above reagents. As a catalyst in this reaction, instead of a palladium compound, a metal compound catalyst such as a rhodium compound catalyst, a cobalt compound catalyst, or an iron compound catalyst can be used.

In Synthesis Scheme (s-11), the organoboron compound (Compound 14) can be obtained also by using an organolithium reagent and a boron reagent. As the organolithium reagent, phenyllithium, n-butyllithium, sec-butyllithium, tert-butyllithium, or the like can be used. The target organoboron compound (Compound 14) can be obtained in the following manner: in Synthesis Scheme (s-11), Compound 12 is lithiated using an organolithium reagent, and a reaction is caused between Compound 12 that is lithiated and a boron compound. Reagents that can be used in this reaction are not limited to the above reagents.

Then, in accordance with Synthesis Scheme (s-12), the organoboron compound (Compound 14) and an aryl compound (Compound 15) are coupled, so that a triarylamine boron compound (Compound 16) can be obtained.

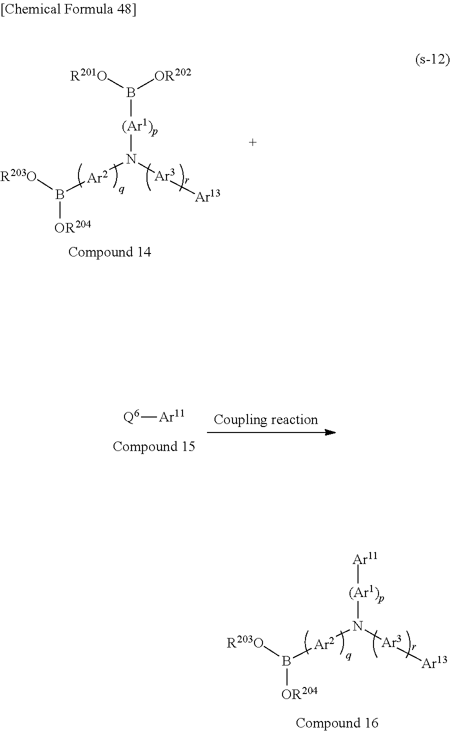

In Synthesis Scheme (s-12), Q⁶ represents chlorine, bromine, iodine, or a trifluoromethanesulfonyl group.

In Synthesis Scheme (s-12), for example, palladium(II) acetate, tetrakis(triphenylphosphine)palladium(0), or bis(triphenylphosphine)palladium(II) dichloride can be used as a palladium catalyst.

In addition, for example, tri(ortho-tolyl)phosphine, triphenylphosphine, or tricyclohexylphosphine can be used as a ligand of the palladium catalyst.

As a base, an organic base such as t-butoxysodium, an inorganic base such as potassium carbonate or sodium carbonate, or the like can be used.

As a reaction solvent, a mixed solvent of toluene and water, a mixed solvent of xylene and water, a mixed solvent of benzene and water, a mixed solvent of water and an ether such as ethylene glycol dimethyl ether or 1,4-dioxane, or the like can be used. Since a boronic acid or a boron compound reacts with a base to form a salt, the boronic acid or the boron compound reacts at a higher rate and potentially brings about an effect of increasing the yield when having higher solubility in an aqueous phase in which the base is dissolved; thus, it is preferable to add water. By contrast, in the case where an ether is used for the solvent, a similar effect can be expected even when water is not added.

In addition, as the reaction solvent, a mixed solvent of toluene, water, and an alcohol such as ethanol, a mixed solvent of xylene, water, and an alcohol such as ethanol, a mixed solvent of benzene, water, and an alcohol such as ethanol, or the like can be used. In particular, a mixed solvent of toluene and water, a mixed solvent of toluene, water, and ethanol, or a mixed solvent of water and an ether such as ethylene glycol dimethyl ether is preferable.

In Synthesis Scheme (s-11), the boron reagent may be replaced with an organometallic reagent or the like, in which case an organoaluminum compound, an organozirconium compound, an organozinc compound, or an organotin compound of Compound 12 can be obtained. Any of these organometallic compounds may replace Compound 14 in Synthesis Scheme (s-12). Also in the case where Compound 14 is replaced with the organoaluminum compound, the organozirconium compound, the organozinc compound, or the organotin compound of Compound 12, conditions such as a metal catalyst, a base, a solvent, and a temperature can be similar to those for the reaction using Compound 14.

Then, in accordance with Synthesis Scheme (s-13), the triarylamine boron compound (Compound 16) and an aryl compound (Compound 17) are coupled, so that the target organic compound represented by General Formula (G1) can be obtained.

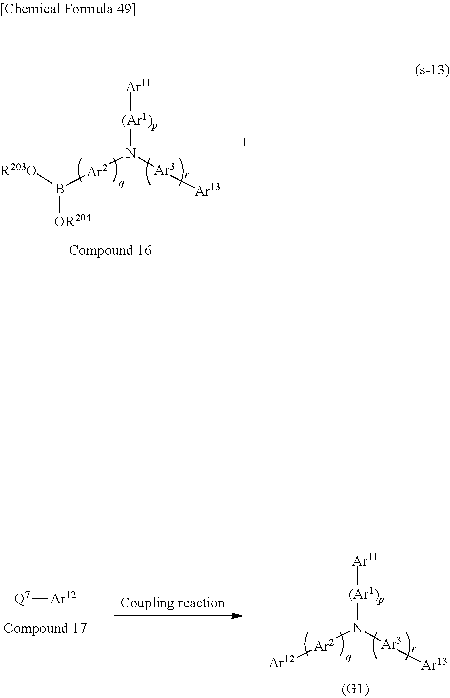

In Synthesis Scheme (s-13), Q⁷ represents chlorine, bromine, iodine, or a trifluoromethanesulfonyl group.

In the case where a cross coupling reaction using a palladium catalyst is employed in Synthesis Scheme (s-13), the reaction can be performed under the same conditions as the reaction in Synthesis Scheme (s-12).

Note that in the case where Ar¹¹ and Ar¹² represent the same substituent, Synthesis Schemes (s-12) and (s-13) can be collectively performed at the same time. That is, in Synthesis Scheme (s-12), two equivalents of Compound 15 are coupled to Compound 14, or two equivalents of Compound 17 are coupled to Compound 14, so that the target organic compound represented by General Formula (G1) can be obtained.

In accordance with Synthesis Scheme (s-14), the triarylamine halide compound (Compound 12) and an organoboron compound (Compound 18) are coupled, so that a triarylamine compound (Compound 19) can be obtained.

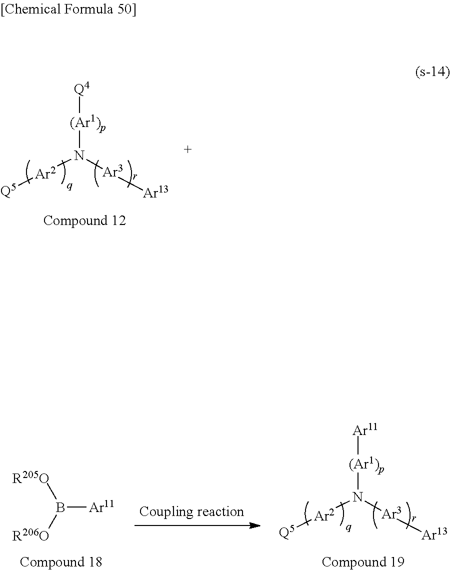

In Synthesis Scheme (s-14), R²⁰⁵ and R²⁰⁶ each independently represent hydrogen (including deuterium) or an alkyl group having 1 to 6 carbon atoms. In the case where R²⁰⁵ and R²⁰⁶ each represent hydrogen, Compound 18 is a boron compound. Furthermore, R²⁰⁵ and R²⁰⁶ may be bonded to each other to form a ring, in which case the boron compound is pinacolborane, for example.

In the case where a cross coupling reaction using a palladium catalyst is employed in Synthesis Scheme (s-14), the reaction can be performed under the same conditions as the reaction in Synthesis Scheme (s-12).

Next, in accordance with Synthesis Scheme (s-15), the triarylamine compound (Compound 19) and an organoboron compound (Compound 20) are coupled, so that the target triarylamine compound represented by General Formula (G1) can be obtained.

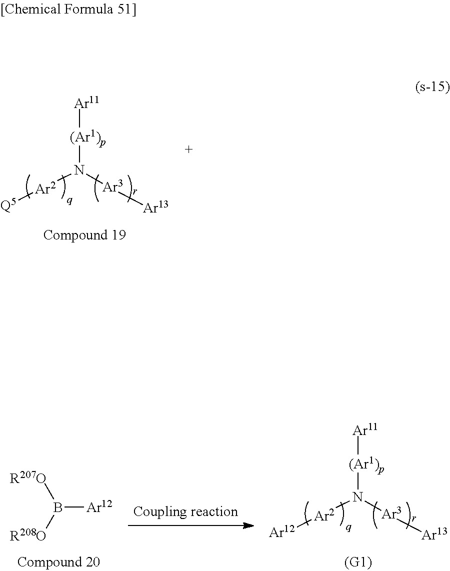

In the case where a cross coupling reaction using a palladium catalyst is employed in Synthesis Scheme (s-15), the reaction can be performed under the same conditions as the reaction in Synthesis Scheme (s-12).

Note that in the case where Ar¹¹ and Ar¹² represent the same substituent, two equivalents of the organoboron compound (Compound 18) are coupled to the triarylamine halide compound (Compound 12) in Synthesis Scheme (s-14), so that the target organic compound represented by General Formula (G1) can be obtained.

In the case where r is an integer of 1 to 4, a reaction is caused between a triarylamine compound (Compound 21) and the halogenating reagent (Compound 11) in accordance with Synthesis Scheme (s-16), so that a triarylamine halide compound (Compound 22) can be obtained.

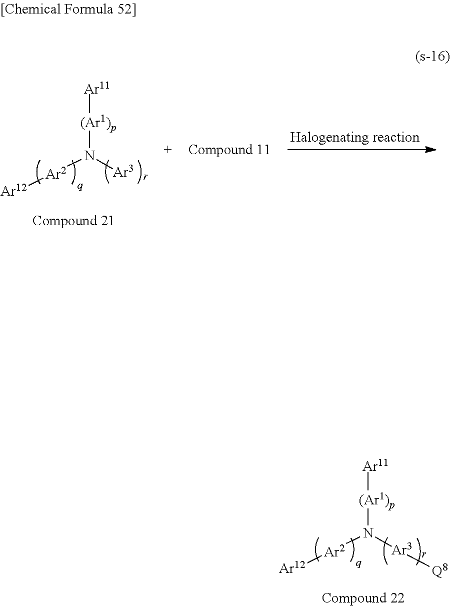

In Synthesis Scheme (s-16), Q¹ represents chlorine, bromine, or iodine.

In Synthesis Scheme (s-16), as the halogenating reagent, N-chlorosuccinimide, N-bromosuccinimide, N-iodosuccinimide, 1,3-diiodo-5,5-dimethylimidazolidine-2,4-dione, bromine, iodine, or the like can be used, for example. Reagents that can be used in this reaction are not limited to the above reagents.

Then, a reaction is caused between the triarylamine halide compound (Compound 22) and the boron reagent (Compound 13) in accordance with Synthesis Scheme (s-17), so that an organoboron compound that is a triarylamine (Compound 23) can be obtained.

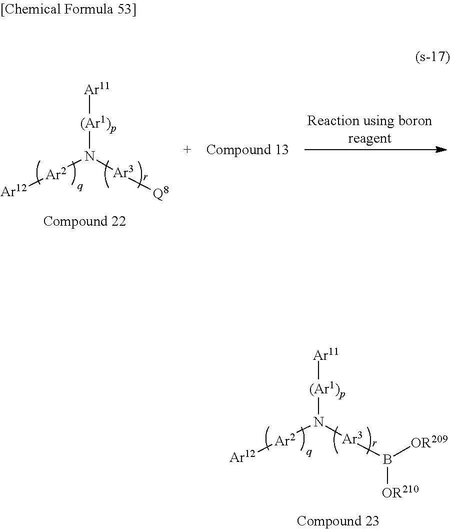

In Synthesis Scheme (s-17), R²⁰⁹ and R²¹⁰ each independently represent hydrogen (including deuterium) or an alkyl group having 1 to 6 carbon atoms. In the case where R²⁰⁹ and R²¹⁰ each represent hydrogen, Compound 23 is a boron compound. Furthermore, R²⁰⁹ and R²¹⁰ may be bonded to each other to form a ring, in which case the boron compound is pinacolborane, for example.

The reaction in Synthesis Scheme (s-17) can be performed under the same conditions as the reaction in Synthesis Scheme (s-11).

In Synthesis Scheme (s-17), the boron reagent may be replaced with an organometallic reagent or the like, in which case an organoaluminum compound, an organozirconium compound, an organozinc compound, or an organotin compound of Compound 22 can be obtained.

Next, in accordance with Synthesis Scheme (s-18), the organoboron compound (Compound 23) and an aryl compound (Compound 24) are coupled, so that the target triarylamine compound represented by General Formula (G1) can be obtained.

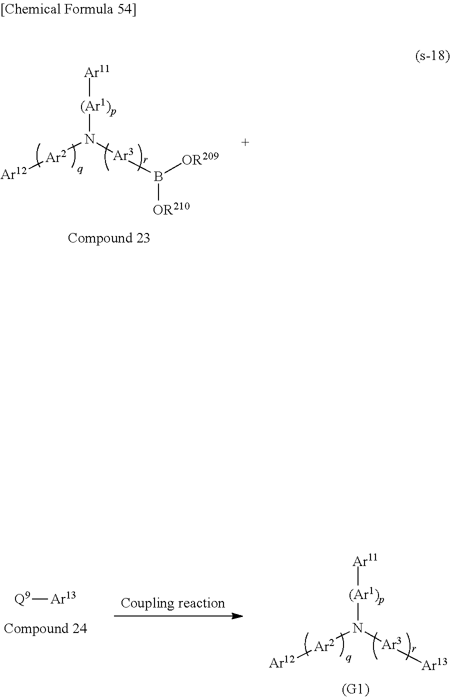

In Synthesis Scheme (s-18), Q⁹ represents chlorine, bromine, iodine, or a trifluoromethanesulfonyl group.

In the case where a cross coupling reaction using a palladium catalyst is employed in Synthesis Scheme (s-18), the reaction can be performed under the same conditions as the reaction in Synthesis Scheme (s-12).

In accordance with Synthesis Scheme (s-19), a reaction is caused between the triarylamine halide compound (Compound 22) and an organoboron compound (Compound 25), so that the target organic compound represented by General Formula (G1) can be obtained.

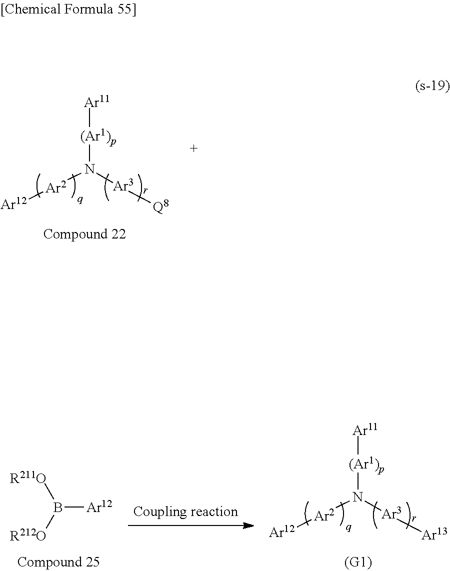

In Synthesis Scheme (s-19), R²¹¹ and R²¹² each independently represent hydrogen (including deuterium) or an alkyl group having 1 to 6 carbon atoms. In the case where R²¹¹ and R²¹² each represent hydrogen, Compound 25 is a boron compound. Furthermore, R²¹¹ and R²¹² may be bonded to each other to form a ring, in which case the boron compound is pinacolborane, for example.

In the case where a cross coupling reaction using a palladium catalyst is employed in Synthesis Scheme (s-19), the reaction can be performed under the same conditions as the reaction in Synthesis Scheme (s-12).

Next, a deuteration reaction is described.

Here, General Formula (G1′) below represents a triarylamine compound in which the number of deuteriums is less than the number of deuteriums included in the organic compound represented by General Formula (G1). Note that the number of deuteriums included in the triarylamine compound represented by General Formula (G1′) may be zero.

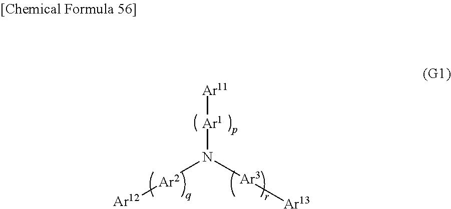

In General Formula (G1′), p, q, and r are the same as those described above and are not described here.

In General Formula (G1′), Ar^{1′} includes no deuterium or fewer deuteriums than Ar¹; Ar^{2′} includes no deuterium or fewer deuteriums than Ar²; Ar^{3′} includes no deuterium or fewer deuteriums than Ar³; Ar^{11′} includes no deuterium or fewer deuteriums than Ar¹¹; Ar^{12′} includes no deuterium or fewer deuteriums than Ar¹²; and Ar^{13′} includes no deuterium or fewer deuteriums than Ar¹³.

When a reaction is caused between the triarylamine compound (G1′) and a deuteration reagent (Compound 26) in accordance with Synthesis Scheme (D-1), the target organic compound represented by General Formula (G1) can be obtained.

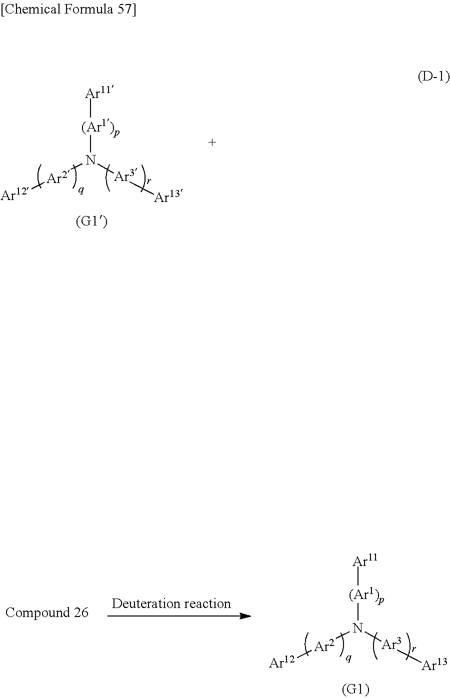

As the deuteration reagent in Synthesis Scheme (D-1), it is possible to use a reagent that contains platinum (Pt), palladium (Pd), rhodium (Rh), iridium (Ir), ruthenium (Ru), or molybdenum (Mo) as a transition metal catalyst, for example. It is also possible to use a reagent that contains formic acid, hydrogen chloride (HCl), sulfuric acid (H₂SO₄), acetic acid (CH₃COOH), trifluoroacetic acid (CF₃COOH), trifluoromethanesulfonic acid (CF₃SO₃H), deuterium chloride (DCl), deuterated sulfuric acid (D₂SO₄), deuterated acetic acid (CH₃COOD or CD₃COOD), deuterated trifluoroacetic acid (CF₃COOD), deuterated trifluoromethanesulfonic acid (CF₃SO₃D), or the like as an acid catalyst, for example. It is also possible to use a reagent that contains potassium carbonate (K₂CO₃), t-butoxysodium (abbreviation: ^{t}BuONa), sodium hydride (NaH), sodium hydroxide (NaOH), alkyllithium, or the like as a base catalyst, for example. Reagents that can be used in this reaction are not limited to the above reagents.

In Synthesis Scheme (D-1), as a solvent, it is possible to use a deuterated solvent such as heavy water (D₂O), deuterated benzene, deuterated toluene, deuterated dimethyl sulfoxide, or deuterated methanol, for example. A mixed solvent in which these solvents are freely combined can also be used. Note that in a deuterium (D₂) atmosphere, a deuteration reaction sometimes proceeds without using a deuterated solvent, and thus, a deuterated solvent is not necessarily used. Solvents that can be used in this reaction are not limited to the above-described solvents.

When a reaction is caused between a raw material that is not yet subjected to a coupling reaction, e.g., an aryl compound (Compound 1′), and the deuteration reagent (Compound 26) as shown in Synthesis Scheme (D-2), the aryl compound (Compound 1) that includes deuterium can be obtained.

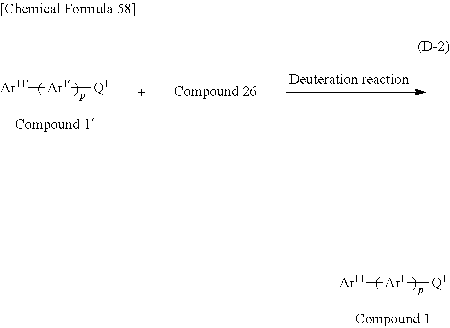

The reaction in Synthesis Scheme (D-2) can be performed under the same conditions as the reaction in Synthesis Scheme (D-1).

In the case where Compound 4 or 6 includes deuterium, Compound 4 or 6 can also be synthesized by a reaction similar to that in Synthesis Scheme (D-2).

When a reaction is caused between, for example, a diarylamine compound (Compound 3′) and the deuteration reagent (Compound 26) as shown in Synthesis Scheme (D-3), the diarylamine compound (Compound 3) that includes deuterium can be obtained.

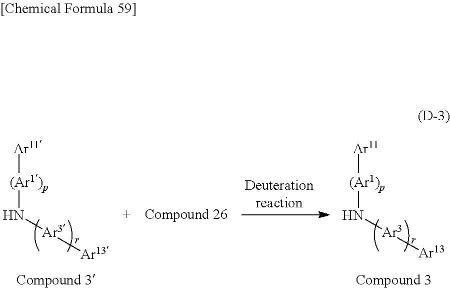

The reaction in Synthesis Scheme (D-3) can be performed under the same conditions as the reaction in Synthesis Scheme (D-1).

In the case where Compound 8 or 9 includes deuterium, Compound 8 or 9 can also be synthesized by a reaction similar to that in Synthesis Scheme (D-1).

When a reaction is caused between, for example, a triarylamine compound (Compound 10′) and the deuteration reagent (Compound 26) as shown in Synthesis Scheme (D-4), the triarylamine compound (Compound 10) that includes deuterium can be obtained.

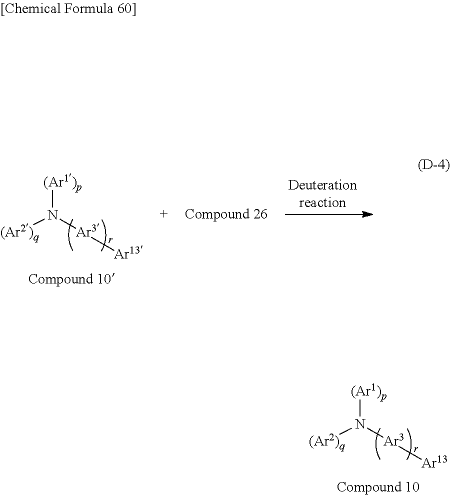

The reaction in Synthesis Scheme (D-4) can be performed under the same conditions as the reaction in Synthesis Scheme (D-1).

In the case where Compound 21 includes deuterium, Compound 21 can also be synthesized by a reaction similar to that in Synthesis Scheme (D-4).

When a reaction is caused between, for example, an aryl compound (Compound 15′) and the deuteration reagent (Compound 26) as shown in Synthesis Scheme (D-5), the aryl compound (Compound 15) that includes deuterium can be obtained.

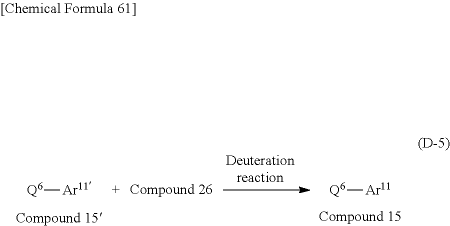

The reaction in Synthesis Scheme (D-5) can be performed under the same conditions as the reaction in Synthesis Scheme (D-1).

In the case where Compound 17 or 24 includes deuterium, Compound 17 or 24 can also be synthesized by a reaction similar to that in Synthesis Scheme (D-1).

Methods for synthesizing deuterium-containing organic compounds are not limited to Synthesis Schemes (D-1) to (D-5) above.

Methods for synthesizing the organic compound represented by General Formula (G1) are not limited to Synthesis Schemes (s-1) to (s-19) and (D-1) to (D-5) above.

The organic compound of one embodiment of the present invention can be synthesized in the above manner, but the present invention is not limited thereto, and other synthesis methods may be employed.

This embodiment can be freely combined with any of the other embodiments and the examples.

### Embodiment 3

In this embodiment, structures of a light-emitting device of one embodiment of the present invention are described.

It is a long time since displays (organic EL displays) that include organic EL devices (hereinafter also referred to as light-emitting devices) as display devices were put into practical use. These displays are usually provided with pixels emitting light with at least three colors of red, green, and blue to achieve full-color display.

The pixels are provided with light-emitting devices for the respective emission colors. In a display fabricated by a side-by-side method, or what is called a separate coloring method, light-emitting devices include light-emitting substances corresponding to the respective emission colors of the pixels.

In particular, since the organic compound described in Embodiment 2 has a good hole-transport property, the organic compound can be suitably used for a carrier-transport layer or a light-emitting layer of a light-emitting device, specifically layers from a hole-injection layer to the light-emitting layer, or more specifically a hole-transport layer. Thus, one embodiment of the present invention is a light-emitting device in which the organic compound described in Embodiment 2 is used as a hole-transport material.

Note that the organic compound described in Embodiment 2 can also be used for a cap layer, for example, in addition to the hole-transport layer and the light-emitting layer. The organic compound is appropriately used in accordance with the characteristics required, in the design of an organic EL device.

### <Basic Structure of Light-Emitting Device>

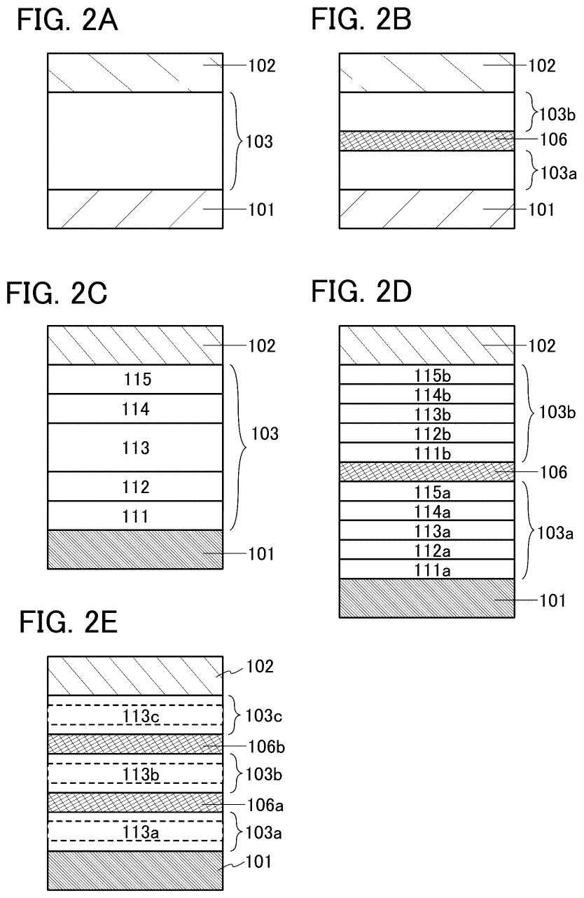

Basic structures of the light-emitting device will be specifically described below with reference to FIGS. 2A to 2E. FIG. 2A illustrates a light-emitting device having a structure (single structure) in which an organic compound layer (also referred to as an EL layer) including a light-emitting layer is provided between a pair of electrodes. Specifically, the organic compound layer 103 is sandwiched between the first electrode 101 and the second electrode 102.

FIG. 2B illustrates a light-emitting device that has a stacked-layer structure (tandem structure) in which a plurality of organic compound layers (two organic compound layers 103a and 103b in FIG. 2B) are provided between a pair of electrodes and a charge-generation layer 106 is provided between the organic compound layers. A light-emitting device having the tandem structure enables fabrication of a light-emitting apparatus that has high efficiency without changing the amount of current.

The charge-generation layer 106 has a function of injecting electrons into one of the organic compound layers 103a and 103b and injecting holes into the other of the organic compound layers 103a and 103b when a potential difference is caused between the first electrode 101 and the second electrode 102. Thus, when voltage is applied in FIG. 2B such that the potential of the first electrode 101 is higher than that of the second electrode 102, the charge-generation layer 106 injects electrons into the organic compound layer 103a and injects holes into the organic compound layer 103b.

Note that in terms of light extraction efficiency, the charge-generation layer 106 preferably has a property of transmitting visible light (specifically, the charge-generation layer 106 preferably has a visible light transmittance higher than or equal to 40%). The charge-generation layer 106 functions even if it has lower conductivity than the first electrode 101 and the second electrode 102.

FIG. 2C illustrates a stacked-layer structure of the organic compound layer 103 in the light-emitting device of one embodiment of the present invention. In this case, the first electrode 101 is regarded as functioning as an anode, and the second electrode 102 is regarded as functioning as a cathode. The organic compound layer 103 has a structure in which the hole-injection layer 111, the hole-transport layer 112, the light-emitting layer 113, the electron-transport layer 114, and the electron-injection layer 115 are stacked in this order over the first electrode 101. Note that the light-emitting layer 113 may have a stacked-layer structure of a plurality of light-emitting layers that emit light of different colors. For example, a light-emitting layer including a light-emitting substance that emits red light, a light-emitting layer including a light-emitting substance that emits green light, and a light-emitting layer including a light-emitting substance that emits blue light may be stacked with or without a layer including a carrier-transport material therebetween. Alternatively, a light-emitting layer including a light-emitting substance that emits yellow light and a light-emitting layer including a light-emitting substance that emits blue light may be used in combination. Note that the stacked-layer structure of the light-emitting layer 113 is not limited to the above. For example, the light-emitting layer 113 may have a stacked-layer structure of a plurality of light-emitting layers that emit light of the same color. For example, a first light-emitting layer including a light-emitting substance that emits blue light and a second light-emitting layer including a light-emitting substance that emits blue light may be stacked with or without a layer including a carrier-transport material therebetween. The structure in which a plurality of light-emitting layers that emit light of the same color are stacked can sometimes achieve higher reliability than a single-layer structure. In the case where a plurality of light-emitting layers are provided as in the tandem structure illustrated in FIG. 2B, the layers in the organic compound layer 103 are sequentially stacked from the anode side as described above. When the first electrode 101 is the cathode and the second electrode 102 is the anode, the stacking order of the layers in the organic compound layer 103 is reversed. Specifically, the layer 111 over the first electrode 101 serving as the cathode is an electron-injection layer; the layer 112 is an electron-transport layer; the layer 113 is a light-emitting layer; the layer 114 is a hole-transport layer; and the layer 115 is a hole-injection layer.

The light-emitting layer 113 included in the organic compound layers (103, 103a, and 103b) includes an appropriate combination of a light-emitting substance and a plurality of substances, so that fluorescent light of a desired color or phosphorescent light of a desired color can be obtained. The light-emitting layer 113 may have a stacked-layer structure having different emission colors. In that case, the light-emitting substance and other substances are different between the stacked light-emitting layers. Alternatively, the plurality of organic compound layers (103a and 103b) in FIG. 2B may exhibit their respective emission colors. Also in that case, the light-emitting substance and other substances are different between the light-emitting layers.

The light-emitting device of one embodiment of the present invention can have a micro optical resonator (microcavity) structure when, for example, the first electrode 101 is a reflective electrode and the second electrode 102 is a transflective electrode in FIG. 2C. Thus, light from the light-emitting layer 113 in the organic compound layer 103 can be resonated between the electrodes and light emitted through the second electrode 102 can be intensified. Thus, high resolution can be easily achieved. In addition, emission intensity at a predetermined wavelength in the front direction can be increased, whereby power consumption can be reduced.

Note that when the first electrode 101 of the light-emitting device is a reflective electrode having a stacked-layer structure of a reflective conductive material and a light-transmitting conductive material (transparent conductive film), optical adjustment can be performed by adjusting the thickness of the transparent conductive film. Specifically, when the wavelength of light obtained from the light-emitting layer 113 is k, the optical path length between the first electrode 101 and the second electrode 102 (the product of the thickness and the refractive index) is preferably adjusted to be mλ/2 (m is an integer greater than or equal to 1) or close to mλ/2.

To amplify desired light (wavelength: λ) obtained from the light-emitting layer 113, each of the optical path length from the first electrode 101 to a region where the desired light is obtained in the light-emitting layer 113 (light-emitting region) and the optical path length from the second electrode 102 to the region where the desired light is obtained in the light-emitting layer 113 (light-emitting region) is preferably adjusted to be (2m′+1)λ/4 (m′ is an integer greater than or equal to 1) or close to (2m′+1)λ/4. Here, the light-emitting region means a region where holes and electrons are recombined in the light-emitting layer 113.

By such optical adjustment, the spectrum of specific monochromatic light obtained from the light-emitting layer 113 can be narrowed and light emission with high color purity can be obtained.

In the above case, the optical path length between the first electrode 101 and the second electrode 102 is, to be exact, the total thickness from a reflective region in the first electrode 101 to a reflective region in the second electrode 102. However, it is difficult to precisely determine the reflective regions in the first electrode 101 and the second electrode 102; thus, it is assumed that the above effect can be sufficiently obtained wherever the reflective regions may be set in the first electrode 101 and the second electrode 102. Furthermore, the optical path length between the first electrode 101 and the light-emitting layer that emits the desired light is, to be exact, the optical path length between the reflective region in the first electrode 101 and the light-emitting region in the light-emitting layer that emits the desired light. However, it is difficult to precisely determine the reflective region in the first electrode 101 and the light-emitting region in the light-emitting layer that emits the desired light; thus, it is assumed that the above effect can be sufficiently obtained wherever the reflective region and the light-emitting region may be set in the first electrode 101 and the light-emitting layer that emits the desired light, respectively.

The light-emitting device illustrated in FIG. 2D is a light-emitting device having the tandem structure. The tandem structure enables a light-emitting device to emit light with high luminance. Furthermore, the amount of current needed for obtaining a predetermined luminance can be smaller in the tandem structure than in the single structure; thus, the tandem structure enables higher reliability. In addition, power consumption can be reduced.

The light-emitting device illustrated in FIG. 2E is an example of the light-emitting device having the tandem structure illustrated in FIG. 2B, and includes three organic compound layers (103a, 103b, and 103c) stacked with charge-generation layers (106a and 106b) positioned therebetween, as illustrated in FIG. 2E. The three organic compound layers (103a, 103b, and 103c) include respective light-emitting layers (113a, 113b, and 113c), and the emission colors of the light-emitting layers can be selected freely. For example, the light-emitting layer 113a can emit blue light, the light-emitting layer 113b can emit red light, green light, or yellow light, and the light-emitting layer 113c can emit blue light; alternatively, the light-emitting layer 113a can emit red light, the light-emitting layer 113b can emit blue light, green light, or yellow light, and the light-emitting layer 113c can emit red light.

In the above light-emitting device of one embodiment of the present invention, at least one of the first electrode 101 and the second electrode 102 is a light-transmitting electrode (e.g., a transparent electrode or a transflective electrode). In the case where the light-transmitting electrode is a transparent electrode, the transparent electrode has a visible light transmittance higher than or equal to 40%. In the case where the light-transmitting electrode is a transflective electrode, the transflective electrode has a visible light reflectance higher than or equal to 20% and lower than or equal to 80%, preferably higher than or equal to 40% and lower than or equal to 70%. These electrodes preferably have a resistivity lower than or equal to 1×10⁻² Ω·cm.

When one of the first electrode 101 and the second electrode 102 is a reflective electrode in the above light-emitting device of one embodiment of the present invention, the visible light reflectance of the reflective electrode is higher than or equal to 40% and lower than or equal to 100%, preferably higher than or equal to 70% and lower than or equal to 100%. This electrode preferably has a resistivity lower than or equal to 1×10⁻² Ω·cm.

### <Specific Structure of Light-Emitting Device>

Next, a specific structure of the light-emitting device of one embodiment of the present invention will be described. Here, the description is made using FIG. 2D illustrating the tandem structure. Note that the structure of the organic compound layer applies also to the structure of the light-emitting devices having the single structure in FIGS. 2A and 2C. When the light-emitting device in FIG. 2D has a microcavity structure, the first electrode 101 is formed as a reflective electrode and the second electrode 102 is formed as a transflective electrode. Thus, a single-layer structure or a stacked-layer structure can be formed using one or more kinds of desired electrode materials. Note that the second electrode 102 is formed after formation of the organic compound layer 103b, with the use of a material selected as appropriate.

### <Materials of Light-Emitting Device>

### <<Light-Emitting Layer>>

The light-emitting layers (113, 113a, and 113b) include a light-emitting substance. Note that as a light-emitting substance that can be used in the light-emitting layers (113, 113a, and 113b), a substance whose emission color is blue, violet, bluish violet, green, yellowish green, yellow, orange, red, or the like can be used as appropriate. When a plurality of light-emitting layers are provided, the use of different light-emitting substances for the light-emitting layers enables exhibiting different emission colors (e.g., white light emission obtained by a combination of complementary emission colors). Furthermore, a stacked-layer structure in which one light-emitting layer contains two or more kinds of light-emitting substances may be employed.

The light-emitting layers (113, 113a, and 113b) may each include one or more kinds of organic compounds (e.g., a host material) in addition to a light-emitting substance (a guest material).

Specifically, the light-emitting layer 113 can have the structure that is described with reference to FIG. 1B. In the light-emitting layer 113, the host materials 118 are present in the largest proportion by weight, and the guest material 119 (phosphorescent compound) is dispersed in the host materials 118. The T₁ levels of the host materials 118 (the organic compounds 118_1 and 118_2) in the light-emitting layer 113 are preferably higher than the T₁ level of the guest material (the guest material 119) in the light-emitting layer 113.

The lowest triplet excitation energy level (T₁ level) can be calculated, using a thin film formed by depositing a sample, from an emission edge obtained by measurement of an emission spectrum (phosphorescence spectrum) at a low temperature (e.g., 10 K). Note that the emission spectrum of an emission center substance may be measured using a sample in the form of a thin film or a solution; however, a sample in the form of a solution is preferably used for examination of the state of an isolated molecule. As a solvent of the solution, a solvent with relatively low polarity, such as toluene or chloroform, is preferably used. In the case where the emission center substance is a phosphorescent compound, the temperature at which the lowest triplet excitation energy level (T₁ level) is measured may be either low temperature (e.g., 10 K) or room temperature (e.g., 298 K), and the lowest triplet excitation energy level is calculated from an emission edge obtained by measurement of an emission spectrum (phosphorescence spectrum). Note that the emission edge can be determined as the intersection of a tangent and the horizontal axis (representing wavelength) or the baseline. The tangent is drawn at a point at which the slope on a shorter wavelength side of the shortest-wavelength peak (or the shortest-wavelength shoulder peak) of the emission spectrum (phosphorescence spectrum) has the maximum absolute value.

Examples of the light-emitting substance that can be used as the guest material include a substance emitting red light. In addition, the substance emitting red light is preferably a substance emitting phosphorescent light, particularly preferably an organometallic complex. Examples of the light-emitting substances include organometallic iridium complexes with a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes with a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes with a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-N]phenyl-KC]iridium(III), and (3,7-diethyl-4,6-nonanedionato-κO⁴,κO⁶)bis[2,4-dimethyl-6-[5-(1-methylethyl)-2-quinolinyl-KN]phenyl-κC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds have an emission peak in the wavelength range from 600 nm to 700 nm. Furthermore, the organometallic iridium complexes with a pyrazine skeleton can provide red light emission with favorable chromaticity. Note that other known red phosphorescent substances can also be used.

In the case where a light-emitting apparatus does not use a red-light-emitting substance as the light-emitting substance or includes light-emitting devices with different structures, the light-emitting substance may be a fluorescent substance, a phosphorescent substance, a substance exhibiting thermally activated delayed fluorescence (TADF), or any other light-emitting substance.

Examples of the material that can be used as a light-emitting substance that emits fluorescent light (a fluorescent substance) in the light-emitting layer 113 are as follows. Any other fluorescent substance can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(N,N′,N″-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N″-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N″-triphenyl-1,4-phenylenediamine (abbreviation: 2DPAPA), N-[9,10-bis(biphenyl-2-yl)-2-anthryl]-N,N′,N″-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine](abbreviation: 1,6BnfAPrn-03), N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Fused aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, and high reliability.

Examples of the material that can be used when a phosphorescent substance is used as the light-emitting substance in the light-emitting layer 113 are as follows.

The examples include organometallic iridium complexes with a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]) and tris(5-methyl-3,4-diphenyl-4H-1,2,4-triazolato)iridium(III) (abbreviation: [Ir(Mptz)₃]); organometallic iridium complexes with a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic iridium complexes with an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-{1-[2,6-bis(1-methylethyl)phenyl]-1H-imidazol-2-yl-κN³}-4-cyanophenyl-κC)iridium(III) (abbreviation: CNImIr); organometallic iridium complexes with a benzimidazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); and organometallic iridium complexes in which a phenylpyridine derivative with an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIr(acac)). These compounds exhibit blue phosphorescence and have an emission peak in the wavelength range from 440 nm to 520 nm.

Other examples include organometallic iridium complexes with a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes with a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes with a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d3)₂(mbfpypy-d3)]), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-KN]phenyl-κC}iridium(III) (abbreviation: Ir(5mtpy-d6)₂(mbfpypy-iPr-d4)), [2-d₃-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d3)]), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir5m(ppy-d3)₂(mdppy-d3)]), [2-methyl-8-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), and [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)); and a rare earth metal complex such as tris(acetylacetonato)(monophenanthroline)terbium(III) (abbreviation: [Tb(acac)₃(Phen)]). These are mainly compounds that exhibit green phosphorescence and have an emission peak in the wavelength range from 500 nm to 600 nm. Note that organometallic iridium complexes with a pyrimidine skeleton have distinctively high reliability or emission efficiency and thus are particularly preferable.

Note that any of the aforementioned red phosphorescent materials can also be used. Besides the above phosphorescent compounds, known phosphorescent compounds may be selected and used.

Examples of a TADF material include a fullerene, a derivative thereof, an acridine, a derivative thereof, and an eosin derivative. Other examples include a metal-containing porphyrin, such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

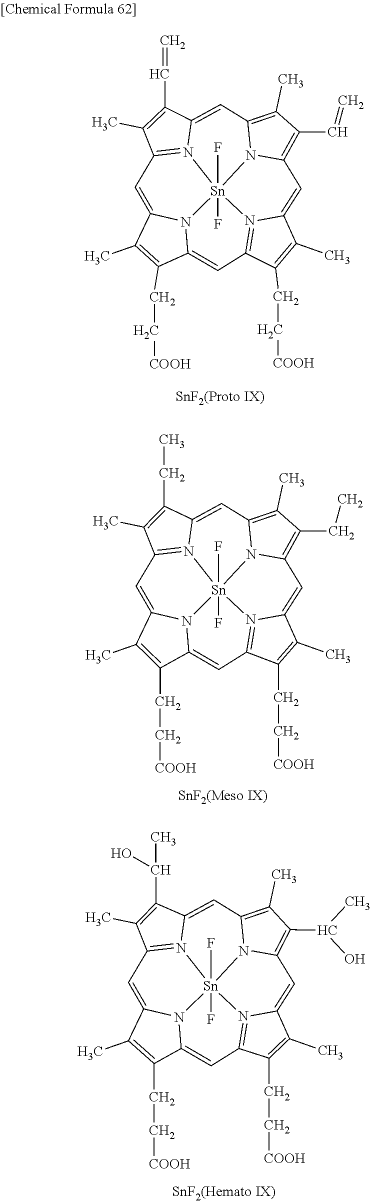

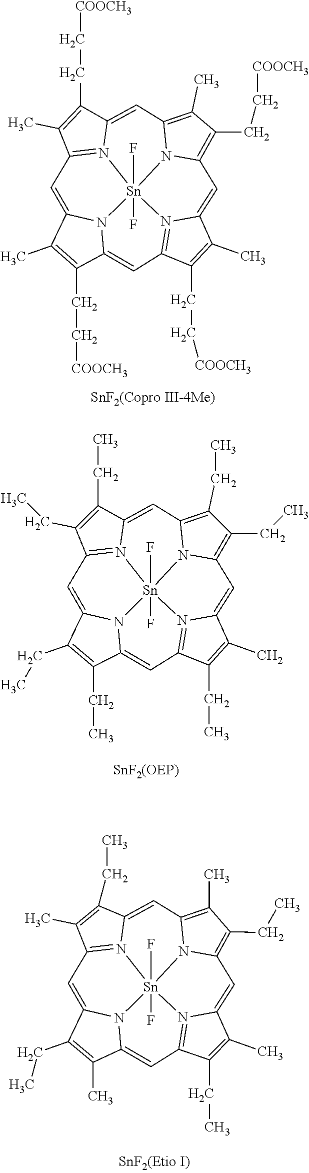

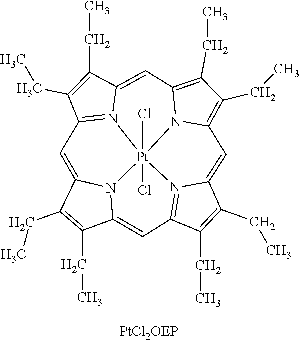

It is also possible to use a heterocyclic compound with one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 9-[4-(4,6-diphenyl-1,3,5-triazin-2-yl)phenyl]-9′-phenyl-3,3′-bi-9H-carbazole (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of its high electron-transport and hole-transport properties due to the π-electron rich heteroaromatic ring and the π-electron deficient heteroaromatic ring. Among skeletons having the π-electron deficient heteroaromatic ring, a pyridine skeleton, a diazine skeleton (a pyrimidine skeleton, a pyrazine skeleton, or a pyridazine skeleton), and a triazine skeleton are particularly preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferred because the electron-donating property of the π-electron rich heteroaromatic ring and the electron-accepting property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring with a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

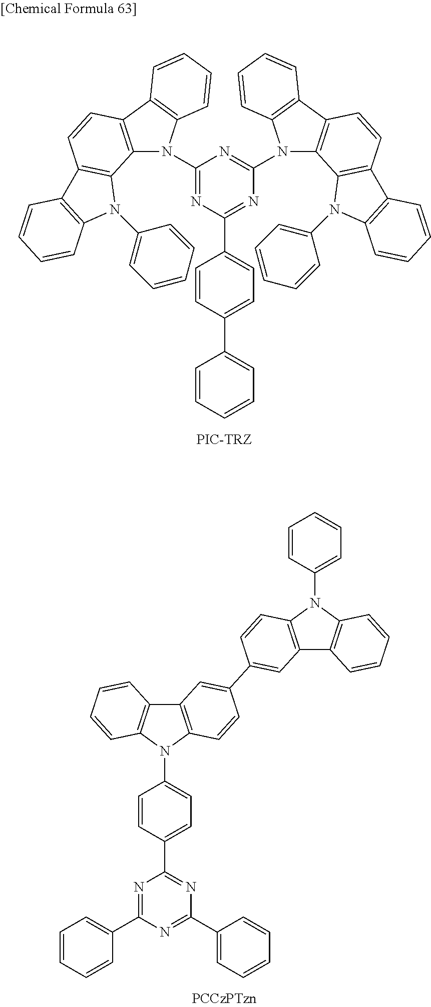 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

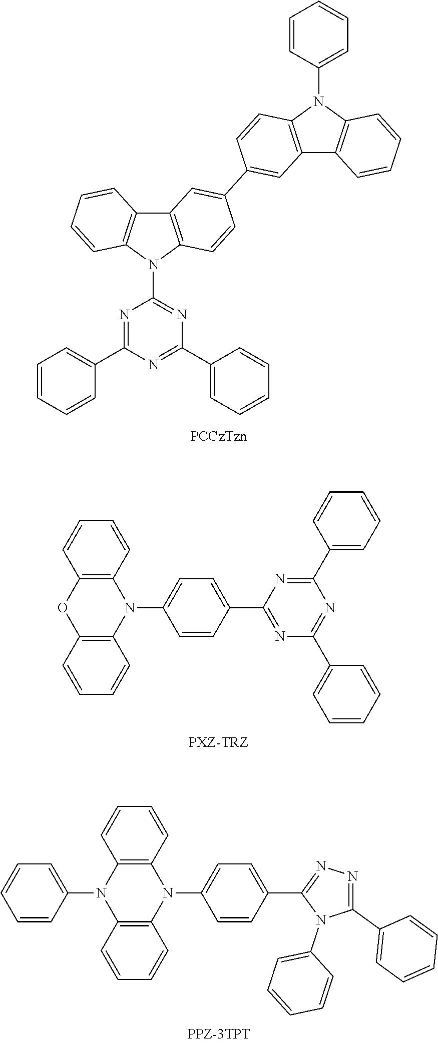 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1]

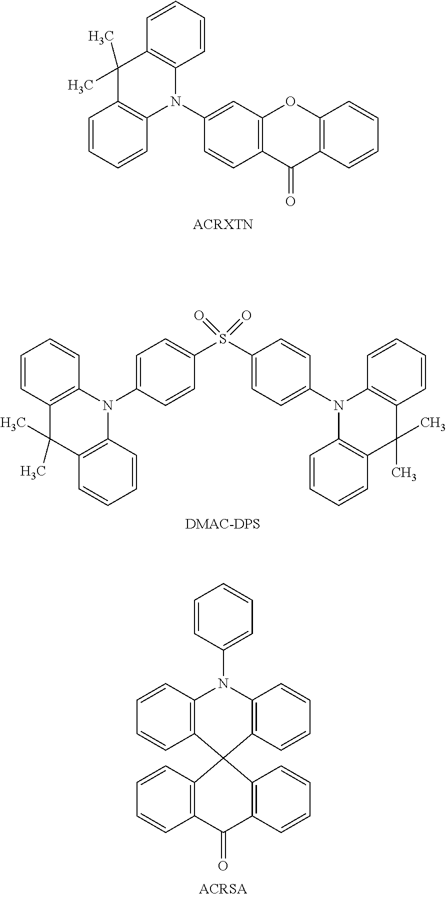 [SMILES: CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

It is also possible to use a TADF material that enables reversible intersystem crossing at extremely high speed and emits light in accordance with a thermal equilibrium model between a singlet excited state and a triplet excited state. Since such a TADF material has an extremely short emission lifetime (excitation lifetime), an efficiency decrease of a light-emitting device in a high-luminance region can be inhibited. Specifically, a material having the following molecular structure can be used.

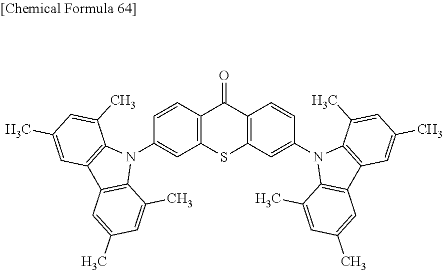

Note that a TADF material is a material having a small difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed by two kinds of substances has an extremely small difference between the S₁ level and the T₁ level and functions as a TADF material capable of converting triplet excitation energy into singlet excitation energy.

A phosphorescence spectrum observed at a low temperature (e.g., 77 K to 10 K) is used for an index of the T₁ level. When the level of energy of light with a wavelength of the line obtained by extrapolating a tangent to the fluorescence spectrum at a tail on the short wavelength side is the S₁ level and the level of energy of light with a wavelength of the line obtained by extrapolating a tangent to the phosphorescence spectrum at a tail on the short wavelength side is the T₁ level, the difference between the S₁ level and the T₁ level of the TADF material is preferably less than or equal to 0.3 eV, further preferably less than or equal to 0.2 eV.

When a TADF material is used as the light-emitting substance, the S₁ level of the host material is preferably higher than that of the TADF material. In addition, the T₁ level of the host material is preferably higher than that of the TADF material.

As an electron-transport material used as the host material (corresponding to a first organic compound in one embodiment of the present invention), for example, any of metal complexes such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), and bis[2-(2-benzothiazolyl)phenolato]zinc(II) (abbreviation: ZnBTZ); or an organic compound having a π-electron deficient heteroaromatic ring can be used. Examples of the organic compound having a π-electron deficient heteroaromatic ring include an organic compound having a heteroaromatic ring with an azole skeleton, such as 2-(4-biphenyl)-5-(4-tert-butyl-phenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(4-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II); an organic compound having a heteroaromatic ring with a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 2,4-bis[4-(1-naphthyl)phenyl]-6-[4-(3-pyridyl)phenyl]pyrimidine (abbreviation: 2,4NP-6PyPPm), 6-(biphenyl-3-yl)-4-[3,5-bis(9H-carbazol-9-yl)phenyl]-2-phenylpyrimidine (abbreviation: 6mBP-4Cz2PPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); an organic compound having a heteroaromatic ring with a pyridine skeleton, such as 3,5-bis[3-(9H-carbazol-9-yl)phenyl]pyridine (abbreviation: 35DCzPPy) or 1,3,5-tri[(3-pyridyl)-phenyl-3-yl]benzene (abbreviation: TmPyPB); and an organic compound having a heteroaromatic ring with a triazine skeleton, such as 2-[3′-(9,9-dimethyl-9H-fluoren-2-yl)biphenyl-3-yl]-4,6-diphenyl-1,3,5-triazine (abbreviation: mFBPTzn), 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn). Among the above materials, the organic compound having a heteroaromatic ring with a diazine skeleton, the organic compound having a heteroaromatic ring with a pyridine skeleton, and the organic compound having a heteroaromatic ring with a triazine skeleton have high reliability and thus are preferable. In particular, the organic compound having a heteroaromatic ring with a diazine (pyrimidine or pyrazine) skeleton and the organic compound having a heteroaromatic ring with a triazine skeleton have a high electron-transport property to contribute to a reduction in driving voltage.

As a hole-transport material used as the host material (corresponding to a second organic compound in one embodiment of the present invention), an organic compound having an amine skeleton or a π-electron rich heteroaromatic ring can also be used. Examples of the organic compound having an amine skeleton or a π-electron rich heteroaromatic ring include a compound having an aromatic amine skeleton, such as 4,4′-bis[N-(1-naphthyl)-N-phenylamino]biphenyl (abbreviation: NPB), N,N′-diphenyl-NN-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), or N-(biphenyl-4-yl)-N-[4-(9-phenyl-9H-carbazol-3-yl)phenyl]-9,9-dimethyl-9H-fluoren-2-amine (abbreviation: PCBBiF); a compound having a carbazole skeleton, such as 1,3-bis(N-carbazolyl)benzene (abbreviation: mCP), 4,4′-di(N-carbazolyl)biphenyl (abbreviation: CBP), or 3,6-bis(3,5-diphenylphenyl)-9-phenylcarbazole (abbreviation: CzTP); a compound having a 3,3′-bicarbazole skeleton, such as 9,9′-diphenyl-9H,9′H-3,3′-bicarbazole (abbreviation: PCCP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, the compound having an aromatic amine skeleton or the compound having a carbazole skeleton is preferable because these compounds are highly reliable and have high hole-transport properties to contribute to a reduction in driving voltage. In addition, the organic compounds given as examples of the material with a hole-transport property that can be used for the hole-transport layer 112 can also be used as the hole-transport material that is the host material.

By mixing the electron-transport material with the hole-transport material, the-transport property of the light-emitting layer 113 can be easily adjusted and a recombination region can be easily controlled. A TADF material can be used as the electron-transport material or the hole-transport material.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength of a lowest-energy absorption band of the fluorescent substance. This enables smooth transfer of excitation energy from the TADF material to the fluorescent substance and accordingly enables efficient light emission, which is preferable.

In order that singlet excitation energy can be efficiently generated from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably includes a protective group around a luminophore (a skeleton which causes light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transport or carrier recombination. Here, the luminophore refers to an atomic group (skeleton) that causes light emission in a fluorescent substance. The luminophore is preferably a skeleton having a π bond, further preferably includes an aromatic ring, and still further preferably includes a fused aromatic ring or a fused heteroaromatic ring. Examples of the luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. In particular, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

In the case where a fluorescent substance is used as the light-emitting substance, a material with an anthracene skeleton is suitably used as the host material. The use of a substance with an anthracene skeleton as the host material for the fluorescent substance makes it possible to obtain a light-emitting layer with high emission efficiency and high durability. As the substance with an anthracene skeleton that is used as the host material, a substance having a diphenylanthracene skeleton, a dinaphthylanthracene skeleton, or a phenylnaphthylanthracene skeleton, or specifically, a 9,10-diphenylanthracene skeleton, a 9,10-dinaphthylanthracene skeleton, or a 9-phenyl-10-naphthylanthracene skeleton, is preferable because of being chemically stable. The host material preferably has a carbazole skeleton to have higher hole-injection and hole-transport properties; further preferably, the host material has a benzocarbazole skeleton in which a benzene ring is further fused to a carbazole skeleton, because the HOMO level of the host material having a benzocarbazole skeleton is shallower than that of the host material having a carbazole skeleton by approximately 0.1 eV and the host material having a benzocarbazole skeleton is thus easier for holes to enter than the host material having a carbazole skeleton. In particular, the host material preferably has a dibenzocarbazole skeleton, because the HOMO level of the host material having a dibenzocarbazole skeleton is shallower than that of the host material having a carbazole skeleton by approximately 0.1 eV, the host material having a dibenzocarbazole skeleton is thus easier for holes to enter than the host material having a carbazole skeleton, and the host material having a dibenzocarbazole skeleton has a higher hole-transport property and higher heat resistance than the host material having a carbazole skeleton. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthryl)phenyl]-9H-carbazole (abbreviation: CzPA), 9-[4-(3-phenyl-9H-carbazol-9-yl)phenyl]-10-phenylanthracene (abbreviation: CzPAP), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9-(1-naphthyl)-10-(2-naphthyl)anthracene (abbreviation: α,β-ADN), 2-(10-phenylanthracen-9-yl)dibenzofuran, 4-[3-(9,10-diphenyl-2-anthryl)phenyl]dibenzofuran (abbreviation: 2mDBFPPA-II), 2-(10-phenyl-9-anthryl)benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), 9-(1-naphthyl)-10-[3-(2-naphthyl)phenyl]anthracene (abbreviation: α,N-mβNPAnth), 1-{4-[10-(biphenyl-4-yl)-9-anthryl]phenyl}-2-ethyl-1H-benzimidazole (abbreviation: EtBImPBPhA), 7-(10-phenyl-9-anthryl)benzo[b]naphtho[2,1-d]furan (abbreviation: aBnfPhA), 2-(10-phenyl-9-anthryl)dibenzofuran (abbreviation: DBfPhA), 2-[10-(biphenyl-2-yl)-9-anthryl]benzo[b]naphtho[2,3-d]furan (abbreviation: Bnf(II)oBPhA), 2-[l0-(biphenyl-4-yl)-9-anthryl]benzo[b]naphtho[2,3-d]furan (abbreviation: Bnf(II)BPhA), 2-[10-(biphenyl-3-yl)-9-anthryl]benzo[b]naphtho[2,3-d]furan (abbreviation: Bnf(II)mBPhA), and 2-[l0-(biphenyl-3-yl)-9-anthryl]benzo[b]naphtho[1,2-d]furan (abbreviation: Bnf(6)mBPhA). In particular, CzPA, CzPAP, cgDBCzPA, 2mBnfPPA, PCzPA, aN-mβNPAnth, and 2aN-aNPAnth have excellent characteristics and thus are preferably selected.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of the mixed materials. These mixed materials are preferably selected so as to form an exciplex that exhibits light emission whose wavelength overlaps with the wavelength of a lowest-energy absorption band of the light-emitting substance, in which case energy can be transferred smoothly and light emission can be obtained efficiently. Such a structure is preferably used to reduce the driving voltage.

Note that at least one of the materials forming an exciplex may be a phosphorescent substance. In that case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the LUMO level of the material having a hole-transport property is preferably higher than or equal to that of the material having an electron-transport property.

The formation of an exciplex can be confirmed by, for example, comparing the emission spectra of the material having a hole-transport property, the material having an electron-transport property, and the mixed film of these materials, and observing the phenomenon in which the emission spectrum of the mixed film is shifted to the longer wavelength side than the emission spectrum of each of the materials (or has another peak on the longer wavelength side). Alternatively, the formation of an exciplex can be confirmed by comparing the transient photoluminescence (PL) of the material having a hole-transport property, the transient PL of the material having an electron-transport property, and the transient PL of the mixed film of the materials, and observing a difference in transient response, such as a phenomenon in which the transient PL lifetime of the mixed film has more long lifetime components or has a larger proportion of delayed components than that of each of the materials. The transient PL can be rephrased as transient electroluminescence (EL). That is, the formation of an exciplex can also be confirmed by a difference in transient response observed by comparison of the transient EL of the material having a hole-transport property, the material having an electron-transport property, and the mixed film of these materials.

Note that the light-emitting layer 113 can be formed by an evaporation method (including a vacuum evaporation method), an ink-jet method, a coating method, gravure printing, or the like. Besides the above-mentioned materials, an inorganic compound such as a quantum dot or a high molecular compound (e.g., an oligomer, a dendrimer, or a polymer) may be used.

When the light-emitting layer includes a fluorescent substance, the T₁ level of the host material in the light-emitting layer is preferably lower than the T₁ level of a compound included in the adjacent carrier-transport layer (the hole-transport layer or the electron-transport layer), in which case the emission efficiency of the light-emitting device can be increased. The T₁ level of the host material is preferably lower than the T₁ level of the compound included in the adjacent carrier-transport layer by greater than or equal to 0.2 eV, further preferably by greater than or equal to 0.5 eV. When the light-emitting layer includes a fluorescent substance, the T₁ level of the host material in the light-emitting layer is preferably lower than the T₁ level of the fluorescent substance. With such a structure, T₁ excitation energy can be transferred from a nearby material to the host material in the light-emitting layer, and the density of the T₁ excited state of the host material in the light-emitting layer increases, so that TTA in the host material is likely to occur, resulting in higher emission efficiency. The deuterium-containing compound of one embodiment of the present invention can have a high T₁ level and is thus preferably stacked with the light-emitting layer. A compound with an anthracene skeleton can have a low T₁ level and is thus a suitable example of the host material. Thus, the carrier-transport layer including the deuterium-containing compound of one embodiment of the present invention and the light-emitting layer including a compound with an anthracene skeleton as the host material are preferably stacked to provide a device having high emission efficiency. Note that the host material is not limited to one having an anthracene skeleton.

The HOMO level of the host material in the light-emitting layer is preferably lower than the HOMO level of a compound included in the adjacent hole-transport layer, in which case holes generated in the hole-injection layer can be efficiently transported to the light-emitting layer through the hole-transport layer, enabling the light-emitting device to have a high hole-transport property and resultantly high emission efficiency. Specifically, the HOMO level of the host material in the light-emitting layer is preferably lower than the HOMO level of the compound included in the adjacent hole-transport layer by greater than or equal to 0.1 eV, further preferably by greater than or equal to 0.2 eV. Note that too large a difference in HOMO level might reduce the property of injecting holes into the light-emitting layer; thus, the difference between the HOMO level of the host material and the HOMO level of the compound included in the adjacent hole-transport layer is preferably less than or equal to 0.5 eV, further preferably less than or equal to 0.3 eV. As materials for achieving such a HOMO level relationship, for example, the deuterium-containing compound of one embodiment of the present invention can be suitably used for the hole-transport layer and a compound with an anthracene skeleton can be suitably used as the host material in the light-emitting layer.

### <<Hole-Injection Layer>>

In FIG. 1A and FIGS. 2A to 2E, the hole-injection layers (111, 111a, and 111b) inject holes from the first electrode 101 serving as the anode and the charge-generation layers (106, 106a, and 106b) into the organic compound layers (103, 103a, and 103b) and include an organic acceptor material and a material having a high hole-injection property.

For the hole-injection layers (111, 111a, and 111b), it is possible to use a compound having an electron-withdrawing group (a halogen group or a cyano group); for example, 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile can be used. A compound in which electron-withdrawing groups are bonded to a fused aromatic ring having a plurality of heteroatoms, such as HAT-CN, is particularly preferable because it is thermally stable. A [3]radialene derivative having an electron-withdrawing group (in particular, a cyano group or a halogen group such as a fluoro group) has a very high electron-accepting property and is thus preferable. Specific examples include α,α′,α″-1,2,3-cyclopropanetriylidenetris(4-cyano-2,3,5,6-tetrafluorobenzeneacetonitrile) (abbreviation: Rad), α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, molybdenum oxide, vanadium oxide, ruthenium oxide, tungsten oxide, manganese oxide, or the like can be used, other than the above-described organic compounds. Alternatively, the hole-injection layers (111, 111a, and 111b) can be formed using a phthalocyanine-based compound such as phthalocyanine (abbreviation: H₂Pc), a phthalocyanine-based complex compound such as copper phthalocyanine (abbreviation: CuPc), an aromatic amine compound such as 4,4′-bis[N-(4-diphenylaminophenyl)-N-phenylamino]biphenyl (abbreviation: DPAB) or N,N′-bis[4-bis(3-methylphenyl)aminophenyl]-N,N′-diphenyl-4,4′-diaminobiphenyl (abbreviation: DNTPD), or a high molecular compound such as poly(3,4-ethylenedioxythiophene)/polystyrenesulfonic acid (abbreviation: PEDOT/PSS). The substance having an acceptor property can extract electrons from an adjacent hole-transport layer (or hole-transport material) by application of an electric field.

Among substances with an acceptor property, an organic compound with an acceptor property, which is easily deposited by evaporation owing to its a low evaporation temperature, is easy to use.

Alternatively, a composite material in which a material with a hole-transport property contains any of the aforementioned substances with an acceptor property can be used for the hole-injection layers (111, 111a, and 111b). In the case of using a composite material in which a material with a hole-transport property contains an acceptor substance, a material used to form an electrode can be selected regardless of its work function. In other words, besides a material having a high work function, a material having a low work function can be used for the anode (the first electrode 101).

As the material with a hole-transport property used for the composite material, any of a variety of organic compounds such as aromatic amine compounds, carbazole derivatives, aromatic hydrocarbons, and high molecular compounds (e.g., oligomers, dendrimers, or polymers) can be used. Note that the material with a hole-transport property used for the composite material preferably has a hole mobility higher than or equal to 1×10⁻⁶ cm²/Vs. Organic compounds that can be used as the material with a hole-transport property in the composite material are specifically given below.

Examples of the aromatic amine compound that can be used for the composite material include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis[4-bis(3-methylphenyl)aminophenyl]-N,N′-diphenyl-4,4′-diaminobiphenyl (abbreviation: DNTPD), and 1,3,5-tris[N-(4-diphenylaminophenyl)-N-phenylamino]benzene (abbreviation: DPA3B). Specific examples of the carbazole derivative include 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthryl)phenyl]-9H-carbazole (abbreviation: CzPA), and 1,4-bis[4-(N-carbazolyl)phenyl]-2,3,5,6-tetraphenylbenzene. Examples of the aromatic hydrocarbon include 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, and 2,5,8,11-tetra(tert-butyl)perylene. Other examples include pentacene and coronene. The aromatic hydrocarbon may have a vinyl skeleton. Examples of the aromatic hydrocarbon having a vinyl group include 4,4′-bis(2,2-diphenylvinyl)biphenyl (abbreviation: DPVBi) and 9,10-bis[4-(2,2-diphenylvinyl)phenyl]anthracene (abbreviation: DPVPA). Note that the organic compound of one embodiment of the present invention can also be used.

Other examples include high molecular compounds such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide](abbreviation: PTPDMA), and poly[N,N′-bis(4-butylphenyl)-N,N′-bis(phenyl)benzidine](abbreviation: poly-TPD).

The material with a hole-transport property used for the composite material further preferably has at least any one of a carbazole skeleton, a dibenzofuran skeleton, a dibenzothiophene skeleton, and an anthracene skeleton. In particular, an aromatic amine having a substituent with a dibenzofuran ring or a dibenzothiophene ring, an aromatic monoamine having a naphthalene ring, or an aromatic monoamine in which a 9-fluorenyl group is bonded to the nitrogen of the amine through an arylene group may be used. Note that the material with a hole-transport property preferably has an N,N′-bis(4-biphenyl)amino group to enable fabricating a light-emitting device having a long lifetime. Specific examples of the material with a hole-transport property include N-(4-biphenyl)-6,N-diphenylbenzo[b]naphtho[1,2-d]furan-8-amine (abbreviation: BnfABP), NN-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N′-bis(4-biphenyl)benzo[b]naphtho[1,2-d]furan-6-amine (abbreviation: BBABnf(6)), N,N′-bis(4-biphenyl)benzo[b]naphtho[1,2-d]furan-8-amine (abbreviation: BBABnf(8)), NN-bis(4-biphenyl)benzo[b]naphtho[2,3-d]furan-4-amine (abbreviation: BBABnf(II)(4)), N,N′-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiPNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N′-bis(biphenyl-4-yl)-9,9′-spirobi[9H-fluoren]-2-amine (abbreviation: BBASF), N,N′-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

It is further preferable that the material with a hole-transport property used in the composite material have a relatively deep HOMO level higher than or equal to −5.7 eV and lower than or equal to −5.4 eV. Using the material with a hole-transport property having a relatively deep HOMO level in the composite material makes it easy to inject holes into the hole-transport layer 112 and to obtain a light-emitting device having a long lifetime. In addition, when the material with a hole-transport property that is used in the composite material has a relatively deep HOMO level, induction of holes can be inhibited properly, so that the light-emitting device can have a longer lifetime.

Note that mixing the above composite material with a fluoride of an alkali metal or an alkaline earth metal (the proportion of fluorine atoms in a layer including the mixed material is preferably higher than or equal to 20%) can lower the refractive index of the layer. This also enables a layer with a low refractive index to be formed in the organic compound layer 103, leading to higher external quantum efficiency of the light-emitting device. The material with a hole-transport property preferably includes an alkyl group. When an alkyl group is included, the refractive index can be reduced. As the alkyl group, a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, an n-hexyl group, a 3-methylpentyl group, a 2-methylpentyl group, a 2-ethylbutyl group, a 1,2-dimethylbutyl group, or a 2,3-dimethylbutyl group can be used, and it is particularly preferable that the material with a hole-transport property include a plurality of alkyl groups. When the material having a hole-transport property and a low refractive index is stacked with a layer including the deuterium-containing compound of one embodiment of the present invention, emitted light can be efficiently extracted to the outside, leading to an increase in external quantum efficiency of the light-emitting device. Furthermore, when the external quantum efficiency increases, the current density for obtaining necessary luminance decreases; thus, the reliability in a continuous driving test can be improved. For example, adding one methyl group to the material with a hole-transport property can reduce the refractive index (e.g., ordinary refractive index no) by 0.02. Thus, when the material with a hole-transport property has a plurality of alkyl groups, the refractive index can be further reduced. For example, the number of alkyl groups is preferably greater than or equal to two, greater than or equal to four, greater than or equal to six, or greater than or equal to eight. However, too many alkyl groups might easily cause decomposition during deposition by evaporation and might reduce the carrier mobility; thus, the number of alkyl groups is preferably less than or equal to 10. Specifically, a compound having a plurality of methyl groups and/or a plurality of tert-butyl groups is preferably used to achieve both high external quantum efficiency and high carrier mobility.

The formation of the hole-injection layers (111, 111a, and 111b) can improve the hole-injection property, which allows the light-emitting device to be driven at a low voltage.

### <<Hole-Transport Layer>>

In FIG. 1A and FIGS. 2A to 2E, the hole-transport layers (112, 112a, and 112b) include a hole-transport material and can be formed using any of the hole-transport materials given as examples of the material of the hole-injection layers (111, 111a, and 111b). In order that the hole-transport layers (112, 112a, and 112b) can have a function of transporting holes injected into the hole-injection layers (111, 111a, and 111b) to the light-emitting layers (113, 113a, and 113b), the HOMO level of the hole-transport layers (112, 112a, and 112b) is preferably equal or close to the HOMO level of the hole-injection layers (111, 111a, and 111b).

As the hole-transport material, a substance having a hole mobility higher than or equal to 1×10⁻⁶ cm²/Vs is preferably used. Note that the hole mobility of the substance may be outside this range as long as the substance has a hole-transport property higher than an electron-transport property. The layer including a substance with a high hole-transport property is not limited to a single layer and may be a stack of two or more layers each including any of the above substances.

For example, in the case where the hole-transport layer has a stacked-layer structure, its layer in contact with the light-emitting layer is preferably formed using a material having a high electron-blocking property. Specifically, when the LUMO level of the layer included in the hole-transport layer and provided in contact with the light-emitting layer is higher than the LUMO level of the material (at least the host material) included in the light-emitting layer, the layer included in the hole-transport layer and provided in contact with the light-emitting layer may function as an electron-blocking layer well. In that case, the LUMO level of the layer included in the hole-transport layer and provided in contact with the light-emitting layer is preferably higher than the LUMO level of the material (at least the host material) included in the light-emitting layer by greater than or equal to 0.3 eV, further preferably by greater than or equal to 0.5 eV, in terms of increasing the emission efficiency. For the layer (electron-blocking layer) included in the hole-transport layer and provided in contact with the light-emitting layer, the organic compound represented by General Formula (G1) in Embodiment 2 can also be used.

Examples of the materials that can be used for the hole-transport layers (112, 112a, and 112b) include a compound having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N′-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiPNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, or N,N-bis(9,9-dimethyl-9H-fluoren-2-yl)-9,9′-spirobi-9H-fluoren-1-amine; a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), or 9-(biphenyl-3-yl)-9′-(biphenyl-4-yl)-9H,9′H-3,3′-bicarbazole (abbreviation: mBPCCBP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, the compound having an aromatic amine skeleton or the compound having a carbazole skeleton is preferable because these compounds are highly reliable and have high hole-transport properties to contribute to a reduction in driving voltage. Note that any of the substances given as examples of the material with a hole-transport property that is used for the composite material for the hole-injection layer 111 can also be suitably used as the material included in the hole-transport layer 112.

### <<Electron-Transport Layer>>

In FIG. 1A and FIGS. 2A to 2E, the electron-transport layers (114, 114a, and 114b) have a function of transporting, to the light-emitting layer 113, electrons injected from the other of the pair of electrodes (the first electrode 101 or the second electrode 102) through the electron-injection layers (115, 115a, and 115b).

As the electron-transport material, it is preferable to use an organic compound with an electron-transport property and an electron mobility higher than or equal to 1×10⁻⁶ cm²/Vs when the square root of the electric field strength [V/cm] is 600. Note that any other substance can also be used as long as the substance has an electron-transport property higher than a hole-transport property. The above organic compound is preferably an organic compound having a π-electron deficient heteroaromatic ring. The organic compound having a π-electron deficient heteroaromatic ring is preferably one or more of an organic compound having a heteroaromatic ring with an azole skeleton, an organic compound having a heteroaromatic ring with a pyridine skeleton, an organic compound having a heteroaromatic ring with a diazine skeleton, and an organic compound having a heteroaromatic ring with a triazine skeleton.

Specific examples of the organic compound having a π-electron deficient heteroaromatic ring and being usable for the above electron-transport layer include an organic compound having an azole skeleton, such as 2-(4-biphenyl)-5-(4-tert-butyl-phenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(4-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound having a heteroaromatic ring with a pyridine skeleton, such as 3,5-bis[3-(9H-carbazol-9-yl)phenyl]pyridine (abbreviation: 35DCzPPy), 1,3,5-tri[(3-pyridyl)-phenyl-3-yl]benzene (abbreviation: TmPyPB), bathophenanthroline (abbreviation: BPhen), bathocuproine (abbreviation: BCP), or 2,9-di(naphthalen-2-yl)-4,7-diphenyl-1,10-phenanthroline (abbreviation: NBPhen); an organic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 8-[3′-(dibenzothiophen-4-yl)biphenyl-3-yl]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,4-bis[4-(1-naphthyl)phenyl]-6-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a triazine skeleton, such as 2-[3′-(9,9-dimethyl-9H-fluoren-2-yl)biphenyl-3-yl]-4,6-diphenyl-1,3,5-triazine (abbreviation: mFBPTzn), 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 9-[4-(4,6-diphenyl-1,3,5-triazin-2-yl)phenyl]-9′-phenyl-3,3′-bi-9H-carbazole (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthryl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl-3-yl)-4-phenyl-6-{8-[(1,1′:4′, 1″-terphenyl)-4-yl]-1-dibenzofuranyl}-1,3,5-triazine (abbreviation: mBP-TPDBfTzn). Among the above materials, the organic compound having a heteroaromatic ring with a diazine skeleton, the organic compound having a heteroaromatic ring with a pyridine skeleton, and the organic compound having a heteroaromatic ring with a triazine skeleton have high reliability and thus are preferable. In particular, the organic compound having a heteroaromatic ring with a diazine (pyrimidine or pyrazine) skeleton and the organic compound having a heteroaromatic ring with a triazine skeleton have a high electron-transport property to contribute to a reduction in driving voltage.

When an electron-transport layer that includes an organic compound having an azine skeleton, a light-emitting layer that includes an organic compound having an anthracene skeleton, and a hole-transport layer that includes the deuterium-containing compound of one embodiment of the present invention are stacked, the reliability of a light-emitting device for continuous driving can be improved and the driving voltage can be reduced. Furthermore, when a material having a hole-transport property and a low refractive index is stacked, a light-emitting device can have improved external quantum efficiency. Thus, the current density required for obtaining high luminance can be reduced, so that the light-emitting device can have reduced power consumption. In particular, when the above layers and the material are combined, i.e., when a hole-transport layer that includes an organic compound having an alkyl group, a hole-transport layer that includes the deuterium-containing compound of one embodiment of the present invention, a light-emitting layer that includes an organic compound having an anthracene skeleton, and an electron-transport layer that includes an organic compound having a triazine skeleton are stacked, the characteristics of the light-emitting device can be improved and the heat resistance or stability of the light-emitting device can be improved.

Each of the electron-transport layers (114, 114a, and 114b) is not limited to a single layer and may be a stack of two or more layers each including any of the above substances.

Between the electron-transport layer (114, 114a, or 114b) and the light-emitting layer (113, 113a, or 113b), a layer that controls transfer of electron carriers may be provided. This is a layer formed by addition of a small amount of a substance having a high electron-trapping property to a material having a high electron-transport property as described above, and the layer is capable of adjusting carrier balance by suppressing transport of electron carriers. Such a structure is very effective in inhibiting a problem (such as a reduction in device lifetime) caused when electrons pass through the light-emitting layer.

### <<Electron-Injection Layer>>

In FIG. 1A and FIGS. 2A to 2E, the electron-injection layers (115, 115a, and 115b) have a function of reducing a barrier to electron injection from the second electrode 102 to promote electron injection.

For the electron-injection layers, a Group 1 metal, a Group 2 metal, an oxide of these metals, a halide of these metals, a carbonate of these metals, or the like can be used. Alternatively, a composite material including any of the electron-transport materials described above and a material having a property of donating electrons to the electron-transport material can also be used. As examples of the material having an electron-donating property, a Group 1 metal, a Group 2 metal, an oxide of any of these metals, and the like can be given. Specifically, an alkali metal, an alkaline earth metal, or a compound thereof, such as lithium fluoride (LiF), sodium fluoride (NaF), cesium fluoride (CsF), calcium fluoride (CaF₂), or lithium oxide (LiOₓ), can be used. Alternatively, a rare earth metal compound like erbium fluoride (ErF₃) can be used. Electride may also be used for the electron-injection layer 115. Examples of the electrode include a substance in which electrons are added at high concentration to calcium oxide-aluminum oxide. The electron-injection layers (115, 115a, and 115b) can be formed using the substance that can be used for the electron-transport layers (114, 114a, and 114b).

A composite material in which an organic compound and an electron donor (donor) are mixed may also be used for the electron-injection layers (115, 115a, and 115b). Such a composite material is excellent in an electron-injection property and an electron-transport property because electrons are generated in the organic compound by the electron donor. In this case, the organic compound is preferably a material that is excellent in transporting the generated electrons. Specifically, any of the above-described substances for forming the electron-transport layer 114 (e.g., a metal complex or a heteroaromatic compound) can be used, for example. As the electron donor, a substance having an electron-donating property with respect to the organic compound can be used. Specifically, it is preferable to use an alkali metal, an alkaline earth metal, or a rare earth metal, such as lithium, sodium, cesium, magnesium, calcium, erbium, or ytterbium. It is also preferable to use an alkali metal oxide or an alkaline earth metal oxide, such as lithium oxide, calcium oxide, or barium oxide. Alternatively, a Lewis base such as magnesium oxide can be used. Further alternatively, an organic compound such as tetrathiafulvalene (abbreviation: TTF) can be used.

Note that the light-emitting layer, the hole-injection layer, the hole-transport layer, the electron-transport layer, and the electron-injection layer described above can each be formed by an evaporation method (including a vacuum evaporation method), an ink-jet method, a coating method, a gravure printing method, or the like. Besides the above-mentioned materials, an inorganic compound such as a quantum dot or a high molecular compound (e.g., an oligomer, a dendrimer, or a polymer) may be used in the light-emitting layer, the hole-injection layer, the hole-transport layer, the electron-transport layer, and the electron-injection layer.

The quantum dot may be a colloidal quantum dot, an alloyed quantum dot, a core-shell quantum dot, or a core quantum dot, for example. The quantum dot including elements belonging to Groups 2 and 16, elements belonging to Groups 13 and 15, elements belonging to Groups 13 and 17, elements belonging to Groups 11 and 17, or elements belonging to Groups 14 and 15 may be used. Alternatively, the quantum dot including an element such as cadmium (Cd), selenium (Se), zinc (Zn), sulfur (S), phosphorus (P), indium (In), tellurium (Te), lead (Pb), gallium (Ga), arsenic (As), or aluminum (Al) may be used.

### <<Pair of Electrodes>>

The first electrode 101 and the second electrode 102 function as the anode and the cathode of the light-emitting device. The first electrode 101 and the second electrode 102 can be formed using a metal, an alloy, or a conductive compound, a mixture or a stack thereof, or the like.

One of the first electrode 101 and the second electrode 102 is preferably formed using a conductive material having a function of reflecting light. Examples of the conductive material include aluminum (Al), an alloy including Al, and the like. Examples of the alloy including Al include an alloy including Al and L (L represents one or more of titanium (Ti), neodymium (Nd), nickel (Ni), and lanthanum (La)), such as an alloy including Al and Ti and an alloy including Al, Ni, and La. Aluminum has low resistance and high light reflectivity. Aluminum is included in earth's crust in large amount and is inexpensive; thus, it is possible to reduce costs for manufacturing a light-emitting device with aluminum. Alternatively, silver (Ag), an alloy of Ag and N (N represents one or more of yttrium (Y), Nd, magnesium (Mg), ytterbium (Yb), Al, Ti, gallium (Ga), zinc (Zn), indium (In), tungsten (W), manganese (Mn), tin (Sn), iron (Fe), Ni, copper (Cu), palladium (Pd), iridium (Ir), and gold (Au)), or the like may be used. Examples of the alloy including silver include an alloy including silver, palladium, and copper, an alloy including silver and copper, an alloy including silver and magnesium, an alloy including silver and nickel, an alloy including silver and gold, an alloy including silver and ytterbium, and the like. Besides, a transition metal such as tungsten, chromium (Cr), molybdenum (Mo), copper, or titanium can be used.

Light emitted from the light-emitting layer is extracted through the first electrode 101 and/or the second electrode 102. Thus, at least one of the first electrode 101 and the second electrode 102 is preferably formed using a conductive material having a function of transmitting light. As the conductive material, a conductive material having a visible light transmittance higher than or equal to 40% and lower than or equal to 100%, preferably higher than or equal to 60% and lower than or equal to 100%, and a resistivity lower than or equal to 1×10⁻² Ω·cm can be used.

The first electrode 101 and the second electrode 102 may each be formed using a conductive material having functions of transmitting light and reflecting light. As the conductive material, a conductive material having a visible light reflectivity higher than or equal to 20% and lower than or equal to 80%, preferably higher than or equal to 40% and lower than or equal to 70%, and a resistivity lower than or equal to 1×10⁻² Ω·cm can be used. For example, one or more kinds of conductive metals and alloys, conductive compounds, and the like can be used. Specifically, a metal oxide such as indium tin oxide (hereinafter referred to as ITO), indium tin oxide including silicon or silicon oxide (ITSO), indium oxide-zinc oxide (indium zinc oxide), indium oxide-tin oxide including titanium, indium titanium oxide, or indium oxide including tungsten oxide and zinc oxide can be used. A metal thin film having a thickness that allows transmission of light (preferably, a thickness greater than or equal to 1 nm and less than or equal to 30 nm) can also be used. As the metal, Ag can be used, for example. As the alloy, an alloy of Ag and Al, an alloy of Ag and Mg, an alloy of Ag and Au, an alloy of Ag and Yb, or the like can be used.

In this specification and the like, as the material having a function of transmitting light, a material having a function of transmitting visible light and having conductivity is used. Examples of the material include, in addition to the above-described oxide conductor typified by ITO, an oxide semiconductor and an organic conductor including an organic substance. Examples of the organic conductor including an organic substance include a composite material in which an organic compound and an electron donor (donor) are mixed and a composite material in which an organic compound and an electron acceptor (acceptor) are mixed. Alternatively, an inorganic carbon-based material such as graphene may be used. The resistivity of the material is preferably lower than or equal to 1×10⁵ Ω·cm, further preferably lower than or equal to 1×10⁴ Ω·cm.

The first electrode 101 and/or the second electrode 102 may be formed by stacking two or more of the materials described above.

In order to improve the light extraction efficiency, a material whose refractive index is higher than that of an electrode having a function of transmitting light may be formed in contact with the electrode. The material may be electrically conductive or non-conductive as long as it has a function of transmitting visible light. In addition to the oxide conductors described above, an oxide semiconductor and an organic substance are given as the examples of the material. Examples of the organic substance include the materials for the light-emitting layer, the hole-injection layer, the hole-transport layer, the electron-transport layer, and the electron-injection layer. Alternatively, an inorganic carbon-based material or a metal film thin enough to transmit light can be used. Further alternatively, a plurality of layers each having a thickness of several nanometers to several tens of nanometers may be stacked.

In the case where the first electrode 101 or the second electrode 102 functions as the cathode, the electrode preferably includes a material having a low work function (lower than or equal to 3.8 eV). For example, it is possible to use an element belonging to Group 1 or 2 of the periodic table (e.g., an alkali metal such as lithium, sodium, or cesium, an alkaline earth metal such as calcium or strontium, or magnesium), an alloy including any of these elements (e.g., Ag—Mg or Al—Li), a rare earth metal such as europium (Eu) or Yb, an alloy including any of these rare earth metals, an alloy including aluminum or silver, or the like.

When the first electrode 101 or the second electrode 102 is used as the anode, a material with a high work function (higher than or equal to 4.0 eV) is preferably used.

The first electrode 101 and the second electrode 102 may be a stacked layer of a conductive material having a function of reflecting light and a conductive material having a function of transmitting light. This structure is preferably employed, in which case the first electrode 101 and the second electrode 102 can have a function of adjusting the optical path length so that light with a desired wavelength emitted from each light-emitting layer resonates and is intensified.

As the method for forming the first electrode 101 and the second electrode 102, a sputtering method, an evaporation method, a printing method, a coating method, a molecular beam epitaxy (MBE) method, a CVD method, a pulsed laser deposition method, an atomic layer deposition (ALD) method, or the like can be used as appropriate.

### <<Charge-Generation Layer (Intermediate Layer)>>

In FIGS. 2B and 2D, the charge-generation layer 106 has a function of injecting electrons into the organic compound layer 103a and injecting holes into the organic compound layer 103b when a voltage is applied between the first electrode (anode) 101 and the second electrode (cathode) 102. The charge-generation layer 106 may be either a p-type layer in which an electron acceptor (acceptor) is added to a hole-transport material or an electron-injection buffer layer in which an electron donor (donor) is added to an electron-transport material. Alternatively, both of these layers may be stacked. Furthermore, an electron-relay layer may be provided between the p-type layer and the electron-injection buffer layer. Note that forming the charge-generation layer 106 with the use of any of the above materials can inhibit an increase in driving voltage caused by the stack of the organic compound layers including light-emitting layers.

In FIG. 2E, the charge-generation layer 106a has a function of injecting electrons into the organic compound layer 103a and injecting holes into the organic compound layer 103b when voltage is applied between the first electrode (anode) 101 and the second electrode (cathode) 102, and the charge-generation layer 106b has a function of injecting electrons into the organic compound layer 103b and injecting holes into the organic compound layer 103c when voltage is applied between the first electrode (anode) 101 and the second electrode (cathode) 102. Note that description of the charge-generation layers 106a and 106b, which is the same as that of the charge-generation layer 106, is omitted.

In the case where the charge-generation layer 106, 106a, or 106b is a p-type layer in which an electron acceptor is added to a hole-transport material, which is an organic compound, any of the hole-transport materials described in this embodiment can be used as the hole-transport material. Examples of the electron acceptor include 7,7,8,8-tetracyano-2,3,5,6-tetrafluoroquinodimethane (abbreviation: F₄-TCNQ), chloranil, α,α′,α″-1,2,3-cyclopropanetriylidenetris(4-cyano-2,3,5,6-tetrafluorobenzeneacetonitrile) (abbreviation: Rad). Other examples include oxides of metals that belong to Group 4 to Group 8 of the periodic table. Specific examples include vanadium oxide, niobium oxide, tantalum oxide, chromium oxide, molybdenum oxide, tungsten oxide, manganese oxide, and rhenium oxide. Any of the above-described acceptor materials may be used. Furthermore, a mixed film obtained by mixing materials of a p-type layer or a stack of films including the respective materials may be used.

In the case where the charge-generation layer 106, 106a, or 106b is an electron-injection buffer layer in which an electron donor is added to an electron-transport material, any of the electron-transport materials described in this embodiment can be used as the electron-transport material.

As the electron donor, it is possible to use an alkali metal, an alkaline earth metal, a rare earth metal, a metal belonging to Group 2 or Group 13 of the periodic table, or an oxide or a carbonate thereof. Specifically, lithium (Li), cesium (Cs), magnesium (Mg), calcium (Ca), ytterbium (Yb), indium (In), lithium oxide (Li₂O), cesium carbonate, or the like is preferably used. An organic compound such as tetrathianaphthacene may be used as the electron donor.

When an electron-relay layer is provided between a p-type layer and an electron-injection buffer layer in the charge-generation layer 106, 106a, or 106b, the electron-relay layer includes at least a substance having an electron-transport property and has a function of preventing an interaction between the electron-injection buffer layer and the p-type layer and transferring electrons smoothly. The LUMO level of the substance having an electron-transport property in the electron-relay layer is preferably between the LUMO level of the acceptor substance in the p-type layer and the LUMO level of the substance having an electron-transport property in the electron-transport layer in contact with the charge-generation layer 106. Specifically, the LUMO level of the substance having an electron-transport property in the electron-relay layer is preferably higher than or equal to −5.0 eV, further preferably higher than or equal to −5.0 eV and lower than or equal to −3.0 eV. Note that as the substance having an electron-transport property in the electron-relay layer, a phthalocyanine-based material or a metal complex having a metal-oxygen bond and an aromatic ligand is preferably used.

Although FIG. 2D illustrates the structure in which two of the organic compound layers 103, i.e., the organic compound layers 103a and 103b, are stacked, organic compound layers including three or more light-emitting layers may be stacked with charge-generation layers each provided between different light-emitting layers; FIG. 2E illustrates a structure in which organic compound layers including three light-emitting layers are stacked.

### <<Cap Layer>>

Although not illustrated in FIGS. 2A to 2E, a cap layer may be provided over the second electrode 102 of the light-emitting device. For example, a material with a high refractive index can be used for the cap layer. When the cap layer is provided over the second electrode 102, extraction efficiency of light emitted through the second electrode 102 can be improved.

Note that the organic compound represented by General Formula (G1) in Embodiment 2 can also be used for the cap layer. Specific examples of a material that can be used for the cap layer include 5,5′-diphenyl-2,2′-di-5H-[1]benzothieno[3,2-c]carbazole (abbreviation: BisBTc) and 4,4′,4″-(benzene-1,3,5-triyl)tri(dibenzothiophene) (abbreviation: DBT3P-II).

### <<Substrate>>

A light-emitting device of one embodiment of the present invention may be formed over a substrate of glass, plastic, or the like. As the way of stacking layers over the substrate, layers may be sequentially stacked from the first electrode 101 side or sequentially stacked from the second electrode 102 side.

For the substrate over which the light-emitting device of one embodiment of the present invention can be formed, glass, quartz, plastic, or the like can be used, for example. Alternatively, a flexible substrate may be used. The flexible substrate means a substrate that can be bent, such as a plastic substrate made of polycarbonate or polyarylate, for example. Alternatively, a film, an inorganic vapor deposition film, or the like can be used. Another material may be used as long as the substrate functions as a support in a manufacturing process of the light-emitting device or an optical device. Another material having a function of protecting the light-emitting device or the optical device may be used.

In this specification and the like, a light-emitting device can be formed using any of a variety of substrates, for example. There is no particular limitation on the type of the substrate. Examples of the substrate include a semiconductor substrate (e.g., a single crystal substrate such as a silicon substrate); an SOI substrate; a glass substrate; a quartz substrate; a plastic substrate; a metal substrate; a stainless steel substrate; a substrate including stainless steel foil; a tungsten substrate; a substrate including tungsten foil; a flexible substrate; an attachment film; and cellulose nanofiber (CNF), paper, and a base material film that include a fibrous material. Examples of a glass substrate include a barium borosilicate glass substrate, an aluminoborosilicate glass substrate, and a soda lime glass substrate. Examples of the flexible substrate, the attachment film, the base material film, and the like are substrates of plastics typified by polyethylene terephthalate (PET), polyethylene naphthalate (PEN), polyether sulfone (PES), and polytetrafluoroethylene (PTFE). Another example is an acrylic resin. Furthermore, polypropylene, polyester, polyvinyl fluoride, and polyvinyl chloride can be given as examples. Other examples include a resin such as a polyamide resin, a polyimide resin, an aramid resin, or an epoxy resin, an inorganic vapor deposition film, and paper.

Alternatively, a flexible substrate may be used as the substrate, and a light-emitting device may be provided directly on the flexible substrate. Further alternatively, a separation layer may be provided between the substrate and the light-emitting device. The separation layer can be used to separate part or the whole of the light-emitting device, which is formed over the separation layer, from the substrate and transfer the separated component onto another substrate. In that case, the light-emitting device can be transferred to a substrate having low heat resistance or a flexible substrate as well. For the above separation layer, a stack including inorganic films, which are a tungsten film and a silicon oxide film, or a structure in which a resin film of polyimide or the like is formed over a substrate can be used, for example.

In other words, after the light-emitting device is formed using a substrate, the light-emitting device may be transferred to another substrate. Examples of the substrate to which the light-emitting device is transferred are, in addition to the above substrates, a cellophane substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), and the like), a leather substrate, a rubber substrate, and the like. When such a substrate is used, a light-emitting device with high durability, high heat resistance, reduced weight, or reduced thickness can be formed.

The light-emitting device may be formed over an electrode electrically connected to a field-effect transistor (FET), for example, that is formed over any of the above-described substrates. In that case, an active matrix display apparatus in which the FET controls the driving of the light-emitting device can be manufactured.

In this embodiment, one embodiment of the present invention has been described. Other embodiments of the present invention are described in other embodiments. Note that one embodiment of the present invention is not limited thereto. In other words, various embodiments of the invention are described in this embodiment and the other embodiments, and one embodiment of the present invention is not limited to a particular embodiment. For example, although the example in which one embodiment of the present invention is applied to a light-emitting device is described, one embodiment of the present invention is not limited thereto. For example, depending on circumstances or conditions, one embodiment of the present invention is not necessarily used in a light-emitting device. One embodiment of the present invention describes, but is not limited to, an example of including the first organic compound, the second organic compound, and the guest material capable of converting triplet excitation energy into light emission, in which the LUMO level of the first organic compound is lower than that of the second organic compound and the HOMO level of the first organic compound is lower than that of the second organic compound. Depending on circumstances or conditions, in one embodiment of the present invention, for example, the LUMO level of the first organic compound is not necessarily lower than that of the second organic compound. Alternatively, the HOMO level of the first organic compound is not necessarily lower than that of the second organic compound. One embodiment of the present invention describes, but is not limited to, an example in which the first organic compound and the second organic compound form an exciplex. Depending on circumstances or conditions, in one embodiment of the present invention, for example, the first organic compound and the second organic compound do not necessarily form an exciplex. One embodiment of the present invention describes, but is not limited to, an example in which the LUMO level of the guest material is higher than that of the first organic compound and the HOMO level of the guest material is lower than that of the second organic compound. Depending on circumstances or conditions, in one embodiment of the present invention, for example, the LUMO level of the guest material is not necessarily higher than that of the first organic compound. Alternatively, the HOMO level of the guest material is not necessarily lower than that of the second organic compound.

The structure described above in this embodiment can be used in combination with any of the structures described in the other embodiments as appropriate.

### Embodiment 4

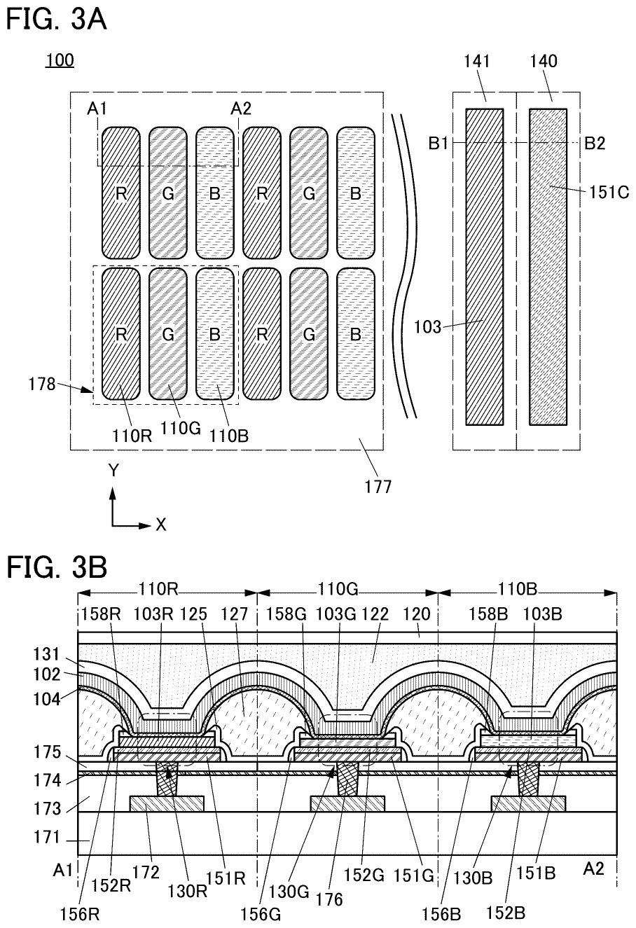

As illustrated in FIGS. 3A and 3B, a plurality of light-emitting devices 130 are formed over an insulating layer 175 to constitute a display apparatus. In this embodiment, a display apparatus of one embodiment of the present invention is described in detail.

A display apparatus 100 includes a pixel portion 177 in which a plurality of pixels 178 are arranged in matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared (IR) light.

In this specification and the like, the row direction and the column direction are sometimes referred to as the X direction and the Y direction, respectively. The X direction and the Y direction intersect with each other and are perpendicular to each other, for example.

FIG. 3A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The organic compound layer 103 is provided in the region 141. A conductive layer 151C is provided in the connection portion 140.

Although FIG. 3A illustrates an example where the region 141 and the connection portion 140 are located on the right side of the pixel portion 177, there is no particular limitation on the positions of the region 141 and the connection portion 140. The number of regions 141 and the number of connection portions 140 can each be one or more.

FIG. 3B is an example of a cross-sectional view along the dashed-dotted line A1-A2 in FIG. 3A. As illustrated in FIG. 3B, the display apparatus 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is attached to the protective layer 131 with a resin layer 122. An inorganic insulating layer 125 and an insulating layer 127 over the inorganic insulating layer 125 are preferably provided between the adjacent light-emitting devices 130.

Although each of the inorganic insulating layer 125 and the insulating layer 127 looks like a plurality of layers in the cross-sectional view in FIG. 3B, each of the inorganic insulating layer 125 and the insulating layer 127 is preferably one continuous layer when the display apparatus 100 is seen from above. In other words, the inorganic insulating layer 125 and the insulating layer 127 preferably include opening portions over first electrodes.

In FIG. 3B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, 130G, or 130B may emit visible light of another color or infrared light.

The display apparatus of one embodiment of the present invention can be, for example, a top-emission display apparatus where light is emitted in the direction opposite to a substrate over which light-emitting devices are formed. Note that the display apparatus of one embodiment of the present invention may be of a bottom-emission type.

Examples of a light-emitting substance included in the light-emitting device 130 include organometallic complexes and organic compounds such as a substance emitting fluorescent light (a fluorescent compound), a substance emitting phosphorescent light (a phosphorescent compound), and a substance exhibiting thermally activated delayed fluorescence (a thermally activated delayed fluorescent (TADF) material). Other examples include inorganic compounds (e.g., a quantum dot material).

The light-emitting device 130R has a structure as illustrated in FIG. 1A. The light-emitting device 130R includes the first electrode (pixel electrode) including a conductive layer 151R and a conductive layer 152R, an organic compound layer 103R over the first electrode, a common layer 104 over the organic compound layer 103R, and a second electrode (common electrode) 102 over the common layer 104. Although the common layer 104 is not necessarily provided, it is preferable to provide the common layer 104 to reduce damage to the organic compound layer 103R during processing. In the case where the common layer 104 is provided, the common layer 104 is preferably an electron-injection layer. Furthermore, in the case where the common layer 104 is provided, a stack of the organic compound layer 103R and the common layer 104 corresponds to the organic compound layer 103 described in Embodiment 3.

The light-emitting device 130G has a structure as illustrated in FIG. 1A. The light-emitting device 130G includes the first electrode (pixel electrode) including a conductive layer 151G and a conductive layer 152G, an organic compound layer 103G over the first electrode, the common layer 104 over the organic compound layer 103G, and the second electrode (common electrode) 102 over the common layer 104. Although the common layer 104 is not necessarily provided, it is preferable to provide the common layer 104 to reduce damage to the organic compound layer 103G during processing. In the case where the common layer 104 is provided, the common layer 104 is preferably an electron-injection layer. Furthermore, in the case where the common layer 104 is provided, a stack of the organic compound layer 103G and the common layer 104 corresponds to the organic compound layer 103 described in Embodiment 3.

The light-emitting device 130B has a structure as illustrated in FIG. 1A. The light-emitting device 130B includes the first electrode (pixel electrode) including a conductive layer 151B and a conductive layer 152B, an organic compound layer 103B over the first electrode, the common layer 104 over the organic compound layer 103B, and the second electrode (common electrode) 102 over the common layer 104. Although the common layer 104 is not necessarily provided, it is preferable to provide the common layer 104 to reduce damage to the organic compound layer 103B during processing. In the case where the common layer 104 is provided, the common layer 104 is preferably an electron-injection layer. Furthermore, in the case where the common layer 104 is provided, a stack of the organic compound layer 103B and the common layer 104 corresponds to the organic compound layer 103 described in Embodiment 3.

In the light-emitting device, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layers 103R, 103G, and 103B are island-shaped layers that are independent of each other on a subpixel basis or on an emission color basis. Providing the island-shaped organic compound layer 103 in each of the light-emitting devices 130 can inhibit leakage current between the adjacent light-emitting devices 130 even in a high-resolution display apparatus. This can prevent crosstalk, so that a display apparatus with extremely high contrast can be obtained. Specifically, a display apparatus having high current efficiency at low luminance can be obtained.

The island-shaped organic compound layer 103 is formed by forming an EL film and processing the EL film by a lithography method.

In the display apparatus of one embodiment of the present invention, the first electrode (pixel electrode) of the light-emitting device preferably has a stacked-layer structure. For example, in the example illustrated in FIG. 3B, the first electrode of the light-emitting device 130 is a stack of the conductive layer 151 and the conductive layer 152. In the case where the display apparatus 100 is of a top-emission type and the pixel electrode of the light-emitting device 130 functions as the anode, for example, the conductive layer 151 preferably has high visible light reflectance, and the conductive layer 152 preferably has a visible-light-transmitting property and a high work function. In the case where the display apparatus 100 is of a top-emission type, the higher the visible light reflectance of the pixel electrode is, the higher the efficiency of extraction of the light emitted by the organic compound layer 103 is. In the case where the pixel electrode functions as the anode, the higher the work function of the pixel electrode is, the easier hole injection into the organic compound layer 103 is. Accordingly, when the pixel electrode of the light-emitting device 130 is a stack of the conductive layer 151 with high visible light reflectance and the conductive layer 152 with a high work function, the light-emitting device 130 can have high light extraction efficiency and a low driving voltage.

In the case where the conductive layer 151 has high visible light reflectance, the visible light reflectance of the conductive layer 151 is preferably higher than or equal to 40% and lower than or equal to 100%, further preferably higher than or equal to 70% and lower than or equal to 100%, for example. When used as an electrode having a visible-light-transmitting property, the conductive layer 152 preferably has a visible light transmittance higher than or equal to 40%, for example.

Here, such a pixel electrode being a stack composed of a plurality of layers might change in quality as a result of, for example, a reaction between the plurality of layers. For example, when a film formed after the formation of the pixel electrode is removed by a wet etching method, contact of a chemical solution with the pixel electrode might cause galvanic corrosion.

In view of the above, an insulating layer 156 is formed on the side surfaces of the conductive layers 151 and 152 in the display apparatus 100 of this embodiment. This can inhibit a chemical solution from coming into contact with the conductive layer 151 when a film that is formed after formation of the pixel electrode including the conductive layer 151 and the conductive layer 152 is removed by a wet etching method, for example. Accordingly, occurrence of galvanic corrosion in the pixel electrode can be inhibited, for example. This allows the display apparatus 100 to be manufactured by a high-yield method and to be accordingly inexpensive. In addition, generation of a defect in the display apparatus 100 can be inhibited, which makes the display apparatus 100 highly reliable.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy including an appropriate combination of any of these metals, for example.

For the conductive layer 152, an oxide including one or more selected from indium, tin, zinc, gallium, titanium, aluminum, and silicon can be used. For example, it is preferable to use a conductive oxide including one or more of indium oxide, indium tin oxide, indium zinc oxide, zinc oxide, zinc oxide including gallium, titanium oxide, indium zinc oxide including gallium, indium zinc oxide including aluminum, indium tin oxide including silicon, indium zinc oxide including silicon, and the like. In particular, indium tin oxide including silicon can be suitably used for the conductive layer 152 because of having a high work function, for example, a work function higher than or equal to 4.0 eV.

The conductive layer 151 and the conductive layer 152 may each be a stack of a plurality of layers that include different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

Note that an end portion of the insulating layer 156 may have a tapered shape. Specifically, when the end portion of the insulating layer 156 has a tapered shape with a taper angle less than 90°, coverage with a component provided along the side surface of the insulating layer 156 can be improved.

### Embodiment 5

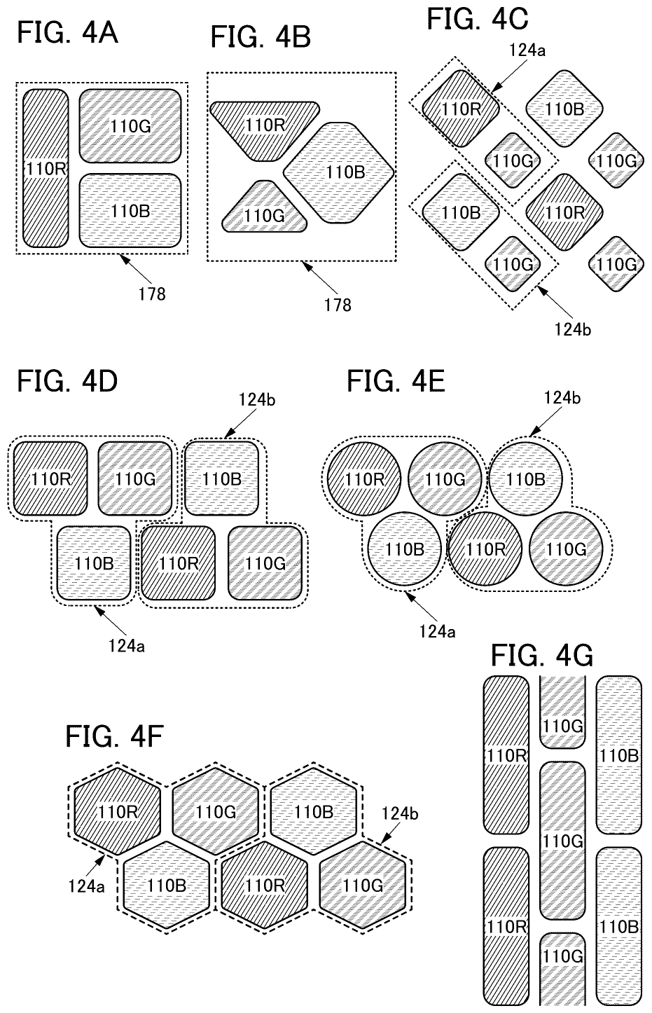

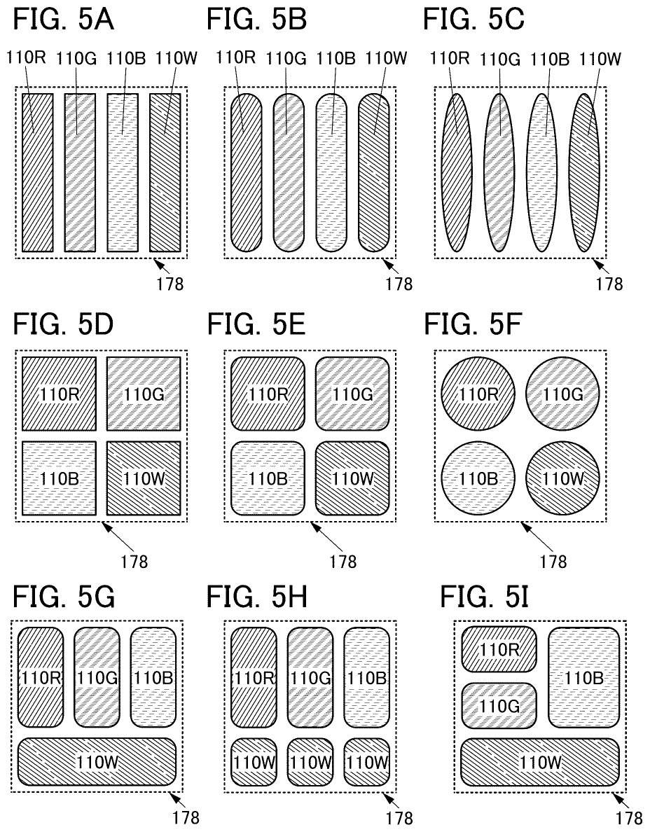

In this embodiment, the light-emitting apparatus of one embodiment of the present invention will be described with reference to FIGS. 4A to 4G and FIGS. 5A to 5I.

### [Pixel Layout]

In this embodiment, pixel layouts different from that in FIG. 3A will be mainly described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

In this embodiment, the top-view shapes of the subpixels shown in the diagrams correspond to the top-view shapes of light-emitting regions.

Examples of the top-view shape of the subpixel include polygons such as a triangle, a tetragon (including a rectangle and a square), and a pentagon; these polygons with rounded corners; an ellipse; and a circle.

The circuit constituting the subpixel is not necessarily placed within the dimensions of the subpixel illustrated in the diagrams and may be placed outside the subpixel.

The pixel 178 illustrated in FIG. 4A employs S-stripe arrangement. The pixel 178 illustrated in FIG. 4A includes three subpixels, the subpixel 110R, the subpixel 110G, and the subpixel 110B.

The pixel 178 illustrated in FIG. 4B includes the subpixel 110R whose top-view shape is a rough trapezoid or a rough triangle with rounded corners, the subpixel 110G whose top-view shape is a rough trapezoid or a rough triangle with rounded corners, and the subpixel 110B whose top-view shape is a rough tetragon or a rough hexagon with rounded corners. The subpixel 110R has a larger light-emitting area than the subpixel 110G. In this manner, the shapes and sizes of the subpixels can be determined independently. For example, the size of a subpixel including a light-emitting device with higher reliability can be smaller.

Pixels 124a and 124b illustrated in FIG. 4C employ PenTile arrangement. FIG. 4C illustrates an example in which the pixels 124a including the subpixels 110R and 110G and the pixels 124b including the subpixels 110G and 110B are alternately arranged.

The pixels 124a and 124b illustrated in FIGS. 4D to 4F employ delta arrangement. The pixel 124a includes two subpixels (the subpixels 110R and 110G) in the upper row (first row) and one subpixel (the subpixel 110B) in the lower row (second row). The pixel 124b includes one subpixel (the subpixel 110B) in the upper row (first row) and two subpixels (the subpixels 110R and 110G) in the lower row (second row).

FIG. 4D illustrates an example where the top-view shape of each subpixel is a rough tetragon with rounded corners, FIG. 4E illustrates an example where the top-view shape of each subpixel is a circle, and FIG. 4F illustrates an example where the top-view shape of each subpixel is a rough hexagon with rounded corners.

In FIG. 4F, subpixels are placed in respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 110R, the subpixel 110R is surrounded by three of the subpixels 110G and three of the subpixels 110B that are alternately arranged.

FIG. 4G illustrates an example where subpixels of different colors are arranged in a zigzag manner. Specifically, the positions of the top sides of two subpixels arranged in the row direction (e.g., the subpixels 110R and 110G or the subpixels 110G and 110B) are not aligned in the top view.

In the pixels illustrated in FIGS. 4A to 4G, for example, it is preferable that the subpixel 110R be a subpixel R that emits red light, the subpixel 110G be a subpixel G that emits green light, and the subpixel 110B be a subpixel B that emits blue light. Note that the structures of the subpixels are not limited thereto, and the colors and the order of the subpixels can be determined as appropriate. For example, the subpixel 110G may be the subpixel R that emits red light, and the subpixel 110R may be the subpixel G that emits green light.

In a photolithography method, as a pattern to be formed by processing becomes finer, the influence of light diffraction becomes more difficult to ignore; thus, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top-view shape of a subpixel is a polygon with rounded corners, an ellipse, a circle, or the like in some cases.

Furthermore, in the method for fabricating the light-emitting apparatus of one embodiment of the present invention, the organic compound layer is processed into an island shape with the use of a resist mask. A resist film formed over the organic compound layer needs to be cured at a temperature lower than the upper temperature limit of the organic compound layer. Thus, the resist film is insufficiently cured in some cases depending on the upper temperature limit of the material of the organic compound layer and the curing temperature of the resist material. An insufficiently cured resist film may have a shape different from a desired shape by processing. As a result, the top-view shape of the organic compound layer may be a polygon with rounded corners, an ellipse, a circle, or the like. For example, when a resist mask whose top-view shape is a square is intended to be formed, a resist mask whose top-view shape is a circle may be formed, and the top-view shape of the organic compound layer may be a circle.

To obtain a desired top-view shape of the organic compound layer, a technique of correcting a mask pattern in advance so that a transferred pattern agrees with a design pattern (an optical proximity correction (OPC) technique) may be used. Specifically, with the OPC technique, a pattern for correction is added to a corner portion of a figure on a mask pattern, for example.

As illustrated in FIGS. 5A to 5I, the pixel can include four types of subpixels.

The pixels 178 illustrated in FIGS. 5A to 5C employ stripe arrangement.

FIG. 5A illustrates an example where each subpixel has a rectangular top-view shape. FIG. 5B illustrates an example where each subpixel has a top-view shape formed by combining two half circles and a rectangle. FIG. 5C illustrates an example where each subpixel has an elliptical top-view shape.

The pixels 178 illustrated in FIGS. 5D to 5F employ matrix arrangement.

FIG. 5D illustrates an example where each subpixel has a square top-view shape. FIG. 5E illustrates an example where each subpixel has a substantially square top-view shape with rounded corners. FIG. 5F illustrates an example where each subpixel has a circular top-view shape.

FIGS. 5G and 5H each illustrate an example where one pixel 178 is composed of two rows and three columns.

The pixel 178 illustrated in FIG. 5G includes three subpixels (the subpixels 110R, 110G, and 110B) in the upper row (first row) and one subpixel (a subpixel 110W) in the lower row (second row). In other words, the pixel 178 includes the subpixel 110R in the left column (first column), the subpixel 110G in the middle column (second column), the subpixel 110B in the right column (third column), and the subpixel 110W across these three columns.

The pixel 178 illustrated in FIG. 5H includes three subpixels (the subpixels 110R, 110G, and 110B) in the upper row (first row) and three of the subpixels 110W in the lower row (second row). In other words, the pixel 178 includes the subpixels 110R and 110W in the left column (first column), the subpixels 110G and 110W in the middle column (second column), and the subpixels 110B and 110W in the right column (third column). Matching the positions of the subpixels in the upper row and the lower row as illustrated in FIG. 5H enables dust that would be produced in the fabrication process, for example, to be removed efficiently. Thus, a light-emitting apparatus having high display quality can be provided.

In the pixel 178 illustrated in FIGS. 5G and 5H, the subpixels 110R, 110G, and 110B are arranged in a stripe pattern, whereby the display quality can be improved.

FIG. 51 illustrates an example where one pixel 178 is composed of three rows and two columns.

The pixel 178 illustrated in FIG. 5I includes the subpixel 110R in the upper row (first row), the subpixel 110G in the middle row (second row), the subpixel 110B across the first row and the second row, and one subpixel (the subpixel 110W) in the lower row (third row). In other words, the pixel 178 includes the subpixels 110R and 110G in the left column (first column), the subpixel 110B in the right column (second column), and the subpixel 110W across these two columns.

In the pixel 178 illustrated in FIG. 5I, the subpixels 110R, 110G, and 110B are arranged in what is called an S-stripe pattern, whereby the display quality can be improved.

The pixel 178 illustrated in each of FIGS. 5A to 5I is composed of four subpixels, which are the subpixels 110R, 110G, 110B, and 110W. For example, the subpixel 110R can be a subpixel that emits red light, the subpixel 110G can be a subpixel that emits green light, the subpixel 110B can be a subpixel that emits blue light, and the subpixel 110W can be a subpixel that emits white light. Note that at least one of the subpixels 110R, 110G, 110B, and 110W may be a subpixel that emits cyan light, magenta light, yellow light, or near-infrared light.

As described above, the pixel composed of the subpixels each including the light-emitting device can employ any of a variety of layouts in the light-emitting apparatus of one embodiment of the present invention.

This embodiment can be combined as appropriate with the other embodiments or examples. In this specification, in the case where a plurality of structure examples are shown in one embodiment, the structure examples can be combined as appropriate.

### Embodiment 6

In this embodiment, a display apparatus of one embodiment of the present invention will be described.

The display apparatus in this embodiment can be a high-resolution display apparatus. Thus, the display apparatus in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display apparatus in this embodiment can be a high-definition display apparatus or a large-sized display apparatus. Accordingly, the display apparatus in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

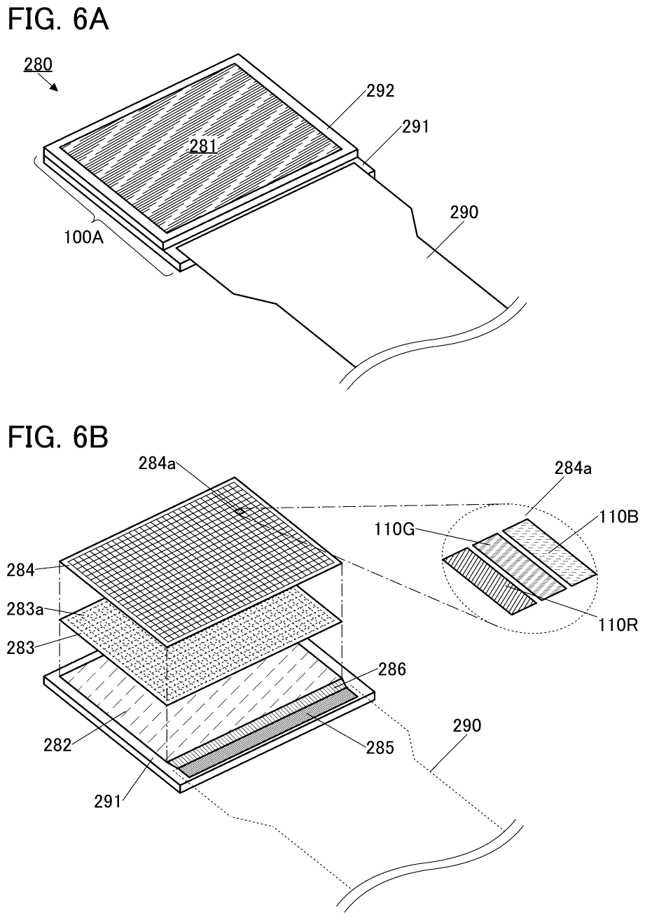

FIG. 6A is a perspective view of a display module 280. The display module 280 includes a display apparatus 100A and an FPC 290. Note that the display apparatus included in the display module 280 is not limited to the display apparatus 100A and may be any of a display apparatus 100B, a display apparatus 100C, a display apparatus 100D, a display apparatus 100D2, a display apparatus 100E, and a display apparatus 100E2 described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 6B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 6B. The pixels 284a can employ any of the structures described in the above embodiments.

The pixel circuit portion 283 includes a plurality of pixel circuits 283a arranged periodically.

One pixel circuit 283a is a circuit that controls driving of a plurality of devices included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion.

### [Display Apparatus 100A]

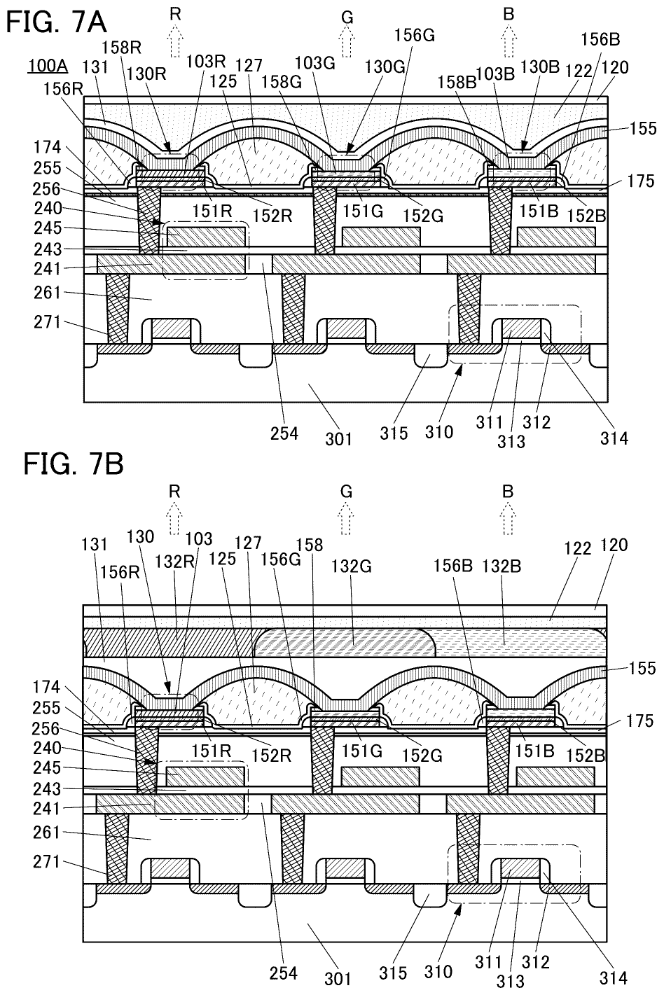

The display apparatus 100A illustrated in FIG. 7A includes a substrate 301, the light-emitting devices 130R, 130G, and 130B, a capacitor 240, and a transistor 310.

The substrate 301 corresponds to the substrate 291 in FIGS. 6A and 6B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

An insulating layer 156R is provided to include a region overlapping with the side surface of the conductive layer 151R. An insulating layer 156G is provided to include a region overlapping with the side surface of the conductive layer 151G. An insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. A sacrificial layer 158R is positioned over the organic compound layer 103R. A sacrificial layer 158G is positioned over the organic compound layer 103G. A sacrificial layer 158B is positioned over the organic compound layer 103B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 is attached to the protective layer 131 with the resin layer 122. Embodiment 5 can be referred to for the details of the light-emitting device 130 and the components thereover up to the substrate 120. The substrate 120 corresponds to the substrate 292 in FIG. 6A.

FIG. 7B illustrates a variation example of the display apparatus 100A illustrated in FIG. 7A. The display apparatus illustrated in FIG. 7B includes a coloring layer 132R, a coloring layer 132G, and a coloring layer 132B, and each of the light-emitting devices 130 includes a region overlapping with one of the coloring layers 132R, 132G, and 132B. In the display apparatus illustrated in FIG. 7B, the light-emitting device 130 can emit white light, for example. The coloring layer 132R, the coloring layer 132G, and the coloring layer 132B can transmit red light, green light, and blue light, respectively, for example.

### [Display Apparatus 100B]

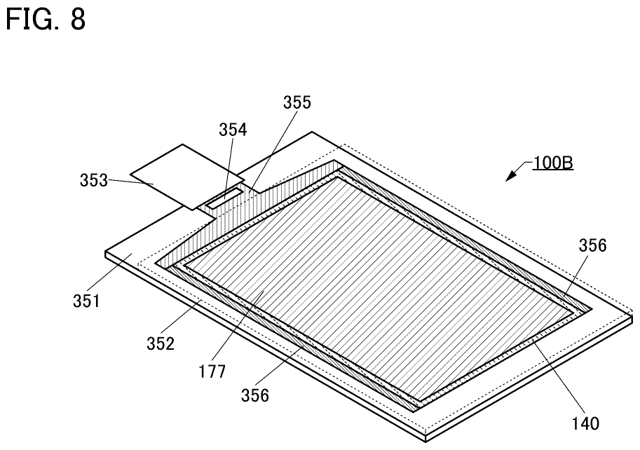

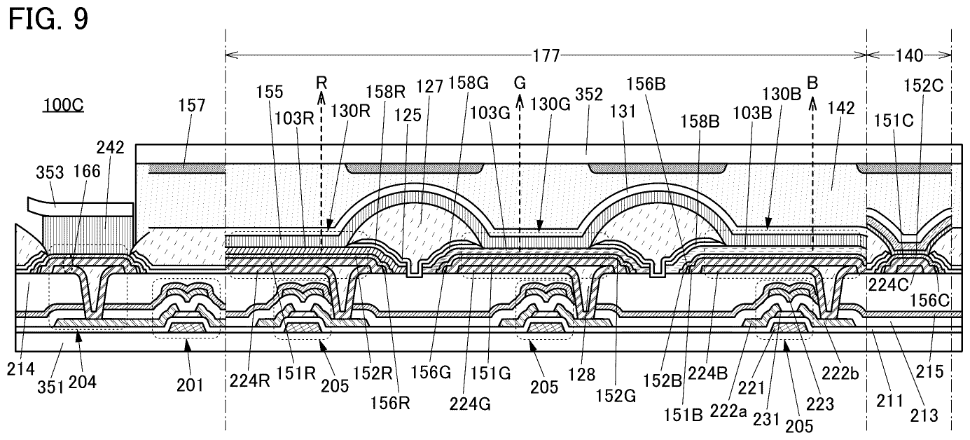

FIG. 8 is a perspective view of the display apparatus 100B, and FIG. 9 is a cross-sectional view of the display apparatus 100C.

In the display apparatus 100B, a substrate 352 and a substrate 351 are bonded to each other. In FIG. 8, the substrate 352 is denoted by a dashed line.

The display apparatus 100B includes the pixel portion 177, the connection portion 140, a circuit 356, a wiring 355, and the like. FIG. 8 illustrates an example in which an IC 354 and an FPC 353 are mounted on the display apparatus 100B. Thus, the structure illustrated in FIG. 8 can be regarded as a display module including the display apparatus 100B, the integrated circuit (IC), and the FPC. Here, a display apparatus in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 8 illustrates an example in which the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display apparatus 100B and the display module are not necessarily provided with an IC. Alternatively, the IC may be mounted on the FPC by a COF method, for example.

FIG. 9 illustrates, as the display apparatus 100C, an example of cross sections of part of a region including the FPC 353, part of the circuit 356, part of the pixel portion 177, part of the connection portion 140, and part of a region including an end portion of the display apparatus 100B in FIG. 8.

### [Display Apparatus 100C]

The display apparatus 100C illustrated in FIG. 9 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 5 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through the opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depression portion covering an opening provided in the insulating layer 214. A layer 128 is embedded in the depression portion.

The layer 128 has a function of filling the depression portions of the conductive layers 224R, 224G, and 224B to enable planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depression portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 9, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Furthermore, the space may be filled with a resin other than the frame-shaped adhesive layer 142.

FIG. 9 illustrates an example in which the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and a conductive layer 152C obtained by processing the same conductive film as the conductive layers 152R, 152G, and 152B. In the example illustrated in FIG. 9, an insulating layer 156C is provided to include a region overlapping with the side surface of the conductive layer 151C.

The display apparatus 100C has a top-emission structure. Light from the light-emitting device is emitted toward the substrate 352. For the substrate 352, a material having a high visible-light-transmitting property is preferably used. The pixel electrode includes a material that reflects visible light, and a counter electrode (a common electrode 155) includes a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, a source electrode or a drain electrode of the transistor 201 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Apparatus 100D]

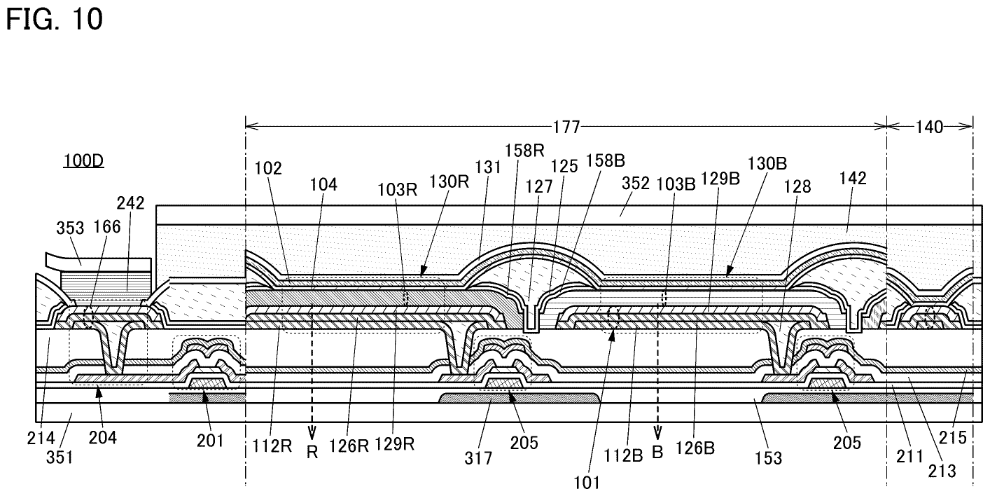

The display apparatus 100D illustrated in FIG. 10 differs from the display apparatus 100C illustrated in FIG. 9 mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

A light-blocking layer 317 is preferably formed between the substrate 351 and the transistor 201 and between the substrate 351 and the transistor 205. FIG. 10 illustrates an example in which the light-blocking layer 317 is provided over the substrate 351, an insulating layer 153 is provided over the light-blocking layer 317, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the second electrode 102.

Although not illustrated in FIG. 10, the light-emitting device 130G is also provided.

Although FIG. 10 and the like illustrate an example in which the top surface of the layer 128 includes a flat portion, the shape of the layer 128 is not particularly limited.

### [Display Apparatus 100D2]

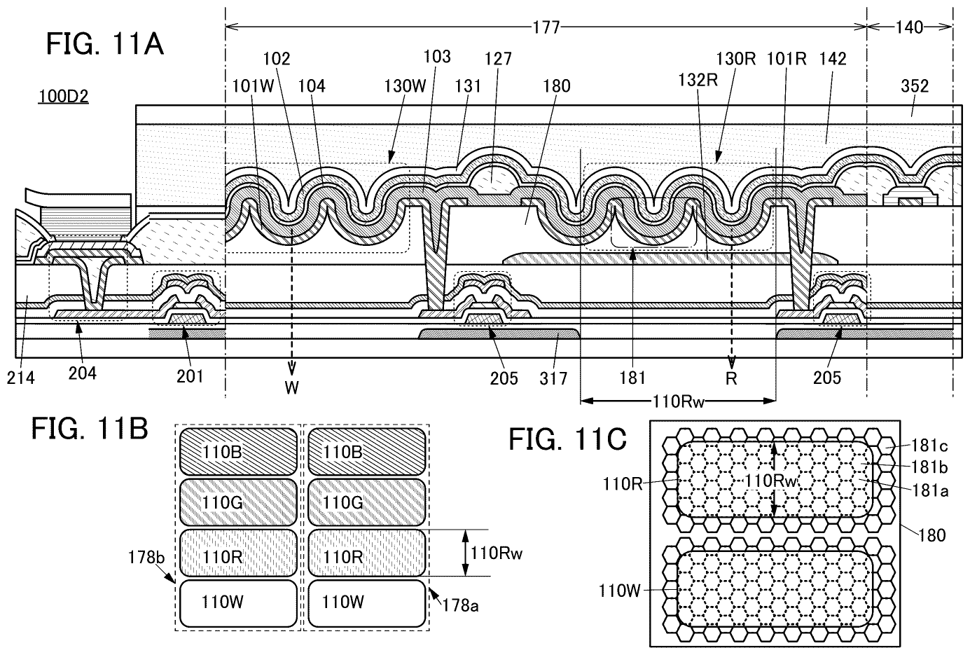

The display apparatus 100D2 illustrated in FIG. 11A is an example of a bottom-emission display apparatus different from the display apparatus 100D illustrated in FIG. 10. The display apparatus 100D2 is different from the display apparatus 100D in including an organic resin layer 180. Note that in the drawings, reference numerals of some of the components that are shown in FIG. 10 are omitted; for the details of the components, the description made with reference to FIG. can be referred to.

FIG. 11B shows a top-view layout of the pixels 178 (a pixel 178a and a pixel 178b) each including the subpixels 110 (the subpixels 110R, 110G, 110B, and 110W), and FIG. 11C shows a top view of the organic resin layer 180 in a region where the subpixels 110R and 110W of the pixel 178 are formed. Note that the width between the light-blocking layer 317 and another light-blocking layer 317 corresponds to a width 110Rw in the light-emitting region of the subpixel 110R.

As illustrated in FIG. 11A, the organic resin layer 180 is provided over the insulating layer 214. As illustrated in FIG. 11C and the region surrounded by the dashed-dotted line in FIG. 11A, the organic resin layer 180 includes depressed portions 181 (depressed portions 181a and depressed portions 181b) each having a curved surface, at least in a region where the subpixels are formed. Note that the depressed portion 181 outside the light-emitting region, like a depressed portion 181c, may also be provided. When the depressed portion 181c is provided, light that has been emitted in the region overlapping with the light-blocking layer 317 or light that has progressed to the region overlapping with the light-blocking layer 317 can be refracted and extracted from the light-emitting region, increasing the emission efficiency.

A plurality of the depressed portions 181 may be formed in a matrix. The depressed portion 181a and the depressed portion 181b may be provided in contact with each other or may have a flat surface therebetween.

Although the top-view shape and the cross-sectional shape of the depressed portion are hexagonal (FIG. 11C) and semicircular (FIG. 11A), respectively, other shapes may be employed as needed. Examples of the top-view shape of the depressed portion include polygons such as a triangle, a tetragon (including a rectangle and a square), and a pentagon; these polygons with rounded corners; an ellipse; and a circle.

As the organic resin layer 180, an insulating layer including an organic material can be used. For the organic resin layer 180, an acrylic resin, a polyimide resin, an epoxy resin, an imide resin, a polyamide resin, a polyimide-amide resin, a silicone resin, a siloxane resin, a benzocyclobutene-based resin, a phenol resin, or a precursor of any of these resins can be used, for example. Alternatively, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used for the organic resin layer 180.

Further alternatively, a photosensitive resin can be used for the organic resin layer 180. A photoresist may be used as the photosensitive resin. As the photosensitive resin, a positive photosensitive material or a negative photosensitive material can be used.

The organic resin layer 180 may include a material absorbing visible light. For example, the organic resin layer 180 itself may be made of a material absorbing visible light, or the organic resin layer 180 may include a pigment absorbing visible light. For the organic resin layer 180, for example, a resin that can be used as a color filter transmitting red, blue, or green light and absorbing light of the other colors or a resin that includes carbon black as a pigment and functions as a black matrix can be used.

The first electrodes 101 (a first electrode 101R and a first electrode 101W) are provided over the organic resin layer 180, and the organic compound layer 103 is provided over the first electrodes 101. End portions of the first electrode 101 and the organic compound layer 103 may be covered with the insulating layer 127.

The first electrode 101 formed over the organic resin layer 180 has a depressed portion along the depressed portion of the organic resin layer 180. Furthermore, the organic compound layer 103 formed over the first electrode 101 has a depressed portion along the depressed portion of the first electrode 101. Furthermore, the common layer 104 formed over the organic compound layer 103 has a depressed portion along the depressed portion of the organic compound layer 103. Furthermore, the second electrode 102 formed over the common layer 104 has a depressed portion along the depressed portion of the common layer 104. That is, the depressed portions of the organic resin layer 180, the first electrode 101, the organic compound layer 103, the common layer 104, and the second electrode 102 overlap with each other.

The common layer 104 is provided over the organic compound layer 103 and the insulating layer 127, and the second electrode 102 is provided over the common layer 104. The protective layer 131 is provided over the second electrode 102, and the substrate 352 is bonded with the use of the adhesive layer 142.

Although not shown in FIGS. 11A to 11C, the light-emitting device 130G and the light-emitting device 130B are also provided.

### [Display Apparatus 100E]

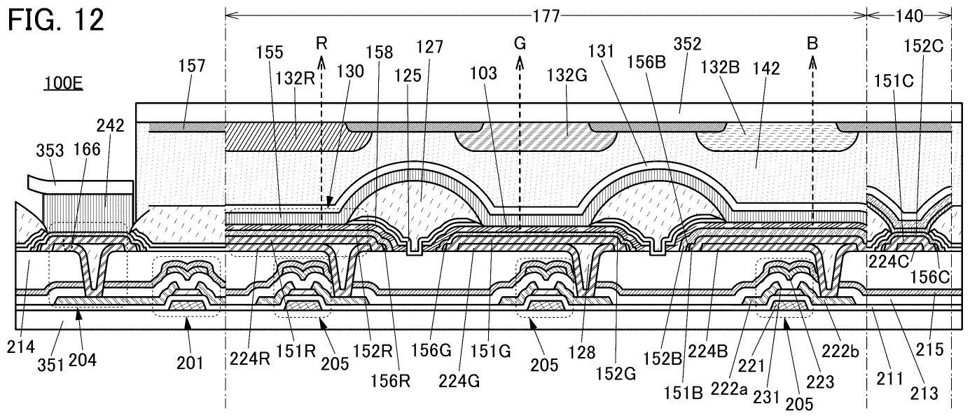

The display apparatus 100E illustrated in FIG. 12 is a variation example of the display apparatus 100C illustrated in FIG. 9 and differs from the display apparatus 100C mainly in including the coloring layers 132R, 132G, and 132B.

In the display apparatus 100E, the light-emitting device 130 includes a region overlapping with one of the coloring layers 132R, 132G, and 132B. The coloring layers 132R, 132G, and 132B can be provided on the surface of the substrate 352 on the substrate 351 side. End portions of the coloring layers 132R, 132G, and 132B can overlap with the light-blocking layer 157.

In the display apparatus 100E, the light-emitting device 130 can emit white light, for example. The coloring layer 132R, the coloring layer 132G, and the coloring layer 132B can transmit red light, green light, and blue light, respectively, for example. Note that in the display apparatus 100E, the coloring layers 132R, 132G, and 132B may be provided between the protective layer 131 and the adhesive layer 142.

### [Display Apparatus 100E2]

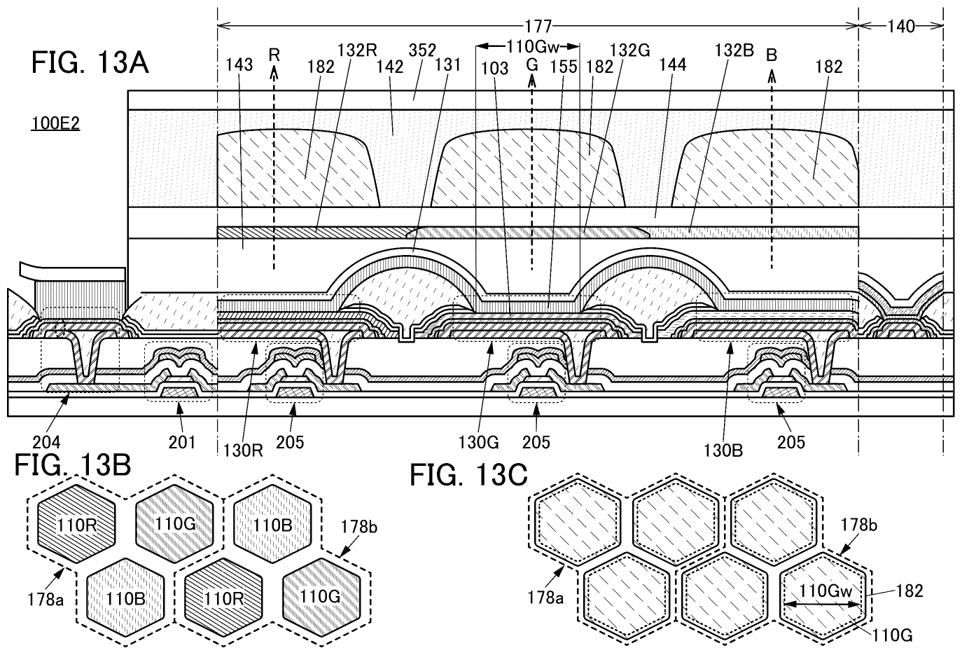

The display apparatus 100E2 illustrated in FIG. 13A is a variation example of the display apparatus 100E illustrated in FIG. 12 and includes microlenses 182 over the coloring layers 132R, 132G, and 132B. Note that in the drawings, reference numerals of some of the components that are shown in FIG. 12 are omitted; for the details of the components, the description made with reference to FIG. 12 can be referred to.

FIG. 13B shows a top-view layout of the pixels 178 (the pixels 178a and 178b) each including the subpixels 110 (the subpixels 110R, 110G, and 110B), and FIG. 13C shows a top view of the microlenses 182 in a region where the subpixels 110R, 110G, and 110B of the pixels 178 are formed. Note that the width of the region where the common electrode 155 and the organic compound layer 103 are in contact with each other corresponds to a width 110Gw in the light-emitting region of the subpixel 110G.

In the display apparatus 100E2 illustrated in FIG. 13A, a planarization film 143 is provided over the protective layer 131, and the coloring layers 132R, 132G, and 132B are provided over the planarization film 143. A planarization film 144 is provided to cover the coloring layers 132R, 132G, and 132B. The microlenses 182 are provided over the planarization film 144.

Note that as illustrated in FIG. 13C, the microlenses 182 are preferably provided on a subpixel basis in the region where the subpixels are formed.

Although the top-view shape of the microlens 182 is illustrated as a hexagon in FIG. 13C, other shapes may be employed as needed. Examples of the top-view shape of the microlens 182 include polygons such as a triangle, a tetragon (including a rectangle and a square), and a pentagon; these polygons with rounded corners; an ellipse; and a circle.

The microlens 182 can be formed using a material similar to that for the organic resin layer 180.

This embodiment can be combined as appropriate with the other embodiments or examples. In this specification, in the case where a plurality of structure examples are shown in one embodiment, the structure examples can be combined as appropriate.

### Embodiment 7

In this embodiment, electronic appliances of embodiments of the present invention will be described.

Electronic appliances of this embodiment include the light-emitting apparatus of one embodiment of the present invention in their display portions. The light-emitting apparatus of one embodiment of the present invention is highly reliable and can be easily increased in resolution and definition. Thus, the light-emitting apparatus of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the light-emitting apparatus of one embodiment of the present invention can have high resolution, and thus can be favorably used for an electronic appliance having a relatively small display portion. Examples of such an electronic appliance include watch-type and bracelet-type information terminal devices (wearable devices) and wearable devices capable of being worn on a head, such as a VR device like a head-mounted display, a glasses-type AR device, and a mixed reality (MR) device.

The definition of the light-emitting apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, definition of 4K, 8K, or higher is preferable. The pixel density (resolution) of the light-emitting apparatus of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the light-emitting apparatus having one or both of such high definition and high resolution can further increase realistic sensation, sense of depth, and the like. There is no particular limitation on the screen ratio (aspect ratio) of the light-emitting apparatus of one embodiment of the present invention. For example, the light-emitting apparatus is compatible with a variety of screen ratios such as 1:1 (a square), 4:3, 16:9, and 16:10.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic appliance in this embodiment can have a variety of functions. For example, the electronic appliance in this embodiment can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

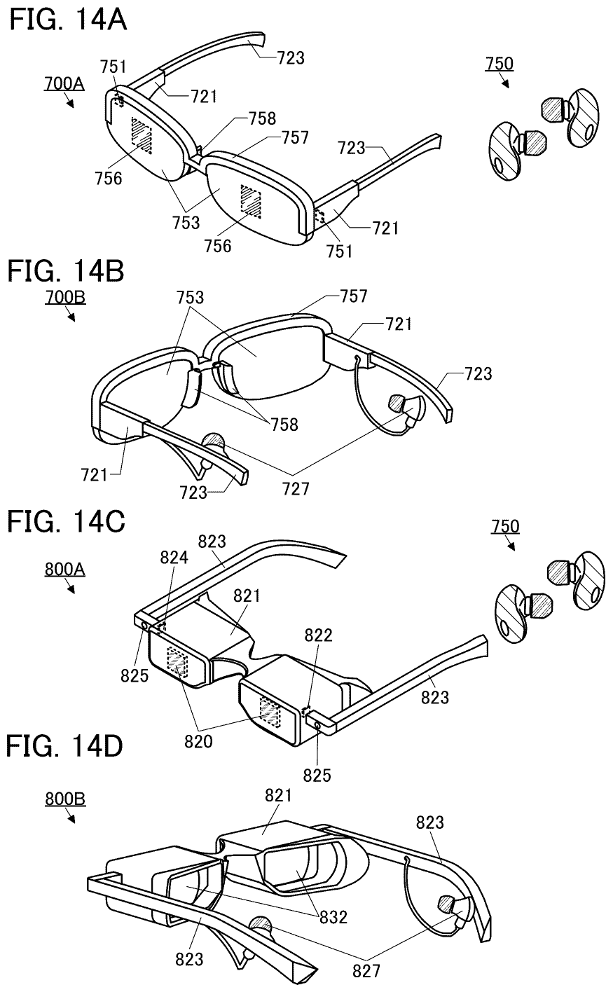

Examples of head-mounted wearable devices are described with reference to FIGS. 14A to 14D. These wearable devices have at least one of a function of displaying AR contents, a function of displaying VR contents, a function of displaying substitutional reality (SR) contents, and a function of displaying MR contents. The electronic appliance having a function of displaying contents of at least one of AR, VR, SR, MR, and the like enables the user to feel a higher level of immersion.

An electronic appliance 700A illustrated in FIG. 14A and an electronic appliance 700B illustrated in FIG. 14B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The light-emitting apparatus of one embodiment of the present invention can be used for the display panels 751. Thus, a highly reliable electronic appliance is obtained.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliances 700A and 700B are electronic appliances capable of performing AR display.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a moving image can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic appliance 800A illustrated in FIG. 14C and an electronic appliance 800B illustrated in FIG. 14D each include a pair of display portions 820, a housing 821, a communication portion 822, a pair of wearing portions 823, a control portion 824, a pair of image capturing portions 825, and a pair of lenses 832.

The light-emitting apparatus of one embodiment of the present invention can be used in the display portions 820. Thus, a highly reliable electronic appliance is obtained.

The display portions 820 are positioned inside the housing 821 so as to be seen through the lenses 832. When the pair of display portions 820 display different images, three-dimensional display using parallax can be performed.

The electronic appliances 800A and 800B can be regarded as electronic appliances for VR. The user who wears the electronic appliance 800A or 800B can see images displayed on the display portions 820 through the lenses 832.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic appliances 800A and 800B preferably include a mechanism for adjusting focus by changing the distance between the lenses 832 and the display portions 820.

The electronic appliance 800A or 800B can be worn on the user's head with the wearing portions 823. FIG. 14C, for instance, shows an example where the wearing portion 823 has a shape like a temple of glasses; however, one embodiment of the present invention is not limited thereto. The wearing portion 823 can have any shape with which the user can wear the electronic appliance, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is described here, a range sensor (hereinafter also referred to as a sensing portion) capable of measuring the distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic appliance 800A.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750. The earphones 750 include a communication portion (not illustrated) and have a wireless communication function. The earphones 750 can receive information (e.g., audio data) from the electronic appliance with the wireless communication function. For example, the electronic appliance 700A in FIG. 14A has a function of transmitting information to the earphones 750 with the wireless communication function. For another example, the electronic appliance 800A in FIG. 14C has a function of transmitting information to the earphones 750 with the wireless communication function.

The electronic appliance may include an earphone portion. The electronic appliance 700B in FIG. 14B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic appliance 800B in FIG. 14D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of a headset by including the audio input mechanism.

As described above, both the glasses-type device (e.g., the electronic appliances 700A and 700B) and the goggles-type device (e.g., the electronic appliances 800A and 800B) are preferable as the electronic appliance of one embodiment of the present invention.

The electronic appliance of one embodiment of the present invention can transmit information to earphones by wire or wirelessly.

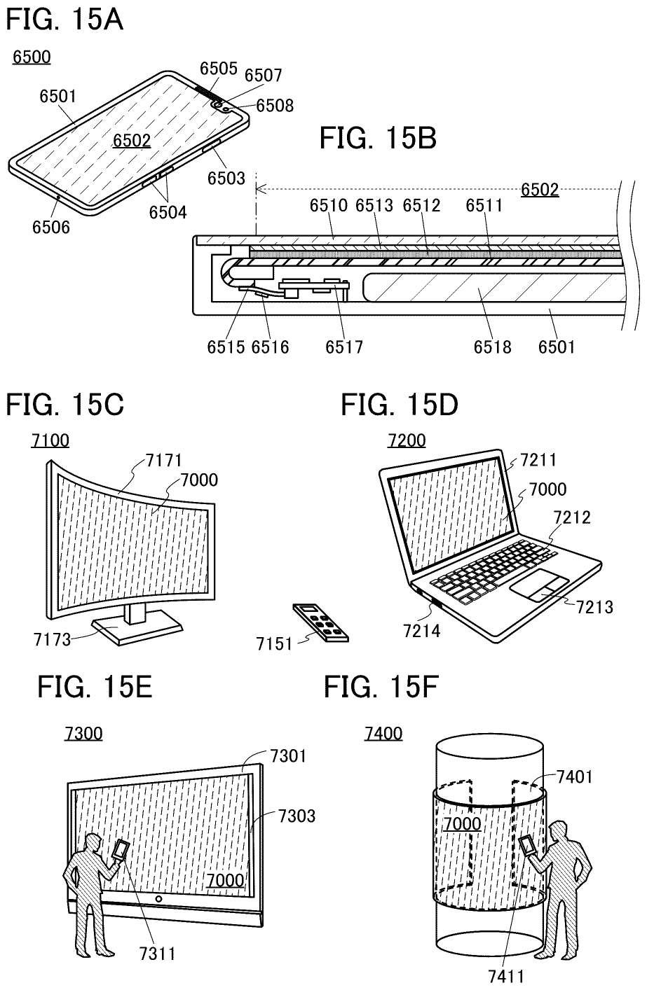

An electronic appliance 6500 illustrated in FIG. 15A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The light-emitting apparatus of one embodiment of the present invention can be used in the display portion 6502. Thus, a highly reliable electronic appliance is obtained.

FIG. 15B is a schematic cross-sectional view including an edge portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The light-emitting apparatus of one embodiment of the present invention can be used in the display panel 6511. Thus, an extremely lightweight electronic appliance can be obtained. Since the display panel 6511 is extremely thin, the battery 6518 with high capacity can be mounted without an increase in the thickness of the electronic appliance. An electronic appliance with a narrow bezel can be obtained when part of the display panel 6511 is folded back so that the portion connected to the FPC 6515 is provided on the back side of a pixel portion.

FIG. 15C illustrates an example of a television device. In a television device 7100, a display portion 7000 is incorporated in a housing 7171. Here, the housing 7171 is supported by a stand 7173.

The light-emitting apparatus of one embodiment of the present invention can be used in the display portion 7000. Thus, a highly reliable electronic appliance is obtained.

Operation of the television device 7100 illustrated in FIG. 15C can be performed with an operation switch provided in the housing 7171 and a separate remote control 7151. Alternatively, the display portion 7000 may include a touch sensor, and the television device 7100 may be operated by touch on the display portion 7000 with a finger or the like. The remote control 7151 may be provided with a display portion for displaying information output from the remote control 7151. With operation keys or a touch panel of the remote control 7151, channels and volume can be controlled and video displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 15D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The light-emitting apparatus of one embodiment of the present invention can be used in the display portion 7000. Thus, a highly reliable electronic appliance is obtained.

FIGS. 15E and 15F illustrate examples of digital signage.

Digital signage 7300 illustrated in FIG. 15E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 15F shows digital signage 7400 attached to a cylindrical pillar 7401. The digital signage 7400 includes the display portion 7000 provided along a curved surface of the pillar 7401.

In FIGS. 15E and 15F, the light-emitting apparatus of one embodiment of the present invention can be used in the display portion 7000. Thus, a highly reliable electronic appliance is obtained.

A larger area of the display portion 7000 can increase the amount of information that can be provided at a time. The display portion 7000 having a larger area attracts more attention, so that the effectiveness of the advertisement can be increased, for example.

The touch panel is preferably used in the display portion 7000, in which case in addition to display of still or moving images on the display portion 7000, intuitive operation by a user is possible. Moreover, in the case of an application for providing information such as route information or traffic information, usability can be enhanced by intuitive operation.

As illustrated in FIGS. 15E and 15F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

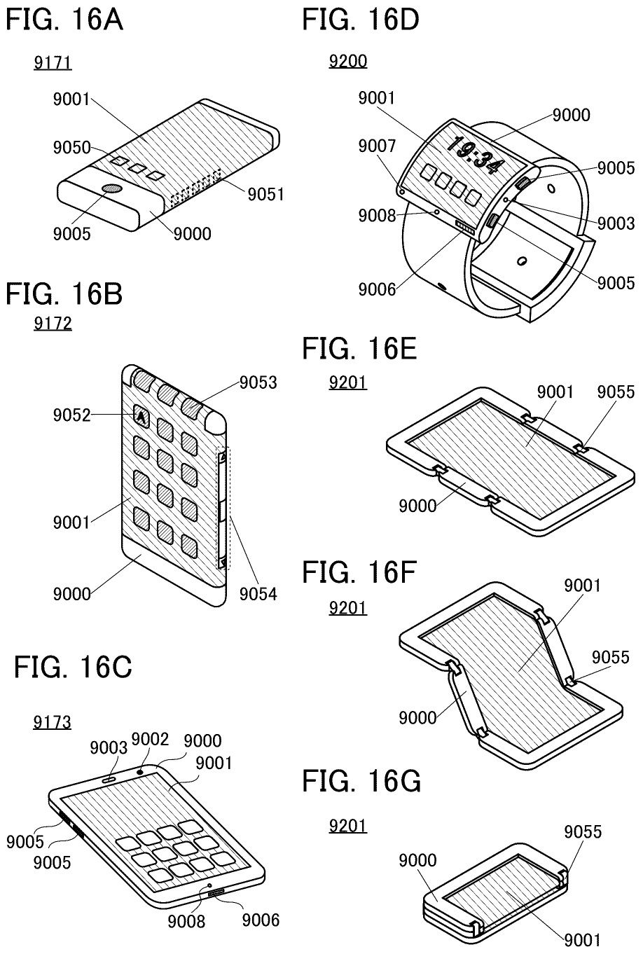

Electronic appliances illustrated in FIGS. 16A to 16G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 16A to 16G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic appliances are not limited thereto, and the electronic appliances can have a variety of functions. The electronic appliances may include a plurality of display portions. The electronic appliances may be provided with a camera or the like and have a function of taking a still image or a moving image, a function of storing the taken image in a storage medium (an external storage medium or a storage medium incorporated in the camera), a function of displaying the taken image on the display portion, and the like.

The electronic appliances in FIGS. 16A to 16G are described in detail below.

FIG. 16A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 16A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 16B is a perspective view of a portable information terminal 9172. The portable information terminal 9172 has a function of displaying information on three or more surfaces of the display portion 9001. Here, an example in which information 9052, information 9053, and information 9054 are displayed on different surfaces is described. For example, the user of the portable information terminal 9172 can check the information 9053 displayed such that it can be seen from above the portable information terminal 9172, with the portable information terminal 9172 put in a breast pocket of his/her clothes. Thus, the user can see the display without taking out the portable information terminal 9172 from the pocket and decide whether to answer the call, for example.

FIG. 16C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 16D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 16E to 16G are perspective views of a foldable portable information terminal 9201. FIG. 16E is a perspective view showing the portable information terminal 9201 that is opened. FIG. 16G is a perspective view showing the portable information terminal 9201 that is folded. FIG. 16F is a perspective view showing the portable information terminal 9201 that is shifted from one of the states in FIGS. 16E and 16G to the other. The portable information terminal 9201 is highly portable when folded. When the portable information terminal 9201 is opened, a seamless large display region is highly browsable. The display portion 9001 of the portable information terminal 9201 is supported by three of the housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or examples. In this specification, in the case where a plurality of structure examples are shown in one embodiment, the structure examples can be combined as appropriate.

### Example 1

In this example, a method for synthesizing N,N′-bis(4-biphenyl-2,2′,3,3′,4′,5,5′,6,6′-d₉)-6-(phenyl-2,3,4,5,6-d₅)benzo[b]naphtho[1,2-d]furan(1,2,3,4,5,9,10,11-d₈)-8-amine (abbreviation: BBABnf-d31), which is the organic compound represented by Structural Formula (100) in Embodiment 2, will be specifically described. The structure of BBABnf-d31 is shown below.

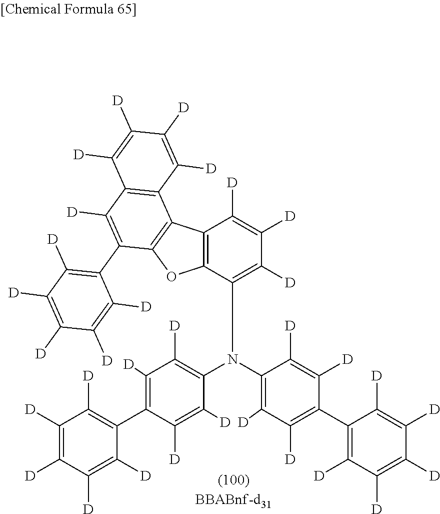 [SMILES: [2H]c1c([2H])c([2H])c(-c2c([2H])c([2H])c(N(c3c([2H])c([2H])c(-c4c([2H])c([2H])c([2H])c([2H])c4[2H])c([2H])c3[2H])c3c([2H])c([2H])c([2H])c4c3oc3c(-c5c([2H])c([2H])c([2H])c([2H])c5[2H])c([2H])c5c([2H])c([2H])c([2H])c([2H])c5c34)c([2H])c2[2H])c([2H])c1[2H]]

### Synthesis Example 1

A method for synthesizing BBABnf-d31 by using a substituent including deuterium is described below.

### Step 1: Synthesis of 8-iodo-6-(phenyl-2,3,4,5,6-d₅)benzo[b]naphtho[1,2-d]furan(1,2,3,4,5,9,10,11-d₈)

First, 10 g (24 mmol) of 8-iodo-6-phenylbenzo[b]naphtho[1,2-d]furan and 40 mL of toluene-d₈ were put into a 100-mL three-neck flask. This mixture was heated to 100° C. under a nitrogen stream, and it was verified that 8-iodo-6-phenylbenzo[b]naphtho[1,2-d]furan was dissolved by this heating. To this solution was added 6.9 g (25 mmol) of molybdenum chloride (MoCl₅), and the mixture was stirred at 100° C. for five minutes. To this mixture were slowly added 10 mL of ethanol and 30 mL of water. The mixture was subjected to suction filtration to remove an insoluble matter, and then, separation was performed using chloroform and pure water. The organic phase was washed once with a saturated aqueous solution of sodium bicarbonate and washed once with a saturated aqueous solution of sodium thiosulfate. The organic phase was dehydrated with magnesium sulfate and subjected to gravity filtration using pleated filter paper. The filtrate was concentrated to give 7.3 g of a reddish brown solid containing the target substance. This solid was purified by liquid chromatography to give 5.6 g of a yellow solid of the target substance in a yield of 55%. Synthesis Scheme (a1-1) of <Step 1> is shown below.

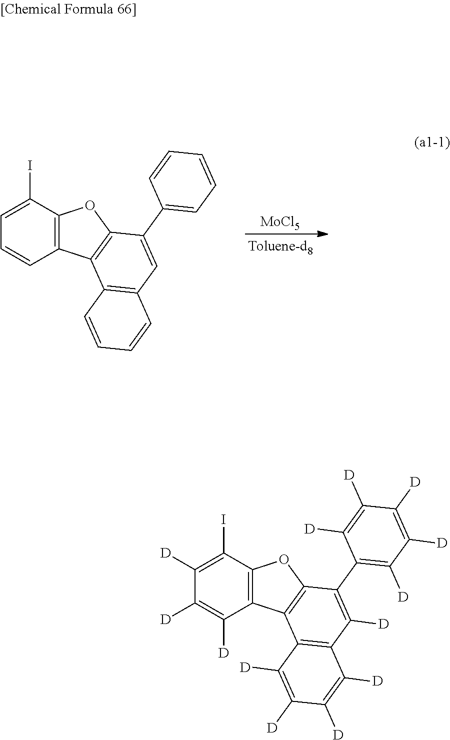

The molecular weight of the yellow solid obtained in <Step 1> above was measured by liquid chromatography-mass spectrometry analysis (hereinafter also referred to as LC/MS analysis). As a result, a signal was observed at m/z 433 while the mass of the target substance was calculated to be 433, revealing that 8-iodo-6-(phenyl-2,3,4,5,6-d₅)benzo[b]naphtho[1,2-d]furan(1,2,3,4,7,8,9,10,11-d₈) was obtained.

### Step 2: Synthesis of BBABnf-d31

Next, 5.6 g (13 mmol) of 8-iodo-6-(phenyl-2,3,4,5,6-d₅)benzo[b]naphtho[1,2-d]furan(1,2,3,4,7,8,9,10,11-d₈) obtained in Step 1, 3.4 g (9.9 mmol) of N,N′-bis(4-biphenylyl-2,2′,3,3′,4′,5,5′,6,6′-d₉), 3.0 g (31 mmol) of ^{t}BuONa, and 75 mL of toluene were put into a 200-mL three-neck flask. This mixture was degassed by being stirred under reduced pressure, and the atmosphere in the flask was replaced with nitrogen; then, the mixture was heated to 100° C. To this reaction solution, 0.5 mL (0.37 mmol) of tri-tert-butylphosphine (abbreviation: P(^{t}Bu)₃) (20 wt % hexane solution) and 73 mg (0.13 mmol) of bis(dibenzylideneacetone)palladium(0) (abbreviation: Pd(dba)₂) were added, and the mixture was stirred at 120° C. for two hours and cooled down to room temperature. Subsequently, this mixture was heated to 80° C.; then, 0.31 g (0.75 mmol) of 2-dicyclohexylphosphino-2′,6′-dimethoxybiphenyl (abbreviation: SPhos) and 0.15 g (0.27 mmol) of Pd(dba)₂ were added, and the mixture was stirred at 120° C. for seven hours. Toluene was added to this mixture, and the resulting mixture was subjected to suction filtration through Alumina, Celite (Catalog No. 537-02305, FUJIFILM Wako Pure Chemical Corporation), and Florisil (Catalog No. 066-05265, FUJIFILM Wako Pure Chemical Corporation). The resulting filtrate was concentrated to give 8.1 g of a pale yellow solid containing the target substance. This solid was purified by liquid chromatography and then dissolved in toluene. To the resulting solution, ethanol was added to precipitate a solid. This solid was collected by suction filtration, so that 6.1 g of a pale yellow solid of the target substance was obtained in a yield of 95%. Synthesis Scheme (a1-2) of <Step 2> is shown below.

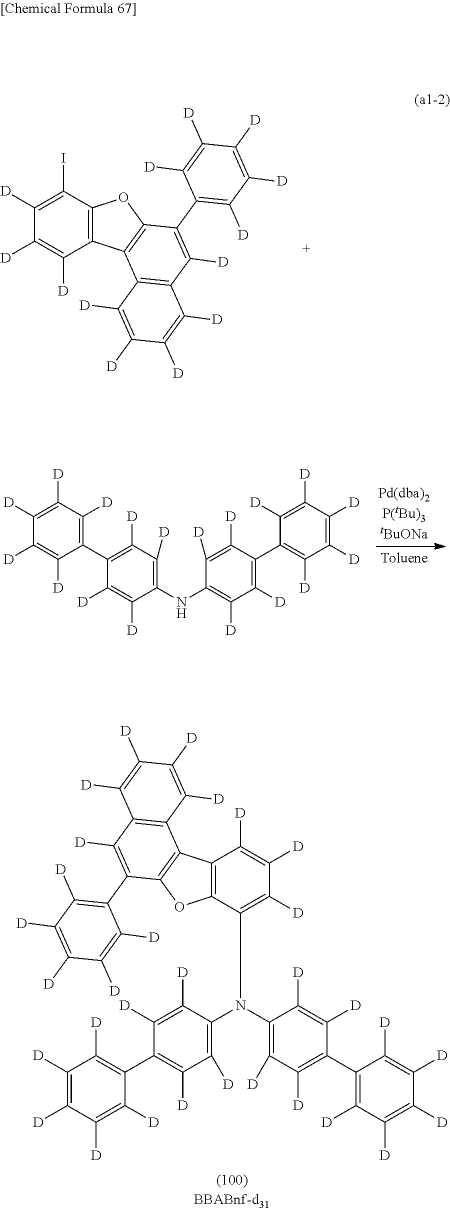

By a train sublimation method, 4.7 g of the obtained pale yellow solid was purified. In the purification by sublimation, the solid was heated at 300° C. under a pressure of 1.55 Pa for 23 hours. After the purification by sublimation, 3.3 g of a colorless solid of the target substance was obtained at a collection rate of 70%.

The molecular weight of the colorless solid obtained in <Step 2> above was measured by LC/MS analysis. As a result, a signal was observed at m/z 644 while the mass of the target substance was calculated to be 644, revealing that BBABnf-d31 was obtained.

In the case where BBABnf-d31 was synthesized by deuteration of the raw materials of the partial structures and the subsequent coupling reaction between the deuterated partial structures as in Synthesis Example 1 and subjected to the molecular weight measurement by LC/MS analysis, a signal was observed at m/z 644 while the mass of the target substance was calculated to be 644. Thus, a method in which a target substance is synthesized by deuteration of raw materials of partial structures and a subsequent coupling reaction as in Synthesis Example 1 is preferably employed to synthesize a compound having a molecular structure in which deuteriums are substituted for all the protiums, and to improve the proportion of deuterium introduced by deuteration.

### <Measurement of Physical Properties>

Next, the ultraviolet-visible absorption spectrum (hereinafter referred to as absorption spectrum) and emission spectrum (photoluminescence (PL) spectrum, hereinafter referred to as PL spectrum) of a toluene solution and a solid thin film of BBABnf-d31, which was obtained in Synthesis Example 1, were measured.

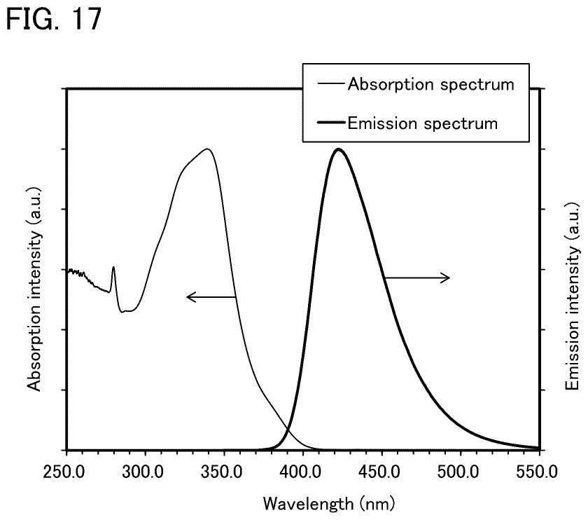

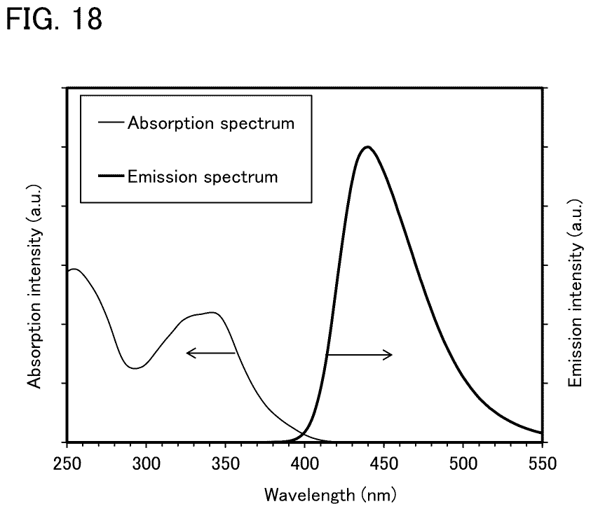

The absorption spectrum of the solution was measured with an ultraviolet-visible spectrophotometer (V-770DS, JASCO Corporation), and the absorption spectrum of the thin film was measured with an ultraviolet-visible spectrophotometer (U-4100, Hitachi). To calculate the absorption spectrum of the toluene solution of BBABnf-d31, the absorption spectrum of toluene put in a quartz cell was measured and then subtracted from the absorption spectrum of the toluene solution of BBABnf-d31 put in a quartz cell. The PL spectrum was measured with a fluorescence spectrophotometer (FP-8600DS, JASCO Corporation). FIG. 17 shows the measurement results of the absorption spectrum and the PL spectrum of the toluene solution of BBABnf-d31, and FIG. 18 shows the measurement results of the absorption spectrum and the PL spectrum of the thin film of BBABnf-d31.

As shown in FIG. 17, the absorption spectrum of the toluene solution of BBABnf-d31 exhibited an absorption peak at around 339 nm. The results reveal that the solution of BBABnf-d31 shows no absorption at wavelengths greater than or equal to 440 nm and that the material of the present invention can be suitably used for a light-emitting device. As shown in FIG. 17, the PL spectrum of the toluene solution of BBABnf-d31 exhibited an emission peak at around 423 nm (excitation wavelength: 339 nm).

As shown in FIG. 18, the absorption spectrum of the thin film of BBABnf-d31 exhibited the maximum absorption peak at around 367 nm. The results reveal that the thin film of BBABnf-d31 also shows no absorption at wavelengths greater than or equal to 440 nm and that the material of the present invention can be suitably used for a light-emitting device. As shown in FIG. 18, the PL spectrum of the thin film of BBABnf-d31 exhibited an emission peak at around 433 nm (excitation wavelength: 368 nm).

The thermogravimetry-differential thermal analysis (TG-DTA) of BBABnf-d31 was performed. For the measurement, a high-sensitivity differential type differential thermogravimeter (STA 2500 Regulus, NETZSCH Japan K. K.) was used. The measurement was performed under first conditions and second conditions. Under the first conditions, the measurement was performed at a temperature rising rate of 10° C./min under atmospheric pressure and a nitrogen stream (flow rate: 200 mL/min). Under the second conditions, the measurement was performed at a temperature rising rate of 10° C./min under 10 Pa.

The thermogravimetry-differential thermal analysis performed under the first measurement conditions reveals that the temperature at which the weight of BBABnf-d31 obtained by thermogravimetry decreases by 5% of the weight at the start of the measurement (i.e., the sublimation or decomposition temperature of BBABnf-d31) is 435° C. under atmospheric pressure. The results show that the sublimation or decomposition temperature of BBABnf-d31 under atmospheric pressure is 435° C., which indicates high heat resistance.

The thermogravimetry-differential thermal analysis performed under the second measurement conditions reveals that the temperature at which the weight of BBABnf-d31 obtained by thermogravimetry decreases by 5% of the weight at the start of the measurement (i.e., the sublimation or decomposition temperature of BBABnf-d31) is 236° C. under 10 Pa. The results show that the sublimation temperature of BBABnf-d31 under 10 Pa is 236° C.

The above results show that the sublimation temperature (236° C.) of BBABnf-d31 under Pa is lower than the sublimation or decomposition temperature (435° C.) thereof under atmospheric pressure by 199° C. This indicates that BBABnf-d31 can be deposited by evaporation at a temperature sufficiently lower than the decomposition temperature under atmospheric pressure. It is thus suggested that the organic compound of one embodiment of the present invention is a material that is less likely to be decomposed during deposition by evaporation and can be formed into a high-purity film by being deposited by evaporation.

Differential scanning calorimetry (DSC) measurement of BBABnf-d31 was performed with DSC8500 manufactured by PerkinElmer, Inc. The DSC measurement was performed in the following manner. The temperature was raised from −10° C. to 400° C. at a temperature rising rate of 40° C./min and held for three minutes; then, the temperature was lowered to −10° C. at a temperature falling rate of 100° C./min and held for three minutes. This operation was performed twice in succession. Subsequently, the temperature was raised from −10° C. to 400° C. at a temperature rising rate of 50° C./min and held for three minutes; then, the temperature was lowered to −10° C. at a temperature falling rate of 100° C./min. This operation was performed once.

According to the results of the DSC measurement in the second temperature raising process, the Tg of BBABnf-d31 is 123° C., and the melting point and the crystallization temperature are not observed. It was found that an organic semiconductor element such as a light-emitting device can have increased heat resistance by including the organic compound of one embodiment of the present invention. Since the melting point and the crystallization temperature were not observed, it was suggested that BBABnf-d31 of the present invention can be formed into a thin film having high heat resistance and stable quality and can be suitably used for an organic semiconductor element.

The HOMO level and the LUMO level of BBABnf-d31 were calculated through cyclic voltammetry (CV) measurement. The calculation method is described below.

An electrochemical analyzer (ALS model 600A or 600C, BAS Inc.) was used as a measurement apparatus. To prepare a solution for the CV measurement, dehydrated dimethylformamide (DMF; Sigma-Aldrich Inc., 99.8%, catalog No. 22705-6) was used as a solvent, and tetra-n-butylammonium perchlorate (n-Bu₄NClO₄; Tokyo Chemical Industry Co., Ltd., catalog No. T0836) as a supporting electrolyte was dissolved at a concentration of 100 mmol/L. Furthermore, the measurement target was also dissolved at a concentration of 2 mmol/L.

A platinum electrode (PTE platinum electrode, BAS Inc.) was used as a working electrode, a platinum electrode (Pt counter electrode for VC-3 (5 cm), BAS Inc.) was used as an auxiliary electrode, and an Ag/Ag⁺ electrode (RE-7 nonaqueous reference electrode, BAS Inc.) was used as a reference electrode. Note that the measurement was performed at room temperature (higher than or equal to 20° C. and lower than or equal to 25° C.). The scan speed in the CV measurement was fixed to 0.1 V/sec, and an oxidation potential Ea [V] and a reduction potential Ec [V] with respect to the reference electrode were measured. The potential Ea is an intermediate potential of an oxidation-reduction wave, and the potential Ec is an intermediate potential of a reduction-oxidation wave. Here, since the potential energy of the reference electrode used in this example with respect to the vacuum level is known to be −4.94 [eV], the HOMO level and the LUMO level can be calculated by the following formulae: HOMO level [eV]=−4.94−Ea and LUMO level [eV]=−4.94−Ec.

The CV measurement was repeated 100 times, and the oxidation-reduction wave in the 100th cycle was compared with the oxidation-reduction wave in the first cycle to examine the electrical stability of the compound.

As a result, in the measurement of the oxidation potential Ea [V] of BBABnf-d31, the HOMO level was found to be −5.55 eV. In contrast, the LUMO level was found to be −2.50 eV in the measurement of the reduction potential Ec [V]. When the oxidation-reduction wave was repeatedly measured, in the Ea measurement, the peak intensity of the oxidation-reduction wave after the 100th cycle was maintained to be 93% of that of the oxidation-reduction wave at the first cycle, and in the Ec measurement, the peak intensity of the oxidation-reduction wave after the 100th cycle was maintained to be 96% of that of the oxidation-reduction wave at the first cycle; thus, the resistance of BBABnf-d31 to repetitive oxidation and repetitive reduction was found to be extremely high.

It has been reported that the peak intensity of the oxidation-reduction wave after the 100th cycle of N,N′-bis(4-biphenyl)-6-phenylbenzo[b]naphtho[1,2-d]furan-8-amine (abbreviation: BBABnf), which is not deuterated, is 90% of that of the oxidation-reduction wave at the first cycle (Patent Document 3: Japanese Published Patent Application No. 2017-139457). It was thus found that BBABnf-d31 described in Example 1 has higher resistance to repetitive oxidation and repetitive reduction than BBABnf, which is not deuterated. In particular, it was found that BBABnf-d31 has much higher resistance to repetitive reduction. Therefore, BBABnf-d31 should be suitable for an electron-blocking layer in an organic EL device.

The lowest triplet excitation energy level (T₁ level) of BBABnf-d31 was calculated through the measurement of a PL spectrum (phosphorescence spectrum). The calculation method is described below.

For calculation of the lowest triplet excitation energy level (T₁ level), a PL spectrum (a phosphorescence spectrum) was measured at a measurement temperature of 10 K using a 50-nm-thick thin film of the sample formed over a quartz substrate. The measurement was performed with a PL microscope (LabRAM HR-PL, HORIBA, Ltd.) and a He—Cd laser (325 nm) as excitation light. Note that the emission edge was determined as the intersection between a tangent and the horizontal axis (representing wavelength) or the baseline. The tangent was drawn at a point at which the slope on a shorter wavelength side of the shortest-wavelength peak (or the shortest-wavelength shoulder peak) of the PL spectrum (phosphorescence spectrum) has the maximum absolute value.

As a result, it was found that the lowest triplet excitation energy level (T₁ level) of BBABnf-d31 is 2.35 eV.

### Example 2

This example specifically describes a synthesis method, which is different from that in Example 1, of N,N′-bis(4-biphenyl-2,2′,3,3′,4′,5,5′,6,6′-d₉)-6-(phenyl-2,3,4,5,6-d₅)benzo[b]naphtho[1,2-d]furan(1,2,3,4,5,9,10,11-d₈)-8-amine (abbreviation: BBABnf-d31), the organic compound represented by Structural Formula (100) in Embodiment 2. The structure of BBABnf-d31 is shown below.

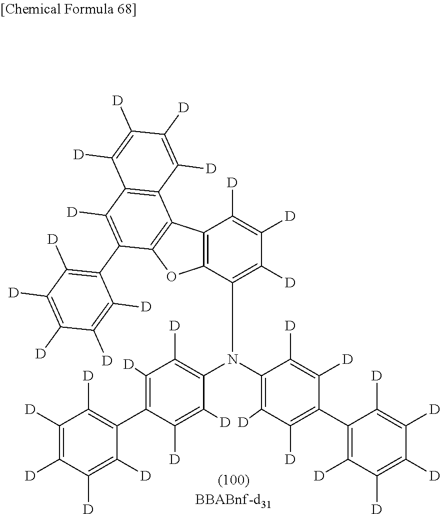 [SMILES: [2H]c1c([2H])c([2H])c(-c2c([2H])c([2H])c(N(c3c([2H])c([2H])c(-c4c([2H])c([2H])c([2H])c([2H])c4[2H])c([2H])c3[2H])c3c([2H])c([2H])c([2H])c4c3oc3c(-c5c([2H])c([2H])c([2H])c([2H])c5[2H])c([2H])c5c([2H])c([2H])c([2H])c([2H])c5c34)c([2H])c2[2H])c([2H])c1[2H]]

### Synthesis Example 2

A method for synthesizing BBABnf-d31 through deuteration of N,N′-bis(4-biphenyl)-6-phenylbenzo[b]naphtho[1,2-d]furan-8-amine (abbreviation: BBABnf) will be described below.

### Step 1: Synthesis of BBABnf-d31

First, 1.2 g (2.0 mmol) of N,N′-bis(4-biphenylyl)-6-phenylbenzo[b]naphtho[1,2-d]furan-8-amine and 21 mL of toluene-d₈ were put into a 50-mL three-neck flask. This mixture was heated to 100° C. under a nitrogen stream, and it was verified that N,N′-bis(4-biphenylyl)-6-phenylbenzo[b]naphtho[1,2-d]furan-8-amine was dissolved by this heating. To this solution was added 512 mg (1.8 mmol) of molybdenum chloride (MoCl₅), and the mixture was stirred at 100° C. for 10 hours. A small amount of the reaction solution was taken, and the molecular weight was measured by LC/MS analysis, so that signals were mainly observed at m/z 628 to 631, and a signal was also observed at m/z 644 while the mass of the target substance was calculated to be 644. These results indicate that BBABnf-d15, BBABnf-d16, BBABnf-d17, and BBABnf-d18 were generated in addition to BBABnf-d31, the target substance. Specific examples of BBABnf-d15, BBABnf-d16, BBABnf-d17, and BBABnf-d18 include the organic compounds represented by Structural Formulae (102) to (105). Synthesis Scheme (a2-1) of <Step 1> is shown below.

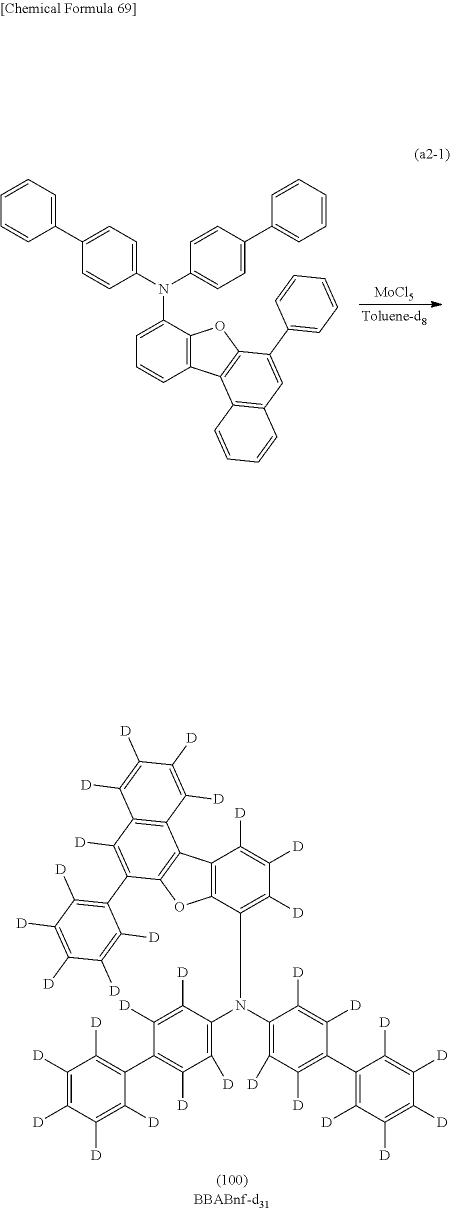

In the case where synthesis is performed as in Synthesis Example 2, a deuteration reaction needs to be caused only once, reducing the synthesis cost and thus enabling a deuterium-substituted compound to be obtained at low cost. Furthermore, since trifluoromethanesulfonic acid is not used, the target substance is less likely to contain fluorine as an impurity, which is extremely preferable. Note that an organic EL material containing fluorine is not preferable and needs to be purified to have a reduced fluorine concentration because a device fabricated using the material is more likely to have lowered reliability or emission efficiency. The deuteration reaction performed as in Synthesis Example 2 enables providing an organic EL material that contains deuterium but no fluorine.

### Example 3

### Synthesis Example 3

In this example, a method for synthesizing N,N′-bis{4-[(dibenzofuran-1,2,3,6,7,8,9-d₇)-4-yl]phenyl-2,3,5,6-d₄}-p-terphenyl-2,2′,2″,3,3′,3″,4″,5,5′,5″,6,6′,6″-d₁₃-4-amine (abbreviation: DBfBB1TP-d35), which is the organic compound represented by Structural Formula (101) in Embodiment 2, will be specifically described. The structure of DBfBB1TP-d35 is shown below.

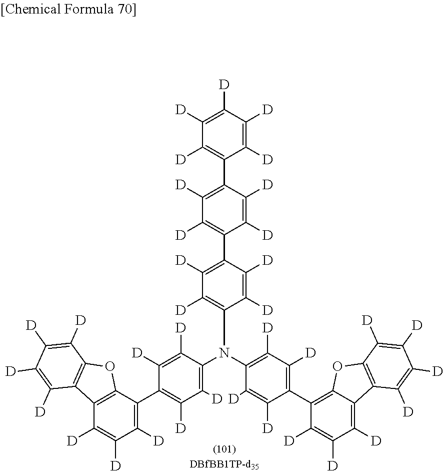 [SMILES: [2H]c1c([2H])c([2H])c(-c2c([2H])c([2H])c(-c3c([2H])c([2H])c(N(c4c([2H])c([2H])c(-c5c([2H])c([2H])c([2H])c6c5oc5c([2H])c([2H])c([2H])c([2H])c56)c([2H])c4[2H])c4c([2H])c([2H])c(-c5c([2H])c([2H])c([2H])c6c5oc5c([2H])c([2H])c([2H])c([2H])c56)c([2H])c4[2H])c([2H])c3[2H])c([2H])c2[2H])c([2H])c1[2H]]

### Step 1-1: Synthesis of 4,4′-di(dibenzofuran-1,2,3,6,7,8,9-d₇-4-yl)diphenylamine-2,2′,3,3′,5,5′,6,6′-d₈

First, into a 50-mL three-neck flask were put 1.0 g (2.0 mmol) of 4,4′-di(dibenzofuran-4-yl)diphenylamine and 20 mL of toluene-d₈. This mixture was heated to 100° C. under a nitrogen stream, and it was verified that 4,4′-di(dibenzofuran-4-yl)diphenylamine was dissolved by this heating. To this solution, 1.6 mL (14 mmol) of trifluoromethanesulfonic acid (abbreviation: TfOH) was added, and the mixture was stirred at 100° C. for eight hours. A small amount of the resulting solution was taken, and the molecular weight was measured by LC/MS analysis.

Note that in the LC/MS analysis, liquid chromatography (LC) separation was performed with UltiMate 3000 manufactured by Thermo Fisher Scientific K. K., and mass spectrometry (MS) was performed with Q Exactive manufactured by Thermo Fisher Scientific K. K.

In the LC/MS analysis results, a signal was observed at m/z 523 while the mass of the target substance was calculated to be 523. This showed that 4,4′-di(dibenzofuran-1,2,3,6,7,8,9-d₇-4-yl)diphenylamine-2,2′,3,3′,5,5′,6,6′-d₈ was generated. This substance was subjected to post-reaction treatment and purification together with the substance synthesized in the next <Step 1-2>, and thus the description of the post-reaction treatment and purification will be made later.

### Step 1-2: Synthesis of 4,4′-di(dibenzofuran-1,2,3,6,7,8,9-d₇-4-yl)diphenylamine-2,2′,3,3′,5,5′,6,6′-d₈

Into a 200-mL three-neck flask were put 3.0 g (6.0 mmol) of 4,4′-di(dibenzofuran-4-yl)diphenylamine and 68 mL of toluene-d₈. This mixture was heated to 100° C. under a nitrogen stream, and it was verified that 4,4′-di(dibenzofuran-4-yl)diphenylamine was dissolved by this heating. To this solution, 4.3 mL (49 mmol) of TfOH was added, and the mixture was stirred at 100° C. for four hours. After being cooled down to room temperature, the mixture was combined with the reaction solution obtained in <Step 1-1>. Chloroform and pure water were added, and separation was performed. The organic phase was washed twice with water, and then washed three times with a saturated aqueous solution of sodium bicarbonate. The organic phase was dehydrated with magnesium sulfate and subjected to gravity filtration using pleated filter paper. The filtrate was concentrated to give 4.6 g of a white solid of the target substance. Synthesis Scheme (b-1) of <Step 1-1> and <Step 1-2> is shown below.

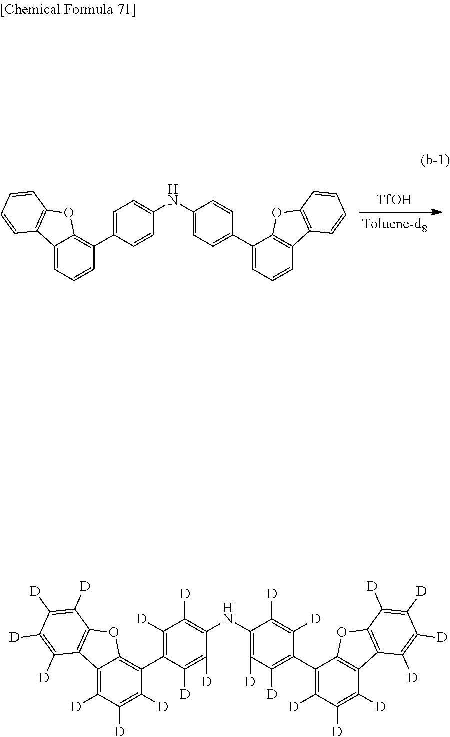

### Step 2: Synthesis of DBfBB1TP-d35

Then, into a 200-mL three-neck flask were put 2.7 g (5.2 mmol) of 4,4′-di(dibenzofuran-1,2,3,6,7,8,9-d₇-4-yl)diphenylamine-2,2′,3,3′,5,5′,6,6′-d₈ obtained in <Step 1-1> and <Step 1-2>, 2.5 g (7.8 mmol) of 4-bromo-p-terphenyl-2,2′,2″,3,3′,3″,4″,5,5′,5″,6,6′,6″-d₃, 1.5 g (16 mmol) of t-butoxysodium (abbreviation: ^{t}BuONa), and 63 mL of toluene. This mixture was degassed by being stirred under reduced pressure, and the atmosphere in the flask was replaced with nitrogen; then, the mixture was heated to 100° C. To this reaction solution were added 0.3 mL (0.1 mmol) of tri-tert-butylphosphine (abbreviation: P(^{t}Bu)₃) (10 wt % hexane solution) and 59 mg (0.1 mmol) of bis(dibenzylideneacetone)palladium(0) (abbreviation: Pd(dba)₂), and stirring was performed at 120° C. for two hours. The following day, this reaction solution was heated to 80° C., and then, 0.5 mL (0.2 mmol) of P(^{t}Bu)₃ (10 wt % hexane solution) and 31 mg (54 μmol) of Pd(dba)₂ were added, followed by stirring at 120° C. for five hours. Toluene was added to this reaction solution, stirring was performed at 100° C., and the resulting mixed solution was subjected to suction filtration through Alumina, Celite (Catalog No. 537-02305, FUJIFILM Wako Pure Chemical Corporation), and Florisil (Catalog No. 066-05265, FUJIFILM Wako Pure Chemical Corporation). The resulting filtrate was concentrated to give 4.2 g of a pale yellow solid containing the target substance. This solid was purified by liquid chromatography to give 2.7 g of a white solid of the target substance in a yield of 68%. Synthesis Scheme (b-2) of <Step 2> is shown below.

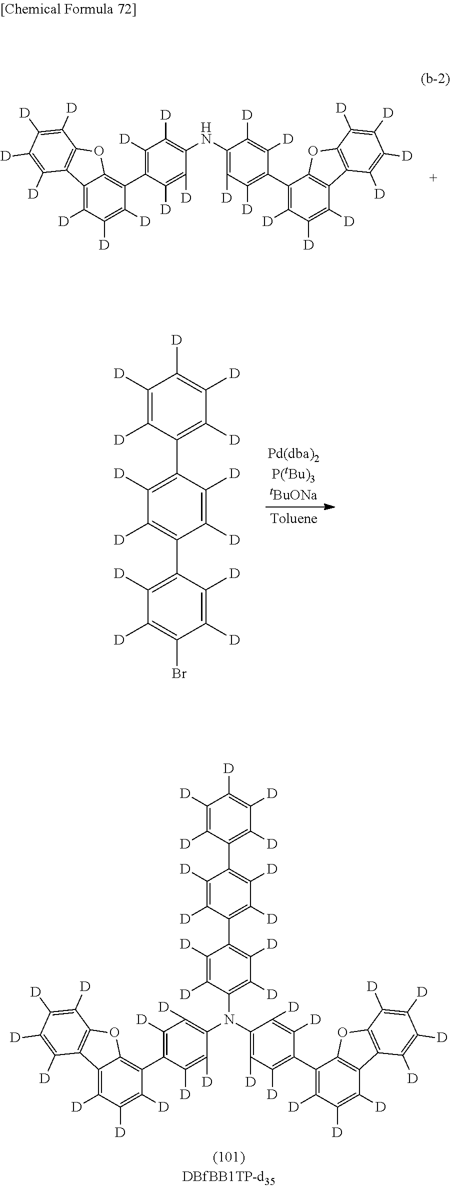

By a train sublimation method, 2.7 g of the obtained white solid was purified. In the purification by sublimation, the solid was heated at 345° C. under a pressure of 2.78 Pa for 24 hours. After the purification by sublimation, 2.3 g of a colorless solid of the target substance was obtained at a collection rate of 86%.

The molecular weight of the colorless solid obtained in Step 2 above was measured by LC/MS analysis, so that a signal was observed at m/z 764 while the mass of the target substance was calculated to be 764. The results revealed that DBfBB1TP-d35 was obtained.

### <Measurement of Physical Properties>

Next, the absorption spectrum and PL spectrum of a toluene solution and a solid thin film of DBfBB1TP-d35 were measured.

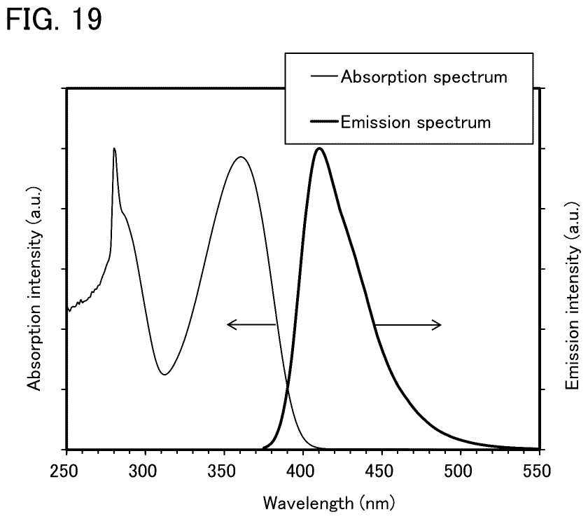

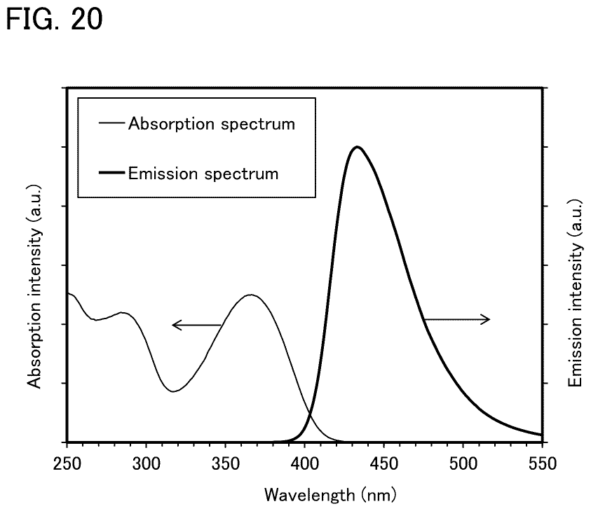

The absorption spectrum of the solution was measured with an ultraviolet-visible spectrophotometer (V-770DS, JASCO Corporation), and the absorption spectrum of the thin film was measured with an ultraviolet-visible spectrophotometer (U-4100, Hitachi). To calculate the absorption spectrum of the toluene solution of DBfBB1TP-d35, the absorption spectrum of toluene put in a quartz cell was measured and then subtracted from the absorption spectrum of the toluene solution of DBfBB1TP-d35 put in a quartz cell. The PL spectrum was measured with a fluorescence spectrophotometer (FP-8600DS, JASCO Corporation). FIG. 19 shows the measurement results of the absorption spectrum and the PL spectrum of the toluene solution of DBfBB1TP-d35, and FIG. 20 shows the measurement results of the absorption spectrum and the PL spectrum of the thin film of DBfBB1TP-d35.

As shown in FIG. 19, the absorption spectrum of the toluene solution of DBfBB1TP-d35 exhibited an absorption peak at around 361 nm. The results reveal that the solution of DBfBB1TP-d35 shows no absorption at wavelengths greater than or equal to 400 nm and that the material of the present invention can be suitably used for a light-emitting device. As shown in FIG. 19, the PL spectrum of the toluene solution of DBfBB1TP-d35 exhibited an emission peak at around 410 nm (excitation wavelength: 361 nm).

As shown in FIG. 20, the absorption spectrum of the thin film of DBfBB1TP-d35 exhibited an absorption peak at around 367 nm. The results reveal that the thin film of DBfBB1TP-d35 also shows no absorption at wavelengths greater than or equal to 440 nm and that the material of the present invention can be suitably used for a light-emitting device. As shown in FIG. 20, the PL spectrum of the thin film of DBfBB1TP-d35 exhibited an emission peak at around 433 nm (excitation wavelength: 368 nm).

The thermogravimetry-differential thermal analysis (TG-DTA) of DBfBB1TP-d35 was performed. For the measurement, a high-sensitivity differential type differential thermogravimeter (STA 2500 Regulus, NETZSCH Japan K. K.) was used. The measurement was performed under first conditions and second conditions. Under the first conditions, the measurement was performed at a temperature rising rate of 10° C./min under atmospheric pressure and a nitrogen stream (flow rate: 200 mL/min). Under the second conditions, the measurement was performed at a temperature rising rate of 10° C./min under 10 Pa.

The thermogravimetry-differential thermal analysis performed under the first measurement conditions reveals that the temperature at which the weight of DBfBB1TP-d35 obtained by thermogravimetry decreases by 5% of the weight at the start of the measurement (i.e., the sublimation or decomposition temperature of DBfBB1TP-d35) is higher than or equal to 500° C. under atmospheric pressure. The results show that the sublimation or decomposition temperature of DBfBB1TP-d35 under atmospheric pressure is higher than or equal to 500° C., which indicates high heat resistance.

The thermogravimetry-differential thermal analysis performed under the second measurement conditions reveals that the temperature at which the weight of DBfBB1TP-d35 obtained by thermogravimetry decreases by 5% of the weight at the start of the measurement (i.e., the sublimation or decomposition temperature of DBfBB1TP-d35) is 294° C. under 10 Pa. The results show that the sublimation temperature of DBfBB1TP-d35 under 10 Pa is 294° C.

The above results show that the sublimation temperature (294° C.) of DBfBB1TP-d35 under 10 Pa is lower than the sublimation or decomposition temperature (higher than or equal to 500° C.) thereof under atmospheric pressure by greater than or equal to 206° C. This indicates that DBfBB1TP-d35 can be deposited by evaporation at a temperature sufficiently lower than the sublimation or decomposition temperature under atmospheric pressure. It is thus suggested that the organic compound of one embodiment of the present invention is a material that is less likely to be decomposed during deposition by evaporation and can be formed into a high-purity film by being deposited by evaporation. It can be said that deposition by evaporation at a sufficiently low temperature is possible when the sublimation temperature under 10 Pa is lower than the sublimation temperature under atmospheric pressure by greater than or equal to 170° C., preferably by greater than or equal to 200° C.

Differential scanning calorimetry (DSC) measurement of DBfBB1TP-d35 was performed with DSC8500 manufactured by PerkinElmer, Inc. The DSC measurement was performed in the following manner. The temperature was raised from −10° C. to 400° C. at a temperature rising rate of 40° C./min and held for three minutes; then, the temperature was lowered to −10° C. at a temperature falling rate of 100° C./min and held for three minutes. This operation was performed twice in succession. Subsequently, the temperature was raised from −10° C. to 400° C. at a temperature rising rate of 50° C./min and held for three minutes; then, the temperature was lowered to −10° C. at a temperature falling rate of 100° C./min. This operation was performed once.

According to the results of the DSC measurement in the second temperature raising process, the Tg of DBfBB1TP-d35 is 129° C., and the melting point and the crystallization temperature are not observed. It was found that an organic semiconductor element such as a light-emitting device can have increased heat resistance by including the organic compound of one embodiment of the present invention. Since the melting point and the crystallization temperature were not observed, it was suggested that DBfBB1TP-d35 of the present invention can be formed into a thin film having high heat resistance and stable quality and can be suitably used for an organic semiconductor element. The Tg of an organic compound that can be suitably used for an organic semiconductor element is preferably higher than or equal to 100° C., further preferably higher than or equal to 110° C., still further preferably higher than or equal to 120° C.

The HOMO level and the LUMO level of DBfBB1TP-d35 were calculated through cyclic voltammetry (CV) measurement. The calculation method is similar to that described in Example 1.

As a result, in the measurement of the oxidation potential Ea [V] of DBfBB1TP-d35, the HOMO level was found to be −5.48 eV. In contrast, the LUMO level was found to be −2.30 eV in the measurement of the reduction potential Ec [V]. When the oxidation-reduction wave was repeatedly measured, in the Ea measurement, the peak intensity of the oxidation-reduction wave after the 100th cycle was maintained to be 92% of that of the oxidation-reduction wave at the first cycle, and in the Ec measurement, the peak intensity of the oxidation-reduction wave after the 100th cycle was maintained to be 95% of that of the oxidation-reduction wave at the first cycle; thus, the resistance of DBfBB1TP-d35 to repetitive oxidation and repetitive reduction was found to be extremely high.

The lowest triplet excitation energy level (T₁ level) of DBfBB1TP-d35 was calculated through the measurement of a PL spectrum (phosphorescence spectrum). The calculation method is similar to that described in Example 1.

As a result, it was found that the lowest triplet excitation energy level (T₁ level) of DBfBB1TP-d35 is 2.38 eV.

### Example 4

In this example, Light-Emitting Device 1A of one embodiment of the present invention and Comparative Light-Emitting Device 1B were fabricated.

Specifically, N,N′-bis(4-biphenyl-2,2′,3,3′,4′,5,5′,6,6′-d₉)-6-(phenyl-2,3,4,5,6-d₅)benzo[b]naphtho[1,2-d]furan(1,2,3,4,5,9,10,11-d₈)-8-amine (abbreviation: BBABnf-d31) represented by Structural Formula (100) in Embodiment 2 was used for a hole-transport layer of Light-Emitting Device 1A.

Meanwhile, N,N′-bis(4-biphenyl)-6-phenylbenzo[b]naphtho[1,2-d]furan-8-amine (abbreviation: BBABnf) was used for a hole-transport layer of Comparative Light-Emitting Device 1B.

The structural formulae of organic compounds used in Light-Emitting Device 1A and Comparative Light-Emitting Device 1B are shown below.

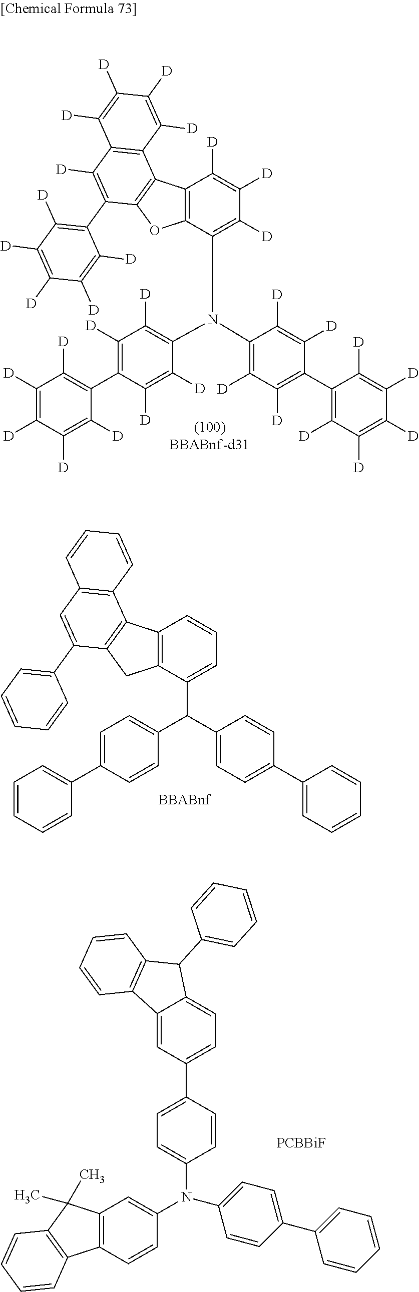

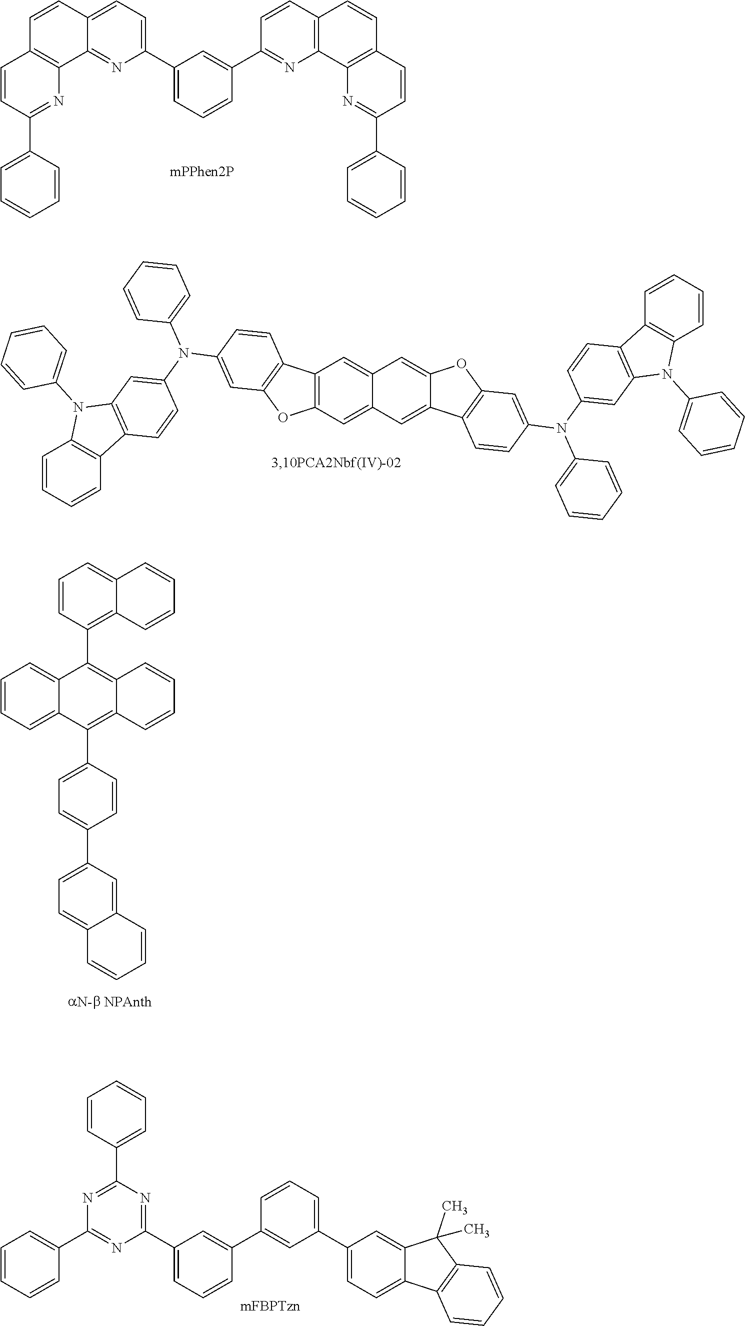

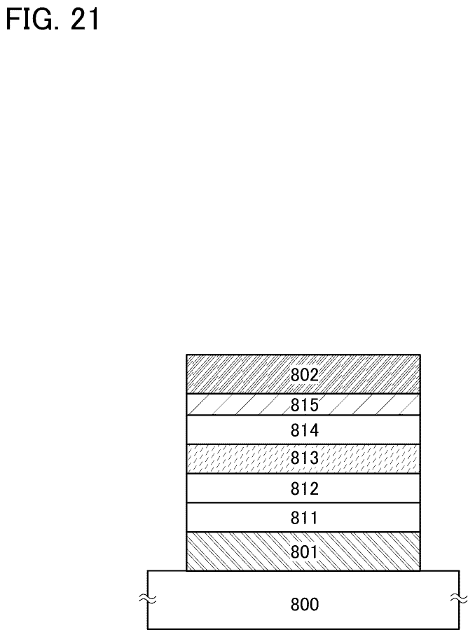

In each of the devices, as illustrated in FIG. 21, a hole-injection layer 811, a hole-transport layer 812, a light-emitting layer 813, an electron-transport layer 814, and an electron-injection layer 815 are stacked in this order over a first electrode 801 formed over a glass substrate 800, and a second electrode 802 is stacked over the electron-injection layer 815.

### <Method for Fabricating Light-Emitting Device 1A>

As the first electrode 801, a film of indium tin oxide containing silicon oxide (ITSO) was formed to a thickness of 110 nm over the glass substrate 800 by a sputtering method. The electrode area was set to 4 mm² (2 mm×2 mm).

Next, in pretreatment for forming the light-emitting device over the substrate, a surface of the substrate was washed with water, and baking was performed at 200° C. for one hour. Then, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus. After that, natural cooling was performed for 45 minutes.

Next, the substrate provided with the first electrode 801 was fixed to a substrate holder provided in the vacuum evaporation apparatus such that the surface on which the first electrode 801 was formed faced downward. Over the first electrode 801, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material containing fluorine and having a molecular weight of 672 (OCHD-003) were deposited by co-evaporation to a thickness of 10 nm such that the weight ratio of PCBBiF to OCHD-003 was 1:0.03, whereby the hole-injection layer 811 was formed.

Subsequently, over the hole-injection layer 811, PCBBiF was deposited by evaporation using resistance heating to a thickness of 90 nm, and then, N,N′-bis(4-biphenyl-2,2′,3,3′,4′,5,5′,6,6′-d₉)-6-(phenyl-2,3,4,5,6-d₅)benzo[b]naphtho[1,2-d]furan(1,2,3,4,5,9,10,11-d₈)-8-amine (abbreviation: BBABnf-d31) represented by Structural Formula (100) was deposited by evaporation using resistance heating to a thickness of 10 nm, so that the hole-transport layer 812 was formed.

Next, over the hole-transport layer 812, 9-(1-naphthyl)-10-[4-(2-naphthyl)phenyl]anthracene (abbreviation: αN-βNPAnth) and N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02) were deposited by co-evaporation using resistance heating to a thickness of 25 nm such that the weight ratio of αN-βNPAnth to 3,10PCA2Nbf(IV)-02 was 1:0.015, whereby the light-emitting layer 813 was formed. The HOMO level, the LUMO level, and the T₁ level of αN-βNPAnth were −5.85 eV, −2.74 eV, and 1.75 eV, respectively. These measurement values were obtained by a method similar to that described in this specification. Note that the T₁ level was measured with Ir(ppy)₃ mixed as a sensitizer.

Next, over the light-emitting layer 813, 2-[3′-(9,9-dimethyl-9H-fluoren-2-yl)biphenyl-3-yl]-4,6-diphenyl-1,3,5-triazine (abbreviation: mFBPTzn) was deposited by evaporation to a thickness of 10 nm, and then 2,2′-(1,3-phenylene)bis(9-phenyl-1,10-phenanthroline) (abbreviation: mPPhen2P) was deposited by evaporation to a thickness of 15 nm, so that the electron-transport layer 814 was formed. The HOMO level, the LUMO level, and the T₁ level of mFBPTzn were −6.11 eV, −2.95 eV, and 2.54 eV, respectively. These measurement values were obtained by a method similar to that described in this specification.

Next, lithium fluoride (LiF) was deposited by evaporation to a thickness of 1 nm over the electron-transport layer 814, so that the electron-injection layer 815 was formed.

Then, aluminum (Al) was deposited by evaporation to a thickness of 120 nm over the electron-injection layer 815, so that the second electrode 802 was formed.

### <Method for Fabricating Comparative Light-Emitting Device 1B>

Next, a method for fabricating Comparative Light-Emitting Device 1B is described. Comparative Light-Emitting Device 1B is different from Light-Emitting Device 1A in the structure of the hole-transport layer 812.

In Comparative Light-Emitting Device 1B, the hole-transport layer 812 was formed in the following manner: over the hole-injection layer 811, PCBBiF was deposited by evaporation using resistance heating to a thickness of 90 nm, and then, N,N′-bis(4-biphenyl)-6-phenylbenzo[b]naphtho[1,2-d]furan-8-amine (abbreviation: BBABnf) was deposited by evaporation using resistance heating to a thickness of 10 nm.

The other components were formed in a manner similar to that for Light-Emitting Device 1A.

The structures of Light-Emitting Device 1A and Comparative Light-Emitting Device 1B are listed in the following table.

TABLE 1

| | | | Comparative |
|---|---|---|---|
| | | Light- | Light- |
| | Thickness | Emitting | Emitting |
| | [nm] | Device 1A | Device 1B |
| Second electrode | 120 | Al | |
| Electron- | 1 | LiF | |
| injection layer | | | |
| Electron- | 15 | mPPhen2P | |
| transport layer | 10 | mFBPTzn | |
| Light-emitting | 25 | αN-βNPAnth:3,10PCA2Nbf(IV)- | |
| layer | | 02 (1:0.015) | |
| Hole-transport | 10 | BBABnf-d31 | BBABnf |

| | | |
|---|---|---|
| layer | 90 | PCBBiF |
| Hole-injection | 10 | PCBBiF:OCHD-003 (1:0.03) |
| layer | | |
| First electrode | 110 | ITSO |

### <Light-Emitting Device Characteristics>

The light-emitting devices were sealed using a glass substrate in a glove box containing a nitrogen atmosphere so as not to be exposed to the air (a sealing material was applied to surround the devices, and UV treatment and heat treatment at 80° C. for one hour were performed at the time of sealing). Then, the characteristics of the light-emitting devices were measured.

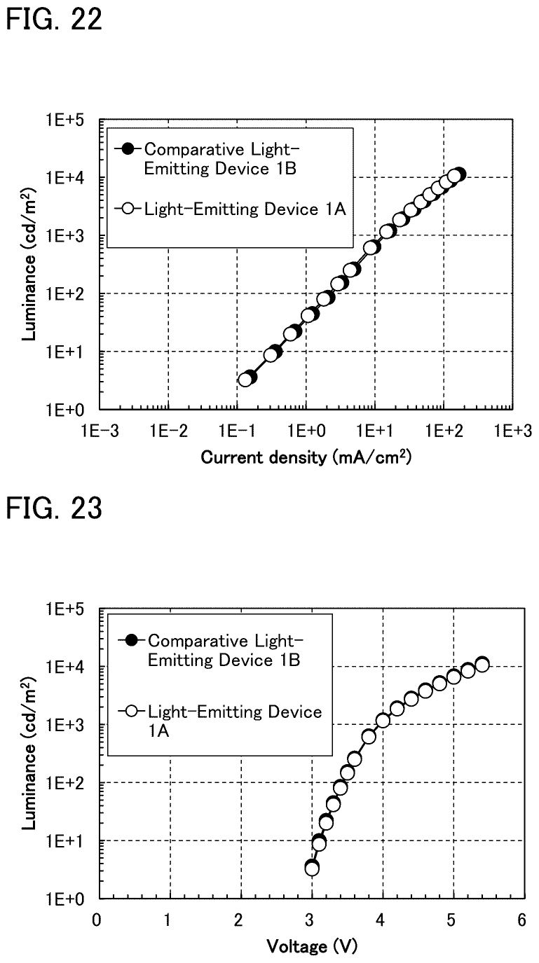

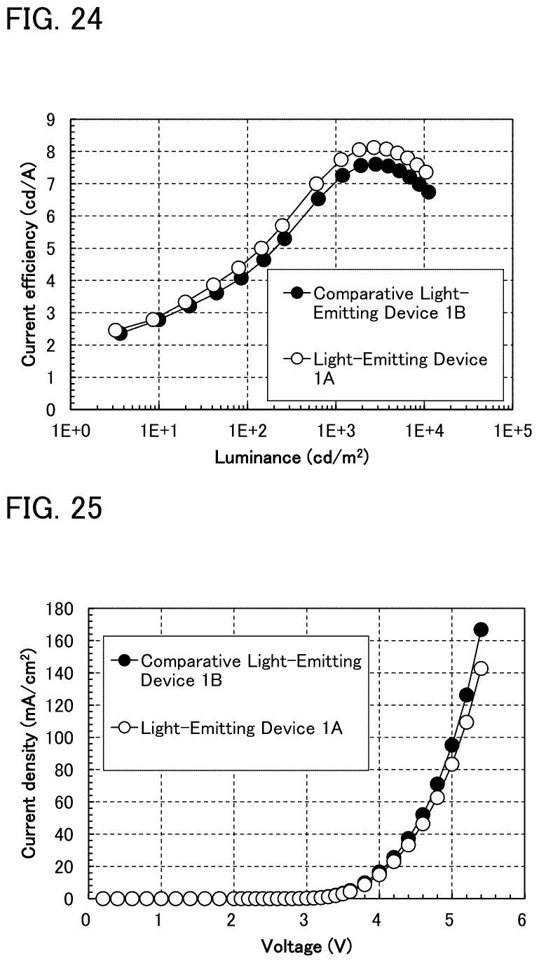

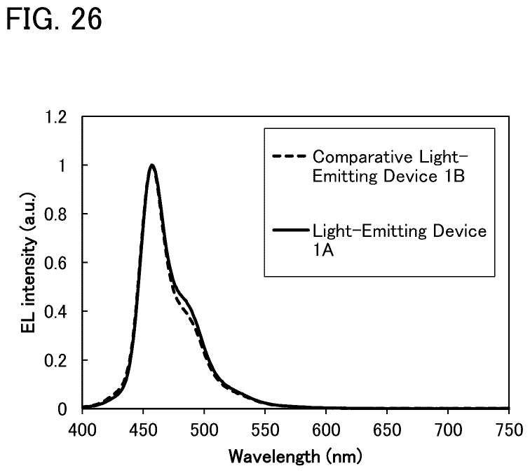

FIG. 22 shows the luminance-current density characteristics of the light-emitting devices. FIG. 23 shows the luminance-voltage characteristics of the light-emitting devices. FIG. 24 shows the current efficiency-luminance characteristics of the light-emitting devices. FIG. 25 shows the current density-voltage characteristics of the light-emitting devices. FIG. 26 shows the electroluminescence spectra of the light-emitting devices.

The main characteristics of the devices at a luminance of approximately 1000 cd/m² are shown in the table below. The luminance, CIE chromaticity, and electroluminescence spectra were measured with a spectroradiometer (SR-UL1R, TOPCON TECHNOHOUSE CORPORATION).

TABLE 2

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Light-Emitting | 4.00 | 0.592 | 14.8 | 0.138 | 0.103 | 1147 | 7.75 |
| Device 1A | | | | | | | |
| Comparative | 4.00 | 0.660 | 16.5 | 0.139 | 0.0970 | 1197 | 7.26 |
| Light-Emitting | | | | | | | |
| Device 1B | | | | | | | |

FIG. 22 to FIG. 26 show that Light-Emitting Device 1A has efficiency as high as that of Comparative Light-Emitting Device 1B. It was thus confirmed that BBABnf-d31, which is a deuterium-containing organic compound, can be suitably used for a light-emitting device.

### <Results of Reliability Test>

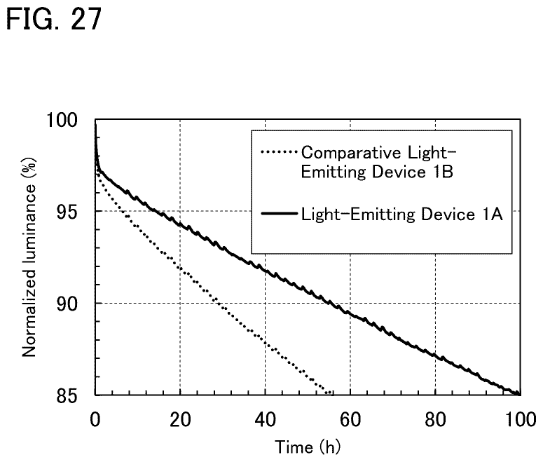

A reliability test was conducted on Light-Emitting Device 1A. FIG. 27 shows a time-dependent change in normalized luminance at the time of constant current density driving (50 [mA/cm²]). In FIG. 27, the vertical axis represents the luminance (%) normalized with the luminance at the time of the start of light emission being regarded as 100%, and the horizontal axis represents time (h).

As shown in FIG. 27, the LT90 (h), which is the time that has elapsed until the measured luminance decreases to 90% of the initial luminance, of Light-Emitting Device 1A was 55 hours. Meanwhile, the LT90 of Comparative Light-Emitting Device 1B was 29 hours. Thus, it was found that the lifetime of Light-Emitting Device 1A including the deuterated organic compound is longer than that of Comparative Light-Emitting Device 1B. This is probably because BBABnf-d31, which was obtained by deuteration of BBABnf, achieved higher stability in an excited state or a state of holding carriers and resultantly higher stability or resistance to inhibit luminance degradation due to driving of the light-emitting device.

Thus, it was confirmed that by including the deuterium-containing organic compound of one embodiment of the present invention, a light-emitting device can have emission efficiency as high as that of a comparative light-emitting device and reliability higher than that of the comparative light-emitting device.

### <HOMO Level and LUMO Level of Material Used in Light-Emitting Layer>

Here, the HOMO level and the LUMO level of 3,10PCA2Nbf(IV)-02, which was used as the guest material in the light-emitting layers of Light-Emitting Device 1A and Comparative Light-Emitting Device 1B fabricated in this example, αN-βNPAnth, which was used as the host material in the light-emitting layers thereof, and mFBPTzn, which was used for the electron-transport layers thereof, were calculated through cyclic voltammetry (CV) measurement. The calculation method is similar to that described in Example 1.

The calculation results of the HOMO levels and the LUMO levels of 3,10PCA2Nbf(IV)-02, αN-βNPAnth, and mFBPTzn are listed in the table below.

TABLE 3

| | HOMO level | LUMO level |
|---|---|---|
| | [eV] | [eV] |
| 3,10PCA2Nbf(IV)-02 | −5.41 | −2.66 |
| αN-βNPAnth | −5.85 | −2.74 |
| mFBPTzn | −6.11 | −2.95 |

According to the above table, in each of the light-emitting devices of this example, the HOMO level of the guest material in the light-emitting layer is higher than the HOMO level of the host material therein, with the difference therebetween being 0.44 eV; this structure causes hole trapping. The LUMO level of the host material in the light-emitting layer is close to the LUMO level of the material used for the electron-transport layer in contact with the light-emitting layer, with the difference therebetween being 0.21 eV; thus, it can be said that the property of injecting electrons from the electron-transport layer into the light-emitting layer is high in this structure.

That is, using the deuterium compound for the hole-transport layer in contact with the light-emitting layer in the light-emitting device having such a structure presumably enabled the light-emitting device to have high emission efficiency and inhibited luminance degradation due to driving of the light-emitting device.

### Example 5

In this example, Light-Emitting Device 2A of one embodiment of the present invention and Comparative Light-Emitting Device 2B were fabricated.

Specifically, N,N′-bis{4-[(dibenzofuran-1,2,3,6,7,8,9-d₇)-4-yl]phenyl-2,3,5,6-d₄}-p-terphenyl-2,2′,2″,3,3′,3″,4″,5,5′,5″,6,6′,6″-d₃-4-amine (abbreviation: DBfBB1TP-d35) represented by Structural Formula (101) in Embodiment 2 was used for a hole-transport layer of Light-Emitting Device 2A.

Meanwhile, N,N′-bis[4-(dibenzofuran-4-yl)phenyl]-4-amino-p-terphenyl (abbreviation: DBfBB1TP) was used for a hole-transport layer of Comparative Light-Emitting Device 2B.

The structural formulae of organic compounds used in Light-Emitting Device 2A and Comparative Light-Emitting Device 2B are shown below.

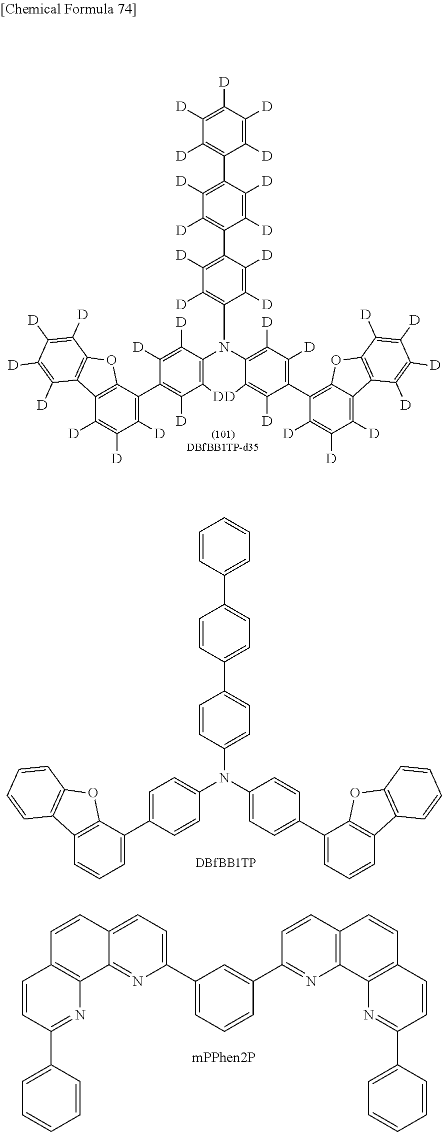 [SMILES: [2H]c1c([2H])c([2H])c(-c2c([2H])c([2H])c(-c3c([2H])c([2H])c(N(c4c([2H])c([2H])c(-c5c([2H])c([2H])c([2H])c6c5oc5c([2H])c([2H])c([2H])c([2H])c56)c([2H])c4[2H])c4c([2H])c([2H])c(-c5c([2H])c([2H])c([2H])c6c5oc5c([2H])c([2H])c([2H])c([2H])c56)c([2H])c4[2H])c([2H])c3[2H])c([2H])c2[2H])c([2H])c1[2H] ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc3ccc4ccc(-c5cccc(-c6ccc7ccc8ccc(-c9ccccc9)nc8c7n6)c5)nc4c3n2)cc1]

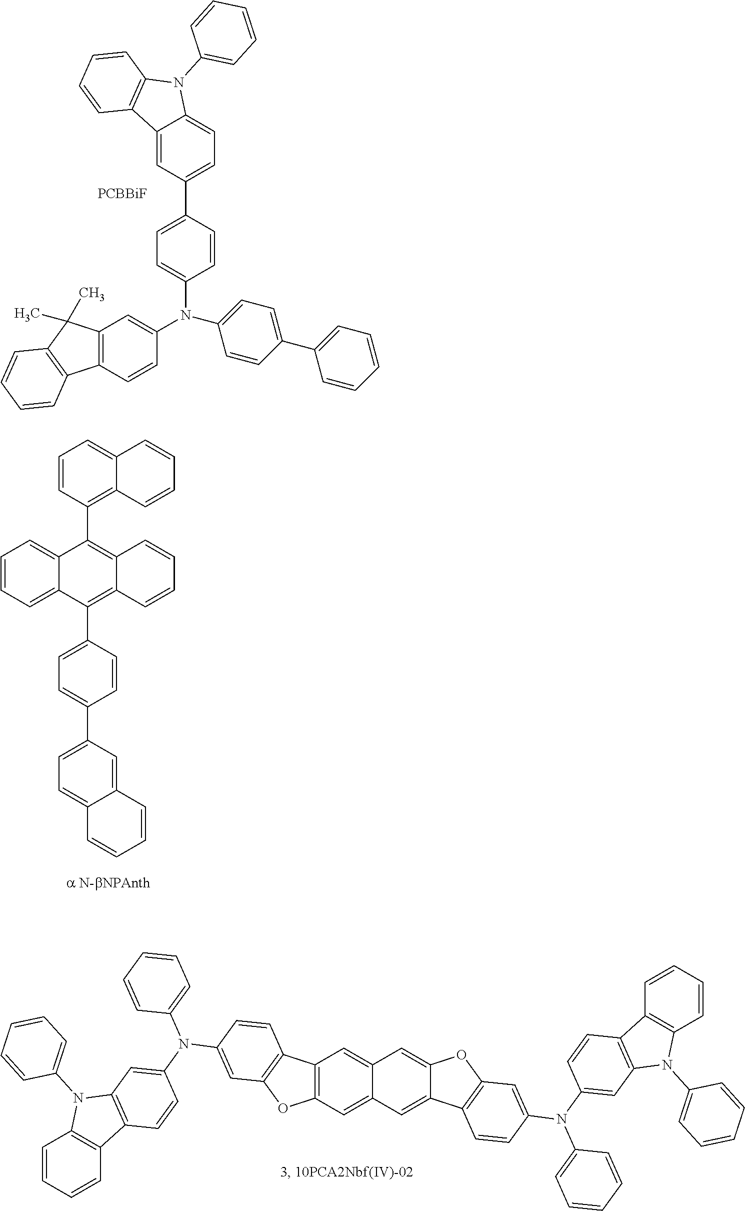

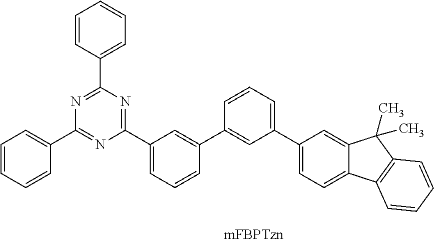 [SMILES: CC1(C)c2ccccc2-c2ccc(-c3cccc(-c4cccc(-c5nc(-c6ccccc6)nc(-c6ccccc6)n5)c4)c3)cc21]

In each of the devices, as illustrated in FIG. 21, the hole-injection layer 811, the hole-transport layer 812, the light-emitting layer 813, the electron-transport layer 814, and the electron-injection layer 815 are stacked in this order over the first electrode 801 formed over the glass substrate 800, and the second electrode 802 is stacked over the electron-injection layer 815.

### <Method for Fabricating Light-Emitting Device 2A>

As the first electrode 801, a film of indium tin oxide containing silicon oxide (ITSO) was formed to a thickness of 110 nm over the glass substrate 800 by a sputtering method. The electrode area was set to 4 mm² (2 mm×2 mm).

Next, in pretreatment for forming the light-emitting device over the substrate, a surface of the substrate was washed with water, and baking was performed at 200° C. for one hour. Then, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus, followed by natural cooling down to lower than or equal to 30° C.

Next, the substrate provided with the first electrode 801 was fixed to a substrate holder provided in the vacuum evaporation apparatus such that the surface on which the first electrode 801 was formed faced downward. Over the first electrode 801, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material containing fluorine and having a molecular weight of 672 (OCHD-003) were deposited by co-evaporation to a thickness of 10 nm such that the weight ratio of PCBBiF to OCHD-003 was 1:0.03, whereby the hole-injection layer 811 was formed.

Subsequently, over the hole-injection layer 811, PCBBiF was deposited by evaporation using resistance heating to a thickness of 90 nm, and then, N,N′-bis{4-[(dibenzofuran-1,2,3,6,7,8,9-d7)-4-yl]phenyl-2,3,5,6-d₄}-p-terphenyl-2,2′,2″,3,3′,3″,4″,5,5′,5″,6,6′,6″-d₃-4-amine (abbreviation: DBfBB1TP-d35) represented by Structural Formula (101) was deposited by evaporation using resistance heating to a thickness of 10 nm, so that the hole-transport layer 812 was formed.

Next, over the hole-transport layer 812, 9-(1-naphthyl)-10-[4-(2-naphthyl)phenyl]anthracene (abbreviation: αN-βNPAnth) and N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02) were deposited by co-evaporation using resistance heating to a thickness of 25 nm such that the weight ratio of αN-βNPAnth to 3,10PCA2Nbf(IV)-02 was 1:0.015, whereby the light-emitting layer 813 was formed.

Next, over the light-emitting layer 813, 2-[3′-(9,9-dimethyl-9H-fluoren-2-yl)biphenyl-3-yl]-4,6-diphenyl-1,3,5-triazine (abbreviation: mFBPTzn) was deposited by evaporation to a thickness of 10 nm, and then 2,2′-(1,3-phenylene)bis(9-phenyl-1,10-phenanthroline) (abbreviation: mPPhen2P) was deposited by evaporation to a thickness of 15 nm, so that the electron-transport layer 814 was formed.

Next, lithium fluoride (LiF) was deposited by evaporation to a thickness of 1 nm over the electron-transport layer 814, so that the electron-injection layer 815 was formed.

Then, aluminum (Al) was deposited by evaporation to a thickness of 120 nm over the electron-injection layer 815, so that the second electrode 802 was formed.

### <Method for Fabricating Comparative Light-Emitting Device 2B>

Next, a method for fabricating Comparative Light-Emitting Device 2B is described. Comparative Light-Emitting Device 2B is different from Light-Emitting Device 2A in the structure of the hole-transport layer 812.

In Comparative Light-Emitting Device 2B, the hole-transport layer 812 was formed in the following manner: over the hole-injection layer 811, PCBBiF was deposited by evaporation using resistance heating to a thickness of 90 nm, and then, N,N′-bis[4-(dibenzofuran-4-yl)phenyl]-4-amino-p-terphenyl (abbreviation: DBfBB1TP) was deposited by evaporation using resistance heating to a thickness of 10 nm.

The other components were formed in a manner similar to that for Light-Emitting Device 2A.

The structures of Light-Emitting Device 2A and Comparative Light-Emitting Device 2B are listed in the following table.

TABLE 4

| | | | Comparative |
|---|---|---|---|
| | | Light- | Light- |
| | Thickness | Emitting | Emitting |
| | [nm] | Device 2A | Device 2B |
| Second electrode | 120 | Al | |
| Electron- | 1 | LiF | |
| injection layer | | | |
| Electron- | 15 | mPPhen2P | |
| transport layer | 10 | mFBPTzn | |
| Light-emitting | 25 | αN-βNPAnth:3,10PCA2Nbf(IV)- | |
| layer | | 02 (1:0.015) | |
| Hole-transport | 10 | DBfBB1TP-d35 | DBfBB1TP |

| | | |
|---|---|---|
| layer | 90 | PCBBiF |
| Hole-injection | 10 | PCBBiF:OCHD-003 (1:0.03) |
| layer | | |
| First electrode | 110 | ITSO |

### <Light-Emitting Device Characteristics>

The light-emitting devices were sealed using a glass substrate in a glove box containing a nitrogen atmosphere so as not to be exposed to the air (a sealing material was applied to surround the devices, and UV treatment and heat treatment at 80° C. for one hour were performed at the time of sealing). Then, the characteristics of the light-emitting devices were measured.

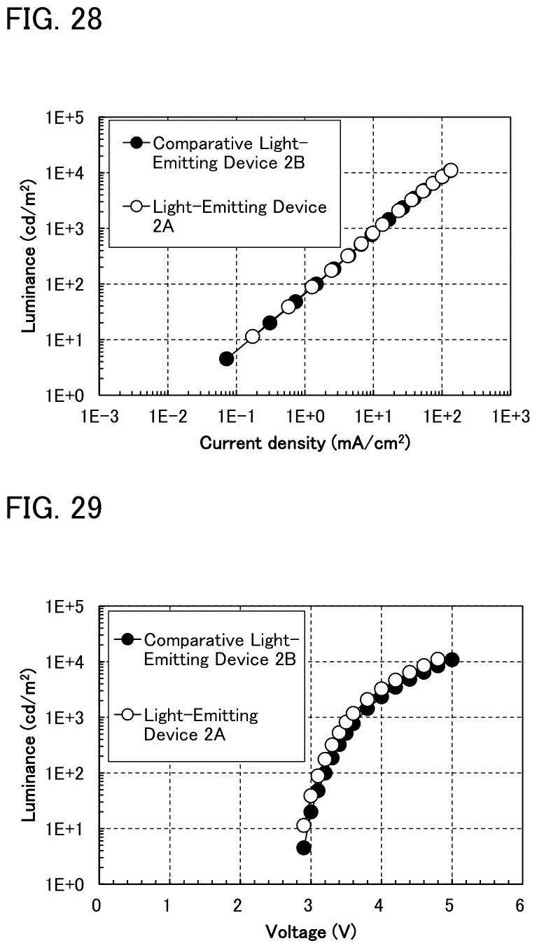

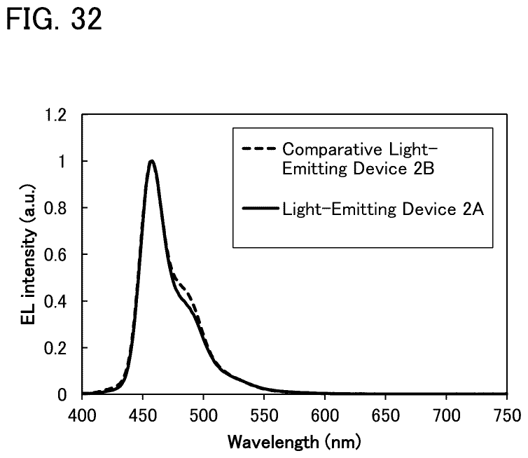

FIG. 28 shows the luminance-current density characteristics of the light-emitting devices. FIG. 29 shows the luminance-voltage characteristics of the light-emitting devices. FIG. shows the current efficiency-luminance characteristics of the light-emitting devices. FIG. 31 shows the current density-voltage characteristics of the light-emitting devices. FIG. 32 shows the electroluminescence spectra of the light-emitting devices.

The main characteristics of the devices at a luminance of approximately 1000 cd/m² are shown in the table below. The luminance, CIE chromaticity, and electroluminescence spectra were measured with a spectroradiometer (SR-UL1R, TOPCON TECHNOHOUSE CORPORATION).

TABLE 5

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Light-Emitting | 3.60 | 0.545 | 13.6 | 0.138 | 0.104 | 1171 | 8.60 |
| Device 2A | | | | | | | |
| Comparative Light- | 3.60 | 0.379 | 9.48 | 0.137 | 0.104 | 767 | 8.10 |
| Emitting Device 2B | | | | | | | |

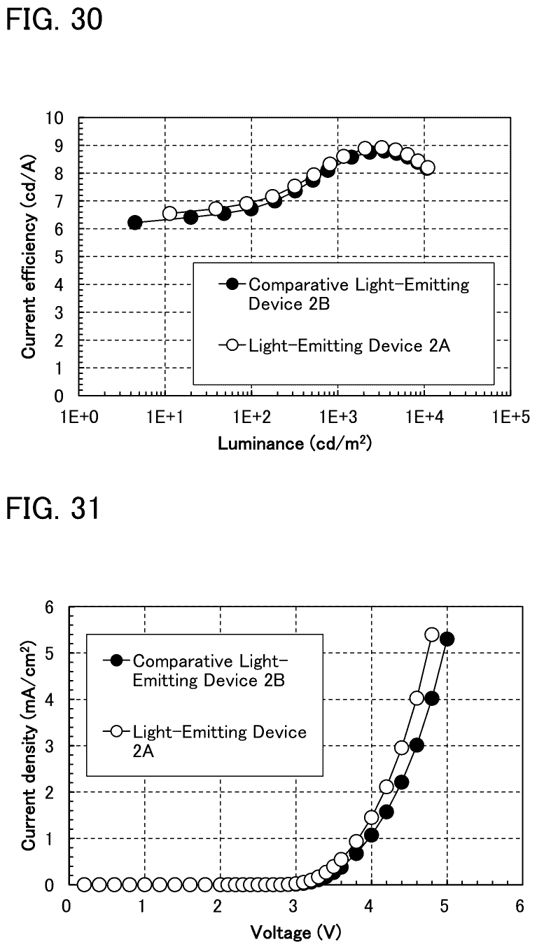

FIG. 28 to FIG. 32 show that Light-Emitting Device 2A has efficiency as high as that of Comparative Light-Emitting Device 2B. It was thus confirmed that DBfBB1TP-d35, which is a deuterium-containing organic compound, can be suitably used for a light-emitting device.

### <Results of Reliability Test>

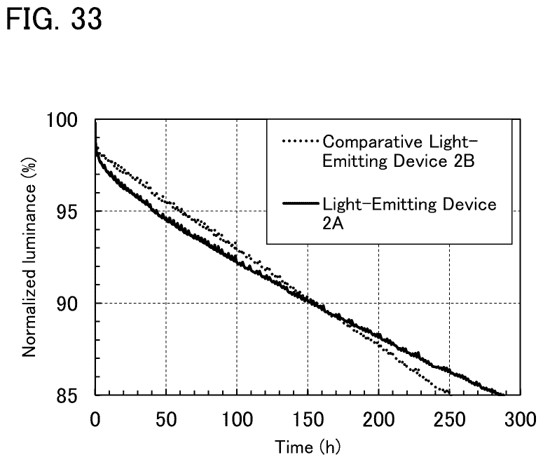

A reliability test was conducted on Light-Emitting Device 2A. FIG. 33 shows a time-dependent change in normalized luminance at the time of constant current density driving (50 [mA/cm²]). In FIG. 33, the vertical axis represents the luminance (%) normalized with the luminance at the time of the start of light emission being regarded as 100%, and the horizontal axis represents time (h).

As shown in FIG. 33, the LT90 (h), which is the time that has elapsed until the measured luminance decreases to 90% of the initial luminance, of Light-Emitting Device 2A was 154 hours. The LT90 of Comparative Light-Emitting Device 2B was 156 hours. However, it was found that the slope of the luminance degradation of Light-Emitting Device 2A was gentle and that the luminance of Light-Emitting Device 2A decreased more slowly than that of Comparative Light-Emitting Device 2B after approximately 160 hours elapsed. This is probably because DBfBB1TP-d35, which was obtained by deuteration of DBfBB1TP, achieved higher stability in an excited state or a state of holding carriers and resultantly higher stability or resistance to inhibit luminance degradation due to driving of the light-emitting device.

Thus, it was confirmed that by including the deuterium-containing organic compound of one embodiment of the present invention, a light-emitting device can have emission efficiency as high as that of a comparative light-emitting device and reliability higher than that of the comparative light-emitting device.

### <HOMO Level and LUMO Level of Material Used in Light-Emitting Layer>

In each of Light-Emitting Device 2A and Comparative Light-Emitting Device 2B fabricated in this example, the structures of the light-emitting layer and the electron-transport layer are similar to those of the light-emitting layer and the electron-transport layer in each of Light-Emitting Device 1A and Comparative Light-Emitting Device 1B in Example 4. Thus, as in Light-Emitting Device 1A and Comparative Light-Emitting Device 1B, hole trapping is caused, and the property of injecting electrons from the electron-transport layer into the light-emitting layer is extremely high.

That is, using the deuterium compound for the hole-transport layer in contact with the light-emitting layer in the light-emitting device having this structure presumably inhibited luminance degradation due to driving of the light-emitting device.

### Example 6

### Synthesis Example 4

In this example, a method for synthesizing N-[4-(1-naphthyl-2,3,4,5,6,7,8-d₇)phenyl-2,3,5,6-d₄]-N-[(9,9′-spirobi[9H-fluoren]-1,3,4,5,6,7,8,1′,2′,3′,4′,5′,6′,7′,8′-d₁₅)-2-yl](benzo[b]naphtho[2,1-d]furan-1,2,3,4,5,6,7,8,9-d₉)-10-amine (abbreviation: SFNBaBnf(10)-d35), which is the organic compound of the present invention represented by Structural Formula (152) in Embodiment 2, will be described. The structure of SFNBaBnf(10)-d35 is shown below.

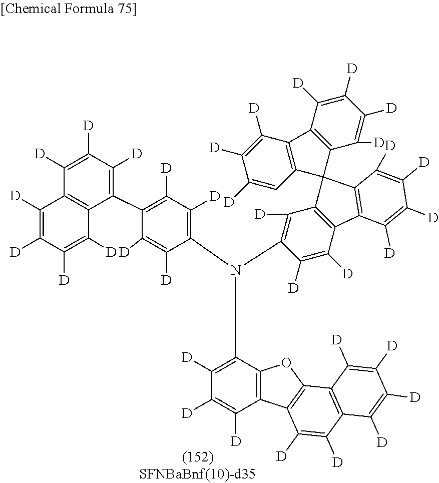 [SMILES: [2H]c1cc2c(c([2H])c1[2H])-c1c([2H])c([2H])c([2H])c([2H])c1C21c2c([2H])c([2H])c([2H])c([2H])c2-c2c([2H])c([2H])c(N(c3c([2H])c([2H])c(-c4c([2H])c([2H])c([2H])c5c([2H])c([2H])c([2H])c([2H])c45)c([2H])c3[2H])c3c([2H])c([2H])c([2H])c4c3oc3c5c([2H])c([2H])c([2H])c([2H])c5c([2H])c([2H])c34)c([2H])c21]

### Step 1-1: Synthesis of N-[4-(1-naphthyl-2,3,4,5,6,7,8-d₇)phenyl-2,3,5,6-d₄]-(9,9′-spirobi[9H-fluoren]-1,3,4,5,6,7,8,1′,2′,3′,4′,5′,6′,7′,8′-d₁₅)-2-amine

Into a 200-mL conical flask were put 11.5 g (21.5 mmol) of N-[4-(1-naphthyl)phenyl]-9,9′-spirobi[9H-fluoren]-2-amine and 55 mL of toluene-d₈. This mixture was stirred at 70° C. under a nitrogen stream. To this solution, 5.0 mL (57 mmol) of trifluoromethanesulfonic acid (abbreviation: TfOH) was added, and the mixture was stirred at 100° C. for three hours. After the reaction solution was cooled down to room temperature, water was slowly added to the reaction solution, and the resulting mixture was transferred to a separating funnel and subjected to extraction with toluene. The obtained organic phase was washed twice with an aqueous solution of sodium hydroxide. Magnesium sulfate was added to the organic phase to perform dehydration, and after a predetermined time elapsed, gravity filtration was performed using pleated filter paper. The resulting filtrate was concentrated to give 12.1 g of a green solid. Ethyl acetate and toluene were added to this solid to give a suspension. The suspension was heated with a heat gun, then cooled down to room temperature, and subjected to suction filtration, so that 7.20 g of a pale greenish white solid of the target substance was obtained in a yield of 60%. Synthesis Scheme (c-1) of Step 1 is shown below.

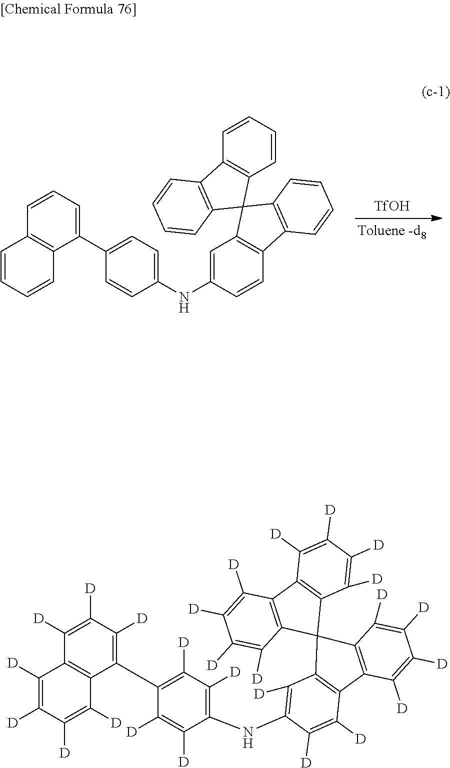

The molecular weight of the pale greenish white solid obtained in Step 1 above was measured by LC/MS, so that a signal was observed at m/z 559 while the mass of the target substance was calculated to be 559. The results revealed that N-[4-(1-naphthyl-2,3,4,5,6,7,8-d₇)phenyl-2,3,5,6-d₄]-(9,9′-spirobi[9H-fluoren]-1,3,4,5,6,7,8,1′,2′,3′,4′,5′,6′,7′,8′-d₅)-2-amine was obtained.

### Step 2: Synthesis of 10-bromobenzo[b]naphtho[2,1-d]furan-1,2,3,4,5,6,7,8,9-d9

Into a 200-mL three-neck flask were put 8.1 g (27 mmol) of 10-bromobenzo[b]naphtho[2,1-d]furan and 21 mL of toluene-d₈. This mixture was heated at 70° C. under a nitrogen stream, and it was verified that 10-bromobenzo[b]naphtho[2,1-d]furan was dissolved by this heating. To this solution was slowly added 7.2 g (26 mmol) of molybdenum chloride (MoCl₅), and the mixture was stirred at 70° C. for three minutes. After the reaction solution was cooled down to room temperature, water was added to the reaction solution, and the resulting mixture was transferred to a separating funnel and subjected to extraction with chloroform. The organic phase was washed twice with pure water and then washed twice with a saturated aqueous solution of sodium hydrogen carbonate. Magnesium sulfate was added to the resulting organic phase to perform dehydration, and after a predetermined time elapsed, gravity filtration was performed using pleated filter paper. The resulting filtrate was concentrated to give 8.7 g of a viscous brown oil. A small amount of toluene was added to the oil to cause dissolution, and then, purification was performed by silica gel column chromatography (as the developing solvent, hexane and toluene in a ratio of 20:1 were used) to give 5.6 g of a pale yellow solid of the target substance in a yield of 68%. Synthesis Scheme (c-2) of Step 2 is shown below.

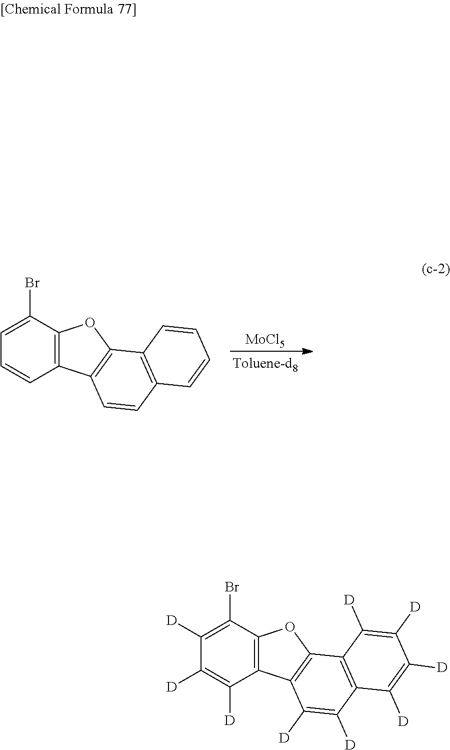

The molecular weight of the pale yellow solid obtained in Step 2 above was measured by LC/MS analysis. As a result, a signal was observed at m/z 305 while the mass of the target substance was calculated to be 305, revealing that 10-bromobenzo[b]naphtho[2,1-d]furan-1,2,3,4,5,6,7,8,9-d₉ was obtained.

### Step 3: Synthesis of SFNBaBnf(10)-d35

Into a 200-mL three-neck flask were put 3.6 g (6.4 mmol) of N-[4-(1-naphthyl-2,3,4,5,6,7,8-d₇)phenyl-2,3,5,6-d₄]-(9,9′-spirobi[9H-fluoren]-1,3,4,5,6,7,8,1′,2′,3′,4′,5′,6′,7′,8′-d₁₅)-2-amine obtained in Step 1, 2.2 g (7.1 mmol) of 10-bromobenzo[b]naphtho[2,1-d]furan-1,2,3,4,5,6,7,8,9-d₉ obtained in Step 2, 1.9 g (20 mmol) of t-butoxysodium (abbreviation: ^{t}BuONa), and 64 mL of toluene. This mixture was degassed by being stirred under reduced pressure, and the atmosphere in the flask was replaced with nitrogen; then, the mixture was heated to 110° C. To this reaction solution were added 0.3 mL (0.15 mmol) of tri-tert-butylphosphine (abbreviation: P(^{t}Bu)₃) (10 wt % hexane solution) and 54 mg (94 μmol) of bis(dibenzylideneacetone)palladium(0) (abbreviation: Pd(dba)₂), and stirring was performed at 120° C. for six hours. Toluene was added to this mixture, stirring was performed at 80° C., and the resulting mixture was subjected to suction filtration through Alumina, Celite (Catalog No. 537-02305, FUJIFILM Wako Pure Chemical Corporation), and Florisil (Catalog No. 066-05265, FUJIFILM Wako Pure Chemical Corporation). The resulting filtrate was concentrated to give 5.6 g of a pale yellow solid containing the target substance. This solid was purified by liquid chromatography (mobile phase: chloroform) to give 4.5 g of a white solid of the target substance in a yield of 89%. Synthesis Scheme (c-3) of Step 3 is shown below.

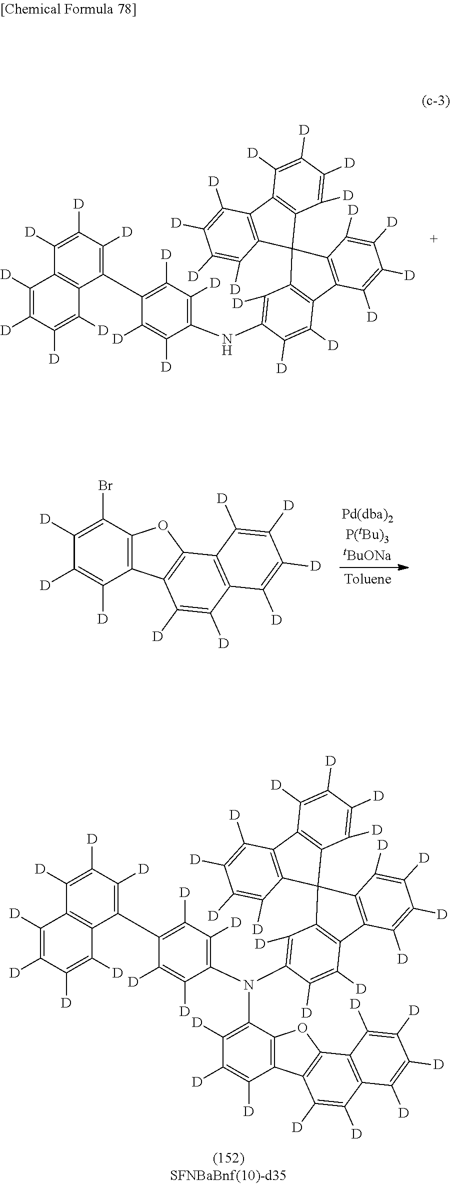

By a train sublimation method, 2.6 g of the obtained white solid was purified. In the purification by sublimation, the solid was heated at 310° C. for 16 hours under an argon stream (flow rate: 10 mL/min) and a pressure of 2.84 Pa. After the purification by sublimation, 2.15 g of a white solid of the target substance was obtained at a collection rate of 83%.

The molecular weight of the obtained white solid was measured by LC/MS analysis. As a result, a signal was observed at m/z 785 while the mass of the target substance was calculated to be 785, revealing that SFNBaBnf(10)-d35 was obtained.

### <Measurement of Physical Properties>

Next, the absorption spectrum and PL spectrum of a toluene solution and a solid thin film of SFNBaBnf(10)-d35 were measured.

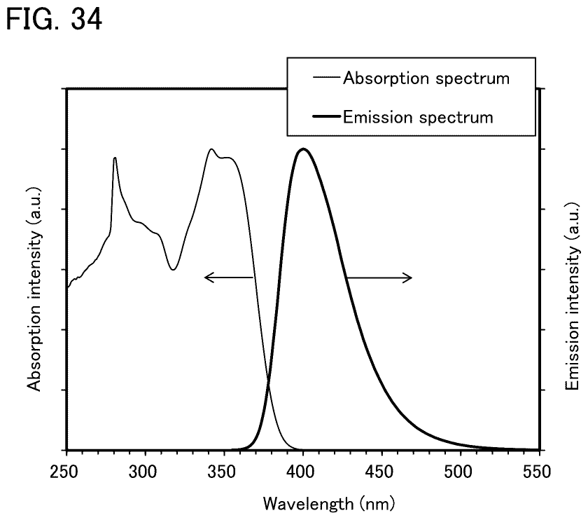

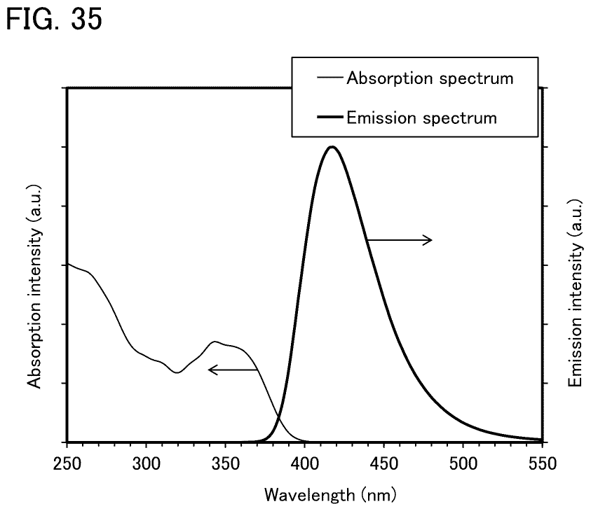

The absorption spectrum of the solution was measured with an ultraviolet-visible spectrophotometer (V-770DS, JASCO Corporation), and the absorption spectrum of the thin film was measured with an ultraviolet-visible spectrophotometer (U-4100, Hitachi). To calculate the absorption spectrum of the toluene solution of SFNBaBnf(10)-d35, the absorption spectrum of toluene put in a quartz cell was measured and then subtracted from the absorption spectrum of the toluene solution of SFNBaBnf(10)-d35 put in a quartz cell. The PL spectrum was measured with a fluorescence spectrophotometer (FP-8600DS, JASCO Corporation). FIG. 34 shows the measurement results of the absorption spectrum and the PL spectrum of the toluene solution of SFNBaBnf(10)-d35, and FIG. 35 shows the measurement results of the absorption spectrum and the PL spectrum of the thin film of SFNBaBnf(10)-d35.

As shown in FIG. 34, the absorption spectrum of the toluene solution of SFNBaBnf(10)-d35 exhibited an absorption peak at around 355 nm. The obtained spectrum reveal that the solution of SFNBaBnf(10)-d35 shows no absorption at wavelengths greater than or equal to 400 nm and that the material of the present invention can be suitably used for a light-emitting device. As shown in FIG. 34, the PL spectrum of the toluene solution of SFNBaBnf(10)-d35 exhibited an emission peak at around 400 nm (excitation wavelength: 342 nm).

As shown in FIG. 35, the absorption spectrum of the thin film of SFNBaBnf(10)-d35 exhibited the maximum absorption peak at around 343 nm and a shoulder peak at around 360 nm. As shown in FIG. 35, the PL spectrum of the thin film of SFNBaBnf(10)-d35 exhibited an emission peak at around 418 nm (excitation wavelength: 344 nm).

The thermogravimetry-differential thermal analysis (TG-DTA) of SFNBaBnf(10)-d35 was performed. For the measurement, a high-sensitivity differential type differential thermogravimeter (STA 2500 Regulus, NETZSCH Japan K. K.) was used. The measurement was performed at a temperature rising rate of 10° C./min under atmospheric pressure and a nitrogen stream (flow rate: 200 mL/min).

The thermogravimetry-differential thermal analysis reveals that the temperature at which the weight of SFNBaBnf(10)-d35 obtained by thermogravimetry decreases by 5% of the weight at the start of the measurement (i.e., the sublimation or decomposition temperature of SFNBaBnf(10)-d35) is 468° C. under atmospheric pressure. The results show that the sublimation or decomposition temperature of SFNBaBnf(10)-d35 under atmospheric pressure is 468° C., which indicates high heat resistance.

Differential scanning calorimetry (DSC) measurement of SFNBaBnf(10)-d35 was performed with DSC8500 manufactured by PerkinElmer, Inc. The DSC measurement was performed in the following manner. The temperature was raised from −10° C. to 330° C. at a temperature rising rate of 40° C./min and held for three minutes; then, the temperature was lowered to −10° C. at a temperature falling rate of 100° C./min and held for three minutes. This operation was performed twice in succession. Subsequently, the temperature was raised from −10° C. to 330° C. at a temperature rising rate of 50° C./min and held for three minutes; then, the temperature was lowered to −10° C. at a temperature falling rate of 100° C./min. This operation was performed once.

According to the results of the DSC measurement in the second temperature raising process at a temperature rising rate of 40° C./min, the glass transition temperature (Tg) of SFNBaBnf(10)-d35 is 154° C. It was found that an organic semiconductor element such as a light-emitting device can have increased heat resistance by including the organic compound of one embodiment of the present invention.

### Example 7

### Synthesis Example 5

In this example, a method for synthesizing N-[4-(1-naphthyl-2,3,4,5,6,7,8-d₇)phenyl-2,3,5,6-d₄]-N-[(9,9′-spirobi[9H-fluoren]-1,1′,2′,3,3′,4,4′,5,5′,6,6′,7,7′,8,8′-d₁₅)-2-yl]-6-(phenyl-2,3,4,5,6-d₅)(benzo[b]naphtho[1,2-d]furan-1,2,3,4,5,9,10,11-d₈)-8-amine (abbreviation: SFNBBnf-d39), which is the organic compound of the present invention represented by Structural Formula (153) in Embodiment 2, will be described. The structure of SFNBBnf-d39 is shown below.

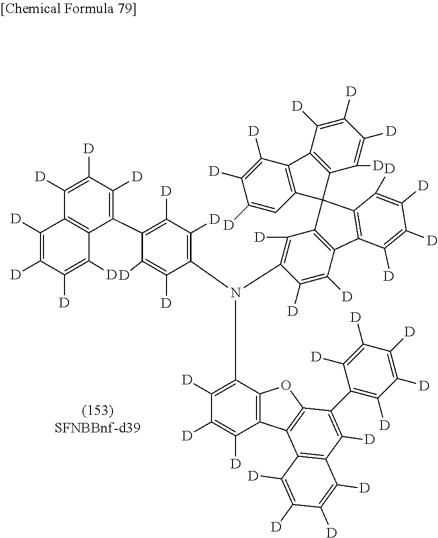 [SMILES: [2H]c1cc2c(c([2H])c1[2H])-c1c([2H])c([2H])c([2H])c([2H])c1C21c2c([2H])c([2H])c([2H])c([2H])c2-c2c([2H])c([2H])c(N(c3c([2H])c([2H])c(-c4c([2H])c([2H])c([2H])c5c([2H])c([2H])c([2H])c([2H])c45)c([2H])c3[2H])c3c([2H])c([2H])c([2H])c4c3oc3c(-c5c([2H])c([2H])c([2H])c([2H])c5[2H])c([2H])c5c([2H])c([2H])c([2H])c([2H])c5c34)c([2H])c21]

### <Synthesis of SFNBBnf-d39>

Into a 200-mL three-neck flask were put 3.6 g (6.4 mmol) of N-[4-(1-naphthyl-2,3,4,5,6,7,8-d₇)phenyl-2,3,5,6-d₄]-(9,9′-spirobi[9H-fluoren]-1,3,4,5,6,7,8,1′,2′,3′,4′,5′,6′,7′,8′-d₁)-2-amine, 3.0 g (6.9 mmol) of 8-iodo-6-(phenyl-2,3,4,5,6-d₅)benzo[b]naphtho[1,2-d]furan(1,2,3,4,5,9,10,11-d₈), 1.9 g (20 mmol) of t-butoxysodium (abbreviation: ^{t}BuONa), and 64 mL of toluene. This mixture was degassed by being stirred under reduced pressure, and the atmosphere in the flask was replaced with nitrogen; then, the mixture was heated to 110° C. To this reaction solution were added 0.3 mL (0.15 mmol) of tri-tert-butylphosphine (abbreviation: P(^{t}Bu)₃) (10 wt % hexane solution) and 55 mg (95 μmol) of bis(dibenzylideneacetone)palladium(0) (abbreviation: Pd(dba)₂), and stirring was performed at 120° C. for six hours. Toluene was added to this mixture, stirring was performed at 80° C., and the resulting mixture was subjected to suction filtration through Alumina, Celite (Catalog No. 537-02305, FUJIFILM Wako Pure Chemical Corporation), and Florisil (Catalog No. 066-05265, FUJIFILM Wako Pure Chemical Corporation). The resulting filtrate was concentrated to give 6.0 g of a yellow solid containing the target substance. This solid was purified by liquid chromatography (mobile phase: chloroform) to give 4.0 g of a white solid of the target substance in a yield of 72%. Synthesis Scheme (d-1) is shown below.

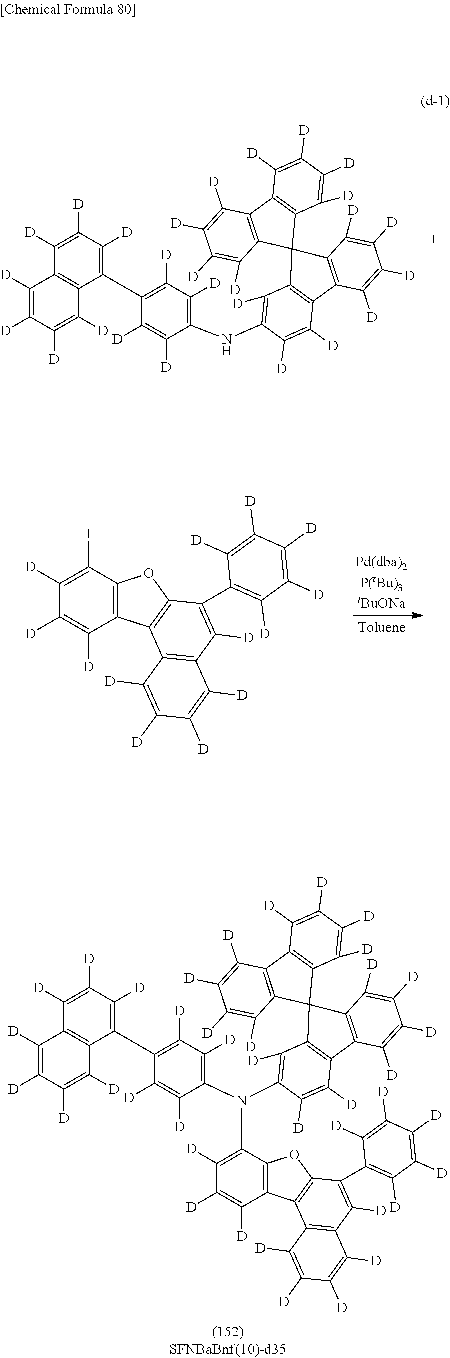

By a train sublimation method, 3.0 g of the obtained white solid was purified. In the purification by sublimation, the solid was heated under an argon stream (flow rate: 10 mL/min) and a pressure of 2.95 Pa at 310° C. for 17 hours and then at 315° C. for 24 hours. After the purification by sublimation, 2.2 g of a white solid of the target substance was obtained at a collection rate of 73%.

The molecular weight of the obtained white solid was measured by LC/MS analysis. As a result, a signal was observed at m/z 865 while the mass of the target substance was calculated to be 865, revealing that SFNBBnf-d39 was obtained.

### <Measurement of Physical Properties>

Next, the absorption spectrum and PL spectrum of a toluene solution and a solid thin film of SFNBBnf-d39 were measured.

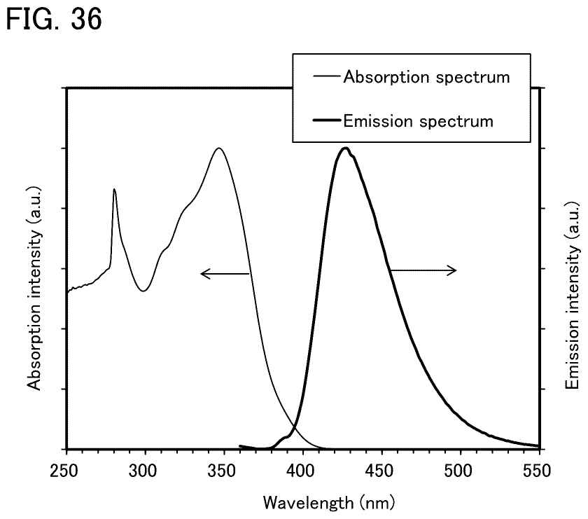

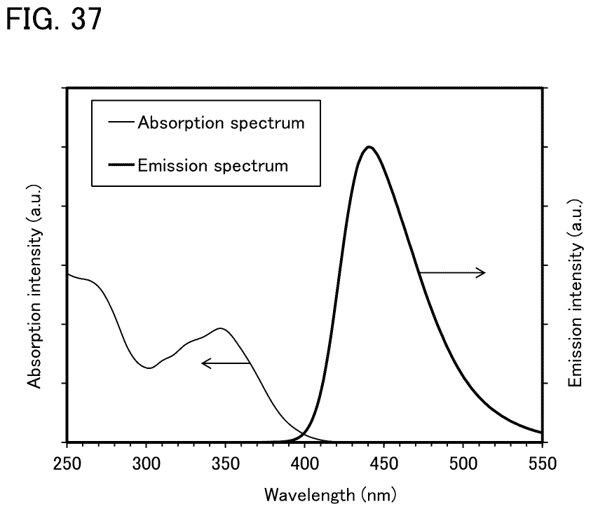

The absorption spectrum of the solution was measured with an ultraviolet-visible spectrophotometer (V-770DS, JASCO Corporation), and the absorption spectrum of the thin film was measured with an ultraviolet-visible spectrophotometer (U-4100, Hitachi). To calculate the absorption spectrum of the toluene solution of SFNBBnf-d39, the absorption spectrum of toluene put in a quartz cell was measured and then subtracted from the absorption spectrum of the toluene solution of SFNBBnf-d39 put in a quartz cell. The PL spectrum was measured with a fluorescence spectrophotometer (FP-8600DS, JASCO Corporation). FIG. 36 shows the measurement results of the absorption spectrum and the PL spectrum of the toluene solution of SFNBBnf-d39, and FIG. 37 shows the measurement results of the absorption spectrum and the PL spectrum of the thin film of SFNBBnf-d39.

As shown in FIG. 36, the absorption spectrum of the toluene solution of SFNBBnf-d39 exhibited an absorption peak at around 347 nm and a shoulder peak at around 389 nm. As shown in FIG. 36, the PL spectrum of the toluene solution of SFNBBnf-d39 exhibited an emission peak at around 427 nm (excitation wavelength: 347 nm).

As shown in FIG. 37, the absorption spectrum of the thin film of SFNBBnf-d39 exhibited the maximum absorption peak at around 347 nm. As shown in FIG. 37, the PL spectrum of the thin film of SFNBBnf-d39 exhibited an emission peak at around 440 nm (excitation wavelength: 350 nm).

The thermogravimetry-differential thermal analysis (TG-DTA) of SFNBBnf-d39 was performed. For the measurement, a high-sensitivity differential type differential thermogravimeter (STA 2500 Regulus, NETZSCH Japan K. K.) was used. The measurement was performed at a temperature rising rate of 10° C./min under atmospheric pressure and a nitrogen stream (flow rate: 200 mL/min).

The thermogravimetry-differential thermal analysis reveals that the temperature at which the weight of SFNBBnf-d39 obtained by thermogravimetry decreases by 5% of the weight at the start of the measurement (i.e., the sublimation or decomposition temperature of SFNBBnf-d39) is 485° C. under atmospheric pressure. The results show that the sublimation or decomposition temperature of SFNBBnf-d39 under atmospheric pressure is 485° C., which indicates high heat resistance.

Differential scanning calorimetry (DSC) measurement of SFNBBnf-d39 was performed with DSC8500 manufactured by PerkinElmer, Inc. The DSC measurement was performed in the following manner. The temperature was raised from −10° C. to 350° C. at a temperature rising rate of 40° C./min and held for three minutes; then, the temperature was lowered to −10° C. at a temperature falling rate of 100° C./min and held for three minutes. This operation was performed twice in succession. Subsequently, the temperature was raised from −10° C. to 350° C. at a temperature rising rate of 50° C./min and held for three minutes; then, the temperature was lowered to −10° C. at a temperature falling rate of 100° C./min. This operation was performed once.

According to the results of the DSC measurement in the second temperature raising process at a temperature rising rate of 40° C./min, the glass transition temperature (Tg) of SFNBBnf-d39 is 166° C. It was found that an organic semiconductor element such as a light-emitting device can have increased heat resistance by including the organic compound of one embodiment of the present invention.

### Example 8

In this example, Light-Emitting Device 3A and Light-Emitting Device 3B of embodiments of the present invention were fabricated. Furthermore, Comparative Light-Emitting Device 3C and Comparative Light-Emitting Device 3D were fabricated.

Specifically, N-[4-(1-naphthyl-2,3,4,5,6,7,8-d₇)phenyl-2,3,5,6-d₄]—N-[(9,9′-spirobi[9H-fluoren]-1,3,4,5,6,7,8,1′,2′,3′,4′,5′,6′,7′,8′-d₁₅)-2-yl](benzo[b]naphtho[2,1-d]furan-1,2,3,4,5,6,7,8,9-d₉)-10-amine (abbreviation: SFNBaBnf(10)-d35) represented by Structural Formula (152) in Embodiment 2 was used for a hole-transport layer of each of Light-Emitting Devices 3A and 3B.

Meanwhile, N-[4-(1-naphthyl)phenyl]-N-(9,9′-spirobi[9H-fluoren]-2-yl)benzo[b]naphtho[2,1-d]furan-10-amine (abbreviation: SFNBaBnf(10)) was used for a hole-transport layer of each of Comparative Light-Emitting Devices 3C and 3D.

The structural formulae of organic compounds used in Light-Emitting Devices 3A and 3B and Comparative Light-Emitting Devices 3C and 3D are shown below.

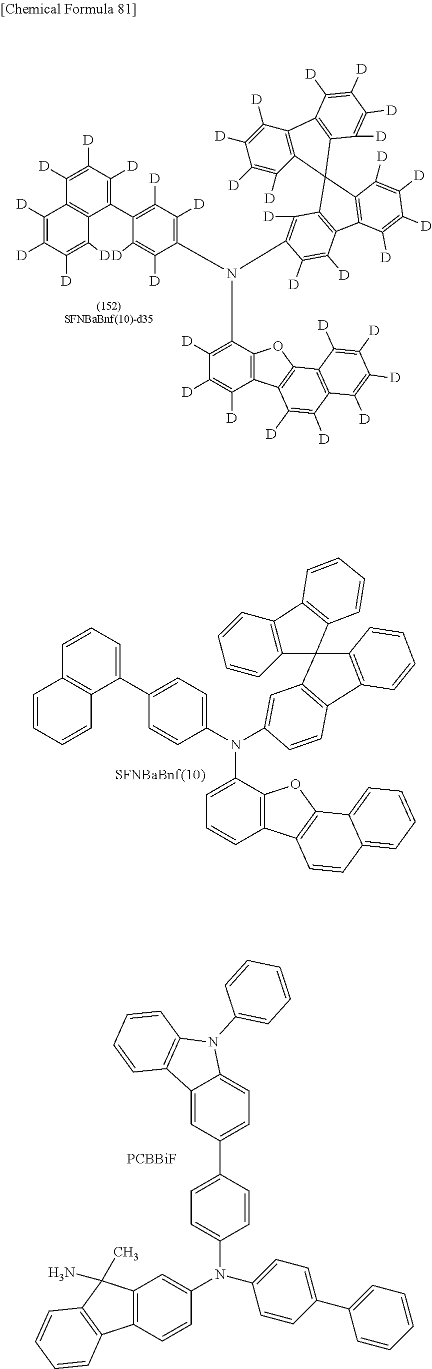

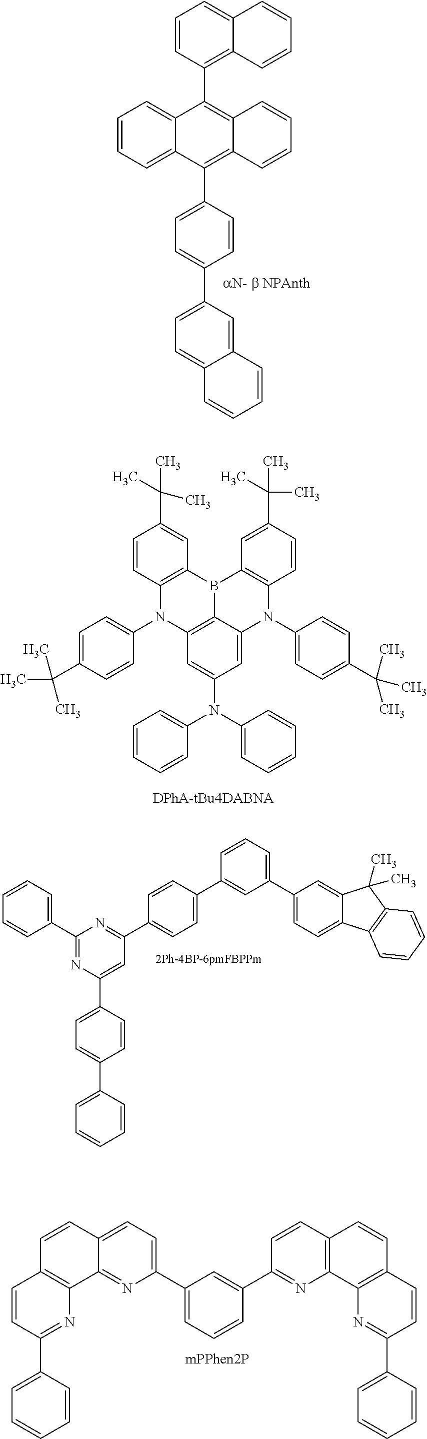

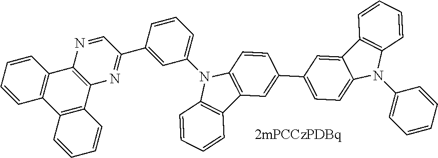 [SMILES: c1ccc(-n2c3ccccc3c3cc(-c4ccc5c(c4)c4ccccc4n5-c4cccc(-c5cnc6c7ccccc7c7ccccc7c6n5)c4)ccc32)cc1]

In each of the devices, as illustrated in FIG. 21, the hole-injection layer 811, the hole-transport layer 812, the light-emitting layer 813, the electron-transport layer 814, and the electron-injection layer 815 are stacked in this order over the first electrode 801 formed over the glass substrate 800, and the second electrode 802 is stacked over the electron-injection layer 815.

### <Method for Fabricating Light-Emitting Device 3A>

As the first electrode 801, a film of indium tin oxide containing silicon oxide (ITSO) was formed to a thickness of 110 nm over the glass substrate 800 by a sputtering method. The electrode area was set to 4 mm² (2 mm×2 mm).

Next, in pretreatment for forming the light-emitting device over the substrate, a surface of the substrate was washed with water, and baking was performed at 200° C. for one hour. Then, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus, followed by natural cooling down to lower than or equal to 30° C.

Next, the substrate provided with the first electrode 801 was fixed to a substrate holder provided in the vacuum evaporation apparatus such that the surface on which the first electrode 801 was formed faced downward. Over the first electrode 801, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material containing fluorine and having a molecular weight of 672 (OCHD-003) were deposited by co-evaporation to a thickness of 10 nm such that the weight ratio of PCBBiF to OCHD-003 was 1:0.03, whereby the hole-injection layer 811 was formed.

Subsequently, over the hole-injection layer 811, PCBBiF was deposited by evaporation using resistance heating to a thickness of 90 nm, and then, N-[4-(1-naphthyl-2,3,4,5,6,7,8-d₇)phenyl-2,3,5,6-d₄]—N-[(9,9′-spirobi[9H-fluoren]-1,3,4,5,6,7,8,1′,2′,3′,4′,5′,6′,7′,8′-d₅)-2-yl](benzo[b]naphtho[2,1-d]furan-1,2,3,4,5,6,7,8,9-d₉)-10-amine (abbreviation: SFNBaBnf(10)-d35) represented by Structural Formula (152) was deposited by evaporation using resistance heating to a thickness of 10 nm, so that the hole-transport layer 812 was formed.

Next, over the hole-transport layer 812, 9-(1-naphthyl)-10-[4-(2-naphthyl)phenyl]anthracene (abbreviation: αN-βNPAnth) and 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA) were deposited by co-evaporation using resistance heating to a thickness of 25 nm such that the weight ratio of αN-βNPAnth to DPhA-tBu4DABNA was 1:0.015, whereby the light-emitting layer 813 was formed.

Next, over the light-emitting layer 813, 2-{3-[3-(N-phenyl-9H-carbazol-3-yl)-9H-carbazol-9-yl]phenyl}dibenzo[f,h]quinoxaline (abbreviation: 2mPCCzPDBq) was deposited by evaporation to a thickness of 10 nm, and then 2,2′-(1,3-phenylene)bis(9-phenyl-1,10-phenanthroline) (abbreviation: mPPhen2P) was deposited by evaporation to a thickness of 15 nm, so that the electron-transport layer 814 was formed.

Next, lithium fluoride (LiF) was deposited by evaporation to a thickness of 1 nm over the electron-transport layer 814, so that the electron-injection layer 815 was formed.

Then, aluminum (Al) was deposited by evaporation to a thickness of 120 nm over the electron-injection layer 815, so that the second electrode 802 was formed.

### <Method for Fabricating Light-Emitting Device 3B>

Next, a method for fabricating Light-Emitting Device 3B is described. Light-Emitting Device 3B is different from Light-Emitting Device 3A in the structure of the electron-transport layer 814.

In Light-Emitting Device 3B, the electron-transport layer 814 was formed in the following manner: over the light-emitting layer 813, 4-(biphenyl-4-yl)-6-[3′-(9,9-dimethyl-9H-fluoren-2-yl)biphenyl-4-yl]-2-phenylpyrimidine (abbreviation: 2Ph-4BP-6pmFBPPm) was deposited by evaporation using resistance heating to a thickness of 10 nm, and then, mPPhen2P was deposited by evaporation using resistance heating to a thickness of 15 nm.

The other components were formed in a manner similar to that for Light-Emitting Device 3A.

### <Method for Fabricating Comparative Light-Emitting Device 3C>

Next, a method for fabricating Comparative Light-Emitting Device 3C is described. Comparative Light-Emitting Device 3C is different from Light-Emitting Device 3A in the structure of the hole-transport layer 812.

In Comparative Light-Emitting Device 3C, the hole-transport layer 812 was formed in the following manner: over the hole-injection layer 811, PCBBiF was deposited by evaporation using resistance heating to a thickness of 90 nm, and then, N-[4-(1-naphthyl)phenyl]-N-(9,9′-spirobi[9H-fluoren]-2-yl)benzo[b]naphtho[2,1-d]furan-10-amine (abbreviation: SFNBaBnf(10)) was deposited by evaporation using resistance heating to a thickness of 10 nm.

The other components were formed in a manner similar to that for Light-Emitting Device 3A.

### <Method for Fabricating Comparative Light-Emitting Device 3D>

Next, a method for fabricating Comparative Light-Emitting Device 3D is described. Comparative Light-Emitting Device 3D is different from Light-Emitting Device 3B in the structure of the hole-transport layer 812.

In Comparative Light-Emitting Device 3D, the hole-transport layer 812 was formed in the following manner: over the hole-injection layer 811, PCBBiF was deposited by evaporation using resistance heating to a thickness of 90 nm, and then, SFNBaBnf(10) was deposited by evaporation using resistance heating to a thickness of 10 nm.

The other components were formed in a manner similar to that for Light-Emitting Device 3B.

The structures of Light-Emitting Devices 3A and 3B and Comparative Light-Emitting Devices 3C and 3D are listed in the following table.

TABLE 6

| | | | | Comparative | Comparative |
|---|---|---|---|---|---|
| | Thickness | Light-Emitting | Light-Emitting | Light-Emitting | Light-Emitting |
| | [nm] | Device 3A | Device 3B | Device 3C | Device 3D |
| Second electrode | 120 | Al | | | |
| Electron-injection | 1 | LiF | | | |
| layer | | | | | |
| Electron-transport | 15 | mPPhen2P | | | |
| layer | 10 | 2mPCCzPDBq | 2Ph-4BP-6pmFBPPm | 2mPCCzPDBq | 2Ph-4BP-6pmFBPPm |

| Light-emitting layer | 25 | αN-βNPAnth:DPhA-tBu4DABNA (1:0.015) | |
|---|---|---|---|
| Hole-transport layer | 10 | SFNBaBnf(10)-d35 | SFNBaBnf(10) |

| | | |
|---|---|---|
| | 90 | PCBBiF |
| Hole-injection layer | 10 | PCBBiF:OCHD-003 (1:0.03) |
| First electrode | 110 | ITSO |

### <Light-Emitting Device Characteristics>

The light-emitting devices were sealed using a glass substrate in a glove box containing a nitrogen atmosphere so as not to be exposed to the air (a sealing material was applied to surround the devices, and UV treatment and heat treatment at 80° C. for one hour were performed at the time of sealing). Then, the characteristics of the light-emitting devices were measured.

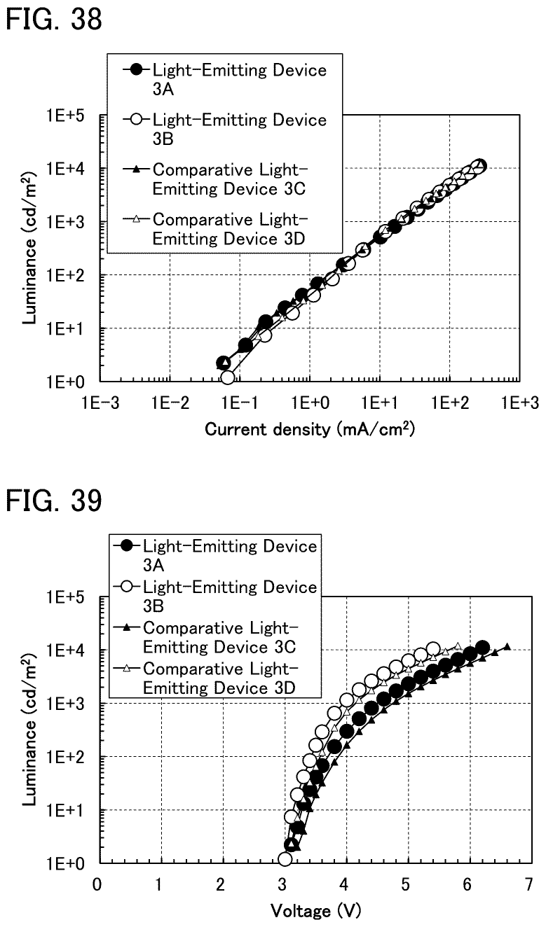

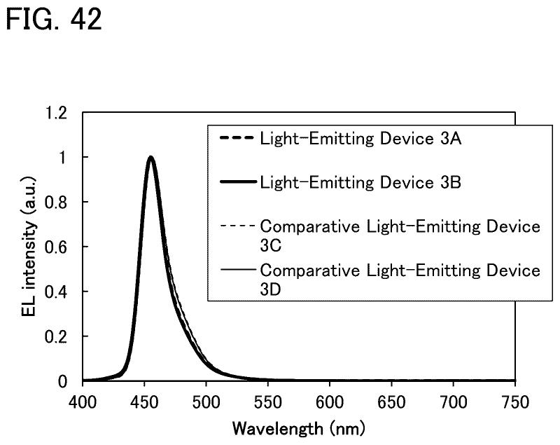

FIG. 38 shows the luminance-current density characteristics of the light-emitting devices. FIG. 39 shows the luminance-voltage characteristics of the light-emitting devices. FIG. shows the current efficiency-luminance characteristics of the light-emitting devices. FIG. 41 shows the current density-voltage characteristics of the light-emitting devices. FIG. 42 shows the electroluminescence spectra of the light-emitting devices.

The main characteristics of the devices at a luminance of approximately 1000 cd/m² are shown in the table below. The luminance, CIE chromaticity, and electroluminescence spectra were measured with a spectroradiometer (SR-UL1R, TOPCON TECHNOHOUSE CORPORATION).

TABLE 7

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Light-Emitting | 4.40 | 0.651 | 16.3 | 0.142 | 0.0561 | 808 | 4.96 |
| Device 3A | | | | | | | |
| Light-Emitting | 4.00 | 0.855 | 21.4 | 0.142 | 0.0546 | 1146 | 5.36 |
| Device 3B | | | | | | | |
| Comparative Light- | 4.80 | 0.842 | 21.0 | 0.139 | 0.0625 | 1093 | 5.19 |
| Emitting Device 3C | | | | | | | |
| Comparative Light- | 4.20 | 0.812 | 20.3 | 0.140 | 0.0613 | 1152 | 5.68 |
| Emitting Device 3D | | | | | | | |

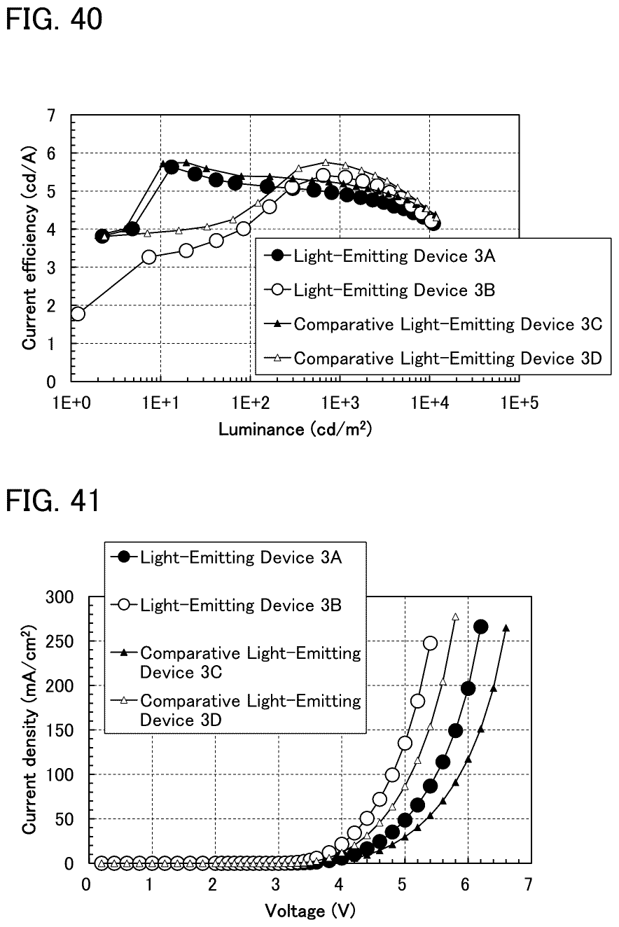

FIG. 38 to FIG. 42 show that Light-Emitting Device 3A has efficiency as high as that of Comparative Light-Emitting Device 3C, and Light-Emitting Device 3B has efficiency as high as that of Comparative Light-Emitting Device 3D.

In each of Light-Emitting Device 3A and Comparative Light-Emitting Device 3C including 2mPCCzPDBq in the electron-transport layers, the property of injecting electrons into the light-emitting layer was low, and favorable carrier balance with holes and resultantly high efficiency were achieved at around 10 cd/m². In each of Light-Emitting Device 3B and Comparative Light-Emitting Device 3D including 2Ph-4BP-6pmFBPPm in the electron-transport layers, the property of injecting electrons into the light-emitting layer was high, and favorable carrier balance with holes and resultantly high efficiency were achieved at around 650 cd/m².

It was thus confirmed that SFNBaBnf(10)-d35, which is a deuterium-containing organic compound, can be suitably used for a light-emitting device.

### <Results of Reliability Test>

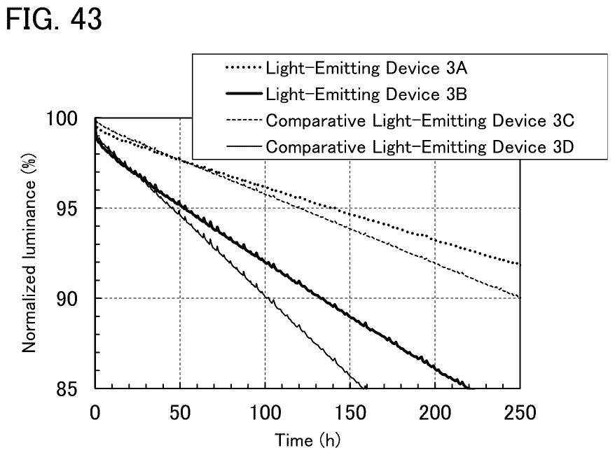

A reliability test was conducted on Light-Emitting Device 3A. FIG. 43 shows a time-dependent change in normalized luminance at the time of constant current density driving (50 [mA/cm²]). In FIG. 43, the vertical axis represents the luminance (%) normalized with the luminance at the time of the start of light emission being regarded as 100%, and the horizontal axis represents time (h).

As shown in FIG. 43, the LT95 (h), which is the time that has elapsed until the measured luminance decreases to 95% of the initial luminance, of Light-Emitting Device 3A was 139 hours. The LT95 of Comparative Light-Emitting Device 3C was 121 hours.

As shown in FIG. 43, the LT95 (h), which is the time that has elapsed until the measured luminance decreases to 95% of the initial luminance, of Light-Emitting Device 3B was 52 hours. The LT95 of Comparative Light-Emitting Device 3D was 45 hours.

Thus, it was confirmed that by including the deuterium-containing organic compound of one embodiment of the present invention, a light-emitting device can have emission efficiency as high as that of a comparative light-emitting device and reliability higher than that of the comparative light-emitting device.

It was also found that Light-Emitting Device 3A and Comparative Light-Emitting Device 3C including 2mPCCzPDBq in the electron-transport layers tend to have higher reliability than Light-Emitting Device 3B and Comparative Light-Emitting Device 3D including 2Ph-4BP-6pmFBPPm in the electron-transport layers. This is because 2Ph-4BP-6pmFBPPm has a higher property of injecting electrons into the light-emitting layer than 2mPCCzPDBq, and thus, carrier recombination is localized at the interface between the electron-blocking layer and the light-emitting layer to promote degradation.

### Example 9

In this example, Light-Emitting Device 4A and Light-Emitting Device 4B of embodiments of the present invention were fabricated. Furthermore, Comparative Light-Emitting Device 4C and Comparative Light-Emitting Device 4D were fabricated.

Specifically, N-[4-(1-naphthyl-2,3,4,5,6,7,8-d₇)phenyl-2,3,5,6-d₄]—N-[(9,9′-spirobi[9H-fluoren]-1,3,4,5,6,7,8,1′,2′,3′,4′,5′,6′,7′,8′-d₁₅)-2-yl](benzo[b]naphtho[2,1-d]furan-1,2,3,4,5,6,7,8,9-d₉)-10-amine (abbreviation: SFNBaBnf(10)-d35) represented by Structural Formula (152) in Embodiment 2 was used for a hole-transport layer of each of Light-Emitting Devices 4A and 4B.

Meanwhile, N-[4-(1-naphthyl)phenyl]-N-(9,9′-spirobi[9H-fluoren]-2-yl)benzo[b]naphtho[2,1-d]furan-10-amine (abbreviation: SFNBaBnf(10)) was used for a hole-transport layer of each of Comparative Light-Emitting Devices 4C and 4D.

The structural formulae of organic compounds used in Light-Emitting Devices 4A and 4B and Comparative Light-Emitting Devices 4C and 4D are shown below.

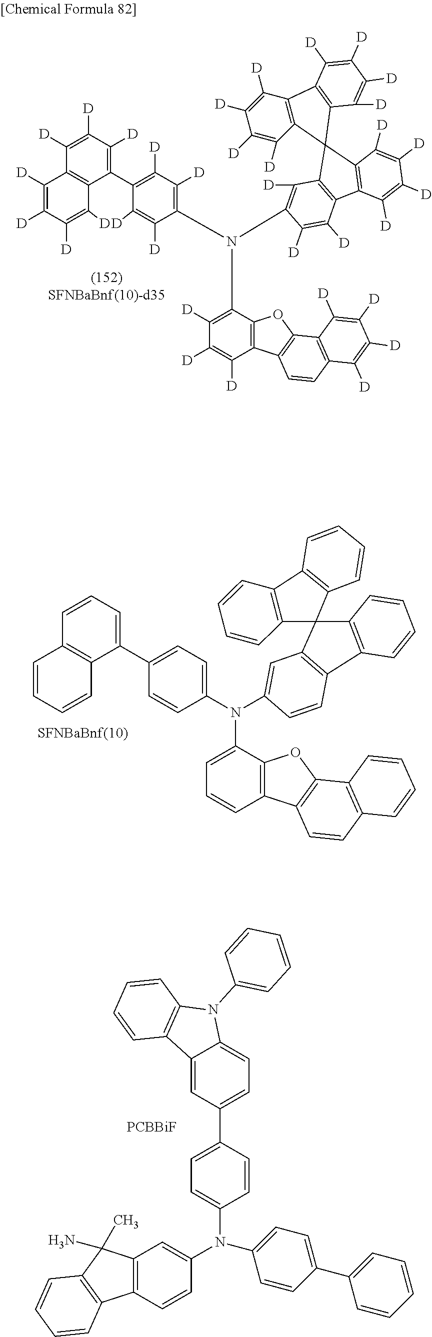 [SMILES: [2H]c1c([2H])c([2H])c2c(c1[2H])-c1c([2H])c([2H])c([2H])c([2H])c1C21c2c([2H])c([2H])c([2H])c([2H])c2-c2c([2H])c([2H])c(N(c3c([2H])c([2H])c(-c4c([2H])c([2H])c([2H])c5c([2H])c([2H])c([2H])c([2H])c45)c([2H])c3[2H])c3c([2H])c([2H])c([2H])c4c3oc3c4ccc4c([2H])c([2H])c([2H])c([2H])c43)c([2H])c21 ; c1ccc2c(c1)-c1ccccc1C21c2ccccc2-c2ccc(N(c3ccc(-c4cccc5ccccc45)cc3)c3cccc4c3oc3c5ccccc5ccc43)cc21 ; CC1(N)c2ccccc2-c2ccc(N(c3ccc(-c4ccccc4)cc3)c3ccc(-c4ccc5c(c4)c4ccccc4n5-c4ccccc4)cc3)cc21 ; "PCBBiF"]

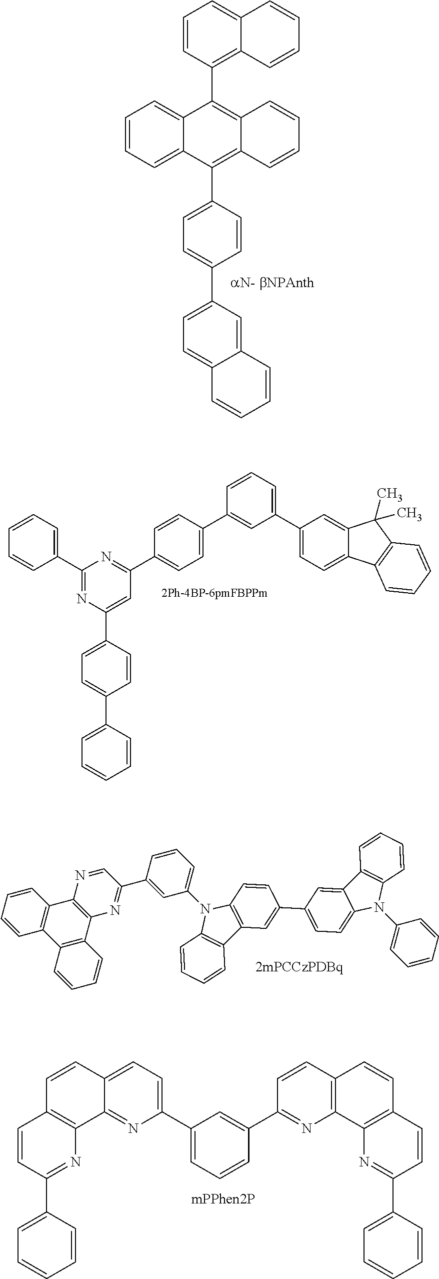

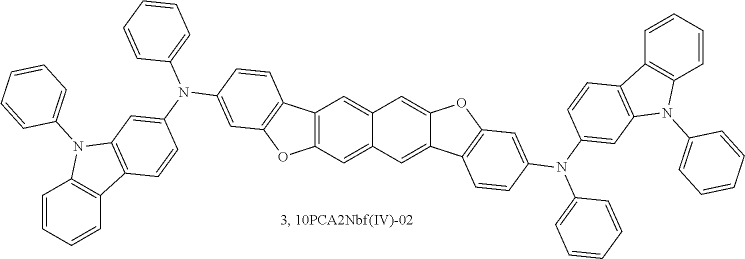 [SMILES: c1ccc(N(c2ccc3c(c2)oc2cc4cc5c(cc4cc23)oc2cc(N(c3ccccc3)c3ccc4c6ccccc6n(-c6ccccc6)c4c3)ccc25)c2ccc3c4ccccc4n(-c4ccccc4)c3c2)cc1]

In each of the devices, as illustrated in FIG. 21, the hole-injection layer 811, the hole-transport layer 812, the light-emitting layer 813, the electron-transport layer 814, and the electron-injection layer 815 are stacked in this order over the first electrode 801 formed over the glass substrate 800, and the second electrode 802 is stacked over the electron-injection layer 815.

### <Method for Fabricating Light-Emitting Device 4A>

As the first electrode 801, a film of indium tin oxide containing silicon oxide (ITSO) was formed to a thickness of 110 nm over the glass substrate 800 by a sputtering method. The electrode area was set to 4 mm² (2 mm×2 mm).

Next, in pretreatment for forming the light-emitting device over the substrate, a surface of the substrate was washed with water, and baking was performed at 200° C. for one hour. Then, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus, followed by natural cooling down to lower than or equal to 30° C.

Next, the substrate provided with the first electrode 801 was fixed to a substrate holder provided in the vacuum evaporation apparatus such that the surface on which the first electrode 801 was formed faced downward. Over the first electrode 801, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material containing fluorine and having a molecular weight of 672 (OCHD-003) were deposited by co-evaporation to a thickness of 10 nm such that the weight ratio of PCBBiF to OCHD-003 was 1:0.03, whereby the hole-injection layer 811 was formed.

Subsequently, over the hole-injection layer 811, PCBBiF was deposited by evaporation using resistance heating to a thickness of 90 nm, and then, N-[4-(1-naphthyl-2,3,4,5,6,7,8-d₇)phenyl-2,3,5,6-d₄]—N-[(9,9′-spirobi[9H-fluoren]-1,3,4,5,6,7,8,1′,2′,3′,4′,5′,6′,7′,8′-d₁₅)-2-yl](benzo[b]naphtho[2,1-d]furan-1,2,3,4,5,6,7,8,9-d₉)-10-amine (abbreviation: SFNBaBnf(10)-d35) represented by Structural Formula (152) was deposited by evaporation using resistance heating to a thickness of 10 nm, so that the hole-transport layer 812 was formed.

Next, over the hole-transport layer 812, 9-(1-naphthyl)-10-[4-(2-naphthyl)phenyl]anthracene (abbreviation: αN-βNPAnth) and N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02) were deposited by co-evaporation using resistance heating to a thickness of 25 nm such that the weight ratio of αN-βNPAnth to 3,10PCA2Nbf(IV)-02 was 1:0.015, whereby the light-emitting layer 813 was formed.

Next, over the light-emitting layer 813, 2-{3-[3-(N-phenyl-9H-carbazol-3-yl)-9H-carbazol-9-yl]phenyl}dibenzo[f,h]quinoxaline (abbreviation: 2mPCCzPDBq) was deposited by evaporation to a thickness of 10 nm, and then 2,2′-(1,3-phenylene)bis(9-phenyl-1,10-phenanthroline) (abbreviation: mPPhen2P) was deposited by evaporation to a thickness of 15 nm, so that the electron-transport layer 814 was formed.

Next, lithium fluoride (LiF) was deposited by evaporation to a thickness of 1 nm over the electron-transport layer 814, so that the electron-injection layer 815 was formed.

Then, aluminum (Al) was deposited by evaporation to a thickness of 120 nm over the electron-injection layer 815, so that the second electrode 802 was formed.

### <Method for Fabricating Light-Emitting Device 4B>

Next, a method for fabricating Light-Emitting Device 4B is described. Light-Emitting Device 4B is different from Light-Emitting Device 4A in the structure of the electron-transport layer 814.

In Light-Emitting Device 4B, the electron-transport layer 814 was formed in the following manner: over the light-emitting layer 813, 4-(biphenyl-4-yl)-6-[3′-(9,9-dimethyl-9H-fluoren-2-yl)biphenyl-4-yl]-2-phenylpyrimidine (abbreviation: 2Ph-4BP-6pmFBPPm) was deposited by evaporation using resistance heating to a thickness of 10 nm, and then, mPPhen2P was deposited by evaporation using resistance heating to a thickness of 15 nm.

The other components were formed in a manner similar to that for Light-Emitting Device 4A.

### <Method for Fabricating Comparative Light-Emitting Device 4C>

Next, a method for fabricating Comparative Light-Emitting Device 4C is described. Comparative Light-Emitting Device 4C is different from Light-Emitting Device 4A in the structure of the hole-transport layer 812.

In Comparative Light-Emitting Device 4C, the hole-transport layer 812 was formed in the following manner: over the hole-injection layer 811, PCBBiF was deposited by evaporation using resistance heating to a thickness of 90 nm, and then, N-[4-(1-naphthyl)phenyl]-N-(9,9′-spirobi[9H-fluoren]-2-yl)benzo[b]naphtho[2,1-d]furan-10-amine (abbreviation: SFNBaBnf(10)) was deposited by evaporation using resistance heating to a thickness of 10 nm.

The other components were formed in a manner similar to that for Light-Emitting Device 4A.

### <Method for Fabricating Comparative Light-Emitting Device 4D>

Next, a method for fabricating Comparative Light-Emitting Device 4D is described. Comparative Light-Emitting Device 4D is different from Light-Emitting Device 4B in the structure of the hole-transport layer 812.

In Comparative Light-Emitting Device 4D, the hole-transport layer 812 was formed in the following manner: over the hole-injection layer 811, PCBBiF was deposited by evaporation using resistance heating to a thickness of 90 nm, and then, SFNBaBnf(10) was deposited by evaporation using resistance heating to a thickness of 10 nm.

The other components were formed in a manner similar to that for Light-Emitting Device 4B.

The structures of Light-Emitting Devices 4A and 4B and Comparative Light-Emitting Devices 4C and 4D are listed in the following table.

TABLE 8

| | | | | Comparative | Comparative |
|---|---|---|---|---|---|
| | Thickness | Light-Emitting | Light-Emitting | Light-Emitting | Light-Emitting |
| | [nm] | Device 4A | Device 4B | Device 4C | Device 4D |
| Second electrode | 120 | Al | | | |
| Electron-injection | 1 | LiF | | | |
| layer | | | | | |
| Electron-transport | 15 | mPPhen2P | | | |
| layer | 10 | 2mPCCzPDBq | 2Ph-4BP-6pmFBPPm | 2mPCCzPDBq | 2Ph-4BP-6pmFBPPm |

| Light-emitting layer | 25 | αN-βNPAnth:3,10PCA2Nbf(IV)-02 (1:0.015) | |
|---|---|---|---|
| Hole-transport | 10 | SFNBaBnf(10)-d35 | SFNBaBnf(10) |

| | | |
|---|---|---|
| layer | 90 | PCBBiF |
| Hole-injection layer | 10 | PCBBiF:OCHD-003 (1:0.03) |
| First electrode | 110 | ITSO |

### <Light-Emitting Device Characteristics>

The light-emitting devices were sealed using a glass substrate in a glove box containing a nitrogen atmosphere so as not to be exposed to the air (a sealing material was applied to surround the devices, and UV treatment and heat treatment at 80° C. for one hour were performed at the time of sealing). Then, the characteristics of the light-emitting devices were measured.

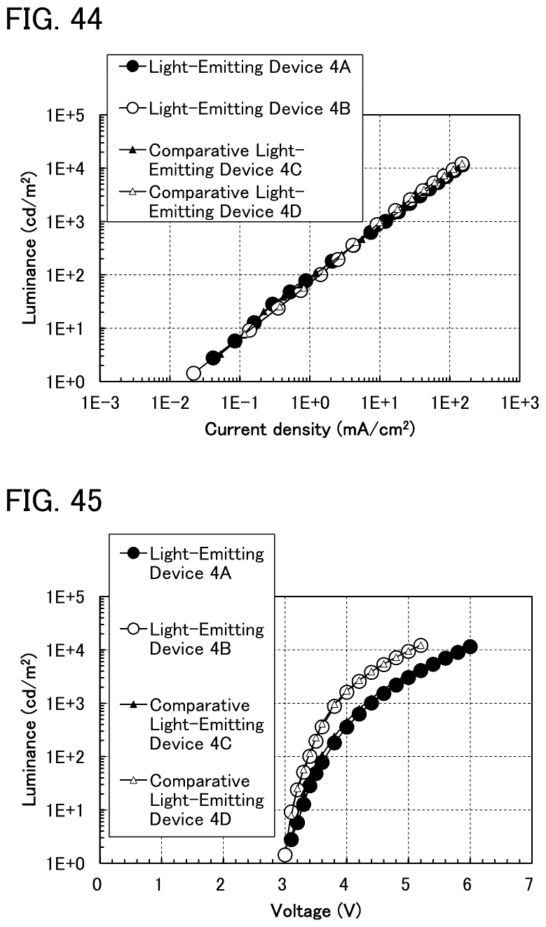

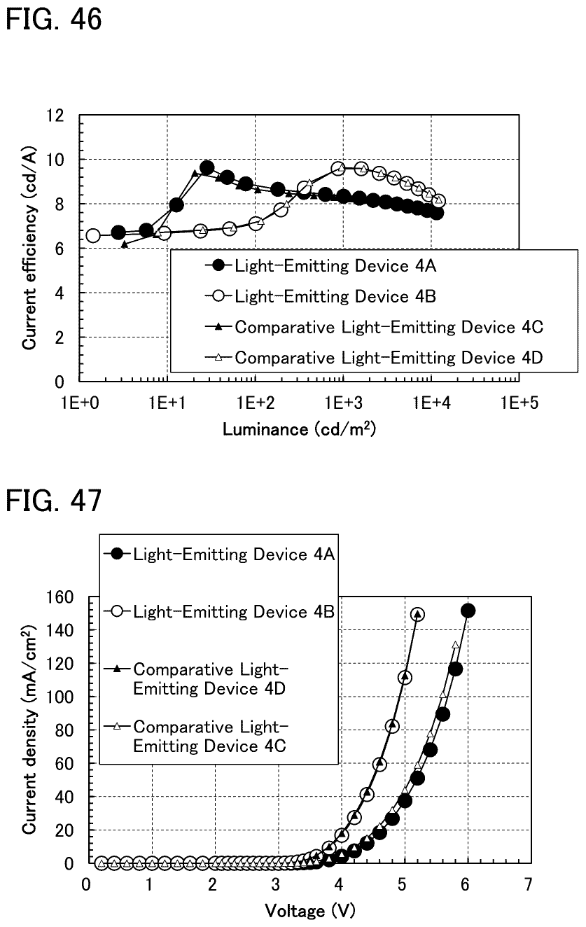

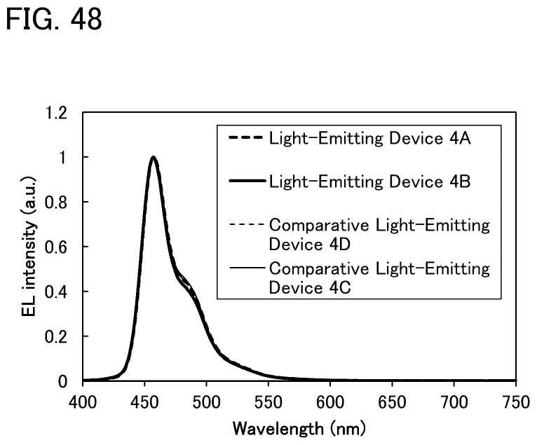

FIG. 44 shows the luminance-current density characteristics of the light-emitting devices. FIG. 45 shows the luminance-voltage characteristics of the light-emitting devices. FIG. 46 shows the current efficiency-luminance characteristics of the light-emitting devices. FIG. 47 shows the current density-voltage characteristics of the light-emitting devices. FIG. 48 shows the electroluminescence spectra of the light-emitting devices.

The main characteristics of the devices at a luminance of approximately 1000 cd/m² are shown in the table below. The luminance, CIE chromaticity, and electroluminescence spectra were measured with a spectroradiometer (SR-UL1R, TOPCON TECHNOHOUSE CORPORATION).

TABLE 9

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Light-Emitting | 4.40 | 0.483 | 12.1 | 0.137 | 0.104 | 1010 | 8.34 |
| Device 4A | | | | | | | |
| Light-Emitting | 3.80 | 0.365 | 9.12 | 0.138 | 0.101 | 874 | 9.58 |
| Device 4B | | | | | | | |
| Comparative Light- | 4.20 | 0.380 | 9.51 | 0.137 | 0.104 | 789 | 8.30 |
| Emitting Device 4C | | | | | | | |
| Comparative Light- | 3.80 | 0.398 | 10.0 | 0.137 | 0.102 | 959 | 9.62 |
| Emitting Device 4D | | | | | | | |

FIG. 44 to FIG. 48 show that Light-Emitting Device 4A has efficiency as high as that of Comparative Light-Emitting Device 4C, and Light-Emitting Device 4B has efficiency as high as that of Comparative Light-Emitting Device 4D.

In each of Light-Emitting Device 4A and Comparative Light-Emitting Device 4C including 2mPCCzPDBq in the electron-transport layers, the property of injecting electrons into the light-emitting layer was low, and thus, carrier balance with holes was achieved and the efficiency had a local maximum at around 30 cd/m². In each of Light-Emitting Device 4B and Comparative Light-Emitting Device 4D including 2Ph-4BP-6pmFBPPm in the electron-transport layers, the property of injecting electrons into the light-emitting layer was high, and thus, carrier balance with holes was achieved and the efficiency had a local maximum at around 1000 cd/m².

It was thus confirmed that SFNBaBnf(10)-d35, which is a deuterium-containing organic compound, can be suitably used for a light-emitting device.

### <Results of Reliability Test>

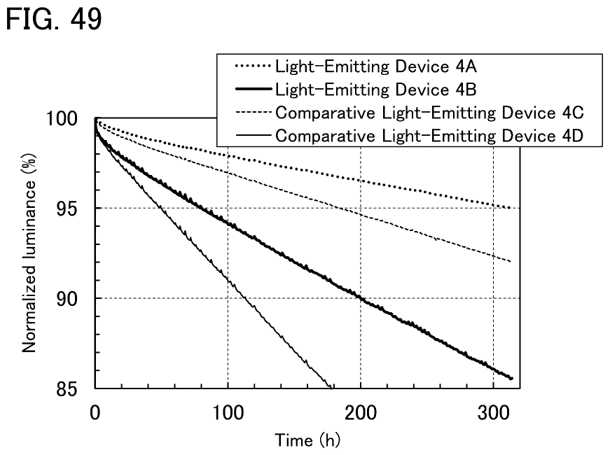

A reliability test was conducted on Light-Emitting Device 4A. FIG. 49 shows a time-dependent change in normalized luminance at the time of constant current density driving (50 [mA/cm²]). In FIG. 49, the vertical axis represents the luminance (%) normalized with the luminance at the time of the start of light emission being regarded as 100%, and the horizontal axis represents time (h).

As shown in FIG. 49, the LT95 (h), which is the time that has elapsed until the measured luminance decreases to 95% of the initial luminance, of Light-Emitting Device 4A was 313 hours. The LT95 of Comparative Light-Emitting Device 4C was 184 hours.

As shown in FIG. 49, the LT95 (h), which is the time that has elapsed until the measured luminance decreases to 95% of the initial luminance, of Light-Emitting Device 4B was 80 hours. The LT95 of Comparative Light-Emitting Device 4D was 50 hours.

Thus, it was confirmed that by including the deuterium-containing organic compound of one embodiment of the present invention, a light-emitting device can have emission efficiency as high as that of a comparative light-emitting device and reliability higher than that of the comparative light-emitting device.

It was also found that Light-Emitting Device 4A and Comparative Light-Emitting Device 4C including 2mPCCzPDBq in the electron-transport layers tend to have higher reliability than Light-Emitting Device 4B and Comparative Light-Emitting Device 4D including 2Ph-4BP-6pmFBPPm in the electron-transport layers. This is because 2Ph-4BP-6pmFBPPm has a higher property of injecting electrons into the light-emitting layer than 2mPCCzPDBq, and thus, carrier recombination is localized at the interface between the electron-blocking layer and the light-emitting layer to promote degradation.

### Example 10

In this example, Light-Emitting Device 5A and Light-Emitting Device 5B of embodiments of the present invention were fabricated. Furthermore, Comparative Light-Emitting Device 5C and Comparative Light-Emitting Device 5D were fabricated.

Specifically, N-[4-(1-naphthyl-2,3,4,5,6,7,8-d₇)phenyl-2,3,5,6-d₄]—N-[(9,9′-spirobi[9H-fluoren]-1,1′,2′,3,3′,4,4′,5,5′,6,6′,7,7′,8,8′-d₁₅)-2-yl]-6-(phenyl-2,3,4,5,6-d₅)(benzo[b]naphtho[1,2-d]furan-1,2,3,4,5,9,10,11-d₈)-8-amine (abbreviation: SFNBBnf-d39) represented by Structural Formula (153) in Embodiment 2 was used for a hole-transport layer of each of Light-Emitting Devices 5A and 5B.

Meanwhile, N-[4-(1-naphthyl)phenyl]-N-(9,9′-spirobi[9H-fluoren]-2-yl)-6-phenylbenzo[b]naphtho[1,2-d]furan-8-amine (abbreviation: SFNBBnf) was used for a hole-transport layer of each of Comparative Light-Emitting Devices 5C and 5D.

The structural formulae of organic compounds used in Light-Emitting Devices 5A and 5B and Comparative Light-Emitting Devices 5C and 5D are shown below.

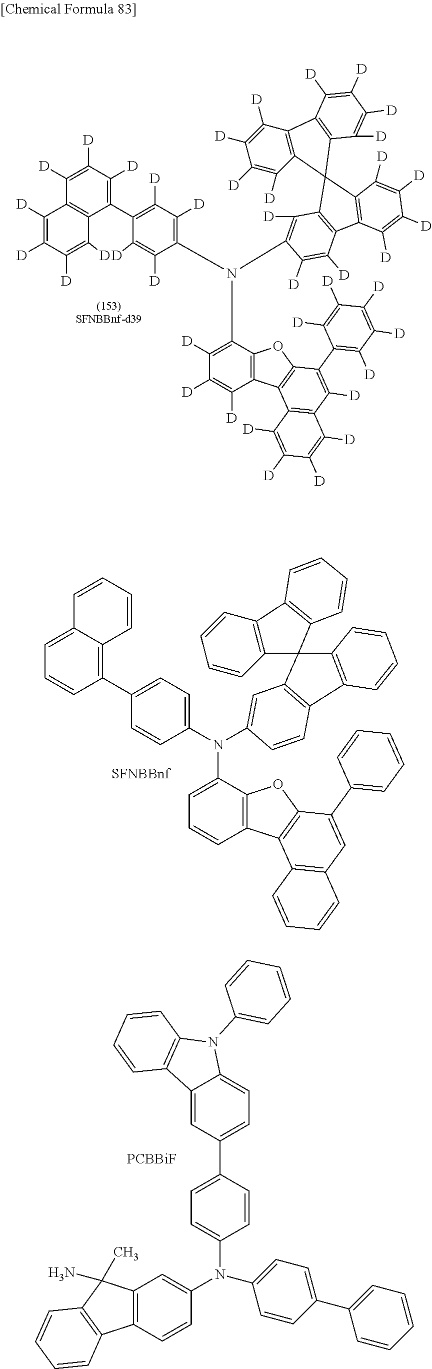

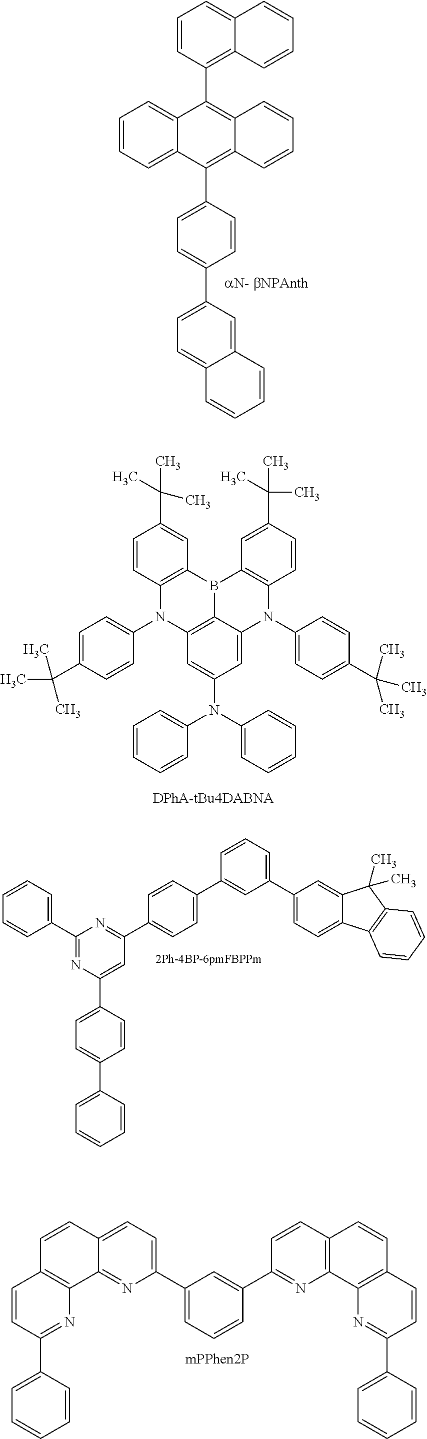

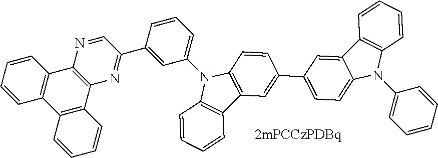 [SMILES: c1ccc(-n2c3ccccc3c3cc(-c4ccc5c(c4)c4ccccc4n5-c4cccc(-c5cnc6c7ccccc7c7ccccc7c6n5)c4)ccc32)cc1]

In each of the devices, as illustrated in FIG. 21, the hole-injection layer 811, the hole-transport layer 812, the light-emitting layer 813, the electron-transport layer 814, and the electron-injection layer 815 are stacked in this order over the first electrode 801 formed over the glass substrate 800, and the second electrode 802 is stacked over the electron-injection layer 815.

### <Method for Fabricating Light-Emitting Device 5A>

As the first electrode 801, a film of indium tin oxide containing silicon oxide (ITSO) was formed to a thickness of 110 nm over the glass substrate 800 by a sputtering method. The electrode area was set to 4 mm² (2 mm×2 mm).

Next, in pretreatment for forming the light-emitting device over the substrate, a surface of the substrate was washed with water, and baking was performed at 200° C. for one hour. Then, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus, followed by natural cooling down to lower than or equal to 30° C.

Next, the substrate provided with the first electrode 801 was fixed to a substrate holder provided in the vacuum evaporation apparatus such that the surface on which the first electrode 801 was formed faced downward. Over the first electrode 801, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material containing fluorine and having a molecular weight of 672 (OCHD-003) were deposited by co-evaporation to a thickness of 10 nm such that the weight ratio of PCBBiF to OCHD-003 was 1:0.03, whereby the hole-injection layer 811 was formed.

Subsequently, over the hole-injection layer 811, PCBBiF was deposited by evaporation using resistance heating to a thickness of 90 nm, and then, N-[4-(1-naphthyl-2,3,4,5,6,7,8-d₇)phenyl-2,3,5,6-d₄]—N-[(9,9′-spirobi[9H-fluoren]-1,1′,2′,3,3′,4,4′,5,5′,6,6′,7,7′,8,8′-d₁₅)-2-yl]-6-(phenyl-2,3,4,5,6-d₅)(benzo[b]naphtho[1,2-d]furan-1,2,3,4,5,9,10,11-d₈)-8-amine (abbreviation: SFNBBnf-d39) represented by Structural Formula (153) was deposited by evaporation using resistance heating to a thickness of 10 nm, so that the hole-transport layer 812 was formed.

Next, over the hole-transport layer 812, 9-(1-naphthyl)-10-[4-(2-naphthyl)phenyl]anthracene (abbreviation: αN-βNPAnth) and 2,12-di(tert-butyl)-5,9-di(4-tert-butylphenyl)-N,N′-diphenyl-5H,9H-[1,4]benzazaborino[2,3,4-kl]phenazaborin-7-amine (abbreviation: DPhA-tBu4DABNA) were deposited by co-evaporation using resistance heating to a thickness of 25 nm such that the weight ratio of αN-βNPAnth to DPhA-tBu4DABNA was 1:0.015, whereby the light-emitting layer 813 was formed.

Next, over the light-emitting layer 813, 2-{3-[3-(N-phenyl-9H-carbazol-3-yl)-9H-carbazol-9-yl]phenyl}dibenzo[f,h]quinoxaline (abbreviation: 2mPCCzPDBq) was deposited by evaporation to a thickness of 10 nm, and then 2,2′-(1,3-phenylene)bis(9-phenyl-1,10-phenanthroline) (abbreviation: mPPhen2P) was deposited by evaporation to a thickness of 15 nm, so that the electron-transport layer 814 was formed.

Next, lithium fluoride (LiF) was deposited by evaporation to a thickness of 1 nm over the electron-transport layer 814, so that the electron-injection layer 815 was formed.

Then, aluminum (Al) was deposited by evaporation to a thickness of 120 nm over the electron-injection layer 815, so that the second electrode 802 was formed.

### <Method for Fabricating Light-Emitting Device 5B>

Next, a method for fabricating Light-Emitting Device 5B is described. Light-Emitting Device 5B is different from Light-Emitting Device 5A in the structure of the electron-transport layer 814.

In Light-Emitting Device 5B, the electron-transport layer 814 was formed in the following manner: over the light-emitting layer 813, 4-(biphenyl-4-yl)-6-[3′-(9,9-dimethyl-9H-fluoren-2-yl)biphenyl-4-yl]-2-phenylpyrimidine (abbreviation: 2Ph-4BP-6pmFBPPm) was deposited by evaporation using resistance heating to a thickness of 10 nm, and then, mPPhen2P was deposited by evaporation using resistance heating to a thickness of 15 nm.

The other components were formed in a manner similar to that for Light-Emitting Device 5A.

### <Method for Fabricating Comparative Light-Emitting Device 5C>

Next, a method for fabricating Comparative Light-Emitting Device 5C is described. Comparative Light-Emitting Device 5C is different from Light-Emitting Device 5A in the structure of the hole-transport layer 812.

In Comparative Light-Emitting Device 5C, the hole-transport layer 812 was formed in the following manner: over the hole-injection layer 811, PCBBiF was deposited by evaporation using resistance heating to a thickness of 90 nm, and then, N-[4-(1-naphthyl)phenyl]-N-(9,9′-spirobi[9H-fluoren]-2-yl)-6-phenylbenzo[b]naphtho[1,2-d]furan-8-amine (abbreviation: SFNBBnf) was deposited by evaporation using resistance heating to a thickness of 10 nm.

The other components were formed in a manner similar to that for Light-Emitting Device 5A.

### <Method for Fabricating Comparative Light-Emitting Device 5D>

Next, a method for fabricating Comparative Light-Emitting Device 5D is described. Comparative Light-Emitting Device 5D is different from Light-Emitting Device 5B in the structure of the hole-transport layer 812.

In Comparative Light-Emitting Device 5D, the hole-transport layer 812 was formed in the following manner: over the hole-injection layer 811, PCBBiF was deposited by evaporation using resistance heating to a thickness of 90 nm, and then, SFNBBnf was deposited by evaporation using resistance heating to a thickness of 10 nm.

The other components were formed in a manner similar to that for Light-Emitting Device 5B.

The structures of Light-Emitting Devices 5A and 5B and Comparative Light-Emitting Devices 5C and 5D are listed in the following table.

TABLE 10

| | | | | Comparative | Comparative |
|---|---|---|---|---|---|
| | Thickness | Light-Emitting | Light-Emitting | Light-Emitting | Light-Emitting |
| | [nm] | Device 5A | Device 5B | Device 5C | Device 5D |
| Second electrode | 120 | Al | | | |
| Electron-injection | 1 | LiF | | | |
| layer | | | | | |
| Electron-transport | 15 | mPPhen2P | | | |
| layer | 10 | 2mPCCzPDBq | 2Ph-4BP-6pmFBPPm | 2mPCCzPDBq | 2Ph-4BP-6pmFBPPm |

| Light-emitting layer | 25 | αN-βNPAnth:DPhA-tBu4DABNA (1:0.015) | |
|---|---|---|---|
| Hole-transport layer | 10 | SFNBBnf-d39 | SFNBBnf |

| | | |
|---|---|---|
| | 90 | PCBBiF |
| Hole-injection layer | 10 | PCBBiF:OCHD-003 (1:0.03) |
| First electrode | 110 | ITSO |

### <Light-Emitting Device Characteristics>

The light-emitting devices were sealed using a glass substrate in a glove box containing a nitrogen atmosphere so as not to be exposed to the air (a sealing material was applied to surround the devices, and UV treatment and heat treatment at 80° C. for one hour were performed at the time of sealing). Then, the characteristics of the light-emitting devices were measured.

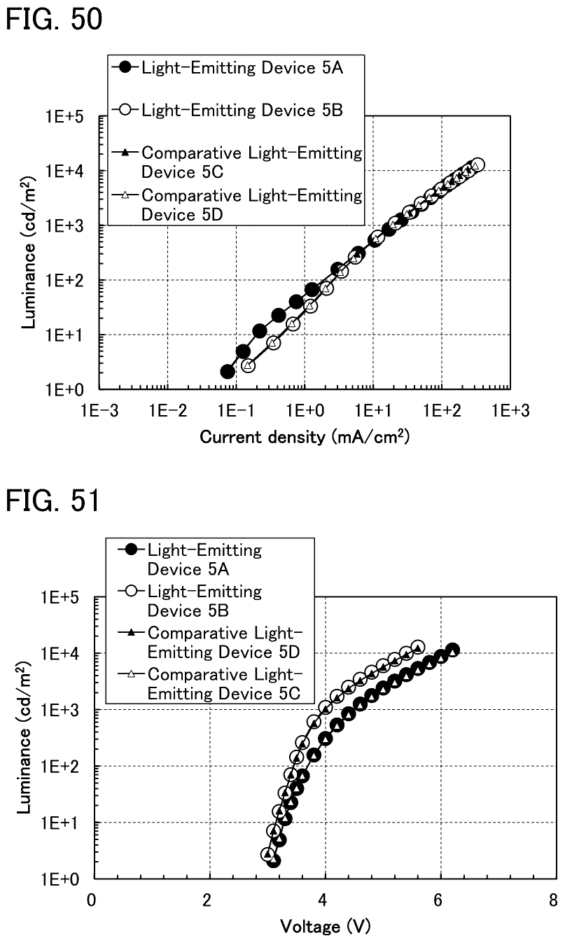

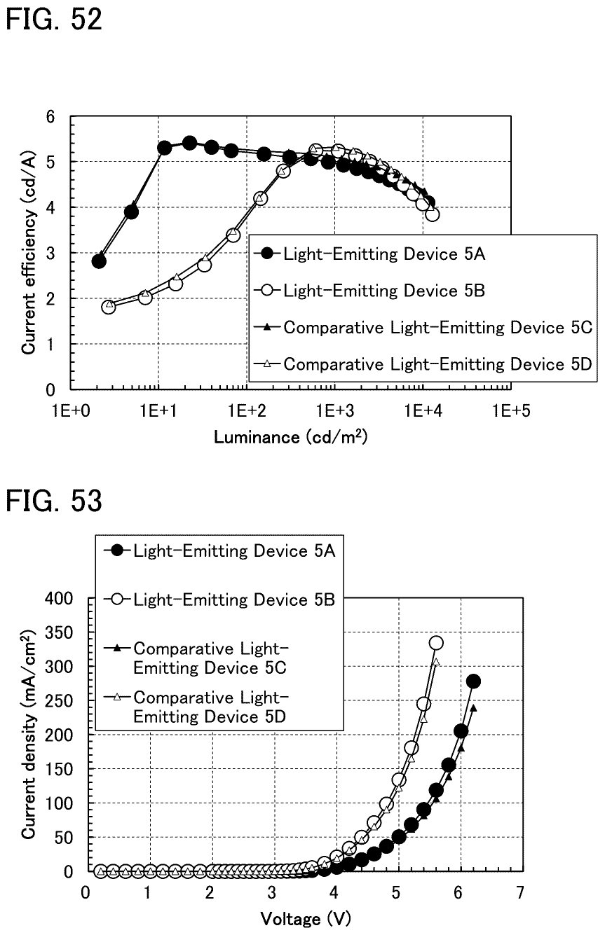

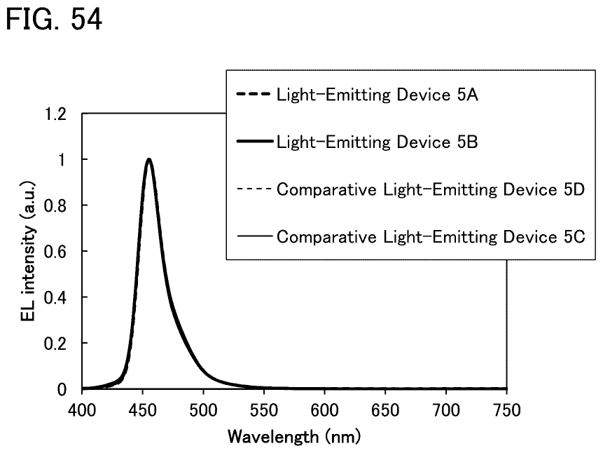

FIG. 50 shows the luminance-current density characteristics of the light-emitting devices. FIG. 51 shows the luminance-voltage characteristics of the light-emitting devices. FIG. 52 shows the current efficiency-luminance characteristics of the light-emitting devices. FIG. 53 shows the current density-voltage characteristics of the light-emitting devices. FIG. 54 shows the electroluminescence spectra of the light-emitting devices.

The main characteristics of the devices at a luminance of approximately 1000 cd/m² are shown in the table below. The luminance, CIE chromaticity, and electroluminescence spectra were measured with a spectroradiometer (SR-UL1R, TOPCON TECHNOHOUSE CORPORATION).

TABLE 11

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Light-Emitting | 4.40 | 0.677 | 16.9 | 0.142 | 0.0568 | 845 | 4.99 |
| Device 5A | | | | | | | |
| Light-Emitting | 4.00 | 0.835 | 20.9 | 0.142 | 0.0553 | 1090 | 5.23 |
| Device 5B | | | | | | | |
| Comparative Light- | 4.40 | 0.632 | 15.8 | 0.141 | 0.0581 | 809 | 5.12 |
| Emitting Device 5C | | | | | | | |
| Comparative Light- | 4.00 | 0.773 | 19.3 | 0.142 | 0.0569 | 1030 | 5.32 |
| Emitting Device 5D | | | | | | | |

FIG. 50 to FIG. 54 show that Light-Emitting Device 5A has efficiency as high as that of Comparative Light-Emitting Device 5C, and Light-Emitting Device 5B has efficiency as high as that of Comparative Light-Emitting Device 5D.

In each of Light-Emitting Device 5A and Comparative Light-Emitting Device 5C including 2mPCCzPDBq in the electron-transport layers, the property of injecting electrons into the light-emitting layer was low, and favorable carrier balance with holes and resultantly high efficiency were achieved at around 20 cd/m². In each of Light-Emitting Device 5B and Comparative Light-Emitting Device 5D including 2Ph-4BP-6pmFBPPm in the electron-transport layers, the property of injecting electrons into the light-emitting layer was high, and favorable carrier balance with holes and resultantly high efficiency were achieved at around 1000 cd/m².

It was thus confirmed that SFNBBnf-d39, which is a deuterium-containing organic compound, can be suitably used for a light-emitting device.

### <Results of Reliability Test>

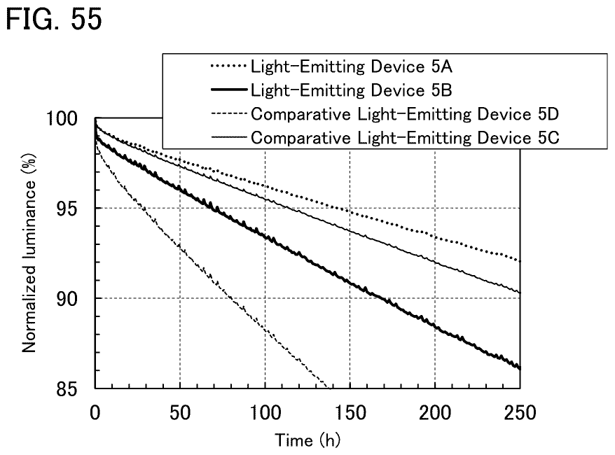

A reliability test was conducted on Light-Emitting Device 5A. FIG. 55 shows a time-dependent change in normalized luminance at the time of constant current density driving (50 [mA/cm²]). In FIG. 55, the vertical axis represents the luminance (%) normalized with the luminance at the time of the start of light emission being regarded as 100%, and the horizontal axis represents time (h).

As shown in FIG. 55, the LT95 (h), which is the time that has elapsed until the measured luminance decreases to 95% of the initial luminance, of Light-Emitting Device 5A was 143 hours. The LT95 of Comparative Light-Emitting Device 5C was 114 hours.

As shown in FIG. 55, the LT95 (h), which is the time that has elapsed until the measured luminance decreases to 95% of the initial luminance, of Light-Emitting Device 5B was 69 hours. The LT95 of Comparative Light-Emitting Device 5D was 29.5 hours.

Thus, it was confirmed that by including the deuterium-containing organic compound of one embodiment of the present invention, a light-emitting device can have emission efficiency as high as that of a comparative light-emitting device and reliability higher than that of the comparative light-emitting device.

It was also found that Light-Emitting Device 5A and Comparative Light-Emitting Device 5C including 2mPCCzPDBq in the electron-transport layers tend to have higher reliability than Light-Emitting Device 5B and Comparative Light-Emitting Device 5D including 2Ph-4BP-6pmFBPPm in the electron-transport layers. This is because 2Ph-4BP-6pmFBPPm has a higher property of injecting electrons into the light-emitting layer than 2mPCCzPDBq, and thus, carrier recombination is localized at the interface between the electron-blocking layer and the light-emitting layer to promote degradation.

### Example 11

In this example, Light-Emitting Device 6A and Light-Emitting Device 6B of embodiments of the present invention were fabricated. Furthermore, Comparative Light-Emitting Device 6C and Comparative Light-Emitting Device 6D were fabricated.

Specifically, N-[4-(1-naphthyl-2,3,4,5,6,7,8-d₇)phenyl-2,3,5,6-d₄]—N-[(9,9′-spirobi[9H-fluoren]-1,1′,2′,3,3′,4,4′,5,5′,6,6′,7,7′,8,8′-d₁₅)-2-yl]-6-(phenyl-2,3,4,5,6-d₅)(benzo[b]naphtho[1,2-d]furan-1,2,3,4,5,9,10,11-d₈)-8-amine (abbreviation: SFNBBnf-d39) represented by Structural Formula (153) in Embodiment 2 was used for a hole-transport layer of each of Light-Emitting Devices 6A and 6B.

Meanwhile, N-[4-(1-naphthyl)phenyl]-N-(9,9′-spirobi[9H-fluoren]-2-yl)benzo[b]naphtho[2,1-d]furan-10-amine (abbreviation: SFNBaBnf(10)) was used for a hole-transport layer of each of Comparative Light-Emitting Devices 6C and 6D.

The structural formulae of organic compounds used in Light-Emitting Devices 6A and 6B and Comparative Light-Emitting Devices 6C and 6D are shown below.

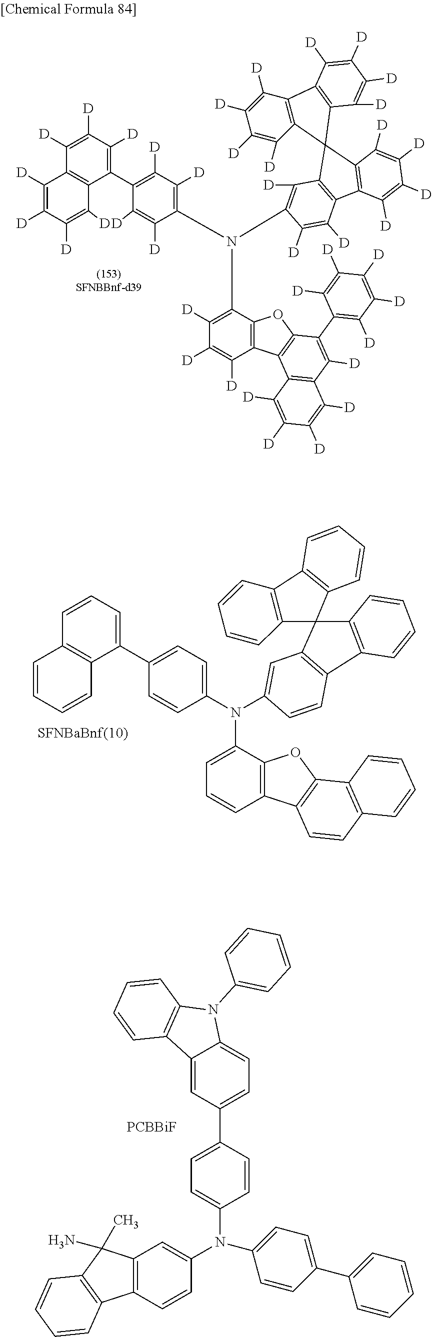

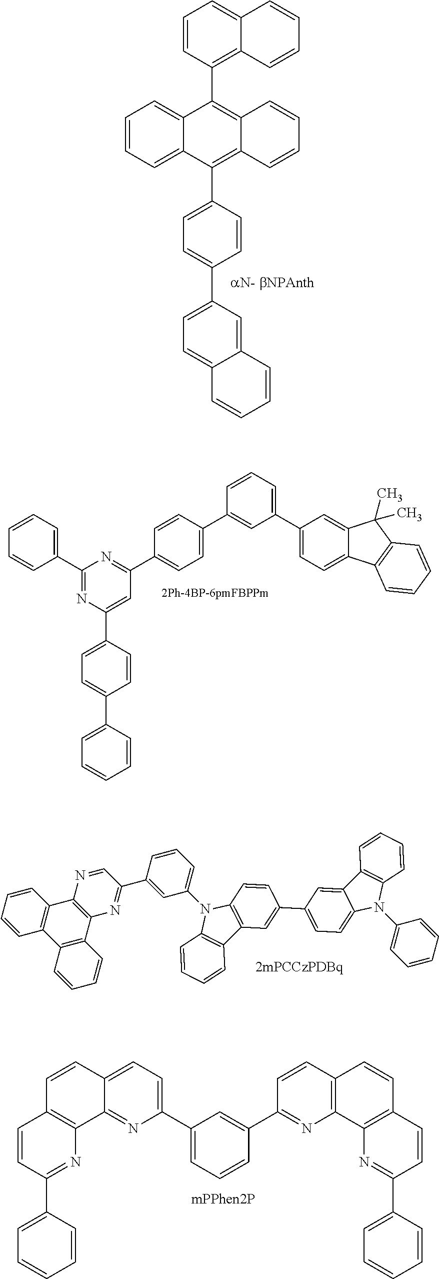

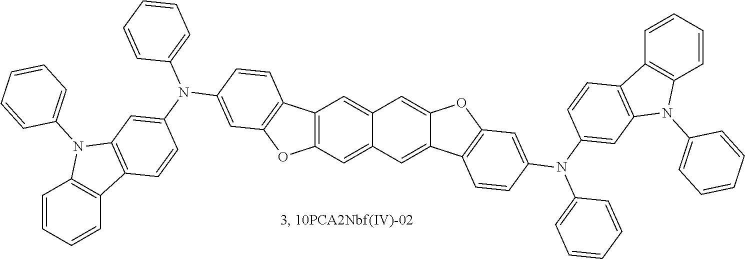 [SMILES: c1ccc(N(c2ccc3c(c2)oc2cc4cc5c(cc4cc23)oc2cc(N(c3ccccc3)c3ccc4c6ccccc6n(-c6ccccc6)c4c3)ccc25)c2ccc3c4ccccc4n(-c4ccccc4)c3c2)cc1]

In each of the devices, as illustrated in FIG. 21, the hole-injection layer 811, the hole-transport layer 812, the light-emitting layer 813, the electron-transport layer 814, and the electron-injection layer 815 are stacked in this order over the first electrode 801 formed over the glass substrate 800, and the second electrode 802 is stacked over the electron-injection layer 815.

### <Method for Fabricating Light-Emitting Device 6A>

As the first electrode 801, a film of indium tin oxide containing silicon oxide (ITSO) was formed to a thickness of 110 nm over the glass substrate 800 by a sputtering method. The electrode area was set to 4 mm² (2 mm×2 mm).

Next, in pretreatment for forming the light-emitting device over the substrate, a surface of the substrate was washed with water, and baking was performed at 200° C. for one hour. Then, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus, followed by natural cooling down to lower than or equal to 30° C.

Next, the substrate provided with the first electrode 801 was fixed to a substrate holder provided in the vacuum evaporation apparatus such that the surface on which the first electrode 801 was formed faced downward. Over the first electrode 801, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material containing fluorine and having a molecular weight of 672 (OCHD-003) were deposited by co-evaporation to a thickness of 10 nm such that the weight ratio of PCBBiF to OCHD-003 was 1:0.03, whereby the hole-injection layer 811 was formed.

Subsequently, over the hole-injection layer 811, PCBBiF was deposited by evaporation using resistance heating to a thickness of 90 nm, and then, N-[4-(1-naphthyl-2,3,4,5,6,7,8-d₇)phenyl-2,3,5,6-d₄]—N-[(9,9′-spirobi[9H-fluoren]-1,1′,2′,3,3′,4,4′,5,5′,6,6′,7,7′,8,8′-d₁₅)-2-yl]-6-(phenyl-2,3,4,5,6-d₅)(benzo[b]naphtho[1,2-d]furan-1,2,3,4,5,9,10,11-d₈)-8-amine (abbreviation: SFNBBnf-d39) represented by Structural Formula (153) was deposited by evaporation using resistance heating to a thickness of 10 nm, so that the hole-transport layer 812 was formed.

Next, over the hole-transport layer 812, 9-(1-naphthyl)-10-[4-(2-naphthyl)phenyl]anthracene (abbreviation: αN-βNPAnth) and N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02) were deposited by co-evaporation using resistance heating to a thickness of 25 nm sch that the weight ratio of αN-βNPAnth to 3,10PCA2Nbf(IV)-02 was 1:0.015, whereby the light-emitting layer 813 was formed.

Next, over the light-emitting layer 813, 2-{3-[3-(N-phenyl-9H-carbazol-3-yl)-9H-carbazol-9-yl]phenyl}dibenzo[f,h]quinoxaline (abbreviation: 2mPCCzPDBq) was deposited by evaporation to a thickness of 10 nm, and then 2,2′-(1,3-phenylene)bis(9-phenyl-1,10-phenanthroline) (abbreviation: mPPhen2P) was deposited by evaporation to a thickness of 15 nm, so that the electron-transport layer 814 was formed.

Next, lithium fluoride (LiF) was deposited by evaporation to a thickness of 1 nm over the electron-transport layer 814, so that the electron-injection layer 815 was formed.

Then, aluminum (Al) was deposited by evaporation to a thickness of 120 nm over the electron-injection layer 815, so that the second electrode 802 was formed.

### <Method for Fabricating Light-Emitting Device 6B>

Next, a method for fabricating Light-Emitting Device 6B is described. Light-Emitting Device 6B is different from Light-Emitting Device 6A in the structure of the electron-transport layer 814.

In Light-Emitting Device 6B, the electron-transport layer 814 was formed in the following manner: over the light-emitting layer 813, 4-(biphenyl-4-yl)-6-[3′-(9,9-dimethyl-9H-fluoren-2-yl)biphenyl-4-yl]-2-phenylpyrimidine (abbreviation: 2Ph-4BP-6pmFBPPm) was deposited by evaporation using resistance heating to a thickness of 10 nm, and then, mPPhen2P was deposited by evaporation using resistance heating to a thickness of 15 nm.

The other components were formed in a manner similar to that for Light-Emitting Device 6A.

### <Method for Fabricating Comparative Light-Emitting Device 6C>

Next, a method for fabricating Comparative Light-Emitting Device 6C is described. Comparative Light-Emitting Device 6C is different from Light-Emitting Device 6A in the structure of the hole-transport layer 812.

In Comparative Light-Emitting Device 6C, the hole-transport layer 812 was formed in the following manner: over the hole-injection layer 811, PCBBiF was deposited by evaporation using resistance heating to a thickness of 90 nm, and then, N-[4-(1-naphthyl)phenyl]-N-(9,9′-spirobi[9H-fluoren]-2-yl)benzo[b]naphtho[2,1-d]furan-10-amine (abbreviation: SFNBaBnf(10)) was deposited by evaporation using resistance heating to a thickness of 10 nm.

The other components were formed in a manner similar to that for Light-Emitting Device 6A.

### <Method for Fabricating Comparative Light-Emitting Device 6D>

Next, a method for fabricating Comparative Light-Emitting Device 6D is described. Comparative Light-Emitting Device 6D is different from Light-Emitting Device 6B in the structure of the hole-transport layer 812.

In Comparative Light-Emitting Device 6D, the hole-transport layer 812 was formed in the following manner: over the hole-injection layer 811, PCBBiF was deposited by evaporation using resistance heating to a thickness of 90 nm, and then, SFNBaBnf(10) was deposited by evaporation using resistance heating to a thickness of 10 nm.

The other components were formed in a manner similar to that for Light-Emitting Device 6B.

The structures of Light-Emitting Devices 6A and 6B and Comparative Light-Emitting Devices 6C and 6D are listed in the following table.

TABLE 12

| | | | | Comparative | Comparative |
|---|---|---|---|---|---|
| | Thickness | Light-Emitting | Light-Emitting | Light-Emitting | Light-Emitting |
| | [nm] | Device 6A | Device 6B | Device 6C | Device 6D |
| Second electrode | 120 | Al | | | |
| Electron-injection | 1 | LiF | | | |
| layer | | | | | |
| Electron-transport | 15 | mPPhen2P | | | |
| layer | 10 | 2mPCCzPDBq | 2Ph-4BP-6pmFBPPm | 2mPCCzPDBq | 2Ph-4BP-6pmFBPPm |

| Light-emitting layer | 25 | αN-βNPAnth:3,10PCA2Nbf(IV)-02 (1:0.015) | |
|---|---|---|---|
| Hole-transport layer | 10 | SFNBBnf-d39 | SFNBaBnf(10) |

| | | |
|---|---|---|
| | 90 | PCBBiF |
| Hole-injection layer | 10 | PCBBiF:OCHD-003 (1:0.03) |
| First electrode | 110 | ITSO |

### <Light-Emitting Device Characteristics>

The light-emitting devices were sealed using a glass substrate in a glove box containing a nitrogen atmosphere so as not to be exposed to the air (a sealing material was applied to surround the devices, and UV treatment and heat treatment at 80° C. for one hour were performed at the time of sealing). Then, the characteristics of the light-emitting devices were measured.

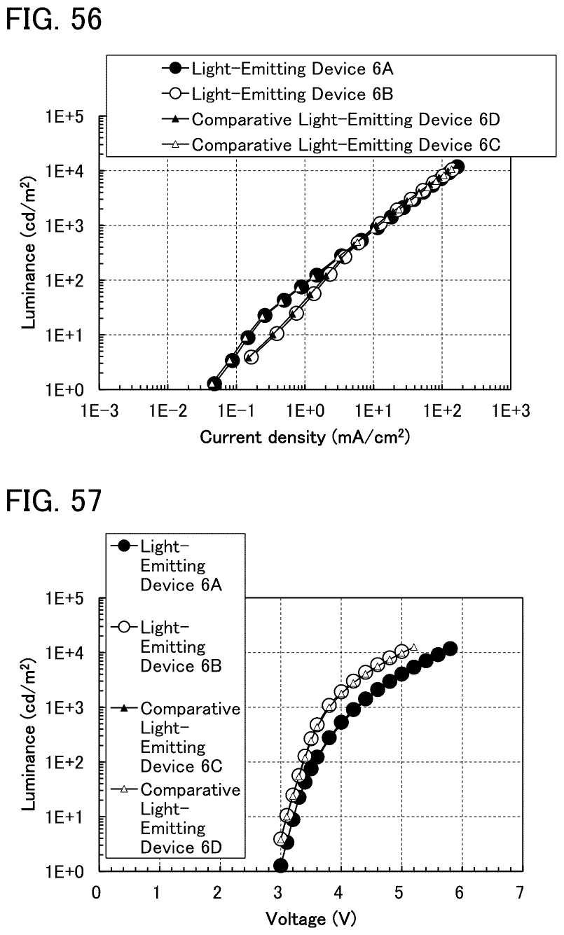

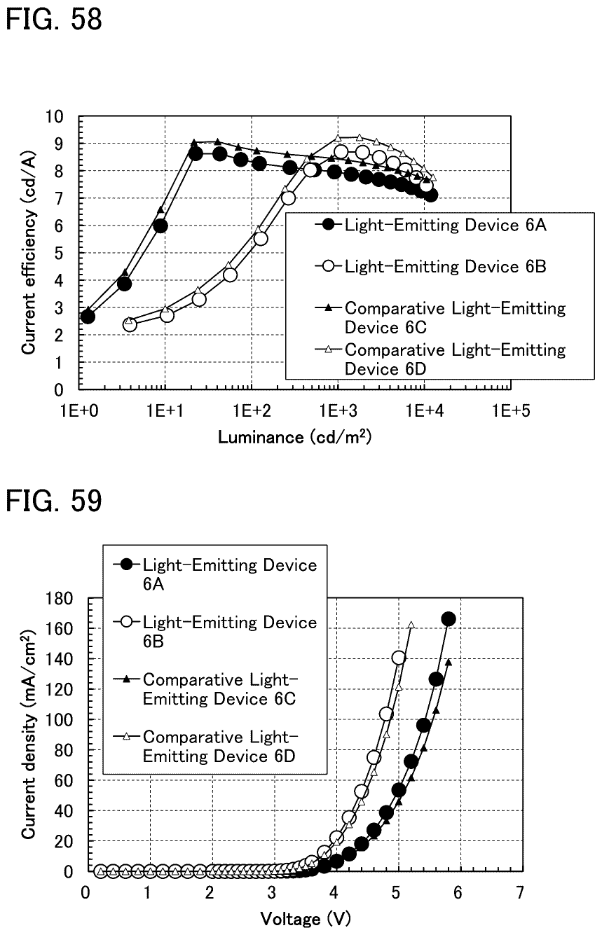

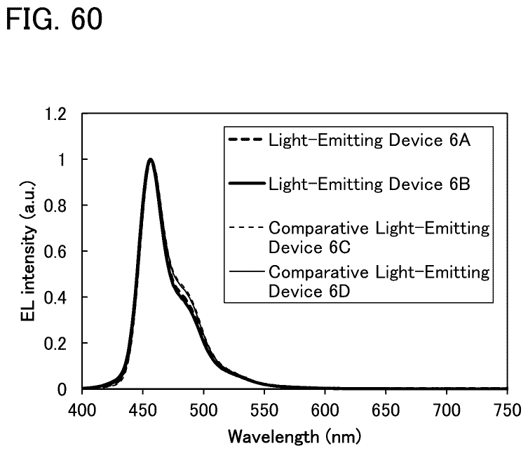

FIG. 56 shows the luminance-current density characteristics of the light-emitting devices. FIG. 57 shows the luminance-voltage characteristics of the light-emitting devices. FIG. 58 shows the current efficiency-luminance characteristics of the light-emitting devices. FIG. 59 shows the current density-voltage characteristics of the light-emitting devices. FIG. 60 shows the electroluminescence spectra of the light-emitting devices.

The main characteristics of the devices at a luminance of approximately 1000 cd/m² are shown in the table below. The luminance, CIE chromaticity, and electroluminescence spectra were measured with a spectroradiometer (SR-UL1R, TOPCON TECHNOHOUSE CORPORATION).

TABLE 13

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Light-Emitting | 4.20 | 0.456 | 11.4 | 0.139 | 0.0964 | 908 | 7.96 |
| Device 6A | | | | | | | |
| Light-Emitting | 3.80 | 0.500 | 12.5 | 0.140 | 0.0931 | 1090 | 8.69 |
| Device 6B | | | | | | | |
| Comparative Light- | 4.20 | 0.398 | 9.94 | 0.137 | 0.104 | 841 | 8.46 |
| Emitting Device 6C | | | | | | | |
| Comparative Light- | 3.80 | 0.434 | 10.9 | 0.138 | 0.102 | 999 | 9.21 |
| Emitting Device 6D | | | | | | | |

FIG. 56 to FIG. 60 show that Light-Emitting Device 6A has efficiency as high as that of Comparative Light-Emitting Device 6C, and Light-Emitting Device 6B has efficiency as high as that of Comparative Light-Emitting Device 6D.

In each of Light-Emitting Device 6A and Comparative Light-Emitting Device 6C including 2mPCCzPDBq in the electron-transport layers, the property of injecting electrons into the light-emitting layer was low, and favorable carrier balance with holes and resultantly high efficiency were achieved at around 20 cd/m². In each of Light-Emitting Device 6B and Comparative Light-Emitting Device 6D including 2Ph-4BP-6pmFBPPm in the electron-transport layers, the property of injecting electrons into the light-emitting layer was high, and favorable carrier balance with holes and resultantly high efficiency were achieved at around 1000 cd/m².

It was thus confirmed that SFNBBnf-d39, which is a deuterium-containing organic compound, can be suitably used for a light-emitting device.

### <Results of Reliability Test>

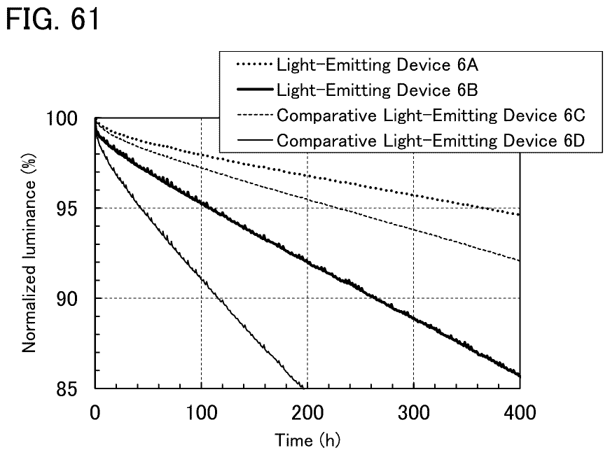

A reliability test was conducted on Light-Emitting Device 6A. FIG. 61 shows a time-dependent change in normalized luminance at the time of constant current density driving (50 [mA/cm²]). In FIG. 61, the vertical axis represents the luminance (%) normalized with the luminance at the time of the start of light emission being regarded as 100%, and the horizontal axis represents time (h).

As shown in FIG. 61, the LT95 (h), which is the time that has elapsed until the measured luminance decreases to 95% of the initial luminance, of Light-Emitting Device 6A was 365 hours. The LT95 of Comparative Light-Emitting Device 6C was 228 hours.

As shown in FIG. 61, the LT95 (h), which is the time that has elapsed until the measured luminance decreases to 95% of the initial luminance, of Light-Emitting Device 6B was 107 hours. The LT95 of Comparative Light-Emitting Device 6D was 43 hours.

Thus, it was confirmed that by including the deuterium-containing organic compound of one embodiment of the present invention, a light-emitting device can have emission efficiency as high as that of a comparative light-emitting device and reliability higher than that of the comparative light-emitting device.

It was also found that Light-Emitting Device 6A and Comparative Light-Emitting Device 6C including 2mPCCzPDBq in the electron-transport layers tend to have higher reliability than Light-Emitting Device 6B and Comparative Light-Emitting Device 6D including 2Ph-4BP-6pmFBPPm in the electron-transport layers. This is because 2Ph-4BP-6pmFBPPm has a higher property of injecting electrons into the light-emitting layer than 2mPCCzPDBq, and thus, carrier recombination is localized at the interface between the electron-blocking layer and the light-emitting layer to promote degradation.

This application is based on Japanese Patent Application Serial No. 2024-108609 filed with Japan Patent Office on Jul. 5, 2024 and Japanese Patent Application Serial No. 2024-116109 filed with Japan Patent Office on Jul. 19, 2024, the entire contents of which are hereby incorporated by reference.

What is claimed is:

1. A light-emitting device comprising:
a light-emitting layer and a hole-transport layer between a pair of electrodes,
wherein the light-emitting layer comprises a first compound as a host and a second compound as a guest,
wherein a HOMO level of the second compound is higher than a HOMO level of the first compound, and
wherein the hole-transport layer comprises a third compound comprising deuterium.

2. The light-emitting device according to claim 1,
wherein the hole-transport layer is in contact with the light-emitting layer.

3. The light-emitting device according to claim 1,
wherein a difference between the HOMO level of the first compound and the HOMO level of the second compound is greater than 0.30 eV and less than 0.90 eV, and
wherein the hole-transport layer is in contact with the light-emitting layer.

4. The light-emitting device according to claim 1,
wherein the third compound comprises only one triarylamine skeleton.

5. The light-emitting device according to claim 1,
wherein the third compound is different from the first compound and the second compound.

6. The light-emitting device according to claim 1,
wherein the second compound is a fluorescent compound.

7. The light-emitting device according to claim 1,
wherein the first compound consists only of carbon and hydrogen.

8. The light-emitting device according to claim 1,
wherein the first compound comprises an anthracene skeleton.

9. The light-emitting device according to claim 1, further comprising:
an electron-transport layer between the pair of electrodes,
wherein the electron-transport layer has a stacked-layer structure comprising two or more layers.

10. The light-emitting device according to claim 1,
wherein the third compound is represented by General Formula (G1): 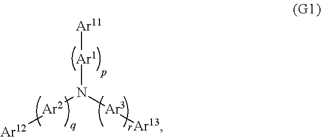
wherein Ar¹ to Ar³ each independently represent a substituted or unsubstituted arylene group having 6 to 30 ring-forming carbon atoms,
wherein Ar¹¹ represents a substituted or unsubstituted aryl group having 6 to 30 ring-forming carbon atoms or a substituted or unsubstituted heteroaryl group having 1 to 30 ring-forming carbon atoms,
wherein Ar¹² represents a group represented by any one of General Formulae (g1) to (g10),
wherein p, q, and r each independently represent an integer of 0 to 4,
wherein the third compound represented by General Formula (G1) comprises one or more deuteriums,
wherein when Ar¹² represents a group represented by General Formula (g1), Ar¹³ represents a group represented by any one of General Formulae (g1) to (g10),
wherein when Ar¹² represents a group represented by any one of General Formulae (g2) to (g10), Ar¹³ represents a substituted or unsubstituted aryl group having 6 to 30 ring-forming carbon atoms or a substituted or unsubstituted heteroaryl group having 1 to 30 ring-forming carbon atoms, 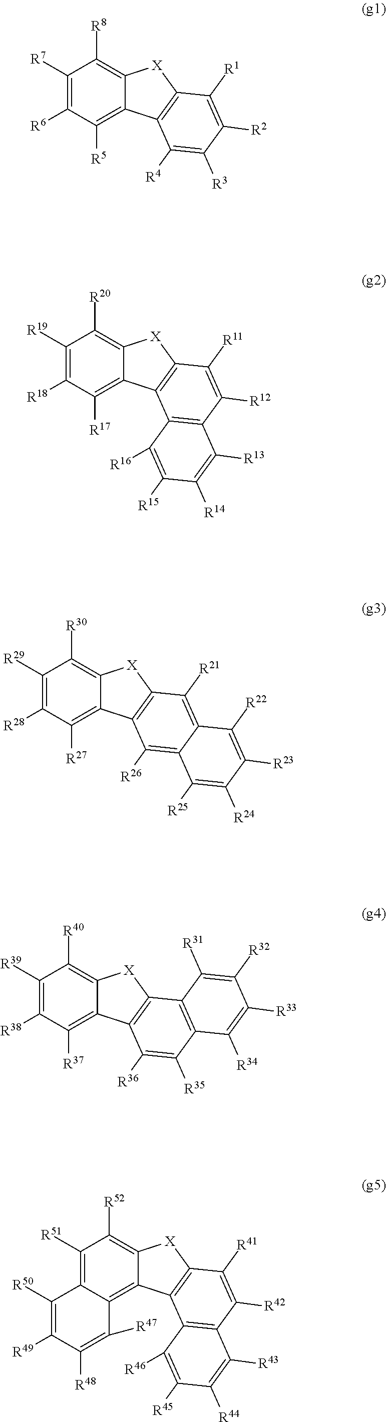 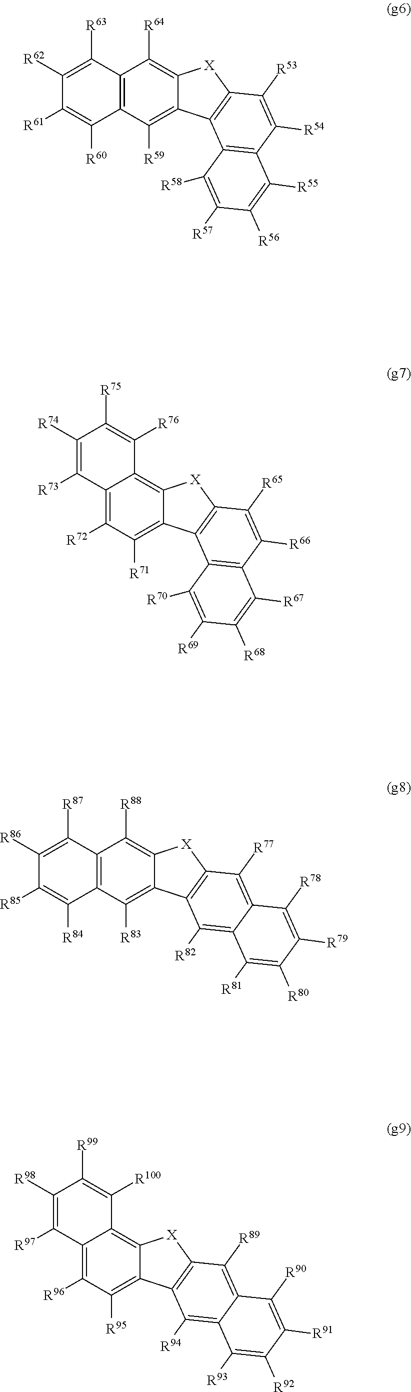 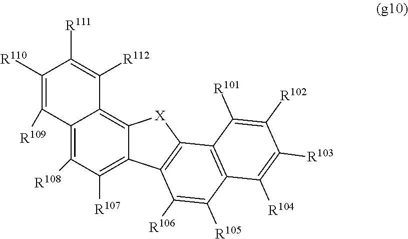
wherein X represents oxygen or sulfur,
wherein R¹ to R⁸ and R¹¹ to R¹¹² each independently represent any one of hydrogen, a straight-chain or branched-chain alkyl group having 1 to 10 carbon atoms, a cycloalkyl group having 3 to 10 carbon atoms, a substituted or unsubstituted aryl group having 6 to 30 carbon atoms, and a substituted or unsubstituted heteroaryl group having 1 to 30 carbon atoms, and
wherein any one of R¹ to R⁸, any one of R¹¹ to R²⁰, any one of R²¹ to R³⁰, any one of R³¹ to R⁴⁰, any one of R⁴¹ to R⁵², any one of R⁵³ to R⁶⁴, any one of R⁶⁵ to R⁷⁶, any one of R⁷⁷ to R⁸⁸, any one of R⁸⁹ to R¹⁰⁰, and any one of R¹⁰¹ to R¹¹² each represent a bond with Ar² or Ar³.

11. A light-emitting device comprising:
a light-emitting layer and a hole-transport layer between a pair of electrodes,
wherein the light-emitting layer comprises a first compound as a host and a second compound as a guest,
wherein the first compound has an electron mobility higher than or equal to 1×10⁻⁷ cm²/Vs when a square root of electric field strength [V/cm] is 600,
wherein the hole-transport layer is in contact with the light-emitting layer, and
wherein the hole-transport layer comprises a third compound comprising deuterium.

12. The light-emitting device according to claim 11,
wherein the third compound comprises only one triarylamine skeleton.

13. The light-emitting device according to claim 11,
wherein the third compound is different from the first compound and the second compound.

14. The light-emitting device according to claim 11,
wherein the second compound is a fluorescent compound.

15. The light-emitting device according to claim 11,
wherein the first compound consists only of carbon and hydrogen.

16. The light-emitting device according to claim 11,
wherein the first compound comprises an anthracene skeleton.

17. The light-emitting device according to claim 11, further comprising:
an electron-transport layer between the pair of electrodes,
wherein the electron-transport layer has a stacked-layer structure comprising two or more layers.

18. The light-emitting device according to claim 11,
wherein the third compound is represented by General Formula (G1): 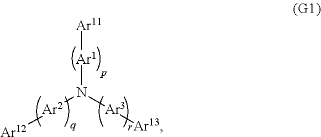
wherein Ar¹ to Ar³ each independently represent a substituted or unsubstituted arylene group having 6 to 30 ring-forming carbon atoms,
wherein Ar¹¹ represents a substituted or unsubstituted aryl group having 6 to 30 ring-forming carbon atoms or a substituted or unsubstituted heteroaryl group having 1 to 30 ring-forming carbon atoms,
wherein Ar¹² represents a group represented by any one of General Formulae (g1) to (g10),
wherein p, q, and r each independently represent an integer of 0 to 4,
wherein the third compound represented by General Formula (G1) comprises one or more deuteriums,
wherein when Ar¹² represents a group represented by General Formula (g1), Ar¹³ represents a group represented by any one of General Formulae (g1) to (g10),
wherein when Ar¹² represents a group represented by any one of General Formulae (g2) to (g10), Ar¹³ represents a substituted or unsubstituted aryl group having 6 to 30 ring-forming carbon atoms or a substituted or unsubstituted heteroaryl group having 1 to 30 ring-forming carbon atoms, 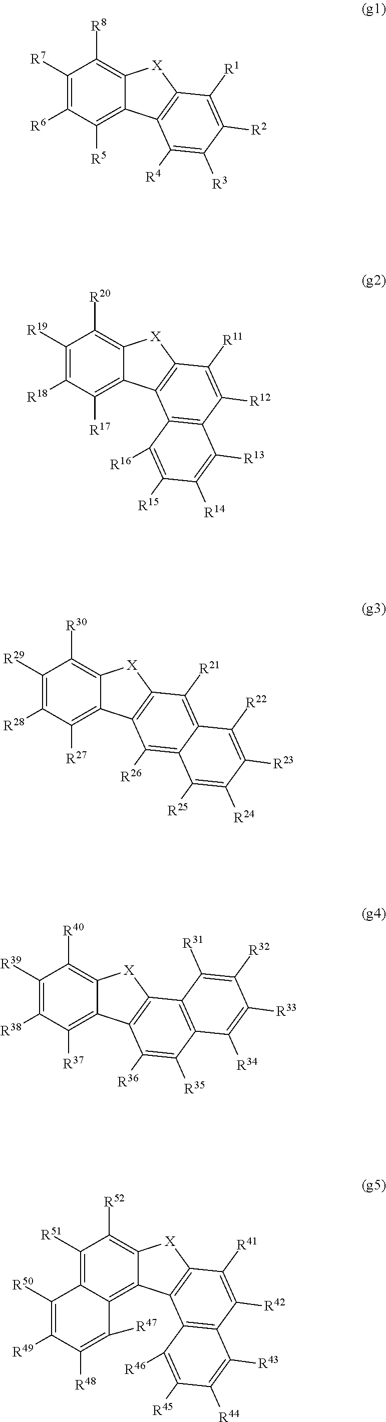 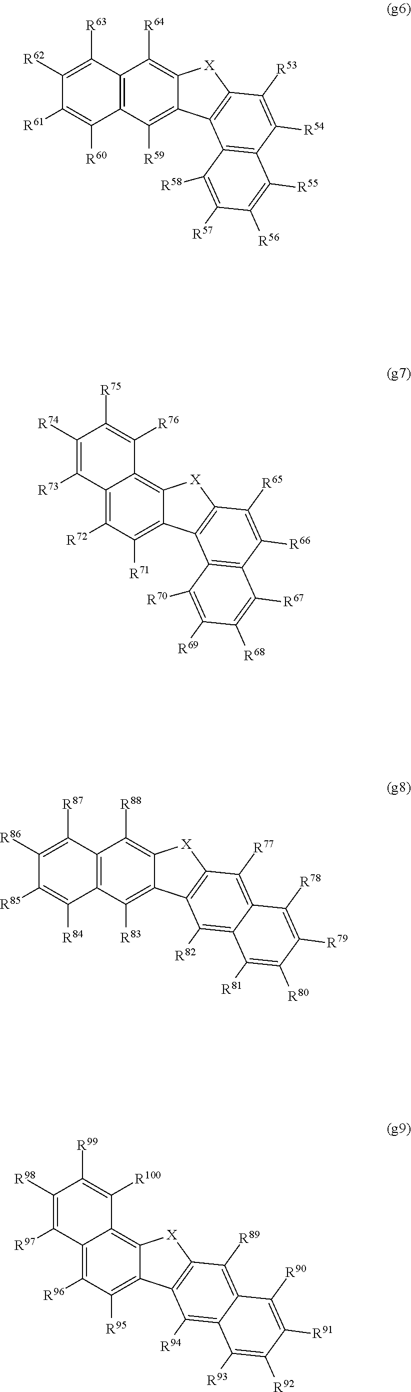 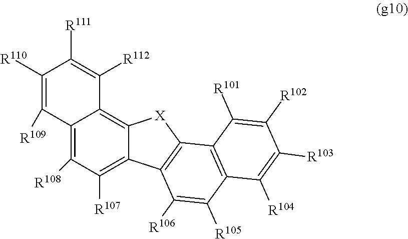
wherein X represents oxygen or sulfur,
wherein R¹ to R⁸ and R¹¹ to R¹¹² each independently represent any one of hydrogen, a straight-chain or branched-chain alkyl group having 1 to 10 carbon atoms, a cycloalkyl group having 3 to 10 carbon atoms, a substituted or unsubstituted aryl group having 6 to 30 carbon atoms, and a substituted or unsubstituted heteroaryl group having 1 to 30 carbon atoms, and
wherein any one of R¹ to R⁸, any one of R¹¹ to R²⁰, any one of R²¹ to R³⁰, any one of R³¹ to R⁴⁰, any one of R⁴¹ to R⁵², any one of R⁵³ to R⁶⁴, any one of R⁶⁵ to R⁷⁶, any one of R⁷⁷ to R⁸⁸, any one of R⁸⁹ to R¹⁰⁰, and any one of R¹⁰¹ to R¹¹² each represent a bond with Ar² or Ar³.

19. A light-emitting device comprising:
a light-emitting layer, a hole-transport layer, a first electron-transport layer, and a second electron-transport layer between a pair of electrodes,
wherein the light-emitting layer comprises a first compound as a host and a second compound as a guest,
wherein the first electron-transport layer is between the light-emitting layer and the second electron-transport layer,
wherein the first electron-transport layer comprises a compound comprising a diazine or triazine skeleton,
wherein the second electron-transport layer comprises a compound comprising a phenanthroline skeleton,
wherein the hole-transport layer is in contact with the light-emitting layer, and
wherein the hole-transport layer comprises a third compound comprising deuterium.

20. The light-emitting device according to claim 19,
wherein the third compound is represented by General Formula (G1): 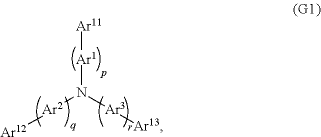
wherein Ar¹ to Ar³ each independently represent a substituted or unsubstituted arylene group having 6 to 30 ring-forming carbon atoms,
wherein Ar¹¹ represents a substituted or unsubstituted aryl group having 6 to 30 ring-forming carbon atoms or a substituted or unsubstituted heteroaryl group having 1 to 30 ring-forming carbon atoms,
wherein Ar¹² represents a group represented by any one of General Formulae (g1) to (g10),
wherein p, q, and r each independently represent an integer of 0 to 4,
wherein the third compound represented by General Formula (G1) comprises one or more deuteriums,
wherein when Ar¹² represents a group represented by General Formula (g1), Ar¹³ represents a group represented by any one of General Formulae (g1) to (g10),
wherein when Ar¹² represents a group represented by any one of General Formulae (g2) to (g10), Ar¹³ represents a substituted or unsubstituted aryl group having 6 to 30 ring-forming carbon atoms or a substituted or unsubstituted heteroaryl group having 1 to 30 ring-forming carbon atoms, 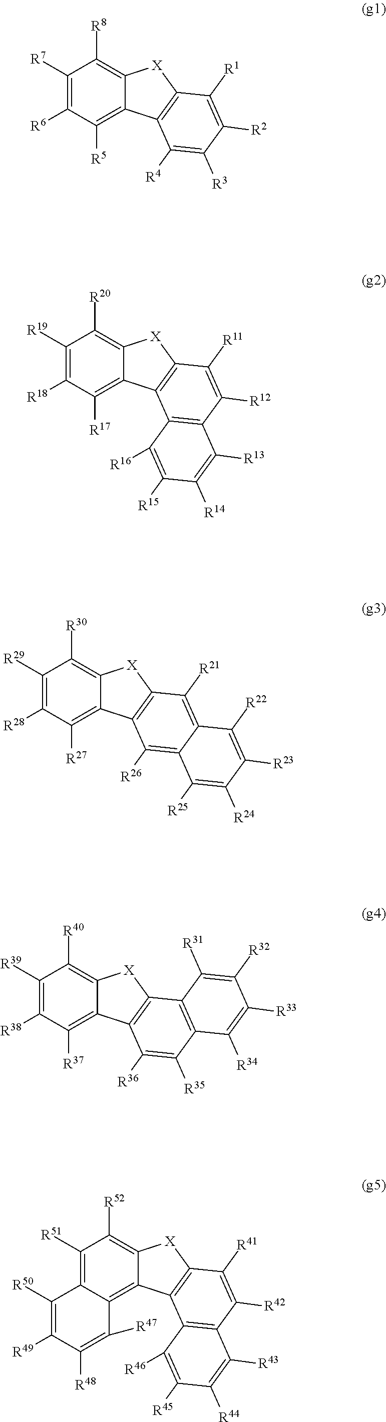 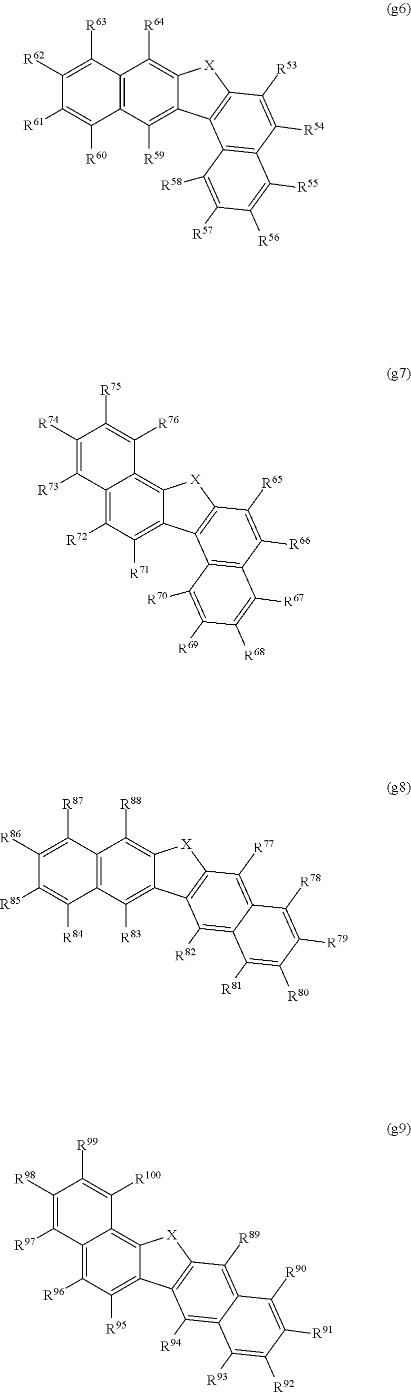 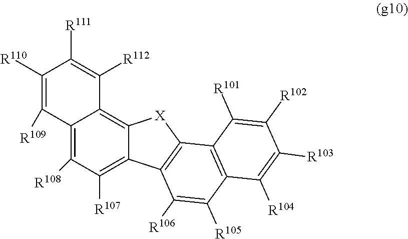
wherein X represents oxygen or sulfur,
wherein R¹ to R⁸ and R¹¹ to R¹¹² each independently represent any one of hydrogen, a straight-chain or branched-chain alkyl group having 1 to 10 carbon atoms, a cycloalkyl group having 3 to 10 carbon atoms, a substituted or unsubstituted aryl group having 6 to 30 carbon atoms, and a substituted or unsubstituted heteroaryl group having 1 to 30 carbon atoms, and
wherein any one of R¹ to R⁸, any one of R¹¹ to R²⁰, any one of R²¹ to R³⁰, any one of R³¹ to R⁴⁰, any one of R⁴¹ to R⁵², any one of R⁵³ to R⁶⁴, any one of R⁶⁵ to R⁷⁶, any one of R⁷⁷ to R⁸⁸, any one of R⁸⁹ to R¹⁰⁰, and any one of R¹⁰¹ to R¹¹² each represent a bond with Ar² or Ar³.
